(19) United States
(12) Patent Application Publication
(10) Pub. No.: US 2023/0038201 A1
(43) Pub. Date: Feb. 9, 2023

(54) TRANSFER FILM, PHOTOSENSITIVE MATERIAL, PATTERN FORMING METHOD, MANUFACTURING METHOD OF CIRCUIT BOARD, AND MANUFACTURING METHOD OF TOUCH PANEL

(71) Applicant: FUJIFILM Corporation, Tokyo (JP)

(72) Inventors: Keigo YAMAGUCHI, Fujinomiya-shi (JP); Kunihiko KODAMA, Fujinomiya-shi (JP); Masaya SUZUKI, Fujinomiya-shi (JP)

(73) Assignee: FUJIFILM Corporation, Tokyo (JP)

(21) Appl. No.: 17/902,404

(22) Filed: Sep. 2, 2022

Related U.S. Application Data
(63) Continuation of application No. PCT/JP2021/011011, filed on Mar. 18, 2021.

(30) Foreign Application Priority Data
Mar. 19, 2020 (JP) 2020-050199
Dec. 25, 2020 (JP) 2020-217873

(51) Int. Cl. G03F 7/038; G03F 7/32

(52) U.S. Cl. CPC G03F 7/038; G03F 7/32; G03F 7/0035

(57) ABSTRACT

A photosensitive material includes: a compound A having a carboxy group, in which the compound A includes a polymer including a repeating unit derived from (meth)acrylic acid, and a content of the carboxy group in a photosensitive layer which is formed from the photosensitive material is reduced by irradiation with an actinic ray or a radiation.

### CROSS-REFERENCE TO RELATED APPLICATIONS

This application is a Continuation of PCT International Application No. PCT/JP2021/011011 filed on Mar. 18, 2021, which claims priority under 35 U.S.C § 119(a) to Japanese Patent Application No. 2020-050199 filed on Mar. 19, 2020, and Japanese Patent Application No. 2020-217873 filed on Dec. 25, 2020. Each of the above application(s) is hereby expressly incorporated by reference, in its entirety, into the present application.

### BACKGROUND OF THE INVENTION

### 1. Field of the Invention

The present invention relates to a transfer film, a photosensitive material, a pattern forming method, a manufacturing method of a circuit board, and a manufacturing method of a touch panel.

### 2. Description of the Related Art

In a display device provided with a touch panel such as a capacitive input device (specifically, a display device such as an organic electroluminescence (EL) display device and a liquid crystal display device), a conductive pattern such as an electrode pattern corresponding to a sensor in a visual recognition portion and a wiring line for a peripheral wiring portion and a lead-out wiring portion is provided inside the touch panel.

Generally, a photosensitive material is used for forming a patterned layer (hereinafter, also simply referred to as a “pattern”), and in particular, since the number of steps to obtain the required pattern shape is small, a method using a transfer film having a temporary support and a photosensitive layer which is formed of the photosensitive material and is disposed on the temporary support. Examples of a method of forming the pattern using a transfer film include a method of exposing and developing a photosensitive layer transferred from a transfer film onto any base material through a mask having a predetermined pattern shape. In the pattern formed on any base material by such a method, in addition to its use as an etching resist film, for example, the pattern may be used as a protective film which protects the conductive pattern (specifically, a protective film (permanent film) which protects the conductive pattern provided inside the above-described touch panel), and it is required to have low moisture permeability.

As the photosensitive material and the transfer film, for example, WO2013/084886A discloses a “photosensitive resin composition containing, on a base material, a binder polymer having a carboxyl group in which an acid value is 75 mgKOH/g or more, a photopolymerizable compound, and a photopolymerization initiator” and a “photosensitive element including a support film and a photosensitive layer consisting of the photosensitive resin composition, which is provided on the support film”.

### SUMMARY OF THE INVENTION

By the way, the transfer film is also required to have excellent resolution (hereinafter, also referred to as “excellent pattern formability”) as basic performance.

In a case of studying the formation of the pattern using the photosensitive element (transfer film) disclosed in WO2013/084886A, the present inventors have found that low moisture permeability does not meet the recent requirements. That is, it is clarified that there is room for studying a transfer film having excellent pattern formability and improved low moisture permeability.

Further, the present inventors also conducted the present study to further improve the pattern formability of the photosensitive material in the study of the photosensitive layer of the transfer film.

Therefore, an object of the present invention is to provide a transfer film with which a pattern having excellent pattern formability and low moisture permeability can be formed.

Another object of the present invention is to provide a photosensitive material having excellent pattern formability.

Another object of the present invention is to provide a pattern forming method, a manufacturing method of a circuit board, and a manufacturing method of a touch panel.

As a result of intensive studies to achieve the above-described objects, the present inventors have found that the above-described objects can be achieved by the following configurations, and have completed the present invention.

[1] A transfer film comprising:

a temporary support; and

a photosensitive layer which is disposed on the temporary support and includes a compound A having an acid group,

in which a content of the acid group in the photosensitive layer is reduced by irradiation with an actinic ray or a radiation.

[2] The transfer film according to [1],

in which the photosensitive layer satisfies any of the following requirement (V01) or the following requirement (W01),

requirement (V01)

the photosensitive layer includes the compound A and a compound β having a structure in which an amount of the acid group included in the compound A is reduced by an exposure,

requirement (W01)

the photosensitive layer includes the compound A, and the compound A further includes a structure in which an amount of the acid group is reduced by an exposure.

[3] The transfer film according to [2],

in which, in the requirement (V01), the compound β is a compound B which has a structure capable of accepting an electron from the acid group included in the compound A in a photoexcited state, and

in the requirement (W01), the structure is a structure capable of accepting an electron from the acid group in a photoexcited state.

[4] The transfer film according to [2] or [3],

in which the requirement (V01) is satisfied,

the compound β is a compound B which has a structure capable of accepting an electron from the acid group included in the compound A in a photoexcited state, and

in the photosensitive layer, a total number of structures capable of accepting the electron, which are included in the compound B, is 1 mol % or more with respect to a total number of acid groups included in the compound A.

[5] The transfer film according to any one of [2] to [4], in which a molar absorption coefficient E of the compound β at 365 nm is 1×10³ (cm·mol/L)⁻¹ or less.

[6] The transfer film according to any one of [2] to [5],

in which a ratio of a molar absorption coefficient E of the compound β at 365 nm to a molar absorption coefficient E′ of the compound β at 313 nm is 3 or less.

[7] The transfer film according to any one of [2] to [6],

in which a pKa of the compound β in a ground state is 2.0 or more.

[8] The transfer film according to any one of [2] to [7],

in which a pKa of the compound β in a ground state is 9.0 or less.

[9] The transfer film according to any one of [2] to [8],

in which the compound β is an aromatic compound which may have a substituent.

[10] The transfer film according to [9],

in which the compound β is an aromatic compound having a substituent.

[11] The transfer film according to any one of [1] to [10],

in which the compound A includes a polymer having a weight-average molecular weight of 50,000 or less.

[12] The transfer film according to any one of [1] to [11],

in which the compound A includes a polymer including a repeating unit derived from (meth)acrylic acid.

[13] The transfer film according to any one of [1] to [12],

in which the photosensitive layer further includes a polymerizable compound.

[14] The transfer film according to any one of [1] to [13],

in which the photosensitive layer further includes a photopolymerization initiator.

[15] The transfer film according to any one of [1] to [14],

in which a relative permittivity of the photosensitive layer is reduced by the irradiation with the actinic ray or the radiation.

[16] The transfer film according to any one of [1] to [15],

in which a transmittance of the photosensitive layer at 365 nm is 65% or more.

[17] The transfer film according to any one of [1] to [16],

in which a ratio of a transmittance of the photosensitive layer at 365 nm to a transmittance of the photosensitive layer at 313 nm is 1.5 or more.

[18] The transfer film according to any one of [1] to [17],

in which the content of the acid group in the photosensitive layer is reduced at a reduction rate of 5 mol % or more by the irradiation with the actinic ray or the radiation.

[19] A pattern forming method comprising:

bringing a surface of the photosensitive layer in the transfer film according to any one of [1] to [18] on an opposite side of a temporary support side into contact with a base material to bond the transfer film and the base material;

exposing the photosensitive layer in a patterned manner; and

developing the exposed photosensitive layer with a developer,

in which, in a case where the developer is an organic solvent-based developer, the method further includes exposing the pattern formed by the development after developing.

[20] A pattern forming method comprising, in the following order:

bringing a surface of the photosensitive layer in the transfer film according to any one of [1] to [18] on an opposite side of a temporary support side into contact with a base material to bond the transfer film and the base material;

exposing the photosensitive layer in a patterned manner;

developing the exposed photosensitive layer with an alkali developer to form a patterned photosensitive layer; and

exposing the patterned photosensitive layer.

[21] A manufacturing method of a circuit wiring, comprising, in the following order:

bringing a surface of the photosensitive layer in the transfer film according to any one of [1] to [18] on an opposite side of a temporary support side into contact with a conductive layer in a substrate having a conductive layer to bond the transfer film and the substrate having the conductive layer;

exposing the photosensitive layer in a patterned manner;

developing the exposed photosensitive layer with an alkali developer to form a patterned photosensitive layer;

exposing the patterned photosensitive layer to form an etching resist film; and

etching the conductive layer in a region on which the etching resist film is not disposed.

[22] A manufacturing method of a touch panel, comprising, in the following order:

bringing a surface of the photosensitive layer in the transfer film according to any one of [1] to [18] on an opposite side of a temporary support side into contact with a conductive layer in a substrate having a conductive layer to bond the transfer film and the substrate having the conductive layer;

exposing the photosensitive layer in a patterned manner;

developing the exposed photosensitive layer with an alkali developer to form a patterned photosensitive layer; and

exposing the patterned photosensitive layer to form a protective film or an insulating film of the conductive layer.

[23] A photosensitive material comprising:

a compound A having a carboxy group,

in which the compound A includes a polymer including a repeating unit derived from (meth)acrylic acid, and

a content of the carboxy group in a photosensitive layer which is formed from the photosensitive material is reduced by irradiation with an actinic ray or a radiation.

[24] The photosensitive material according to [23],

in which a weight-average molecular weight of the polymer is 50,000 or less.

[25] The photosensitive material according to [23] or [24],

in which any of the following requirement (V02) or the following requirement (W02) is satisfied,

requirement (V02): the photosensitive material includes the compound A and a compound β having a structure in which an amount of the carboxy group included in the compound A is reduced by an exposure,

requirement (W02): the photosensitive material includes the compound A, and the compound A includes a structure in which an amount of the carboxy group is reduced by an exposure.

[26] The photosensitive material according to [25],

in which, in the requirement (V02), the compound β is a compound B which has a structure capable of accepting an electron from the carboxy group included in the compound A in a photoexcited state, and

in the requirement (W02), the structure is a structure capable of accepting an electron from the carboxy group in a photoexcited state.

[27] The photosensitive material according to [25] or [26],

in which the requirement (V02) is satisfied,

the compound β is a compound B which has a structure capable of accepting an electron from the carboxy group included in the compound A in a photoexcited state, and

in the photosensitive material, a total number of structures capable of accepting the electron, which are included in the compound B, is 1 mol % or more with respect to a total number of carboxy groups included in the compound A.

[28] The photosensitive material according to any one of [25] to [27], in which a molar absorption coefficient E of the compound β at 365 nm is 1×10³ (cm·mol/L)⁻¹ or less.

[29] The photosensitive material according to any one of [25] to [28],

in which a ratio of a molar absorption coefficient E of the compound β at 365 nm to a molar absorption coefficient E′ of the compound β at 313 nm is 3 or less.

[30] The photosensitive material according to any one of [25] to [29],

in which a pKa of the compound β in a ground state is 2.0 or more.

[31] The photosensitive material according to any one of [25] to [30],

in which a pKa of the compound β in a ground state is 9.0 or less.

[32] The photosensitive material according to any one of [25] to [31],

in which the compound β is an aromatic compound which may have a substituent.

[33] The photosensitive material according to [32],

in which the compound β is an aromatic compound having a substituent.

[34] The photosensitive material according to any one of [23] to [33],

in which the content of the carboxy group in the photosensitive layer which is formed from the photosensitive material is reduced at a reduction rate of 5 mol % or more by the irradiation with the actinic ray or the radiation.

[35] The photosensitive material according to any one of [23] to [34],

in which the carboxy group is decarboxylated by the irradiation with the actinic ray or the radiation.

[36] The photosensitive material according to any one of [23] to [35],

in which a relative permittivity of the photosensitive layer which is formed from the photosensitive material is reduced by the irradiation with the actinic ray or the radiation.

[37] A pattern forming method comprising:

forming a photosensitive layer on a base material by using the photosensitive material according to any one of [23] to [36];

exposing the photosensitive layer in a patterned manner; and

developing the exposed photosensitive layer with a developer, in which, in a case where the developer is an organic solvent-based developer, the method further includes exposing the pattern formed by the development after developing.

[38] A pattern forming method comprising, in the following order:

forming a photosensitive layer on a base material by using the photosensitive material according to any one of [23] to [36];

exposing the photosensitive layer in a patterned manner;

developing the exposed photosensitive layer with an alkali developer to form a patterned photosensitive layer; and

exposing the patterned photosensitive layer.

[39] A manufacturing method of a circuit wiring, comprising, in the following order:

forming a photosensitive layer on a base material having a conductive layer by using the photosensitive material according to any one of [23] to [36];

exposing the photosensitive layer in a patterned manner;

developing the exposed photosensitive layer with an alkali developer to form a patterned photosensitive layer;

exposing the patterned photosensitive layer to form an etching resist film; and

etching the conductive layer in a region on which the etching resist film is not disposed.

[40] A manufacturing method of a touch panel, comprising, in the following order:

forming a photosensitive layer on a base material having a conductive layer by using the photosensitive material according to any one of [23] to [36];

exposing the photosensitive layer in a patterned manner;

developing the exposed photosensitive layer with an alkali developer to form a patterned photosensitive layer; and

exposing the patterned photosensitive layer to form a protective film or an insulating film of the conductive layer.

According to the present invention, it is possible to provide a transfer film with which a pattern having excellent pattern formability and low moisture permeability can be formed.

In addition, according to the present invention, it is possible to provide a photosensitive material having excellent pattern formability.

In addition, according to the present invention, it is possible to provide a pattern forming method, a manufacturing method of a circuit board, and a manufacturing method of a touch panel.

### BRIEF DESCRIPTION OF THE DRAWINGS

FIG. 1 is a schematic view showing an example of a layer configuration of a transfer film according to an embodiment.

### DESCRIPTION OF THE PREFERRED EMBODIMENTS

Hereinafter, the present invention will be described in detail.

In the present specification, a numerical range expressed using “to” means a range that includes the preceding and succeeding numerical values of “to” as a lower limit value and an upper limit value, respectively.

In addition, in a numerical range described in a stepwise manner in the present specification, an upper limit value or a lower limit value described in a certain numerical range may be replaced with an upper limit value or a lower limit value in another numerical range described in a stepwise manner. In addition, regarding the numerical range described in the present specification, an upper limit value or a lower limit value described in a numerical range may be replaced with a value described in Examples.

In addition, a term “step” in the present specification includes not only an independent step but also a step that cannot be clearly distinguished from other steps, as long as the intended purpose of the step is achieved.

In the present specification, “transparent” means that an average transmittance of visible light having a wavelength of 400 nm to 700 nm is 80% or more, preferably 90% or more. Therefore, for example, a “transparent resin layer” refers to a resin layer having an average transmittance of visible light having a wavelength of 400 to 700 nm is 80% or more.

In addition, the average transmittance of visible light is a value measured by using a spectrophotometer, and for example, can be measured by using a spectrophotometer U-3310 manufactured by Hitachi, Ltd.

In the present specification, “actinic ray” or “radiation” means, for example, a bright line spectrum of a mercury lamp such as g-rays, h-rays and i-rays, far ultraviolet rays typified by an excimer laser, extreme ultraviolet rays (EUV light), X-rays, electron beams (EB), or the like. In addition, in the present invention, light means the actinic ray or the radiation.

Unless otherwise specified, “exposure” in the present specification encompasses not only exposure by a bright line spectrum of a mercury lamp, far ultraviolet rays typified by an excimer laser, extreme ultraviolet rays, X-rays, EUV light, or the like, but also drawing by particle beams such as electron beams and ion beams.

In the present specification, a content ratio of each structural unit of a polymer is a molar ratio unless otherwise specified.

In addition, in the present specification, a refractive index is a value measured with an ellipsometer at a wavelength of 550 nm unless otherwise specified.

In the present specification, unless otherwise specified, a molecular weight in a case of a molecular weight distribution is a weight-average molecular weight.

In the present specification, a weight-average molecular weight of a resin is a weight-average molecular weight obtained by performing polystyrene conversion of a value measured by gel permeation chromatography (GPC).

In the present specification, “(meth)acrylic acid” is a concept including both acrylic acid and methacrylic acid, and “(meth)acryloyl group” is a concept including both an acryloyl group and a methacryloyl group.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The average thickness is an average thickness obtained by forming a section to be measured using an ultramicrotome, measuring thicknesses of any five points, and arithmetically averaging the values.

[Transfer Film]

A transfer film according to an embodiment of the present invention includes a temporary support and a photosensitive layer which is disposed on the temporary support and includes a compound A having an acid group (hereinafter, also simply referred to as a “compound A”).

A feature point of the transfer film according to the embodiment of the present invention is that a content of the above-described acid group in the above-described photosensitive layer is reduced by irradiation with an actinic ray or a radiation (hereinafter, also referred to as an “exposure”). In other words, the feature point of the transfer film according to the embodiment of the present invention is that the transfer film includes a photosensitive layer having a mechanism for reducing the content of the acid group derived from the compound A by the exposure.

Examples of the above-described photosensitive layer include a photosensitive layer which includes a compound A having a carboxy group, and has a mechanism for causing a decarboxylation reaction of the carboxy group by the exposure to reduce the content of the carboxy group in the layer (hereinafter, also referred to as a “photosensitive layer X”). The photosensitive layer X will be described later.

The transfer film according to the embodiment of the present invention having the above-described configuration exhibits excellent pattern formability with respect to a developer (particularly, an alkali developer). In addition, a pattern formed from the transfer film according to the embodiment of the present invention has low moisture permeability, and can be suitably used as a protective film (permanent film) for, for example, a conductive pattern and the like.

Detailed mechanism of the action of the transfer film according to the embodiment of the present invention is not clear, but the present inventors have presumed as follows.

According to the present studies by the present inventors, it has been found that the inclusion of the acid group in the pattern is one of causes of increasing the moisture permeability of the pattern.

On the other hand, in the transfer film according to the embodiment of the present invention, due to the photosensitive layer having a mechanism for reducing the content of the acid group derived from the compound A by the exposure, it is possible to form a pattern having a low moisture permeability.

In addition, according to the present studies by the present inventors, in the photosensitive layer having a mechanism for reducing the content of the acid group derived from the compound A by the exposure, it is also confirmed that a relative permittivity after exposure is lower than that before exposure.

In particular, the transfer film according to the embodiment of the present invention is more suitable for a developing method using an alkali developer.

In order to ensure good pattern forming performance with respect to the alkali developer, usually, for example, as disclosed in WO2013/084886A, it is necessary to blend a component having a high affinity to the alkali developer (for example, a component having an acid group, such as an alkali-soluble resin) in the photosensitive layer. That is, it is presumed that, in the pattern to be formed, it is inevitable that a component having a high affinity to the alkali developer remains, which is a cause of increasing the moisture permeability.

On the other hand, in the transfer film according to the embodiment of the present invention, due to the photosensitive layer having a mechanism for reducing the content of the acid group derived from the compound A by the exposure, it is possible to form a pattern having a low moisture permeability while having excellent pattern formability with respect to the alkali developer.

In the following, the presumed mechanism of action of the transfer film according to the embodiment of the present invention will be described while explaining an example of a pattern forming method using the transfer film.

[Embodiments and Mechanism of Action of Pattern Forming Method Using Transfer Film]

<<<Pattern Forming Method of Embodiment 1>>>

A pattern forming method of an embodiment 1 includes steps X1 to X3. The following step X2 corresponds to a step of reducing the content of the acid group derived from the compound A in the photosensitive layer by the exposure. However, in a case where a developer in the step X3 is an organic solvent-based developer, a step X4 is further included after the step X3.

Step X1: step of bringing a surface of the photosensitive layer in the transfer film on an opposite side of a temporary support side into contact with a base material to bond the transfer film and the base material

Step X2: step of exposing the photosensitive layer in a patterned manner (pattern exposure)

Step X3: step of developing the photosensitive layer with a developer

Step X4: step of further exposing the pattern formed by the development after the developing step of the step X3

In the pattern forming method of the embodiment 1, by the step X1, the photosensitive layer of the transfer film and any base material are bonded together, and a laminate having a base material and a photosensitive layer disposed on the base material is formed. Next, in a case where the step X2 (exposure treatment) is performed on the photosensitive layer of the obtained laminate, the content of the acid group in the exposed portion is reduced. On the other hand, in the non-exposed portion, the content of the acid group does not change. That is, by going through the above-described step X2, a difference in solubility (dissolution contrast) in the developer may occur between the exposed portion and the non-exposed portion of the photosensitive layer. As a result, in the subsequent step X3 (developing step), in a case where the developer is an alkali developer, the non-exposed portion of the photosensitive layer is dissolved and removed in the alkali developer so that a negative tone pattern can be formed. In the formed pattern, since the content of the acid group in the exposed portion (residual film) is reduced by performing the above-described step X2, the decrease in moisture permeability due to the remaining acid groups is suppressed. On the other hand, in a case where the developer of the step X3 is an organic solvent-based developer, since the exposed portion of the photosensitive layer is dissolved and removed in the developer so that a positive tone pattern is formed, in the subsequent step X4, the pattern is exposed to reduce the content of the acid group. In the pattern formed through the step X4, the decrease in moisture permeability due to the remaining acid groups is suppressed.

That is, in the pattern forming method of the embodiment 1, due to the photosensitive layer having a mechanism for reducing the content of the acid group derived from the compound A by the exposure, it is possible to form a pattern having a low moisture permeability with a reduced content of the acid group.

Among these, the pattern forming method of the embodiment 1 is suitable for a developing method using an alkali developer. Due to the photosensitive layer having a mechanism for reducing the content of the acid group derived from the compound A by the exposure, it is possible to form a pattern having a low moisture permeability with a reduced content of the acid group while having excellent pattern formability with respect to the alkali developer. In addition, in a case where the pattern forming method of the embodiment 1 carries out development using an alkali developer, it is also preferable that the photosensitive layer further includes a polymerizable compound (radical polymerizable compound).

As described above, as the photosensitive layer having a mechanism for reducing the content of the acid group derived from the compound A by the exposure, for example, the photosensitive layer X described later can be adopted.

Specific aspects of each step of the pattern forming method of the embodiment 1 will be described in the latter part.

<<<Pattern Forming Method of Embodiment 2>>>

A pattern forming method of an embodiment 2 includes a step Y1, a step Y2P, and a step Y3 in this order, and further includes a step Y2Q (step of further exposing the photosensitive layer exposed in the step Y2P) before the step Y3 or after the step Y3.

Step Y1: step of bringing a surface of the photosensitive layer in the transfer film on an opposite side of a temporary support side into contact with a base material to bond the transfer film and the base material

Step Y2P: step of exposing the photosensitive layer Step Y3: step of developing the photosensitive layer with a developer

The pattern forming method of the embodiment 2 corresponds to an aspect in which the photosensitive layer further includes a photopolymerization initiator and a polymerizable compound.

In the pattern forming method of the embodiment 2, the exposure treatments are performed in the step Y2P and the step Y2Q, and one of the exposure treatments is an exposure for reducing the content of the acid group derived from the compound A by the exposure, and one of the exposure treatments corresponds to an exposure for causing a polymerization reaction of the polymerizable compound based on the photopolymerization initiator. In addition, the exposure treatment may be either the entire exposure or an exposure in a patterned shape (pattern exposure), but any one of the exposure treatments is the pattern exposure.

For example, in a case where the step Y2P is a pattern exposure for reducing the content of the acid group derived from the compound A by the exposure, the developer used in the step Y3 may be an alkali developer or an organic solvent-based developer. However, in a case of a development with an organic solvent-based developer, the step Y2Q is usually performed after the step Y3. By performing the step Y2Q, in the developed photosensitive layer (pattern), the polymerization reaction of the polymerizable compound based on the photopolymerization initiator occurs, and the content of the acid group (preferably, a carboxy group) derived from the compound A is reduced.

In addition, for example, in a case where the step Y2P is a pattern exposure for causing a polymerization reaction of the polymerizable compound based on the photopolymerization initiator, the developer used in the step Y3 is usually an alkali developer. In this case, the step Y2Q may be performed before or after the step Y3, and the step Y2Q in a case of being performed before the step Y3 is usually a pattern exposure.

Among these, as the pattern forming method of the embodiment 2, it is preferable to include a step Y1, a step Y2A, a step Y3, and a step Y2B in this order. One of the step Y2A and the step Y2B is an exposing step for reducing the content of the acid group derived from the compound A by the exposure, and the other is an exposing step for causing a polymerization reaction of the polymerizable compound based on the photopolymerization initiator.

Step Y1: step of bringing a surface of the photosensitive layer in the transfer film on an opposite side of a temporary support side into contact with a base material to bond the transfer film and the base material

Step Y2A: step of exposing the photosensitive layer in a patterned manner (pattern exposure)

Step Y3: step of developing the photosensitive layer with an alkali developer to form a patterned photosensitive layer

Step Y2B: step of exposing the patterned photosensitive layer

In the following, the configuration and mechanism of action of the pattern forming method of the embodiment 2 will be described by taking, as an example, an aspect in which the step Y2A is an exposing step for causing a polymerization reaction of the polymerizable compound based on the photopolymerization initiator, and the step Y2B is an exposing step for reducing the content of the acid group derived from the compound A by the exposure.

In the pattern forming method of the embodiment 2, by the step Y1, the photosensitive layer of the transfer film and any base material are bonded together, and a laminate having a base material and a photosensitive layer disposed on the base material is formed. Next, in a case where the exposing step of the step Y2A is performed on the photosensitive layer of the obtained laminate, a polymerization reaction (curing reaction) of the polymerizable compound proceeds in the exposed portion, and in the subsequent developing step of the step Y3, the non-exposed portion of the photosensitive layer is dissolved and removed in the alkali developer to form a negative tone patterned photosensitive layer (cured layer). In the step Y4, the patterned photosensitive layer obtained in the step Y3 is subjected to an exposure (preferably, the entire exposure) to reduce the content of the acid group in the photosensitive layer.

That is, in the pattern forming method of the embodiment 2, since a predetermined amount of the acid group is present in the photosensitive layer during the alkali developing step of the step Y2A, the photosensitive layer has excellent pattern formability with respect to the alkali developer. Further, in the step Y4, since the content of the acid group in the photosensitive layer is reduced, a pattern having a low moisture permeability is formed. That is, in the pattern forming method of the embodiment 2, due to the photosensitive layer having a mechanism for reducing the content of the acid group derived from the compound A by the exposure, it is possible to form a pattern having a low moisture permeability with a reduced content of the acid group while having excellent pattern formability with respect to the alkali developer.

In the above, the aspect in which the step Y2A is an exposing step for causing a polymerization reaction of the polymerizable compound based on the photopolymerization initiator, and the step Y2B is an exposing step for reducing the content of the acid group derived from the compound A by the exposure has been described, a similar mechanism of action can be obtained even in an aspect in which the step Y2A and the step Y2B are changed.

As described above, as the photosensitive layer having a mechanism for reducing the content of the acid group derived from the compound A by the exposure, for example, the photosensitive layer X described later can be adopted.

Specific aspects of each step of the pattern forming method of the embodiment 2 will be described in the latter part.

<<<Photosensitive Layer X>>>

Hereinafter, the photosensitive layer X and its mechanism of action will be described.

The photosensitive layer X satisfies any of the following requirement (V1-C) and the following requirement (W1-C). The photosensitive layer may be a photosensitive layer which satisfies both the requirement (V1-C) and the requirement (W1-C).

Requirement (V1-C)

The photosensitive layer X includes a compound A having a carboxy group and a compound B which has a structure (hereinafter, also referred to as a “specific structure S1”) capable of accepting an electron from the carboxy group included in the compound A in a photoexcited state.

Requirement (W1-C)

The photosensitive layer X includes a compound A having a carboxy group, and the compound A further includes a structure (specific structure S1) capable of accepting an electron from the carboxy group included in the compound A in a photoexcited state.

In the photosensitive layer X, due to the following mechanism of action starting from the specific structure S1, the content of the carboxy group derived from the compound A can be reduced by the exposure.

In a case where the above-described specific structure S1 is exposed, acceptability of the electron increases, and the electron is transferred from the carboxy group of the compound A. In a case of transferring the electron, the above-described carboxy group may be an anion.

In a case where the above-described carboxy group which may be an anion transfers the electron to the specific structure S1, the above-described carboxy group is unstable and to be carbon dioxide, and is eliminated. In a case where the carboxy group, which is the acid group, is to be carbon dioxide and is eliminated, polarity of that portion decreases. That is, in the photosensitive layer X, by the above-described mechanism of action, the polarity changes due to the elimination of the carboxy group of the compound A in the exposed portion, and the solubility in the developer changes (in the exposed portion, the solubility in an alkali developer is decreased, and the solubility in an organic solvent-based developer is increased). On the other hand, in the non-exposed portion, the solubility in the developer has not changed. As a result, the photosensitive layer X has excellent pattern formability. In addition, in a case where the developer is an alkali developer, it is possible to form a pattern having a low moisture permeability with a reduced content of the carboxy group. Further, in a case where the developer is an organic solvent-based developer, by further performing an exposure treatment on the developed pattern, it is possible to form a pattern having a low moisture permeability with a reduced content of the carboxy group.

Various components and forming methods of the photosensitive layer X will be described in the latter part.

In addition, as described later, it is also preferable that the photosensitive layer X includes a polymerizable compound.

As described above, in a case where the above-described carboxy group transfers the electron to the specific structure S1, the above-described carboxy group is unstable and to be carbon dioxide, and is eliminated. In this case, a radical is generated at a position on the compound A where the carboxy group is to be carbon dioxide and is eliminated, and such a radical causes a radical polymerization reaction of the polymerizable compound. As a result, in the photosensitive layer X after exposure, in particular, the pattern forming ability to the alkali developer is further improved, and a film hardness is also excellent.

Further, as will be described later, it is also preferable that the photosensitive layer X includes a polymerizable compound and a photopolymerization initiator.

In a case where the photosensitive layer X includes a photopolymerization initiator, the elimination of the carboxy group and the polymerization reaction as described above can occur at different timings. For example, first, the photosensitive layer X may be subjected to a first exposure to a wavelength or an exposure amount at which the elimination of the carboxy group hardly occurs, and the polymerization reaction of the polymerizable compound based on the photopolymerization initiator may be allowed to proceed and be cured. Thereafter, the cured photosensitive layer may be subjected to a second exposure to cause the elimination of the carboxy group.

<<Embodiments of Photosensitive Layer X>>

The following shows an example of embodiments of the photosensitive layer X.

<Photosensitive Layer X of Embodiment X-1-a1-C>

A photosensitive layer which satisfies any of the requirement (V1-C) or the requirement (W1-C) and does not substantially include the polymerizable compound and the photopolymerization initiator.

<Photosensitive Layer X of Embodiment X-1-a2-C>

A photosensitive layer which satisfies any of the requirement (V1-C) or the requirement (W1-C) and does not substantially include the photopolymerization initiator.

<Photosensitive Layer X of Embodiment X-1-a3-C>

A photosensitive layer which satisfies any of the requirement (V1-C) or the requirement (W1-C) and includes the polymerizable compound and the photopolymerization initiator.

In the photosensitive layer X of the embodiment X-1-a1-C, the “photosensitive layer X does not substantially include the polymerizable compound” means that a content of the polymerizable compound may be less than 3% by mass, preferably 0% to 1% by mass and more preferably 0% to 0.1% by mass with respect to the total mass of the photosensitive layer X.

In addition, in the photosensitive layers X of the embodiment X-1-a1-C and the embodiment X-1-a2-C, the “photosensitive layer X does not substantially include the photopolymerization initiator” means that a content of the photopolymerization initiator may be less than 0.1% by mass, preferably 0% to 0.05% by mass and more preferably 0% to 0.01% by mass with respect to the total mass of the photosensitive layer X.

The photosensitive layers X of the embodiment X-1-a1-C and the embodiment X-1-a2-C are preferably adopted to the pattern forming method of the embodiment 1 described above. In addition, the photosensitive layer X of the embodiment X-1-a3-C is preferably adopted to the pattern forming method of the embodiment 2 described above.

[Configuration of Transfer Film]

The configuration of the transfer film will be described below.

The transfer film according to the embodiment of the present invention includes a temporary support and a photosensitive layer which is disposed on the temporary support and includes a compound A having an acid group (compound A).

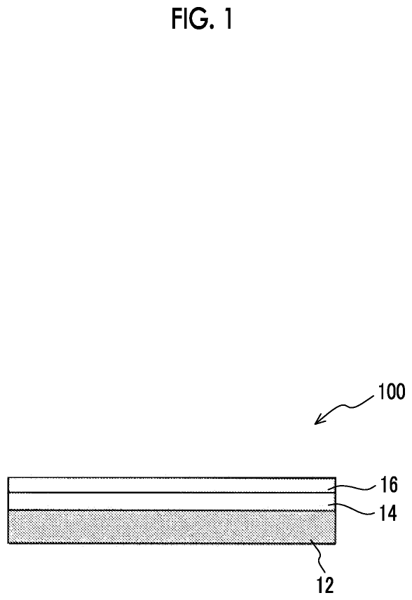

FIG. 1 is a schematic cross-sectional view showing an example of an embodiment of the transfer film according to the present invention.

A transfer film 100 shown in FIG. 1 has a configuration in which a temporary support 12, a photosensitive layer 14, and a cover film 16 are laminated in this order.

The transfer film 100 shown in FIG. 1 is in a form in which the cover film 16 is disposed, but the cover film 16 may not be disposed.

Hereinafter, each element constituting the transfer film will be described.

<<<Temporary Support>>>

The temporary support is a support which supports the photosensitive layer and can be peeled off from the photosensitive layer.

From the viewpoint that the photosensitive layer can be exposed through the temporary support in a case where the photosensitive layer is exposed in a patterned manner, the temporary support preferably has light-transmitting property.

Here, the “has light-transmitting property” means that a transmittance of light having a main wavelength used for the exposure (either the pattern exposure or the entire exposure) is 50% or more. From the viewpoint of more excellent exposure sensitivity, the transmittance of the light having the main wavelength used for the exposure is preferably 60% or more, and more preferably 70% or more. Examples of a method for measuring the transmittance include a measuring method using MCPD Series manufactured by OTSUKA ELECTRONICS Co., Ltd.

Specific examples of the temporary support include a glass substrate, a resin film, and paper, and from the viewpoint of more excellent strength and flexibility, a resin film is preferable. Examples of the resin film include a polyethylene terephthalate film, a cellulose triacetate film, a polystyrene film, and a polycarbonate film. Among these, a biaxially stretched polyethylene terephthalate film is preferable.

From the viewpoint of pattern formability during pattern exposure through the temporary support and transparency of the temporary support, it is preferable that the number of particles, foreign substances, and defects included in the temporary support is small. The number of particles, foreign substances, and defects having a diameter of 2 μm or more is preferably 50 pieces/10 mm² or less, more preferably 10 pieces/10 mm² or less, and still more preferably 3 pieces/10 mm² or less. The lower limit is not particularly limited, but can be 1 piece/10 mm² or more.

From the viewpoint of further improving handleability, the temporary support preferably has a layer in which 1 pieces/mm² or more particles with a diameter of 0.5 to 5 μm are present on a surface opposite to the side where the photosensitive layer is formed, and it is more preferable to have a layer in which 1 to 50 pieces/mm² particles with a diameter of 0.5 to 5 μm are present.

A thickness of the temporary support is not particularly limited, but from the viewpoint of ease of handling and excellent general-purpose properties, is preferably 5 to 200 μm and more preferably 10 to 150 μm.

From the viewpoint of strength as a support, flexibility required for bonding to a substrate for forming a circuit wiring, and light-transmitting property required in the first exposing step, the thickness of the temporary support can be appropriately selected according to the material.

Preferred aspects of the temporary support are described in, for example, paragraphs 0017 and 0018 of JP2014-085643A, paragraphs 0019 to 0026 of JP2016-027363A, paragraphs 0041 to 0057 of WO2012/081680A1, and paragraphs 0029 to 0040 of WO2018/179370A1, and the contents of these publications are incorporated in the present specification.

As the temporary support, for example, COSMOSHINE (registered trademark) A4100 manufactured TOYOBO Co., Ltd., LUMIRROR (registered trademark) 16FB40 manufactured by Toray Industries, Inc., or LUMIRROR (registered trademark) 16QS62 (16KS40) manufactured by Toray Industries, Inc. may be used.

In addition, particularly preferred examples of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 9 μm.

<<<Photosensitive Layer>>>

The photosensitive layer includes a compound A having an acid group (compound A), and has a mechanism for reducing the content of the acid group derived from the compound A by the exposure.

A reduction rate of the content of the acid group derived from the compound A in the photosensitive layer can be calculated by measuring the amount of the acid group in the photosensitive layer before and after the exposure. In a case of measuring the amount of the acid group in the photosensitive layer before the exposure, for example, the amount thereof can be analyzed and quantified by potentiometric titration. In addition, in a case of measuring the amount of the acid group in the photosensitive layer after the exposure, the hydrogen atom of the acid group is substituted with a metal ion such as lithium, and the amount thereof can be calculated by analyzing and quantifying the amount of this metal ion by inductively coupled plasma optical emission spectrometer (ICP-OES).

In addition, the reduction rate of the content of the acid group derived from the compound A in the photosensitive layer can also be obtained by measuring an infrared (IR) spectrum of the photosensitive layer before and after the exposure and calculating a reduction rate of a peak derived from the acid group. In a case where the acid group is a carboxy group, the reduction rate of the content of the carboxy group can be obtained by calculating a reduction rate of a peak of C═O stretching and contracting (peak of 1710 cm⁻¹) of the carboxy group.

The photosensitive layer is preferably a photosensitive layer which satisfies any of the following requirement (V01) or the following requirement (W01). The photosensitive layer may be a photosensitive layer which satisfies both the requirement (V01) and the requirement (W01).

Requirement (V01)

The photosensitive layer includes a compound A having an acid group and a compound β having a structure (hereinafter, also referred to as a “specific structure S0”) in which an amount of the acid group included in the compound A is reduced by an exposure.

Requirement (W01)

The photosensitive layer includes a compound A having an acid group, and the compound A further includes a structure (specific structure S0) in which an amount of the acid group is reduced by an exposure.

The above-described specific structure S0 is a structure which exhibits an action of reducing the amount of the acid group included in the compound A in a case of being exposed. The specific structure S0 is preferably a structure which transitions from a ground state to an excited state by the exposure, and exhibits the action of reducing the acid group in the compound A in the excited state. Examples of the specific structure S0 include a structure (specific structure S1 described later) capable of accepting an electron from the acid group included in the compound A in a photoexcited state by the exposure.

In addition, the following shows an example of embodiments of the photosensitive layer.

<Photosensitive Layer of Embodiment X-1-a1>

A photosensitive layer which satisfies any of the requirement (V01) or the requirement (W01) and does not substantially include the polymerizable compound and the photopolymerization initiator.

<Photosensitive Layer of Embodiment X-1-a2>

A photosensitive layer which satisfies any of the requirement (V01) or the requirement (W01) and does not substantially include the photopolymerization initiator.

<Photosensitive Layer of Embodiment X-1-a3>

A photosensitive layer which satisfies any of the requirement (V01) or the requirement (W01) and includes the polymerizable compound and the photopolymerization initiator.

In the photosensitive layer of the embodiment X-1-a1, the “photosensitive layer does not substantially include the polymerizable compound” means that a content of the polymerizable compound may be less than 3% by mass, preferably 0% to 1% by mass and more preferably 0% to 0.1% by mass with respect to the total mass of the photosensitive layer.

In addition, in the photosensitive layers of the embodiment X-1-a1 and the embodiment X-1-a2, the “photosensitive layer does not substantially include the photopolymerization initiator” means that a content of the photopolymerization initiator may be less than 0.1% by mass, preferably 0% to 0.05% by mass and more preferably 0% to 0.01% by mass with respect to the total mass of the photosensitive layer.

The photosensitive layers of the embodiment X-1-a1 and the embodiment X-1-a2 are preferably adopted to the pattern forming method of the embodiment 1 described above. In addition, the photosensitive layer of the embodiment X-1-a3 is preferably adopted to the pattern forming method of the embodiment 2 described above.

The above-described requirement (V01) is preferably a requirement (V1) shown below, and the above-described requirement (W01) is preferably a requirement (W1) shown below. That is, in the above-described requirement (V01), the above-described compound β is preferably a compound B which has a structure capable of accepting an electron from the acid group included in the compound A in a photoexcited state. In addition, in the above-described requirement (W01), the above-described structure is preferably a structure capable of accepting an electron from the acid group included in the compound A in a photoexcited state.

Requirement (V1): a photosensitive layer includes a compound A having an acid group and a compound B which has a structure (specific structure S1) capable of accepting an electron from the acid group included in the compound A in a photoexcited state.

Requirement (W1): a photosensitive layer includes a compound A having an acid group, and the compound A further includes a structure (specific structure S1) capable of accepting an electron from the acid group in a photoexcited state.

Among these, the photosensitive layer is more preferably a photosensitive layer which satisfies any of the above-described requirement (V1-C) or the above-described requirement (W1-C). The requirement (V1-C) corresponds to an aspect in which the acid group in the requirement (V1) is a carboxy group, and the requirement (W1-C) corresponds to an aspect in which the acid group in the requirement (W1) is a carboxy group.

In addition, as the embodiment of the photosensitive layer, among these, the above-descried photosensitive layers of embodiments X-1-a1-C to X-1-a3-C are more preferable. The embodiments X-1-a1-C to X-1-a3-C correspond to aspects in which, in the embodiments X-1-a1 to X-1-a3, the requirement (V01) and the requirement (W01) are the requirement (V1-C) and the requirement (W1-C), respectively.

The mechanism for reducing the content of the acid group derived from the compound A by the exposure is not limited to a method by decarboxylation described later, and a known method capable of reducing the content of the acid group derived from the compound A can be appropriately selected.

<<Various Components>>

<Compound A Having Acid Group>

The photosensitive layer includes a compound A having an acid group (compound A).

The acid group included in the compound A is preferably a proton dissociative group having a pKa of 12 or less. Specific examples of the acid group include a carboxy group, a sulfonamide group, a phosphonic acid group, a sulfo group, a phenolic hydroxyl group, and a sulfonylimide group, and a carboxy group is preferable.

The compound A may be a low-molecular-weight compound or a high-molecular-weight compound (hereinafter, also referred to as a “polymer”), but is preferably a polymer.

In a case where the compound A is a low-molecular-weight compound, a molecular weight of the compound A is preferably less than 5,000, more preferably 2,000 or less, still more preferably 1,000 or less, particularly preferably 500 or less, and most preferably 400 or less.

In a case where the compound A is a polymer, from the viewpoint of excellent formability of the photosensitive layer (in other words, excellent film forming ability for forming the photosensitive layer), a lower limit value of a weight-average molecular weight of the compound A is preferably 5,000 or more, more preferably 10,000 or more, and still more preferably 15,000 or more. An upper limit value thereof is not particularly limited, but from the viewpoint of more excellent adhesiveness (laminate adhesiveness) in a case of being bonded to any base material (during transfer), is preferably 50,000 or less.

In a case where the compound A is a polymer, the polymer is an alkali-soluble resin.

In the present disclosure, the “alkali-soluble” means that the dissolution rate obtained by the following method is 0.01 μm/sec or more.

A propylene glycol monomethyl ether acetate solution having a concentration of a target compound (for example, a resin) of 25% by mass is applied to a glass substrate, and then heated in an oven at 100° C. for 3 minutes to obtain a coating film (thickness: 2.0 μm) of the target compound. The above-described coating film is immersed in a 1% by mass aqueous solution of sodium carbonate (liquid temperature: 30° C.), thereby obtaining the dissolution rate (μm/sec) of the above-described coating film.

In a case where the target compound is not dissolved in propylene glycol monomethyl ether acetate, the target compound is dissolved in an organic solvent (for example, tetrahydrofuran, toluene, and ethanol) having a boiling point of lower than 200° C., other than propylene glycol monomethyl ether acetate.

In addition, in a case where the compound A is a polymer, from the viewpoint of developability, an acid value of the compound A as a polymer is preferably 60 to 300 mgKOH/g, more preferably 60 to 275 mgKOH/g, and still more preferably 75 to 250 mgKOH/g.

In the present specification, the acid value of the resin is a value measured by a titration method specified in JIS K0070 (1992).

It is also preferable that the compound A includes a structure (specific structure S0) in which the amount of the acid group included in the compound A is reduced by the exposure. In the following, a compound A which does not include the specific structure S0 is also referred to as a “compound Aa”, and a compound A which includes the specific structure S0 is also referred to as a “compound Ab”. The compound Ab is preferably a polymer.

The fact that the compound A does not include the specific structure S0 means that the compound A does not substantially include the specific structure S0, and for example, it is sufficient that a content of the specific structure S0 included in the compound Aa is less than 1% by mass, preferably 0% to 0.5% by mass and more preferably 0% to 0.05% by mass with respect to the total mass of the compound Aa.

A content of the specific structure S0 in the compound Ab is preferably 1% by mass or more, more preferably 1% to 50% by mass, and still more preferably 5% to 40% by mass with respect to the total mass of the compound Ab.

In a case where the compound A includes the compound Ab, a content of the compound Ab is preferably 5% to 100% by mass with respect to the total mass of the compound A.

Here, as described above, the specific structure S0 is a structure which exhibits an action of reducing the amount of the acid group included in the compound A in a case of being exposed. The specific structure S0 is preferably a structure which transitions from a ground state to an excited state by the exposure, and exhibits the action of reducing the acid group in the compound A in the excited state.

Examples of the specific structure S0 included in the compound A include a structure (specific structure S1) capable of accepting an electron from the acid group included in the compound A in a photoexcited state.

Examples of such a specific structure S1 include a heteroaromatic ring.

The above-described heteroaromatic ring may be monocyclic or polycyclic, and is preferably polycyclic. In the polycyclic heteroaromatic ring, a plurality of (for example, 2 to 5) aromatic ring structures is fused, and at least one of the plurality of aromatic ring structures has a heteroatom as a ring member atom.

The heteroaromatic ring has one or more heteroatoms (nitrogen atom, oxygen atom, sulfur atom, and the like) as a ring member atom, and the number thereof is preferably 1 to 4. In addition, the heteroaromatic ring preferably has one or more (for example, 1 to 4) nitrogen atoms as a ring member atoms.

The number of ring member atoms in the above-described heteroaromatic ring is preferably 5 to 15.

Examples of the above-described heteroaromatic ring include monocyclic heteroaromatic rings such as a pyridine ring, a pyrazine ring, a pyrimidine ring, and a triazine ring; heteroaromatic rings in which two rings are fused, such as a quinoline ring, an isoquinoline ring, a quinoxaline ring, and a quinazoline ring; and heteroaromatic rings in which three rings are fused, such as an acridine ring, a phenanthridine ring, a phenanthroline ring, and a phenazine ring.

The above-described heteroaromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, and a nitro group. In addition, in a case where the above-described aromatic ring has two or more substituents, a plurality of substituents may be bonded to each other to form a non-aromatic ring.

In addition, it is also preferable that the above-described heteroaromatic ring is directly bonded to a carbonyl group.

It is also preferable that the above-described heteroaromatic ring is bonded to an imide group to form a heteroaromatic imide group. The imide group in the heteroaromatic imide group may or may not form an imide ring together with the heteroaromatic ring.

In the compound A, in a case where a plurality of aromatic rings (for example, 2 to 5 aromatic rings) forms a series of aromatic ring structures bonded with a structure selected from the group consisting of a single bond, a carbonyl group, and a multiple bond (for example, a vinylene group which may have a substituent, —C≡C—, —N═N—, and the like), and one or more of the plurality of aromatic rings constituting the series of aromatic ring structures are the above-described heteroaromatic ring, the entire series of aromatic ring structures is regarded as one specific structure S1.

In addition, some or all of the acid groups included in the compound A may or may not be anionized in the photosensitive layer, and both anionized acid group and non-anionized acid group are referred to as the acid group. That is, the compound A may or may not be anionized in the photosensitive layer.

Among these, as the compound A, from the viewpoint of more excellent pattern forming performance of the photosensitive layer and viewpoint of more excellent film-forming properties, a compound having a carboxy group is preferable.

As the compound having a carboxy group, a monomer including a carboxy group (hereinafter, also referred to as a “carboxy group-containing monomer”) or a polymer including a carboxy group (hereinafter, also referred to as a “carboxy group-containing polymer”) is preferable, and from the viewpoint of more excellent pattern forming performance of the photosensitive layer and viewpoint of more excellent film-forming properties, a carboxy group-containing polymer is more preferable.

Some or all of carboxy groups (—COOH) included in the carboxy group-containing monomer and the carboxy group-containing polymer may or may not be anionized in the photosensitive layer, and both anionized carboxy group (—COO⁻) and non-anionized carboxy group are referred to as the carboxy group.

That is, the carboxy group-containing monomer may or may not be anionized in the photosensitive layer, and both anionized carboxy group-containing monomer and non-anionized carboxy group-containing monomer are referred to as the carboxy group-containing monomer.

That is, the carboxy group-containing polymer may or may not be anionized in the photosensitive layer, and both anionized carboxy group-containing polymer and non-anionized carboxy group-containing polymer are referred to as the carboxy group-containing polymer.

As described above, the compound A including a carboxy group may include the specific structure S0 (preferably, the specific structure S1). In other words, the carboxy group-containing monomer and the carboxy group-containing polymer may include the specific structure S0 (preferably, the specific structure S1). Among these, in a case where the compound A including a carboxy group includes the specific structure S0 (preferably, the specific structure S1), a carboxy group-containing polymer including the specific structure S0 (preferably, the specific structure S1) is preferable, and a carboxy group-containing polymer including the specific structure S1 is more preferable.

In the photosensitive layer, a lower limit value of the content of the compound A is preferably 1% by mass or more, more preferably 25% by mass or more, still more preferably 30% by mass or more, even more preferably 45% by mass or more, and particularly preferably 50% by mass or more with respect to the total mass of the photosensitive layer. An upper limit value of the content of the compound A is preferably 100% by mass or less, more preferably 99% by mass or less, still more preferably 97% by mass or less, particularly preferably 93% by mass or less, more particularly preferably 85% by mass or less, and most preferably 75% by mass or less with respect to the total mass of the photosensitive layer. In a case where the photosensitive layer satisfies the requirement (W01), the upper limit value of the content of the compound A is preferably 99% by mass or less with respect to the total mass of the photosensitive layer.

The compound A may be used alone, or in combination of two or more kinds thereof

(Carboxy Group-Containing Monomer)

The carboxy group-containing monomer is a polymerizable compound which includes a carboxy group and includes one or more (for example, 1 to 15) ethylenically unsaturated groups.

Examples of the ethylenically unsaturated group include a (meth)acryloyl group, a vinyl group, and a styryl group, and a (meth)acryloyl group is preferable.

From the viewpoint of more excellent film-forming properties, the carboxy group-containing monomer is preferably a bi- or higher functional monomer including a carboxy group. The bi- or higher functional monomer means a polymerizable compound having two or more (for example, 2 to 15) ethylenically unsaturated groups in one molecule.

The carboxy group-containing monomer may further have an acid group other than the carboxy group as the acid group. Examples of the acid group other than the carboxy group include a phenolic hydroxyl group, a phosphoric acid group, and a sulfonic acid group.

The bi- or higher functional monomer including a carboxy group is not particularly limited, and can be appropriately selected from known compounds.

Examples of the bi- or higher functional monomer including a carboxy group include ARONIX (registered trademark) TO-2349 (manufactured by Toagosei Co., Ltd.), ARONIX M-520 (manufactured by Toagosei Co., Ltd.), and ARONIX M-510 (manufactured by Toagosei Co., Ltd.).

In addition, examples of the bi- or higher functional monomer including a carboxy group also include a tri- or tetra-functional polymerizable compound having a carboxy group (compound obtained by introducing a carboxy group to pentaerythritol tri- and tetra-acrylate [PETA] skeleton (acid value=80 to 120 mgKOH/g)), and a penta- to hexa-functional polymerizable compound including a carboxy group (compound obtained by introducing a carboxy group to dipentaerythritol penta- and hexa-acrylate [DPHA] skeleton (acid value=25 to 70 mgKOH/g)). In a case where the above-described tri- or higher functional monomer including a carboxy group is used, from the viewpoint of more excellent film-forming properties, it is also preferable to use the bi- or higher functional monomer including a carboxy group in combination.

Examples of the bi- or higher functional monomer including a carboxy group also include polymerizable compounds having an acid group, which are described in paragraphs 0025 to 0030 of JP2004-239942A. The content of this publication is incorporated in this specification.

(Carboxy Group-Containing Polymer)

Usually, the carboxy group-containing polymer is an alkali-soluble resin. The definition and measuring method of alkali solubility are as described above.

The carboxy group-containing polymer may further have an acid group other than the carboxy group as the acid group. Examples of the acid group other than the carboxy group include a phenolic hydroxyl group, a phosphoric acid group, and a sulfonic acid group.

From the viewpoint of developability, an acid value of the carboxy group-containing polymer is preferably 60 to 300 mgKOH/g, more preferably 60 to 275 mgKOH/g, and still more preferably 75 to 250 mgKOH/g.

<<Repeating Unit Having Carboxy Group>>

The carboxy group-containing polymer preferably has a repeating unit having a carboxy group.

Examples of the repeating unit having a carboxy group include a repeating unit represented by General Formula (A).

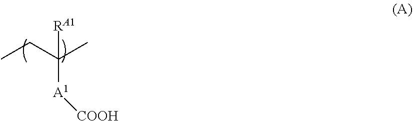

In General Formula (A), R^{A1} represents a hydrogen atom, a halogen atom, or an alkyl group.

The above-described alkyl group may be linear or branched. The number of carbon atoms in the above-described alkyl group is preferably 1 to 5 and more preferably 1.

In General Formula (A), A¹ represents a single bond or a divalent linking group.

Examples of the above-described divalent linking group include —CO—, —O—, —S—, —SO—, —SO₂—, —NR^{N}— (R^{N} is a hydrogen atom or an alkyl group having 1 to 5 carbon atoms), a hydrocarbon group (for example, an alkylene group, a cycloalkylene group, an alkenylene group, and an arylene group such as a phenylene group), and a linking group in which a plurality of these groups is linked.

Examples of a monomer from which the repeating unit having a carboxy group is derived include (meth)acrylic acid, crotonic acid, itaconic acid, maleic acid, and fumaric acid. Among these, from the viewpoint of more excellent patterning properties, (meth)acrylic acid is preferable. That is, the repeating unit having a carboxy group is preferably a repeating unit derived from (meth)acrylic acid.

A content of the repeating unit having a carboxy group in the carboxy group-containing polymer is preferably 5 to 100 mol %, more preferably 10 to 65 mol %, and still more preferably 15 to 45 mol % with respect to all repeating units of the carboxy group-containing polymer.

In addition, the content of the repeating unit having a carboxy group in the carboxy group-containing polymer is preferably 1% to 100% by mass, more preferably 5% to 70% by mass, and still more preferably 12% to 50% by mass with respect to all repeating units of the carboxy group-containing polymer.

The repeating unit having a carboxy group may be used alone, or in combination of two or more kinds thereof

<<Repeating Unit Having Polymerizable Group>>

The carboxy group-containing polymer also preferably has a repeating unit having a polymerizable group in addition to the above-described repeating units.

Examples of the polymerizable group include an ethylenically unsaturated group (for example, a (meth)acryloyl group, a vinyl group, a styryl group, and the like), and a cyclic ether group (for example, an epoxy group, an oxetanyl group, and the like), and an ethylenically unsaturated group is preferable and a (meth)acryloyl group is more preferable.

Examples of the repeating unit having a polymerizable group include a repeating unit represented by General Formula (B).

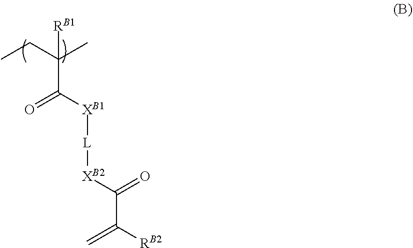

In General Formula (B), X^{B1} and X^{B2} each independently represent —O— or —NR^{N}—.

R^{N} represents a hydrogen atom or an alkyl group. The above-described alkyl group may be linear or branched, and the number of carbon atoms therein is preferably 1 to 5.

L represents an alkylene group or an arylene group. The above-described alkylene group may be linear or branched, and the number of carbon atoms therein is preferably 1 to 5. The above-described arylene group may be monocyclic or polycyclic, and the number of carbon atoms therein is preferably 6 to 15. The above-described alkylene group and arylene group may have a substituent, and the substituent is preferably, for example, a hydroxyl group.

R^{B1} and R^{B2} each independently represent a hydrogen atom or an alkyl group. The above-described alkyl group may be linear or branched. The number of carbon atoms in the above-described alkyl group is preferably 1 to 5 and more preferably 1.

A content of the repeating unit having a polymerizable group in the carboxy group-containing polymer is preferably 3 to 60 mol %, more preferably 5 to 40 mol %, and still more preferably 10 to 30 mol % with respect to all repeating units of the carboxy group-containing polymer.

A content of the repeating unit having a polymerizable group in the carboxy group-containing polymer is preferably 1% to 70% by mass, more preferably 5% to 50% by mass, and still more preferably 12% to 45% by mass with respect to all repeating units of the carboxy group-containing polymer.

The repeating unit having a polymerizable group may be used alone, or in combination of two or more kinds thereof.

<<Repeating Unit Having Specific Structure S0>>

The carboxy group-containing polymer also preferably has a repeating unit having the specific structure S0 (preferably, the specific structure S1) in addition to the above-described repeating units.

The specific structure S0 and the specific structure S1 are as described above.

In the repeating unit having the specific structure S0 (preferably, the specific structure S1), the specific structure S0 (preferably, the specific structure S1) may be present in a main chain or may be present in a side chain, and is preferably present in the side chain. In a case where the specific structure S0 (preferably, the specific structure S1) is present in the side chain, the specific structure S0 (preferably, the specific structure S1) is bonded to a polymer main chain through a single bond or a linking group.

The repeating unit having the specific structure S0 (preferably, the specific structure S1) is, for example, a repeating unit based on a monomer having a heteroaromatic ring (specifically, a (meth)acrylate monomer having a vinyl heteroaromatic ring such as a vinylpyridine and vinyl(iso)quinoline or a heteroaromatic ring, and the like).

Hereinafter, specific examples of the repeating unit having the specific structure S0 (preferably, the specific structure S1) will be described, but the present invention is not limited thereto.

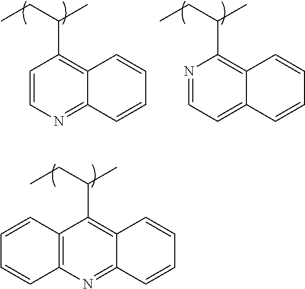

In a case where the carboxy group-containing polymer has a repeating unit having the specific structure S0 (preferably, the specific structure S1), a content thereof is preferably 3 to 75 mol %, more preferably 5 to 60 mol %, and still more preferably 10 to 50 mol % with respect to all repeating units of the carboxy group-containing polymer.

In a case where the carboxy group-containing polymer has a repeating unit having the specific structure S0 (preferably, the specific structure S1), a content thereof is preferably 1% to 75% by mass, more preferably 3% to 60% by mass, and still more preferably 5% to 30% by mass with respect to all repeating units of the carboxy group-containing polymer.

The repeating unit having the specific structure S0 (preferably, the specific structure S1) may be used alone, or in combination of two or more kinds thereof

<<Repeating Unit Having Aromatic Ring>>

The carboxy group-containing polymer also preferably has a repeating unit having an aromatic ring (preferably, an aromatic hydrocarbon ring) in addition to the above-described repeating units. Examples thereof include a repeating unit based on (meth)acrylate having an aromatic ring and a repeating unit based on styrene or a polymerizable styrene derivative.

Examples of the (meth)acrylate having an aromatic ring include benzyl (meth)acrylate, phenethyl (meth)acrylate, and phenoxyethyl (meth)acrylate.

Examples of the styrene and the polymerizable styrene derivative include methylstyrene, vinyltoluene, tert-butoxystyrene, acetoxystyrene, 4-vinylbenzoic acid, styrene dimer, and styrene trimer.

As the repeating unit having an aromatic ring, for example, a repeating unit represented by General Formula (C) is also preferable.

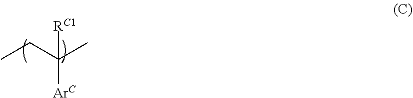

In General Formula (C), R^{C} represents a hydrogen atom, a halogen atom, or an alkyl group. The above-described alkyl group may be linear or branched. The number of carbon atoms in the above-described alkyl group is preferably 1 to 5 and more preferably 1.

Ar^{C} represents a phenyl group or a naphthyl group. The above-described phenyl group and naphthyl group may have one or more kinds of substituents, and examples of the substituent include an alkyl group, an alkoxy group, an aryl group, a halogen atom, and a hydroxy group.

The repeating unit having an aromatic ring is described below.

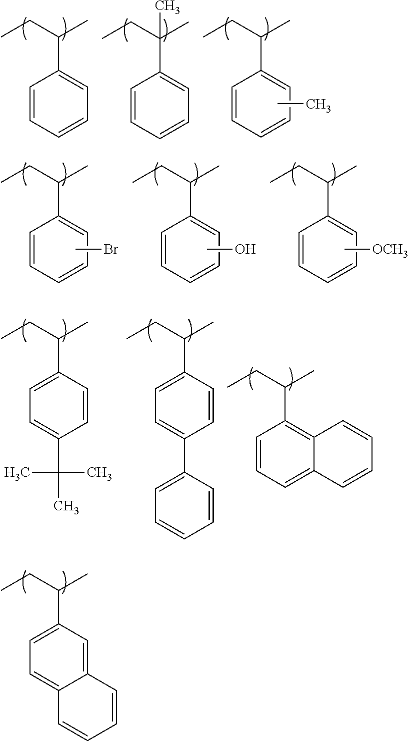

As the repeating unit having an aromatic ring, among these, the following structure is preferable.

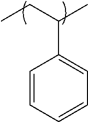

A content of the repeating unit having an aromatic ring in the carboxy group-containing polymer is preferably 5 to 80 mol %, more preferably 15 to 75 mol %, and still more preferably 30 to 70 mol % with respect to all repeating units of the carboxy group-containing polymer.

A content of the repeating unit having an aromatic ring in the carboxy group-containing polymer is preferably 5% to 90% by mass, more preferably 10% to 80% by mass, and still more preferably 30% to 70% by mass with respect to all repeating units of the carboxy group-containing polymer.

The repeating unit having an aromatic ring may be used alone, or in combination of two or more kinds thereof

<<Repeating Unit Having Alicyclic Structure>>

The carboxy group-containing polymer also preferably has a repeating unit having an alicyclic ring structure in addition to the above-described repeating units. The alicyclic ring structure may be monocyclic or polycyclic.

Examples of the alicyclic structure include a dicyclopentanyl ring structure, a dicyclopentenyl ring structure, an isobornyl ring structure, an adamantane ring structure, and a cyclohexyl ring structure.

Examples of a monomer from which the repeating unit having an alicyclic structure is derived include dicyclopentanyl (meth)acrylate, dicyclopentenyl (meth)acrylate, isobornyl (meth)acrylate, adamantyl (meth)acrylate, and cyclohexyl (meth)acrylate.

A content of the repeating unit having an alicyclic structure in the carboxy group-containing polymer is preferably 3 to 70 mol %, more preferably 5 to 60 mol %, and still more preferably 10 to 55 mol % with respect to all repeating units of the carboxy group-containing polymer.

A content of the repeating unit having an alicyclic structure in the carboxy group-containing polymer is preferably 3% to 90% by mass, more preferably 5% to 70% by mass, and still more preferably 25% to 60% by mass with respect to all repeating units of the carboxy group-containing polymer.

The repeating unit having an alicyclic structure may be used alone, or in combination of two or more kinds thereof

<<Other Repeating Units>>

The carboxy group-containing polymer may have other repeating units in addition to the above-described repeating units.

Examples of a monomer from which the other repeating units include (meth)acrylic acid alkyl esters, and examples of an alkyl group include an alkyl group having a chain structure. The chain structure may be a linear structure or a branched structure. The alkyl group may have a substituent such as a hydroxy group. Examples of the number of carbon atoms in the alkyl group include 1 to 50, preferably 1 to 10. Specific examples thereof include methyl (meth)acrylate.

A content of the other repeating units in the carboxy group-containing polymer is preferably 1 to 70 mol %, more preferably 2 to 50 mol %, and still more preferably 3 to 20 mol % with respect to all repeating units of the carboxy group-containing polymer.

A content of the other repeating units in the carboxy group-containing polymer is preferably 1% to 70% by mass, more preferably 2% to 50% by mass, and still more preferably 5% to 35% by mass with respect to all repeating units of the carboxy group-containing polymer.

The other repeating units may be used alone, or in combination of two or more kinds thereof.

A weight-average molecular weight of the carboxy group-containing polymer is preferably 5000 to 200000, more preferably 10000 to 100000, and most preferably 11000 to 49000.

A content of the carboxy group-containing polymer in the compound A is preferably 75% to 100% by mass, more preferably 85% to 100% by mass, still more preferably 90% to 100% by mass, and particularly preferably 95% to 100% by mass with respect to the total content of the compound A.

A content of the carboxy group-containing monomer in the compound A is preferably 0% to 25% by mass, more preferably 0% to 10% by mass, and still more preferably 0% to 5% by mass with respect to the total content of the compound A.

Among these, in the photosensitive layer of the embodiment X-1-a1, the content of the compound A is preferably 40% to 98% by mass, more preferably 50% to 96% by mass, and still more preferably 60% to 93% by mass with respect to the total mass of the photosensitive layer.

In the photosensitive layer of the embodiment X-1-a2, the content of the compound A is preferably 30% to 85% by mass and more preferably 45% to 75% by mass with respect to the total mass of the photosensitive layer.

In the photosensitive layer of the embodiment X-1-a3, the content of the compound A is preferably 30% to 85% by mass and more preferably 45% to 75% by mass with respect to the total mass of the photosensitive layer.

<Compound β>

The photosensitive layer preferably includes a compound β.

The compound β is a compound having a structure (specific structure S0) in which the amount of the acid group included in the compound A is reduced by the exposure. The specific structure S0 is as described above.

The specific structure S0 included in the compound β may be an overall structure constituting the entire compound β or a partial structure constituting a part of the compound β.

The compound β may be a high-molecular-weight compound or a low-molecular-weight compound, and is preferably a low-molecular-weight compound.

A molecular weight of the compound β as a low-molecular-weight compound is preferably less than 5,000, more preferably less than 1,000, still more preferably 65 to 300, and particularly preferably 75 to 250.

Among these, as the specific structure S0, a structure (specific structure S1) capable of accepting an electron from the acid group included in the compound A in a photoexcited state is preferable. That is, the compound β is preferably a compound B having a structure (specific structure S1) capable of accepting an electron from the acid group included in the compound A in a photoexcited state.

Hereinafter, the compound β (preferably, the compound B) will be described.

From the viewpoint of more excellent pattern forming ability and/or viewpoint that the moisture permeability of the pattern to be formed is further lowered, the compound β (preferably, the compound B) is preferably an aromatic compound.

Here, the aromatic compound is a compound having one or more aromatic rings.

Only one aromatic ring may be present in the compound β (preferably, the compound B), or a plurality of aromatic rings may be present therein. In a case where a plurality of aromatic rings is present, for example, the above-described aromatic rings may be present in the side chain or the like of the resin.

In the compound β (preferably, the compound B), the aromatic ring can be used as the above-described structure (specific structure S1) capable of accepting an electron from the acid group included in the compound A in a photoexcited state. The above-described aromatic ring may be an overall structure constituting the entire compound β (preferably, the compound B) or a partial structure constituting a part of the compound β (preferably, the compound B).

The above-described aromatic ring may be monocyclic or polycyclic, and is preferably polycyclic. For example, the polycyclic aromatic ring is an aromatic ring in which a plurality of (for example, 2 to 5) aromatic ring structures is fused, and at least one of the plurality of aromatic ring structures preferably has a heteroatom as a ring member atom.

The above-described aromatic ring may be a heteroaromatic ring, and it is preferable to have one or more (for example, 1 to 4) heteroatoms (nitrogen atom, oxygen atom, sulfur atom, and the like) as a ring member atom and it is more preferable to have one or more (for example, 1 to 4) nitrogen atoms as a ring member atom.

The number of ring member atoms in the above-described aromatic ring is preferably 5 to 15.

The compound β (preferably, the compound B) is preferably a compound having a 6-membered aromatic ring having a nitrogen atom as a ring member atom.

Examples of the above-described aromatic ring include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a phenanthridine ring, a phenanthroline ring, and a phenazine ring.

The above-described aromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, an amino group, and a nitro group. In addition, in a case where the above-described aromatic ring has two or more substituents, a plurality of substituents may be bonded to each other to form a non-aromatic ring.

In addition, it is also preferable that the above-described aromatic ring is directly bonded to a carbonyl group to form an aromatic carbonyl group in the compound β (preferably, the compound B). It is also preferable that a plurality of aromatic rings is bonded through a carbonyl group.

It is also preferable that the above-described aromatic ring is bonded to an imide group to form an aromatic imide group in the compound β (preferably, the compound B). The imide group in the aromatic imide group may or may not form an imide ring together with the aromatic ring.

In a case where a plurality of aromatic rings (for example, 2 to 5 aromatic rings) forms a series of aromatic ring structures bonded with a structure selected from the group consisting of a single bond, a carbonyl group, and a multiple bond (for example, a vinylene group which may have a substituent, —C≡C—, —N═N—, and the like), the entire series of aromatic ring structures is regarded as one specific structure S1.

In addition, it is preferable that one or more of aromatic rings constituting the series of aromatic ring structures are the above-described heteroaromatic rings.

From the viewpoint of more excellent pattern forming ability and/or viewpoint that the moisture permeability of the pattern to be formed is further lowered, the compound β (preferably, the compound B) is preferably a compound satisfying one or more (for example, 1 to 4) of the following requirements (1) to (4). Among these, it is preferable that at least the requirement (2) is satisfied, and it is preferable that the heteroatom of the heteroaromatic ring has at least a nitrogen atom.

(1) having a polycyclic aromatic ring

(2) having a heteroaromatic ring

(3) having an aromatic carbonyl group

(4) having an aromatic imide group

Specific examples of the compound β (preferably, the compound B) include monocyclic aromatic compounds such as pyridine and a pyridine derivative, pyrazine and a pyrazine derivative, pyrimidine and a pyrimidine derivative, and triazine and a triazine derivative; compounds in which two rings are fused to form an aromatic ring, such as quinoline and a quinoline derivative, isoquinoline and an isoquinoline derivative, quinoxaline and a quinoxaline derivative, and quinazoline and a quinazoline derivative; and compounds in which three or more rings are fused to form an aromatic ring, such as acridine and an acridine derivative, phenanthridine and a phenanthridine derivative, phenanthroline and a phenanthroline derivative, and phenazine and a phenazine derivative.

Among these, the compound β (preferably, the compound B) is preferably one or more kinds selected from the group consisting of pyridine and a pyridine derivative, quinoline and a quinoline derivative, and isoquinoline and an isoquinoline derivative, more preferably one or more kinds selected from the group consisting of quinoline and a quinoline derivative, and isoquinoline and an isoquinoline derivative, and still more preferably one or more kinds selected from the group consisting of isoquinoline and an isoquinoline derivative.

These compounds and derivatives thereof may further have a substituent, and as the substituent, an alkyl group, an aryl group, a halogen atom, an acyl group, an alkoxycarbonyl group, an arylcarbonyl group, a carbamoyl group, a hydroxy group, a cyano group, an amino group, or a nitro group is preferable, an alkyl group, an aryl group, a halogen atom, an acyl group, an alkoxycarbonyl group, an arylcarbonyl group, a carbamoyl group, a hydroxy group, a cyano group, or a nitro group is more preferable, an alkyl group, an aryl group, an acyl group, an alkoxycarbonyl group, an arylcarbonyl group, a carbamoyl group, a hydroxy group, a cyano group, or a nitro group is still more preferable, and an alkyl group (for example, a linear or branched alkyl group having 1 to 10 carbon atoms) is particularly preferable.

In addition, from the viewpoint of more excellent pattern forming ability and/or viewpoint that the moisture permeability of the pattern to be formed is further lowered, the compound β (preferably, the compound B) is preferably an aromatic compound having a substituent (compound having a substituent at a constituent atom of the aromatic ring included in the compound β (preferably, the compound B)), and more preferably a compound which satisfies one or more (for example, 1 to 4) of the above-described requirements (1) to (4) and further has a substituent.

As the position of the substituent, for example, in a case where the compound β (preferably, the compound B) is quinoline or a quinoline derivative, from the viewpoint of more excellent pattern forming ability and/or viewpoint that the moisture permeability of the pattern to be formed is further lowered, it is preferable to have a substituent at at least a 2-position and a 4-position on the quinoline ring. In addition, for example, in a case where the compound β (preferably, the compound B) is isoquinoline or an isoquinoline derivative, from the viewpoint of more excellent pattern forming ability and/or viewpoint that the moisture permeability of the pattern to be formed is further lowered, it is preferable to have a substituent at at least a 1-position on the isoquinoline ring. The substituent is preferably an alkyl group (for example, a linear or branched alkyl group having 1 to 10 carbon atoms).

In a case where the compound β (preferably, the compound B) is a polymer, the compound β may be a polymer in which the specific structure S0 (preferably, the specific structure S1) is bonded to a polymer main chain through a single bond or a linking group. The compound β (preferably, the compound B) as a polymer is obtained by, for example, polymerizing a monomer having a heteroaromatic ring (specifically, a (meth)acrylate monomer having a vinyl heteroaromatic ring and/or the specific structure S0 (preferably the specific structure S1 and more preferably a heteroaromatic ring)). If necessary, it may be copolymerized with another monomer.

From the viewpoint of more excellent pattern forming ability and/or viewpoint that the moisture permeability of the pattern to be formed is further lowered, a molar absorption coefficient (molar absorption coefficient E) of the compound β (preferably, the compound B) to light having a wavelength of 365 nm is, for example, 1×10³ (cm·mol/L)⁻¹ or less, preferably 1×10³ (cm·mol/L)⁻¹ or less, more preferably 5×10² (cm·mol/L)⁻¹ or less, and still more preferably 1×10² (cm·mol/L)⁻¹ or less. The lower limit of the above-described molar absorption coefficient E is not particularly limited, and for example, is more than 0 (cm·mol/L)⁻¹.

The fact that the molar absorption coefficient E of the compound β (preferably, the compound B) is within the above-described range is particularly advantageous in a case where the photosensitive layer is exposed through the temporary support (preferably, a PET film).

That is, in a case where the acid group of the compound A having an acid group is a carboxy group, since the molar absorption coefficient E is moderately low, even in a case of being exposed through the temporary support, generation of bubbles due to the decarboxylation can be controlled, and deterioration of the pattern shape can be prevented.

In addition, in a case where the photosensitive layer is used for producing a protective film (permanent film), coloration of the film can be suppressed by setting the molar absorption coefficient E of the compound β (preferably, the compound B) within the above-described range.

As the compound having such a molar absorption coefficient E, the above-described monocyclic aromatic compound or the above-described aromatic compound in which two rings are fused to form an aromatic ring is preferable, and pyridine and a pyridine derivative, quinoline and a quinoline derivative, or isoquinoline and an isoquinoline derivative is preferable.

In addition, from the viewpoint of more excellent pattern forming ability and/or viewpoint that the moisture permeability of the pattern to be formed is further lowered, a ratio of the molar absorption coefficient (molar absorption coefficient E) of the compound β (preferably, the compound B) at 365 nm to a molar absorption coefficient (molar absorption coefficient ε′) of the compound β (preferably, the compound B) at 313 nm (that is, a ratio represented by molar absorption coefficient E/molar absorption coefficient ε′) is preferably 3 or less, more preferably 2 or less, and still more preferably less than 1. The lower limit value thereof is not particularly limited, and for example, is 0.01 or more.

The molar absorption coefficient (molar absorption coefficient ε) of the compound β (preferably, the compound B) to light having a wavelength of 365 nm and the molar absorption coefficient (molar absorption coefficient ε′) of the compound β (preferably, the compound B) to light having a wavelength of 313 nm are a molar absorption coefficient measured by dissolving the compound β (preferably, the compound B) in acetonitrile. In a case where the compound β (preferably, the compound B) is insoluble in acetonitrile, a solvent for dissolving the compound β (preferably, the compound B) may be appropriately changed.

Specific examples of the compound β (preferably, the compound B) include 5,6,7,8-tetrahydroquinoline, 4-acetylpyridine, 4-benzoylpyridine, 1-phenylisoquinoline, 1-n-butylisoquinoline, 1-n-butyl-4-methylisoquinoline, 1-methylisoquinoline, 2,4,5,7-tetramethylquinoline, 2-methyl-4-methoxyquinoline, 2,4-dimethylquinoline, phenanthridine, 9-methylacridine, 9-phenylacridine, pyridine, isoquinoline, quinoline, acridine, 4-aminopyridine, and 2-chloropyridine.

A lower limit value of a pKa of the compound β (preferably, the compound B) in a ground state is preferably 0.5 or more, and from the viewpoint of more excellent pattern forming ability and/or viewpoint that the moisture permeability of the pattern to be formed is further lowered, is more preferably 2.0 or more. In addition, an upper limit value of the pKa of the compound β (preferably, the compound B) in a ground state is preferably 10.0 or less, and from the viewpoint of more excellent pattern forming ability and/or viewpoint that the moisture permeability of the pattern to be formed is further lowered, is more preferably 9.0 or less. From the viewpoint of more excellent pattern forming ability and/or viewpoint that the moisture permeability of the pattern to be formed is further lowered, the upper limit value of the pKa of the compound β (preferably, the compound B) in a ground state is more preferably to be smaller, still more preferably 8.0 or less, and particularly preferably 7.0 or less. The pKa of the compound β (preferably, the compound B) in a ground state is intended to be a pKa of the compound β (preferably, the compound B) in an unexcited state, and can be determined by acid titration. In a case where the compound β (preferably, the compound B) is a nitrogen-containing aromatic compound, the pKa of the compound β (preferably, the compound B) in a ground state is intended to be a pKa of a conjugate acid of the compound β (preferably, the compound B) in a ground state.

In addition, in a case where the photosensitive layer is formed by coating, from the viewpoint of being less likely to volatilize in the coating process and having more excellent residual ratio in the photosensitive layer (as a result, from the viewpoint of more excellent pattern forming ability and/or viewpoint that the moisture permeability of the pattern to be formed is further lowered), a molecular weight of the compound β (preferably, the compound B) is preferably 120 or more, more preferably 130 or more, and still more preferably 180 or more. The upper limit value of the molecular weight of the compound β (preferably, the compound B) is not particularly limited, but is, for example, 50,000 or less.

In addition, in a case where the compound β (preferably, the compound B) is a compound exhibiting a cationic state (for example, a nitrogen-containing aromatic compound), an energy level of highest occupied molecular orbital (HOMO) of the compound β (preferably, the compound B) in the cationic state is preferably −8.5 eV or less, and from the viewpoint of more excellent pattern forming ability and/or viewpoint that the moisture permeability of the pattern to be formed is further lowered, is more preferably −7.8 eV or less. The lower limit value thereof is not particularly limited, but is more preferably −13.6 eV or more.

In the present specification, the energy level of HOMO (HOMO in the first electron excited state) of the compound β (preferably, the compound B) in the cationic state is calculated by the quantum chemical calculation program Gaussian 09 (Gaussian 09, Revision A.02, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jalamillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford Conn., 2009.).

As a calculation method, a time-dependent density functional theory using B3LYP as a functional and 6-31+G(d,p) as a basis function is used. In addition, in order to incorporate a solvent effect, a PCM method based on a chloroform parameter set in Gaussian 09 is also used in combination. By this method, a structure optimization calculation of the first electron excited state is performed to obtain a structure with the minimum energy, and the energy of HOMO in the structure is calculated.

Hereinafter, the HOMO energy level (eV) of a representative example of the compound β (preferably, the compound B) in a cationic state is shown. The molecular weight is also shown.

TABLE 1
First table

| | | HOMO energy level |
|---|---|---|
| Compound β | Molecular weight | in cationic state (eV) |
| Isoquinoline | 129 | −8.08 |
| Quinoline | 129 | −8.30 |
| Acridine | 179 | −7.70 |
| 2,4-Dimethylquinoline | 157 | −8.13 |
| 1-Me-isoquinoline | 143 | −7.97 |
| Pyridine | 79 | −9.63 |

From the viewpoint of more excellent pattern forming ability and/or viewpoint that the moisture permeability of the pattern to be formed is further lowered, a content of the compound β (preferably, the compound B) in the photosensitive layer is preferably 0.1% to 50% by mass with respect to the total mass of the photosensitive layer.

Among these, in the photosensitive layer of the embodiment X-1-a1, the content of the compound β (preferably, the compound B) is preferably 2.0% to 40% by mass, more preferably 4% to 35% by mass, and still more preferably 8% to 30% by mass with respect to the total mass of the photosensitive layer.

In the photosensitive layer of the embodiment X-1-a2, the content of the compound β (preferably, the compound B) is preferably 0.5% to 20% by mass and more preferably 1.0% to 10% by mass with respect to the total mass of the photosensitive layer.

In the photosensitive layer of the embodiment X-1-a3, the content of the compound β (preferably, the compound B) is preferably 0.3% to 20% by mass and more preferably 0.5% to 8% by mass with respect to the total mass of the photosensitive layer.

The compound β (preferably, the compound B) may be used alone, or in combination of two or more kinds thereof.

In a case where the compound β is the compound B, from the viewpoint of more excellent pattern forming ability and/or viewpoint that the moisture permeability of the pattern to be formed is further lowered, in the photosensitive layer, the total number of structures (specific structures S1) capable of accepting the electron, which are included in the compound B, is preferably 1 mol % or more, more preferably 3 mol % or more, still more preferably 5 mol % or more, particularly preferably 10 mol % or more, and most preferably 20 mol % or more with respect to the total number of acid groups (preferably, carboxy groups) included in the compound A.

The upper limit of the total number of structures (specific structures S1) capable of accepting the electron, which are included in the compound B, is not particularly limited, but from the viewpoint of quality of the film to be obtained, is preferably 200 mol % or less, more preferably 100 mol % or less, and still more preferably 80 mol % or less with respect to the total number of acid groups (preferably, carboxy groups) included in the compound A.

<Polymerizable Compound>

The photosensitive layer also preferably includes a polymerizable compound. This polymerizable compound is a component different from the compound A having an acid group, and does not include an acid group.

The polymerizable compound is preferably a component different from the compound A, and for example, is preferably a compound having a molecular weight (a weight-average molecular weight in a case of having a molecular weight distribution) of less than 5,000 and also preferably a polymerizable monomer.

The polymerizable compound is a polymerizable compound having one or more (for example, 1 to 15) ethylenically unsaturated groups in one molecule.

The polymerizable compound preferably includes a bi- or higher functional polymerizable compound.

Here, the bi- or higher functional polymerizable compound means a polymerizable compound having two or more (for example, 2 to 15) ethylenically unsaturated groups in one molecule.

Examples of the ethylenically unsaturated group include a (meth)acryloyl group, a vinyl group, and a styryl group, and a (meth)acryloyl group is preferable.

The polymerizable compound is preferably (meth)acrylate.

The photosensitive layer preferably includes a bifunctional polymerizable compound (preferably, bifunctional (meth)acrylate) and a tri- or higher functional polymerizable compound (preferably, tri- or higher functional (meth)acrylate).

The bifunctional polymerizable compound is not particularly limited and can be appropriately selected from a known compound.

Examples of the bifunctional polymerizable compound include tricyclodecane dimethanol diacrylate, tricyclodecane dimethanol di(meth)acrylate, 1,9-nonanediol di(meth)acrylate, and 1,6-hexanediol di(meth)acrylate.

More specifically, examples of the bifunctional polymerizable compound include tricyclodecane dimethanol diacrylate (A-DCP manufactured by Shin-Nakamura Chemical Co., Ltd.), tricyclodecane dimethanol dimethacrylate (DCP manufactured by Shin-Nakamura Chemical Co., Ltd.), 1,9-nonanediol diacrylate (A-NOD-N manufactured by Shin-Nakamura Chemical Co., Ltd.), and 1,6-hexanediol diacrylate (A-HD-N manufactured by Shin-Nakamura Chemical Co., Ltd.).

The tri- or higher functional polymerizable compound is not particularly limited and can be appropriately selected from a known compound.

Examples of the tri- or higher functional polymerizable compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

In addition, examples of the polymerizable compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (A-GLY-9E manufactured by Shin-Nakamura Chemical Co., Ltd., or the like).

Examples of the polymerizable compound also include urethane (meth)acrylate (preferably, tri- or higher functional urethane (meth)acrylate). The lower limit of the number of functional groups is more preferably 6 or more and still more preferably 8 or more. The upper limit of the number of functional groups is, for example, 20 or less.

Examples of the tri- or higher functional urethane (meth)acrylate include 8UX-015A (manufactured by Taisei Fine Chemical Co., Ltd.); UA-32P, U-15HA, and UA-1100H (all manufactured by Shin-Nakamura Chemical Co., Ltd.); AH-600 (product name) manufactured by KYOEISHA CHEMICAL Co., LTD; and UA-306H, UA-306T, UA-306I, UA-510H, and UX-5000 (all manufactured by Nippon Kayaku Co., Ltd.).

A weight-average molecular weight (Mw) of the polymerizable compound which can be included in the photosensitive layer is preferably 200 to 3000, more preferably 250 to 2600, and still more preferably 280 to 2200.

In a case where the photosensitive layer includes a polymerizable compound, among all polymerizable compounds included in the photosensitive layer, a molecular weight of a polymerizable compound having the smallest molecular weight is preferably 250 or more and more preferably 280 or more.

In a case where the photosensitive layer includes a polymerizable compound, a content thereof is preferably 3% to 70% by mass, more preferably 10% to 70% by mass, and particularly preferably 20% to 55% by mass with respect to the total mass of the photosensitive layer.

In a case where the photosensitive layer includes a polymerizable compound and a carboxy group-containing polymer, a mass proportion of the polymerizable compound to the carboxy group-containing polymer (mass of polymerizable compound/mass of carboxy group-containing polymer) is preferably 0.2 to 2.0 and more preferably 0.4 to 0.9.

The polymerizable compound may be used alone, or in combination of two or more kinds thereof.

In addition, in a case where the photosensitive layer includes a bifunctional polymerizable compound and a tri- or higher functional polymerizable compound, a content of the bifunctional polymerizable compound is preferably 10% to 90% by mass, more preferably 20% to 85% by mass, and still more preferably 30% to 80% by mass with respect to all polymerizable compounds included in the photosensitive layer.

In addition, in this case, a content of the tri- or higher functional polymerizable compound is preferably 10% to 90% by mass, more preferably 15% to 80% by mass, and still more preferably 20% to 70% by mass with respect to all polymerizable compounds included in the photosensitive layer.

In addition, in a case where the photosensitive layer includes a bi- or higher functional polymerizable compound, this photosensitive layer may further contain a monofunctional polymerizable compound.

However, in a case where the photosensitive layer includes a bi- or higher functional polymerizable compound, it is preferable that, among the polymerizable compounds which can be included in the photosensitive layer, a main component is the bi- or higher functional polymerizable compound.

Specifically, in a case where the photosensitive layer includes a bi- or higher functional polymerizable compound, a content of the bi- or higher functional polymerizable compound is preferably 60% to 100% by mass, more preferably 80% to 100% by mass, and still more preferably 90% to 100% by mass with respect to the total content of polymerizable compounds included in the photosensitive layer.

<Photopolymerization Initiator>

The photosensitive layer also preferably includes a photopolymerization initiator.

The photopolymerization initiator may be a photoradical polymerization initiator, a photocationic polymerization initiator, or a photoanionic polymerization initiator, but a photoradical polymerization initiator is preferable.

The photopolymerization initiator is not particularly limited and a known photopolymerization initiator can be used.

The photopolymerization initiator is preferably one or more kinds selected from the group consisting of an oxime ester compound (photopolymerization initiator having an oxime ester structure) and an aminoacetophenone compound (photopolymerization initiator having an aminoacetophenone structure), and more preferably includes both compounds. In a case of including both compounds, a content of the oxime ester compound is preferably 5% to 90% by mass and more preferably 15% to 50% by mass with respect to the total content of both compounds. Other photopolymerization initiators may be further used in combination, and examples thereof include a hydroxyacetophenone compound, an acylphosphine oxide compound, and a bistriphenylimidazole compound.

In addition, as the photopolymerization initiator, for example, polymerization initiators described in paragraphs 0031 to 0042 of JP2011-095716A and paragraphs 0064 to 0081 of JP2015-014783A may be used.

Specific examples of the photopolymerization initiator include the following photopolymerization initiators.

Examples of the oxime ester compound include 1,2-octanedione, 1-[4-(phenylthio)phenyl-,2-(O-benzoyloxime)] (product name: IRGACURE OXE-01; IRGACURE series are manufactured by BASF SE), etanone,1-[9-ethyl-6-(2-methylbenzoyl)-9H-carbazol-3-yl]-,1-(O-acetyloxime) (product name: IRGACURE OXE-02, manufactured by BASF SE), [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(O-acetyloxime) (product name: IRGACURE OXE-04, manufactured by BASF SE; and product name: Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad series are manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of other photopolymerization initiators include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl) phenylphosphine oxide (product name: Omnirad 819).

In a case where the photosensitive layer includes a photopolymerization initiator, a content thereof is preferably 0.1% to 15% by mass, more preferably 0.5% to 10% by mass, and particularly preferably 1% to 5% by mass with respect to the total mass of the photosensitive layer.

The photopolymerization initiator may be used alone, or in combination of two or more kinds thereof

<Surfactant>

The photosensitive layer may include a surfactant.

Examples of the surfactant include an anionic surfactant, a cationic surfactant, a nonionic surfactant, and an amphoteric surfactant, and a nonionic surfactant is preferable.

Examples of the nonionic surfactant include polyoxyethylene higher alkyl ethers, polyoxyethylene higher alkylphenyl ethers, polyoxyethylene glycol higher fatty acid diesters, silicone-based surfactants, and fluorine-based surfactants.

As the surfactant, for example, surfactants described in paragraphs 0120 to 0125 of WO2018/179640A can also be used.

In addition, as the surfactant, surfactants described in paragraph 0017 of JP4502784B and surfactants described in paragraphs 0060 to 0071 of JP2009-237362A can also be used.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond-containing group in the side chain can also be used. Examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC (registered trademark) L10, L31, L61, L62, 10R5, 17R2, and 25R2 (all of which are manufactured by BASF SE), TETRONIC 304, 701, 704, 901, 904, and 150R1 (all of which are manufactured by BASF SE), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Silicone Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

A content of the surfactant is preferably 0.0001% to 10% by mass, more preferably 0.001% to 5% by mass, and still more preferably 0.005% to 3% by mass with respect to the total mass of the photosensitive layer.

The surfactant may be used alone, or in combination of two or more kinds thereof

<Other Additives>

The photosensitive layer may include other additives as necessary.

Examples the other additives include a plasticizer, a sensitizer, a heterocyclic compound, and an alkoxysilane compound.

Examples of the plasticizer, the sensitizer, the heterocyclic compound, and the alkoxysilane compound include those described in paragraphs 0097 to 0119 of WO2018/179640A.

In a case where the photosensitive layer is formed of a photosensitive material including a solvent, the solvent may remain, but it is preferable that the photosensitive layer does not include the solvent.

A content of the solvent in the photosensitive layer is preferably 5% by mass or less, more preferably 2% by mass or less, still more preferably 1% by mass or less, particularly preferably 0.5% by mass or less, and most preferably 0.1% by mass or less with respect to the total mass of the photosensitive layer.

In addition, the photosensitive layer may further include, as other additives, a known additive such as a rust inhibitor, metal oxide particles, an antioxidant, a dispersing agent, an acid proliferation agent, a development promoter, a conductive fiber, a colorant, a thermal radical polymerization initiator, a thermal acid generator, an ultraviolet absorber, a thickener, a crosslinking agent, and an organic or inorganic anti-precipitation agent.

Preferred aspects of these components are described in paragraphs 0165 to 0184 of JP2014-085643A, and the contents of these publications are incorporated in the present specification.

The photosensitive layer may include impurities.

Examples of the impurities include sodium, potassium, magnesium, calcium, iron, manganese, copper, aluminum, titanium, chromium, cobalt, nickel, zinc, tin, halogen, and ions of these. Among these, halide ion, sodium ion, and potassium ion are easily mixed as impurities, so that the following content is particularly preferable.

A content of impurities in the photosensitive layer is preferably 80 ppm by mass or less, more preferably 10 ppm by mass or less, and still more preferably 2 ppm by mass or less with respect to the total mass of the photosensitive layer. The content of impurities in the photosensitive layer may be 1 ppb by mass or 0.1 ppm by mass or more with respect to the total mass of the photosensitive layer.

Examples of a method of setting the impurities in the above-described range include selecting a raw material having a low content of impurities as a raw material for the photosensitive material, preventing the impurities from being mixed in a case of forming the photosensitive material, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In addition, in the photosensitive layer, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low in each layer. A content of these compounds in the photosensitive layer is preferably 100 ppm by mass or less, more preferably 20 ppm by mass or less, and still more preferably 4 ppm by mass or less with respect to the total mass of the photosensitive layer.

The lower limit of the above-described content may be 10 ppb by mass or more or 100 ppb by mass or more with respect to the total mass of the photosensitive layer. The content of these compounds can be suppressed in the same manner as in the above-described metal as impurities. In addition, the compounds can be quantified by a known measurement method.

From the viewpoint of improving patterning properties, a content of water in the photosensitive layer is preferably 0.01% to 1.0% by mass and more preferably 0.05% to 0.5% by mass with respect to the total mass of the photosensitive layer.

<<Average Thickness of Photosensitive Layer>>

An average thickness of the photosensitive layer is preferably 0.5 to 20 μm. In a case where the average thickness of the photosensitive layer is 20 μm or less, resolution of the pattern is more excellent, and in a case where the average thickness of the photosensitive layer is 0.5 μm or more, it is preferable from the viewpoint of pattern linearity. The average thickness of the photosensitive layer is more preferably 0.8 to 15 μm and still more preferably 1.0 to 10 μm. Specific examples of the average thickness of the photosensitive layer include 3.0 μm, 5.0 μm, and 8.0 μm.

<<Method for Forming Photosensitive Layer>>

The photosensitive layer can be formed by preparing a photosensitive material including components used for forming the photosensitive layer and a solvent, and applying and drying the photosensitive material. It is also possible to prepare a composition by dissolving each component in a solvent in advance and then mixing the obtained solution at a predetermined proportion. The composition prepared as described above is preferably filtered using, for example, a filter having a pore size of 0.2 to 30 μm.

The photosensitive layer can be formed by applying the photosensitive material to a temporary support or a cover film, and drying the photosensitive material.

The application method is not particularly limited, and examples thereof include known methods such as a slit coating, a spin coating, a curtain coating, and an inkjet coating.

In addition, in a case where other layers described later are formed on the temporary support or the cover film, the photosensitive layer may be formed on the other layers.

From the viewpoint of more excellent pattern forming ability and/or viewpoint that the moisture permeability of the pattern to be formed is further lowered, a transmittance of the photosensitive layer at 365 nm is preferably 20% or more, more preferably 65% or more, and still more preferably 90% or more. The upper limit value thereof is not particularly limited, and is 100% or less.

In addition, from the viewpoint of more excellent pattern forming ability and/or viewpoint that the moisture permeability of the pattern to be formed is further lowered, a ratio of the transmittance of the photosensitive layer at 365 nm to a transmittance of the photosensitive layer at 313 nm (ratio represented by transmittance of photosensitive layer at 365 nm/transmittance of photosensitive layer at 313 nm) is preferably 1 or more and more preferably 1.5 or more. The upper limit value thereof is not particularly limited, and for example, is 1000 or less.

In the photosensitive layer, the acid group included in the compound A is preferably a carboxy group. Further, in the photosensitive layer, it is preferable that a content of the carboxy group in the photosensitive layer is reduced at a reduction rate of 5 mol % or more by the irradiation with the actinic ray or the radiation. Such a photosensitive layer is more preferably a photosensitive layer which satisfies any of the above-described requirement (V1-C) or the above-described requirement (W1-C).

In addition, as the embodiment of the photosensitive layer, among these, the above-descried photosensitive layers of embodiments X-1-a1-C to X-1-a3-C are more preferable.

A visible light transmittance of the photosensitive layer at a film thickness of approximately 1.0 μm is preferably 80% or more, more preferably 90% or more, and most preferably 95% or more.

As the visible light transmittance, it is preferable that an average transmittance at a wavelength of 400 nm to 800 nm, the minimum value of the transmittance at a wavelength of 400 nm to 800 nm, and a transmittance at a wavelength of 400 nm all satisfy the above.

Examples of a preferred value of the visible light transmittance of the photosensitive layer at a film thickness of approximately 1.0 μm include 87%, 92%, and 98%.

From the viewpoint of suppressing residue during development, a dissolution rate of the photosensitive layer in a 1.0% by mass sodium carbonate aqueous solution is preferably 0.01 μm/sec or more, more preferably 0.10 μm/sec or more, and still more preferably 0.20 μm/sec or more. In addition, from the viewpoint of edge shape of the pattern, it is preferable to be 5.0 μm/sec or less. Examples of a specific preferred numerical value include 1.8 μm/sec, 1.0 μm/sec, and 0.7 μm/sec.

The dissolution rate of the photosensitive layer in a 1.0% by mass sodium carbonate aqueous solution per unit time is measured as follows.

A photosensitive layer (within a film thickness of 1.0 to 10 μm) formed on a glass substrate, from which the solvent has been sufficiently removed, is subjected to a shower development with a 1.0% by mass sodium carbonate aqueous solution at 25° C. until the photosensitive layer is dissolved completely (however, the maximum time is 2 minutes).

The dissolution rate of the photosensitive layer is obtained by dividing the film thickness of the photosensitive layer by the time required for the photosensitive layer to dissolve completely. In a case where the photosensitive layer is not dissolved completely in 2 minutes, the dissolution rate of the photosensitive layer is calculated in the same manner as above, from the amount of change in film thickness up to 2 minutes.

For development, a shower nozzle of ¼ MINJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

From the viewpoint of pattern formability, the number of foreign substances having a diameter of 1.0 μm or more in the photosensitive layer is preferably 10 pieces/mm² or less, and more preferably 5 pieces/mm² or less.

The number of foreign substances is measured as follows.

Any 5 regions (1 mm×1 mm) on a surface of the photosensitive layer are visually observed from a normal direction of the surface of the photosensitive layer with an optical microscope, the number of foreign substances having a diameter of 1.0 μm or more in each region is measured, and the values are arithmetically averaged to calculate the number of foreign substances.

Examples of a specific preferred numerical value include 0 pieces/mm², 1 pieces/mm², 4 pieces/mm², and 8 pieces/mm².

From the viewpoint of suppressing generation of aggregates during development, a haze of a solution obtained by dissolving 1.0 cm³ of the photosensitive layer in 1.0 liter of a 1.0% by mass sodium carbonate aqueous solution at 30° C. is preferably 60% or less, more preferably 30% or less, still more preferably 10% or less, and most preferably 1% or less.

The haze is measured as follows.

First, a 1.0% by mass sodium carbonate aqueous solution is prepared, and a liquid temperature is adjusted to 30° C. 1.0 cm³ of the photosensitive layer is added to 1.0 L of the sodium carbonate aqueous solution. The solution is stirred at 30° C. for 4 hours, being careful not to mix air bubbles. After stirring, the haze of the solution in which the photosensitive resin layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm

Examples of a specific preferred numerical value include 0.4%, 1.0%, 9%, and 24%.

<Photosensitive Material>

The photosensitive material preferably includes components used for forming the photosensitive layer and a solvent. The photosensitive layer can be suitably formed by mixing each component and the solvent, adjusting the viscosity, and applying and drying the mixture.

(Components Used for Forming Photosensitive Layer)

The components used for forming the photosensitive layer are as described above. Suitable numerical range of the content of each component in the photosensitive material is the same as the suitable range in which the “content (% by mass) of each component with respect to the total mass of the photosensitive layer” described above is read as a “content (% by mass) of each component with respect to the total solid content of the photosensitive material”. The solid content of the photosensitive material means a component in the photosensitive material, other than the solvent. Therefore, for example, the description of “content of the compound A in the photosensitive layer is preferably 25% by mass or more with respect to the total mass of the photosensitive layer” is read as “content of the compound A in the photosensitive material is preferably 25% by mass or more with respect to the total solid content of the photosensitive material”. The solid content is intended to be all components of the photosensitive material, except the solvent. In addition, in a case where the photosensitive material is liquid, components other than the solvent are regarded as the solid content.

(Solvent)

As the solvent, a commonly used solvent can be used without particular limitation.

As the solvent, an organic solvent is preferable.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, 2-propanol, and a mixed solvent thereof.

As the solvent, a mixed solvent of methyl ethyl ketone and propylene glycol monomethyl ether acetate, a mixed solvent of diethylene glycol ethyl methyl ether and propylene glycol monomethyl ether acetate, or a mixed solvent of methyl ethyl ketone, propylene glycol monomethyl ether, and propylene glycol monomethyl ether acetate is preferable.

In a case where the photosensitive material includes a solvent, the solid content of the photosensitive material is preferably 5% to 80% by mass, more preferably 8% to 40% by mass, and still more preferably 10% to 30% by mass. That is, in a case where the photosensitive material includes a solvent, the content of the solvent is preferably 20% to 95% by mass, more preferably 60% to 95% by mass, and still more preferably 70% to 95% by mass with respect to the total mass of the photosensitive material.

The solvent may be used alone, or in combination of two or more kinds thereof.

In a case where the photosensitive material includes a solvent, from the viewpoint of coating properties, a viscosity (25° C.) of the photosensitive material is preferably 1 to 50 mPa·s, more preferably 2 to 40 mPa·s, and still more preferably 3 to 30 mPa·s.

The viscosity is measured using, for example, a VISCOMETER TV-22 (manufactured by TOKI SANGYO CO., LTD.).

In a case where the photosensitive material includes a solvent, from the viewpoint of coating properties, a surface tension (25° C.) of the photosensitive material is preferably 5 to 100 mN/m, more preferably 10 to 80 mN/m, and still more preferably 15 to 40 mN/m.

The surface tension is measured using, for example, Automatic Surface Tensiometer CBVP-Z (manufactured by Kyowa Interface Science Co., Ltd.).

As the solvent, solvents described in paragraphs 0054 and 0055 of US2005/282073A can also be used, and the contents of these publications are incorporated in the present specification.

In addition, as the solvent, an organic solvent (high-boiling-point solvent) having a boiling point of 180° C. to 250° C. can also be used as necessary.

<<<Other Layers>>>

In addition, in a case where a layer of high refractive index and/or other layers, which are described later, is formed on the temporary support or the cover film, the photosensitive layer may be formed on the layer of high refractive index and/or other layers.

<<Layer of High Refractive Index>>

The transfer film also preferably has a layer of high refractive index.

The layer of high refractive index is preferably disposed adjacent to the photosensitive layer, and is also preferably disposed on a side opposite to the temporary support in a case of being viewed from the photosensitive layer.

The layer of high refractive index is not particularly limited except that the layer has a refractive index of 1.50 or more at a wavelength of 550 nm.

The above-described refractive index of the layer of high refractive index is preferably 1.55 or more and more preferably 1.60 or more.

The upper limit of the refractive index of the layer of high refractive index is not particularly limited, but is preferably 2.10 or less, more preferably 1.85 or less, still more preferably 1.78 or less, and particularly preferably 1.74 or less.

In addition, it is preferable that the refractive index of the layer of high refractive index is higher than the refractive index of the photosensitive layer.

The layer of high refractive index may have photocuring properties (that is, photosensitivity), may have thermosetting properties, or may have both photocuring properties and thermosetting properties.

The aspect in which the layer of high refractive index has photosensitivity, has an advantage, from a viewpoint of collectively patterning the photosensitive layer and the layer of high refractive index transferred onto the base material by photolithography at one time, after the transferring.

The layer of high refractive index preferably has alkali solubility (for example, solubility with respect to weak alkali aqueous solution).

In addition, the layer of high refractive index is preferably a transparent layer.

A film thickness of the layer of high refractive index is preferably 500 nm or less, more preferably 110 nm or less, and still more preferably 100 nm or less.

In addition, the film thickness of the layer of high refractive index is preferably 20 nm or more, more preferably 55 nm or more, still more preferably 60 nm or more, and particularly preferably 70 nm or more.

After the transferring, the layer of high refractive index may be sandwiched between a transparent electrode pattern (preferably, an ITO pattern) and the photosensitive layer to form a laminate together with the transparent electrode pattern and the photosensitive layer. In this case, by reducing a difference in refractive index between the transparent electrode pattern and the layer of high refractive index and a difference in refractive index between the layer of high refractive index and the photosensitive layer, a light reflection is further reduced. As a result, covering property of the transparent electrode pattern is further improved.

For example, in a case where the transparent electrode pattern, the layer of high refractive index, and the photosensitive layer are laminated in this order, this transparent electrode pattern is less likely to be visually recognized in a case of being viewed from the transparent electrode pattern side.

The refractive index of the layer of high refractive index is preferably adjusted in accordance with the refractive index of the transparent electrode pattern.

For example, in a case where the transparent electrode pattern is formed of an oxide of In and Sn (ITO), the refractive index of the transparent electrode pattern is in a range of 1.8 to 2.0, and the refractive index of the layer of high refractive index is preferably 1.60 or more. The upper limit of the refractive index of the layer of high refractive index in this case is not particularly limited, but is preferably 2.1 or less, more preferably 1.85 or less, still more preferably 1.78 or less, and particularly preferably 1.74 or less.

For example, in a case where the transparent electrode pattern is formed of an oxide of In and Zn (Indium Zinc Oxide; IZO), the refractive index of the transparent electrode pattern is more than 2.0, and the refractive index of the layer of high refractive index is preferably 1.70 to 1.85.

A method for controlling the refractive index of the layer of high refractive index is not particularly limited, and examples thereof include a method using a resin having a predetermined refractive index alone, a method using a resin and metal oxide particles or metal particles, and a method using a composite body of a metal salt and a resin.

The type of the metal oxide particles or the metal particles is not particularly limited, and known metal oxide particles or metal particles can be used. The metal of the metal oxide particles or the metal particles also includes semimetal such as B, Si, Ge, As, Sb, or Te.

From the viewpoint of transparency, for example, an average primary particle diameter of the particles (metal oxide particles or metal particles) is preferably 1 to 200 nm and more preferably 3 to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

Specifically, as the metal oxide particles, at least one selected from the group consisting of zirconium oxide particles (ZrO₂ particles), Nb₂O₅ particles, titanium oxide particles (TiO₂ particles), silicon dioxide particles (Sift particles), and composite particles thereof is preferable.

Among these, for example, from the viewpoint that the refractive index of the layer of high refractive index can be easily adjusted to 1.6 or more, the metal oxide particles are more preferably at least one selected from the group consisting of zirconium oxide particles and titanium oxide particles.

In a case where the layer of high refractive index includes metal oxide particles, the layer of high refractive index may include only one kind of metal oxide particles, or may include two or more kinds thereof.

From the viewpoint that covering property of a concealed object such as the electrode pattern is improved and visibility of the concealed object can be effectively improved, a content of the particles (metal oxide particles or metal particles) is preferably 1% to 95% by mass, more preferably 20% to 90% by mass, and still more preferably 40% to 85% by mass with respect to the total mass of the layer of high refractive index.

In a case where titanium oxide is used as the metal oxide particles, a content of the titanium oxide particles is preferably 1% to 95% by mass, more preferably 20% to 90% by mass, and still more preferably 40% to 85% by mass with respect to the total mass of the layer of high refractive index.

Examples of a commercially available product of the metal oxide particles include calcined zirconium oxide particles (manufactured by CIK-Nano Tek., product name: ZRPGM15WT %-F04), calcined zirconium oxide particles (manufactured by CIK-Nano Tek., product name: ZRPGM15WT %-F74), calcined zirconium oxide particles (manufactured by CIK-Nano Tek., product name: ZRPGM15WT %-F75), calcined zirconium oxide particles (manufactured by CIK-Nano Tek., product name: ZRPGM15WT %-F76), zirconium oxide particles (NanoUse OZ-S30M, manufactured by Nissan Chemical Corporation), and zirconium oxide particles (NanoUse OZ-S30K, manufactured by Nissan Chemical Corporation).

The layer of high refractive index preferably includes one or more kinds selected from the group consisting of inorganic particles (metal oxide particles or metal particles) having a refractive index 1.50 or more (more preferably 1.55 or more and still more preferably 1.60 or more), a resin having a refractive index 1.50 or more (more preferably 1.55 or more and still more preferably 1.60 or more), and a polymerizable compound having a refractive index 1.50 or more (more preferably 1.55 or more and still more preferably 1.60 or more).

According to this aspect, the refractive index of the layer of high refractive index is easily adjusted to 1.50 or more (more preferably 1.55 or more and particularly preferably 1.60 or more).

In addition, the layer of high refractive index preferably includes a binder polymer, a polymerizable monomer, and particles.

With regard to the components of the layer of high refractive index, components of a curable transparent resin layer described in paragraphs 0019 to 0040 and 0144 to 0150 of JP2014-108541A, and components of a transparent layer described in paragraphs 0024 to 0035 and 0110 to 0112 of JP2014-010814A, and components of a composition including ammonium salt described in paragraphs 0034 to 0056 of WO2016/009980A can be referred to.

In addition, it is also preferable that the layer of high refractive index includes a metal oxidation inhibitor.

The metal oxidation inhibitor is a compound which can be used to surface-treat a member that is in direct contact with the layer of high refractive index (for example, a conductive member formed on the base material) (however, the compound β is excluded).

In a case where the layer of high refractive index includes a metal oxidation inhibitor, during transferring the layer of high refractive index onto the base material (that is, an object to be transferred), a member that is in direct contact with the layer of high refractive index (for example, a conductive member formed on the base material) can be surface-treated. This surface treatment imparts a metal oxide inhibiting function (protection properties) with respect to the member that is in direct contact with the layer of high refractive index.

The metal oxidation inhibitor is preferably a compound having an aromatic ring having a nitrogen atom. The compound having an aromatic ring having a nitrogen atom may have a substituent.

The metal oxidation inhibitor is preferably a compound having a 5-membered aromatic ring having a nitrogen atom as a ring member atom.

The aromatic ring including a nitrogen atom is preferably an imidazole ring, a triazole ring, a tetrazole ring, a thiazole ring, a thiadiazole ring, or a fused ring of any one of these rings and another aromatic ring, and more preferably an imidazole ring, a triazole ring, a tetrazole ring, or a fused ring of any one of these rings and another aromatic ring.

The “another aromatic ring” forming the fused ring may be a homocyclic ring or a heterocyclic ring, is preferably a homocyclic ring, more preferably a benzene ring or a naphthalene ring, and still more preferably a benzene ring.

As the metal oxidation inhibitor, imidazole, benzimidazole, tetrazole, 5-amino-1H-tetrazole, mercaptothiadiazole, or benzotriazole is preferable, and imidazole, benzimidazole, 5-amino-1H-tetrazole, or benzotriazole is more preferable.

A commercially available product may be used as the metal oxidation inhibitor, and as the commercially available product, for example, BT120 manufactured by JOHOKU CHEMICAL CO., LTD., which includes benzotriazole, can be preferably used.

In a case where the layer of high refractive index includes a metal oxidation inhibitor, a content of the metal oxidation inhibitor is preferably 0.1% to 20% by mass, more preferably 0.5% to 10% by mass, and still more preferably 1% to 5% by mass with respect to the total solid content of the layer of high refractive index.

The layer of high refractive index may contain a component other than the above-described components.

Examples of other components which can be included in the layer of high refractive index include components same as those which can be included in the photosensitive layer.

The layer of high refractive index also preferably includes a surfactant.

A method for forming the layer of high refractive index is not particularly limited.

Examples of the method for forming the layer of high refractive index include a forming method in which a composition for forming the layer of high refractive index in an aspect of including an aqueous solvent is applied to the above-described photosensitive layer which has been formed on the temporary support, and the composition is dried as necessary.

The composition for forming the layer of high refractive index can contain each component of the above-described layer of high refractive index.

For example, the composition for forming the layer of high refractive index includes a binder polymer, a polymerizable monomer, particles, and an aqueous solvent.

In addition, as the composition for forming the layer of high refractive index, a composition including ammonium salt, described in paragraphs 0034 to 0056 of WO2016/009980A, is also preferable.

The photosensitive layer and the layer of high refractive index are preferably achromatic. Specifically, in CIE1976 (L*, a*, b*) color space of the total reflection (incidence angle: 8°, light source: D-65 (visual field: 2°), the L* value is preferably 10 to 90, the a* value is preferably −1.0 to 1.0, and the b* value is preferably −1.0 to 1.0.

<<Cover Film>>

The transfer film according to the embodiment of the present invention may further have a cover film on a side of the photosensitive layer opposite to the temporary support.

In a case where the transfer film according to the embodiment of the present invention includes a layer of high refractive index, the cover film is preferably disposed on a side opposite to the temporary support (that is, a side opposite to the photosensitive layer) in a case of being viewed from the layer of high refractive index. In this case, for example, the transfer film is a laminate in which “temporary support/photosensitive layer/layer of high refractive index/cover film” are laminated in this order.

The cover film preferably has 5 pieces/m² or less of the number of fisheyes with a diameter of 80 μm or more in the cover film. The “fisheye” means that, in a case where a material is hot-melted, kneaded, extruded, biaxially stretched, cast or the like to produce a film, foreign substances, undissolved substances, oxidatively deteriorated substances, and/or the like of the material are incorporated into the film.

The number of particles having a diameter of 3 μm or more included in the cover film is preferably 30 particles/mm² or less, more preferably 10 particles/mm² or less, and still more preferably 5 particles/mm² or less. As a result, it is possible to suppress defects caused by ruggedness due to the particles included in the cover film being transferred to the photosensitive resin layer.

An arithmetic average roughness Ra of a surface of the cover film is preferably 0.01 μm or more, more preferably 0.02 μm or more, and still more preferably 0.03 μm or more. In a case where Ra is within such a range, for example, in a case where the transfer film has a long shape, take-up property in a case of winding the transfer film can be improved.

In addition, from the viewpoint of suppressing defects during transfer, Ra is preferably less than 0.50 μm, more preferably 0.40 μm or less, and still more preferably 0.30 μm or less.

Examples of the cover film include a polyethylene terephthalate film, a polypropylene film, a polystyrene film, and a polycarbonate film.

As the cover film, for example, films described in paragraphs 0083 to 0087 and 0093 of JP2006-259138A may be used.

As the cover film, for example, ALPHAN (registered trademark) FG-201 manufactured by Oji F-Tex Co., Ltd., ALPHAN (registered trademark) E-201F manufactured by Oji F-Tex Co., Ltd., Cerapeel (registered trademark) 25WZ manufactured by TORAY ADVANCED FILM CO., LTD., or LUMIRROR (registered trademark) 16QS62 (16KS40) manufactured by Toray Industries, Inc. may be used.

<<Other Layers>>

The transfer film may include a layer other than the above-described layers (hereinafter, also referred to as “other layers”). Examples of the other layers include an interlayer and a thermoplastic resin layer, and known ones can be appropriately adopted.

A preferred aspect of the thermoplastic resin layer is described in paragraphs 0189 to 0193 of JP2014-085643A, and preferred aspects of layers other than the above each are described in paragraphs 0194 to 0196 of JP2014-085643A, and the contents of these publications are incorporated in the present specification.

<<<Manufacturing Method of Transfer Film>>>

A manufacturing method of the transfer film is not particularly limited, and a known manufacturing method can be adopted.

The manufacturing method of the transfer film preferably includes a step of forming a photosensitive layer by applying and drying a photosensitive material including a solvent on a temporary support, and more preferably includes a step of further disposing a cover film on the photosensitive layer after the step of forming the photosensitive layer.

In addition, after the step of forming the photosensitive layer, a step of forming a layer of high refractive index by applying and drying a composition for forming the layer of high refractive index may be included. In this case, after the step of forming the layer of high refractive index, it is preferable to further include a step of disposing a cover film on the layer of high refractive index.

[Pattern Forming Method]

A pattern forming method according to an embodiment of the present invention is not particularly limited as long as it is a pattern forming method using the above-described transfer film, but it is preferable to include a step of forming a photosensitive layer on a base material, a step of exposing the photosensitive layer in a patterned manner, and a step of developing the exposed photosensitive layer (alkali development or organic solvent development) in this order. In a case where the above-described development is an organic solvent development, it is preferable to include a step of further exposing the obtained pattern.

Examples of specific embodiments of the pattern forming method according to the present invention include the above-described pattern forming methods of the embodiment 1 and the embodiment 2.

Hereinafter, each step of the pattern forming methods of the embodiment 1 and the embodiment 2 will be described in detail.

[Pattern Forming Method of Embodiment 1]

A pattern forming method of an embodiment 1 includes steps X1 to X3. The following step X2 corresponds to a step of reducing the content of the acid group derived from the compound A in the photosensitive layer by the exposure. However, in a case where a developer in the step X3 is an organic solvent-based developer, a step X4 is further included after the step X3.

Step X1: step of bringing a surface of the photosensitive layer in the transfer film on an opposite side of a temporary support side into contact with a base material to bond the transfer film and the base material

Step X2: step of exposing the photosensitive layer in a patterned manner

Step X3: step of developing the photosensitive layer with a developer

Step X4: step of further exposing the pattern formed by the development after the developing step of the step X3

In a case where an alkali developer is used as the developer in the step X3, the above-described photosensitive layer is preferably the photosensitive layers of the embodiment X-1-a1 and the embodiment X-1-a2. In a case where an organic solvent-based developer is used as the developer in the step X3, the above-described photosensitive layer is preferably the photosensitive material of the embodiment X-1-a1.

The pattern forming method of the embodiment 1 is preferably adopted to the transfer film including the above-described photosensitive layers of the embodiment X-1-a1 and the embodiment X-1-a2.

<<<Step X1>>>

The pattern forming method of the embodiment 1 includes a step of bringing a surface of the photosensitive layer in the transfer film on an opposite side of a temporary support side into contact with a base material to bond the transfer film and the base material.

<<Base Material>>

The base material is not particularly limited, and examples thereof include a glass substrate, a silicon substrate, a resin substrate, and a substrate having a conductive layer. Examples of the substrate included in the substrate having a conductive layer include a glass substrate, a silicon substrate, and a resin substrate.

The above-described base material is preferably transparent.

A refractive index of the above-described base material is preferably 1.50 to 1.52.

The above-described base material may be composed of a translucent substrate such as a glass substrate, and for example, tempered glass typified by Gorilla glass of Corning can also be used. In addition, as the material included in the above-described base material, materials used in JP2010-086684A, JP2010-152809A, and JP2010-257492A are also preferable.

In a case where the above-described base material includes a resin substrate, as the resin substrate, it is more preferable to use a resin film having a small optical distortion and/or a high transparency. Specific examples of the material include polyethylene terephthalate (PET), polyethylene naphthalate, polycarbonate, triacetyl cellulose, and a cycloolefin polymer.

As the substrate included in the substrate having a conductive layer, from the viewpoint of manufacturing by roll-to-roll method, a resin substrate is preferable and a resin film is more preferable.

Examples of the conductive layer include any conductive layer used for general circuit wiring or touch panel wiring.

As the conductive layer, from the viewpoint of conductivity and fine line formability, one or more layers selected from the group consisting of a metal layer, a conductive metal oxide layer, a graphene layer, a carbon nanotube layer, and a conductive polymer layer are preferable, a metal layer is more preferable, and a copper layer or a silver layer is still more preferable.

In addition, the conductive layer in the substrate having a conductive layer may be one layer or two or more layers.

In a case where the substrate having a conductive layer includes two or more conductive layers, it is preferable that each conductive layer is a conductive layer formed of different materials.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” means that a volume resistivity is less than 1×10⁶ Ω·cm, and the volume resistivity is preferably less than 1×10⁴∩·cm.

In a case where the number of conductive layers in the substrate having a conductive layer is 2 or more, it is preferable that at least one conductive layer among the conductive layers includes the conductive metal oxide.

The conductive layer is preferably an electrode pattern corresponding to a sensor in a visual recognition portion used for a capacitive touch panel or a wiring line for a peripheral wiring portion.

In addition, the conductive layer is preferably a transparent layer.

<<Procedure of Step X1>>

The step X1 is preferably a bonding step of pressurization by a roll or the like and heating.

A known laminator such as a laminator, a vacuum laminator, and an auto-cut laminator can be used for the bonding.

The step X1 is preferably performed by a roll-to-roll method, and therefore, the base material to which the transfer film is bonded is preferably a resin film or a resin film having a conductive layer.

Hereinafter, the roll-to-roll method will be described.

The roll-to-roll method refers to a method in which, as the base material, a base material which can be wound up and unwound is used, a step (also referred to as an “unwinding step”) of unwinding the base material or a structure including the base material is included before any of the steps included in the pattern forming method according to the embodiment of the present invention, a step (also referred to as a “winding step”) of winding the base material is included after any of the steps, and at least one of the steps (preferably, all steps or all steps other than the heating step) is performed while transporting the base material.

An unwinding method in the unwinding step and a winding method in the winding step are not particularly limited, and a known method may be used in the manufacturing method to which the roll-to-roll method is adopted.

<<Step X2>>

The pattern forming method of the embodiment 1 includes a step (step X2) of exposing the photosensitive layer in a patterned manner after the above-described step X1. The step X2 corresponds to a step of reducing the content of the acid group derived from the compound A in the photosensitive layer by the exposure. More specifically, it is preferable that, by using light having a wavelength which excites the specific structure S0 (preferably, the specific structure S1) in the compound β (preferably, the compound B) in the photosensitive layer (in a case of the requirement (V01)) and the specific structure S0 (preferably, the specific structure S1) in the compound A (in a case of the requirement (W01)), the photosensitive layer is exposed in a patterned manner.

Detailed arrangement and specific size of the pattern in the exposing step are not particularly limited.

For example, in a case where the pattern forming method of the embodiment 1 is adopted to the manufacturing of a circuit wiring, from the viewpoint of improving display quality of a display device (for example, a touch panel) including an input device having the circuit wiring manufactured by the pattern forming method of the embodiment 1, and viewpoint of reducing an area occupied by a lead-out wiring as much as possible, at least a part of the pattern (in particular, a portion of the electrode pattern of the touch panel and the lead-out wiring) is preferably a thin line having a width of 100 μm or less, and more preferably a thin line having a width of 70 μm or less.

As a light source used for the exposure, any light source which irradiates light in a wavelength range capable of reducing the content of the acid group derived from the compound A in the photosensitive layer (light having a wavelength which excites the specific structure S0 (preferably, the specific structure S1) in the compound β (preferably, the compound B) in the photosensitive layer (in a case of the requirement (V01)) and the specific structure S0 (preferably, the specific structure S1) in the compound A (in a case of the requirement (W01)); for example, in a case where the photosensitive layer is the above-described photosensitive layer, examples thereof include light in a wavelength range such as 254 nm, 313 nm, 365 nm, and 405 nm) can be appropriately selected. Specific examples thereof include an ultra-high pressure mercury lamp, a high pressure mercury lamp, a metal halide lamp, and a light emitting diode (LED).

An exposure amount is preferably 10 to 10000 mJ/cm² and more preferably 50 to 3000 mJ/cm².

In the step X2, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through a mask and a direct exposure using a laser or the like.

Before the step X3 described later, the temporary support is peeled off from the photosensitive layer.

<<Step X3>>

The pattern forming method of the embodiment 1 includes a step (step X3) of, after the above-described step X2, developing the photosensitive layer exposed in a patterned manner with a developer (alkali developer or organic solvent-based developer).

By reducing the content of the acid group in the photosensitive layer of the exposed portion, a difference in solubility (dissolution contrast) in the developer may occur between the exposed portion and the non-exposed portion of the photosensitive layer which has undergone the step X2. By forming the dissolution contrast in the photosensitive layer, it is possible to form a pattern in the step X3. In a case where the developer in the above-described step X3 is an alkali developer, the non-exposed portion is removed and a negative pattern is formed by performing the above-described step X3. On the other hand, in a case where the developer in the above-described step X3 is an organic solvent-based developer, the exposed portion is removed and a positive pattern is formed by performing the above-described step X3. For the obtained positive pattern, it is necessary to perform a treatment for reducing the content of the acid group derived from the compound A by the step X4 described later.

(Alkali Developer)

The alkali developer is not particularly limited as long as the non-exposed portion of the photosensitive resin layer can be removed, and a known developer such as a developer described in JP1993-072724A (JP-H5-072724A) can be used.

As the alkali developer, for example, an alkali aqueous solution-based developer including a compound having a pKa of 7 to 13 at a concentration of 0.05 to 5 mol/L (liter) is preferable.

In addition, the alkali developer may further include a water-soluble organic solvent, a surfactant, and the like. As the alkali developer, for example, developers described in paragraph 0194 of WO2015/093271A are preferable.

(Organic Solvent-Based Developer)

The organic solvent-based developer is not particularly limited as long as it can remove the exposed portion of the photosensitive resin layer, and for example, a developer including an organic solvent such as a ketone-based solvent, an ester-based solvent, an alcohol-based solvent, an amide-based solvent, an ether-based solvent, and a hydrocarbon-based solvent can be used.

In the organic solvent-based developer, a plurality of organic solvents may be mixed, or may be mixed with an organic solvent other than the above or water and used. However, in order to fully exert the effects of the present invention, a moisture content of the organic solvent-based developer as a whole is preferably less than 10% by mass, and the organic solvent-based developer is more preferably substantially free of the moisture. A concentration of the organic solvent (in a case of mixing a plurality of organic solvents, a total thereof) in the organic solvent-based developer is preferably 50% by mass or more, more preferably 60% by mass or more, still more preferably 85% by mass or more, particularly preferably 90% by mass or more, and most preferably 95% by mass or more. The upper limit value thereof is, for example, 100% by mass or less.

A development method is not particularly limited, and may be any of a puddle development, a shower development, a spin development, a dip development, or the like. Here, as the shower development, unnecessary portions can be removed by spraying the developer on the photosensitive resin layer after the exposure with a shower. In addition, after the development, it is also preferable to spray a washing agent and the like with a shower and rub with a brush and the like to remove the developing residue. A liquid temperature of the developer is preferably 20° C. to 40° C.

The pattern forming method of the embodiment 1 may further include a post-baking step of heat-treating a pattern including the photosensitive layer obtained by development.

The post-baking is preferably performed in an environment of 8.1 to 121.6 kPa, and more preferably performed in an environment of 50.66 kPa or more. On the other hand, it is more preferably performed in an environment of 111.46 kPa or less, and still more preferably performed in an environment of 101.3 kPa or less.

A temperature of the post-baking is preferably 80° C. to 250° C., more preferably 110° C. to 170° C., and still more preferably 130° C. to 150° C.

A time of the post-baking is preferably 1 to 60 minutes, more preferably 2 to 50 minutes, and still more preferably 5 to 40 minutes.

The post-baking may be performed in an air environment or a nitrogen replacement environment.

<<Step X4>>

In a case where the developer in the above-described step X3 is an organic solvent-based developer, the step X4 is performed on the obtained positive pattern. The step X4 corresponds to a step of exposing the positive pattern obtained in the step X3 to reduce the content of the acid group derived from the compound A. More specifically, it is preferable that, by using light having a wavelength which excites the specific structure S0 (preferably, the specific structure S1) in the compound β (preferably, the compound B) in the photosensitive layer (in a case of the requirement (V01)) and the specific structure S0 (preferably, the specific structure S1) in the compound A (in a case of the requirement (W01)), the photosensitive layer is exposed in a patterned manner.

A light source and exposure amount used for the exposure are the same as the light source and exposure amount described in the step X1, and preferred aspects thereof are also the same.

[Pattern Forming Method of Embodiment 2]

A pattern forming method of an embodiment 2 includes a step Y1, a step Y2P, and a step Y3 in this order, and further includes a step Y2Q (step of further exposing the photosensitive layer exposed in the step Y2P) between the step Y2P and the step Y3 or after the step Y3.

Step Y1: step of bringing a surface of the photosensitive layer in the transfer film on an opposite side of a temporary support side into contact with a base material to bond the transfer film and the base material

Step Y2P: step of exposing the photosensitive layer Step Y3: step of developing the photosensitive layer with a developer

As described above, the pattern forming method of the embodiment 2 corresponds to an aspect in which the photosensitive layer further includes a photopolymerization initiator and a polymerizable compound. Therefore, the pattern forming method of the embodiment 2 is preferably adopted to the transfer film including the above-described photosensitive layer of the embodiment X-1-a3.

Hereinafter, the pattern forming method of the embodiment 2 will be described, but the step Y1 and the step Y3 are the same as the step X1 and the step X3, respectively, so that the description thereof will be omitted.

It is sufficient that the step Y3 is performed at least after the step Y2P, and the step Y3 may be performed between the step Y2P and the step Y2Q.

The pattern forming method of the embodiment 2 may further include, after the step Y3, a post-baking step of heat-treating a pattern including the photosensitive layer obtained by development. The post-baking step can be performed by the same method as the post-baking step which may be included in the above-described pattern forming method of the embodiment 1. In a case where the step Y3 is performed between the step Y2P and the step Y2Q, the post-baking step may be performed before the step Y2Q or after the step Y2Q as long as it is performed after the step Y3.

<<Step Y2P and Step Y2Q>>

The pattern forming method of the embodiment 2 includes a step (step Y2P) of exposing the photosensitive layer through the step Y1 and a step (step Y2Q) of further exposing the exposed photosensitive layer.

One of the exposure treatments (the step Y2P and the step Y2Q) is an exposure for mainly reducing the content of the acid group derived from the compound A by the exposure, and the other of the exposure treatments (the step Y2P and the step Y2Q) is an exposure for mainly causing a polymerization reaction of the polymerizable compound based on the photopolymerization initiator. In addition, the exposure treatments (the step Y2P and the step Y2Q) may be either the entire exposure or the pattern exposure, but any one of the exposure treatments is the pattern exposure.

For example, in a case where the step Y2P is a pattern exposure for reducing the content of the acid group derived from the compound A by the exposure, the developer used in the step Y3 may be an alkali developer or an organic solvent-based developer. However, in a case of developing with an organic solvent-based developer, the step Y2Q is usually performed after the step Y3, and in the developed photosensitive layer (pattern), the polymerization reaction of the polymerizable compound based on the photopolymerization initiator occurs, and the content of the acid group (preferably, a carboxy group) derived from the compound A is reduced.

In addition, for example, in a case where the step Y2P is a pattern exposure for causing a polymerization reaction of the polymerizable compound based on the photopolymerization initiator, the developer used in the step Y3 is usually an alkali developer. In this case, the step Y2Q may be performed before or after the step Y3, and the step Y2Q in a case of being performed before the step Y3 is usually a pattern exposure.

In the step Y2P and the step Y2Q, as a light source used for the exposure, any light source which irradiates light in a wavelength range capable of reducing the content of the acid group derived from the compound A in the photosensitive layer (light having a wavelength which excites the specific structure S0 (preferably, the specific structure S1) in the compound R (preferably, the compound B) in the photosensitive layer (in a case of the requirement (V01)) and the specific structure S0 (preferably, the specific structure S1) in the compound A (in a case of the requirement (W01)); for example, in a case where the photosensitive layer is the above-described photosensitive layer, examples thereof include light in a wavelength range such as 254 nm, 313 nm, 365 nm, and 405 nm) or light in a wavelength range capable of causing a reaction of the polymerizable compound based on the photopolymerization initiator in the photosensitive layer (light having a wavelength which exposes the photopolymerization initiator; examples thereof include 254 nm, 313 nm, 365 nm, and 405 nm) can be appropriately selected. Specific examples thereof include an ultra-high pressure mercury lamp, a high pressure mercury lamp, a metal halide lamp, and a light emitting diode (LED).

In the exposure for reducing the content of the acid group derived from the compound A in the photosensitive layer, an exposure amount is preferably 10 to 10000 mJ/cm², and more preferably 50 to 3000 mJ/cm².

In the exposure for causing a reaction of the polymerizable compound based on the photopolymerization initiator in the photosensitive layer, an exposure amount is preferably 5 to 200 mJ/cm², and more preferably 10 to 150 mJ/cm².

In the step Y2P and the step Y2Q, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through a mask and a direct exposure using a laser or the like.

Detailed arrangement and specific size of the pattern in the exposing step are not particularly limited.

For example, in a case where the pattern forming method of the embodiment 2 is adopted to the manufacturing of a circuit wiring, from the viewpoint of improving display quality of a display device (for example, a touch panel) including an input device having the circuit wiring manufactured by the pattern forming method of the embodiment 2, and viewpoint of reducing an area occupied by a lead-out wiring as much as possible, at least a part of the pattern (in particular, a portion of the electrode pattern of the touch panel and the lead-out wiring) is preferably a thin line having a width of 100 μm or less, and more preferably a thin line having a width of 70 μm or less.

<<Preferred Aspect>>

Among these, as the pattern forming method of the embodiment 2, it is preferable to include a step Y1, a step Y2A, a step Y3, and a step Y2B in this order. One of the step Y2A and the step Y2B is an exposing step for reducing the content of the acid group derived from the compound A by the exposure, and the other is an exposing step for causing a polymerization reaction of the polymerizable compound based on the photopolymerization initiator.

Step Y1: step of bringing a surface of the photosensitive layer in the transfer film on an opposite side of a temporary support side into contact with a base material to bond the transfer film and the base material

Step Y2A: step of exposing the photosensitive layer in a patterned manner Step Y3: step of developing the photosensitive layer with an alkali developer to form a patterned photosensitive layer

Step Y2B: step of exposing the patterned photosensitive layer

The above-described step Y2A is preferably an exposing step for causing a polymerization reaction of the polymerizable compound based on the photopolymerization initiator, and the above-described step Y2B is preferably an exposing step for reducing the content of the acid group derived from the compound A by the exposure.

[Optional Step which May be Included in Pattern Forming Methods of Embodiment 1 and Embodiment 2]

The pattern forming methods of the embodiment 1 and the embodiment 2 may include optional steps (other steps) in addition to those described above. Examples thereof include the following steps, but the other steps are not limited to these steps.

<<Cover Film Peeling Step>>

In the above-described pattern forming method, in a case where the transfer film has a cover film, it is preferable to include a step (hereinafter, also referred to as a “cover film peeling step”) of peeling off the cover film of the transfer film. A method of peeling off the cover film is not particularly limited, and a known method can be adopted.

<<Step of Reducing Visible Light Reflectivity>>

In a case where the substrate is the substrate having a conductive layer, the above-described pattern forming method may further include a step of performing a treatment of reducing a visible light reflectivity of the conductive layer. In a case where the above-described substrate is a substrate having a plurality of conductive layers, the treatment of reducing the visible light reflectivity may be performed on some conductive layers or all conductive layers.

Examples of the treatment of reducing the visible light reflectivity include an oxidation treatment. For example, by oxidizing copper to copper oxide, the visible light reflectivity of the conductive layer can be reduced due to blackening.

Preferred aspects of the treatment of reducing the visible light reflectivity are described in paragraphs 0017 to 0025 of JP2014-150118A, and paragraphs 0041, 0042, 0048, and 0058 of JP2013-206315A, and the contents of these publications are incorporated in the present specification.

<<Etching Step>>

In a case where the substrate is the substrate having a conductive layer, the above-described pattern forming method preferably includes a step (etching step) of etching, using the pattern formed by the step X3 (or the step X4) and the step Y3 as an etching resist film, the conductive layer in a region where the etching resist film is not disposed.

As a method of the etching treatment, a method by wet etching, which is described in paragraphs 0048 to 0054 of JP2010-152155A, a method by dry etching such as a known plasma etching, or the like can be adopted.

For example, examples of the method of the etching treatment include a wet etching method by immersing in an etchant, which is generally performed. As the etchant used for the wet etching, an acidic type or alkaline type etchant may be appropriately selected according to the etching target.

Examples of the acidic type etchant include aqueous solutions of acidic component alone, such as hydrochloric acid, sulfuric acid, hydrofluoric acid, and phosphoric acid, and mixed aqueous solutions of an acidic component and a salt such as ferric chloride, ammonium fluoride, and potassium permanganate. As the acidic component, a component in which a plurality of acidic components is combined may be used.

Examples of the alkaline type etchant include aqueous solutions of alkaline component alone, such as sodium hydroxide, potassium hydroxide, ammonia, organic amine, and a salt of organic amine such as tetramethylammonium hydroxide, and mixed aqueous solutions of an alkaline component and a salt such as potassium permanganate. As the alkaline component, a component in which a plurality of alkaline components is combined may be used.

A temperature of the etchant is not particularly limited, but is preferably 45° C. or lower. In a manufacturing method of a circuit wiring according to an embodiment of the present invention, the pattern formed by the step X3 (or the step X4) and the step Y3 used as the etching resist film preferably exhibits particularly excellent resistance to the acidic and alkaline etchant in a temperature range of 45° C. or lower. With the above-described configuration, the etching resist film is prevented from peeling off during the etching step, and a portion where the etching resist film does not exist is selectively etched.

After the etching step, in order to prevent contamination of the process line, a washing step of washing the etched substrate and a drying step of drying the washed substrate may be performed as necessary.

### Other Embodiments

As the above-described pattern forming method, it is also preferable to use a substrate having a plurality of conductive layers on both surfaces and sequentially or simultaneously form a pattern on the conductive layers formed on both surfaces.

With such a configuration, it is possible to form a first conductive pattern is formed on one surface of the substrate and form a second conductive pattern on the other surface. It is also preferable to form from both surfaces of the base material by the roll-to-roll.

[Pattern]

The pattern formed by the above-described pattern forming methods of the embodiment 1 and the embodiment 2 has reduced content of the acid group, so that polarity is low, and moisture permeability and relative permittivity are low.

The content of the acid group in the above-described pattern is preferably reduced by 5 mol % or more, more preferably reduced by 10 mol % or more, even more preferably reduced by 20 mol % or more, still more preferably reduced by 31 mol % or more, particularly preferably reduced by 40 mol % or more, more particularly preferably reduced by 51 mol % or more, and most preferably reduced by 71 mol % or more with respect to the content of the acid group in the photosensitive layer formed in the step X1 or the step Y1. The upper limit value thereof is not particularly limited, and for example, is 100 mol % or less.

The moisture permeability of the above-described pattern is preferably reduced by 5% or more, more preferably reduced by 10% or more, and still more preferably reduced by 20% or more with respect to the moisture permeability of the photosensitive layer formed in the step X1 or the step Y1. The upper limit value thereof is not particularly limited, and for example, is 100% or less.

The relative permittivity of the above-described pattern is preferably reduced by 5% or more, more preferably reduced by 10% or more, and still more preferably reduced by 15% or more with respect to the relative permittivity of the photosensitive layer formed in the step X1 or the step Y1. The upper limit value thereof is not particularly limited, and for example, is 100% or less.

An average thickness of the pattern formed by the above-described pattern forming method is preferably 0.5 to 20 μm. The average thickness of the pattern is more preferably 0.8 to 15 μm and still more preferably 1.0 to 10 μm.

The pattern formed by the above-described pattern forming method is preferably achromatic.

Specifically, in CIE1976 (L*, a*, b*) color space, the total reflection (incidence angle: 8°, light source: D-65 (visual field: 2°) preferably has a pattern L* value of 10 to 90, preferably has a pattern a* value of −1.0 to 1.0, and preferably has a pattern b* value of −1.0 to 1.0.

The use of the pattern formed by the above-described pattern forming method is not particularly limited, and can be used as various protective films or insulating films.

Specific examples thereof include the use as a protective film (permanent film) which protects a conductive pattern, the use as an interlayer insulating film between conductive patterns, and the use as an etching resist film in the manufacturing of the circuit wiring. Among these, since the above-described pattern is excellent in low moisture permeability, it is preferably used as a protective film (permanent film) which protects the conductive pattern or an interlayer insulating film between the conductive patterns.

The above-described pattern can be used as a protective film (permanent film) which protects a conductive pattern such as an electrode pattern corresponding to a sensor in a visual recognition portion and a wiring line for a peripheral wiring portion and a lead-out wiring portion is provided inside the touch panel, or as an interlayer insulating film between conductive patterns.

[Manufacturing Method of Circuit Wiring]

A manufacturing method of a circuit wiring according to an embodiment of the present invention is not particularly limited as long as it is a manufacturing method of a circuit wiring using the above-described transfer film, but it is preferable to include, in the following order, a step (bonding step) of bringing a surface of the photosensitive layer in the transfer film on an opposite side of a temporary support side into contact with a conductive layer in a substrate having a conductive layer to bond the transfer film and the substrate having a conductive layer, a step (first exposing step) of exposing the photosensitive layer in the bonded transfer film in a patterned manner, a step (alkali developing step) of developing the exposed photosensitive layer with an alkali developer to form a patterned photosensitive layer, a step (second exposing step) of exposing the patterned photosensitive layer to form an etching resist film, and a step (etching step) of etching the conductive layer in a region on which the etching resist film is not disposed.

In the manufacturing method of a circuit wiring according to the embodiment of the present invention, all of the bonding step, the first exposing step, the alkali developing step, and the second exposing step can be performed by the same procedure as in the step Y1, the step Y2A, the step Y3, and the step Y2B of the above-described pattern forming method of the embodiment 2. In addition, the substrate having a conductive layer, which is used in the manufacturing method of a circuit wiring according to the embodiment of the present invention, is the same as the substrate having a conductive layer, which is used in the above-described step X1. In addition, the manufacturing method of a circuit wiring according to the embodiment of the present invention may include a step other than the above-described steps. Examples of other steps include the same steps as the optional step which may be included in the pattern forming methods of the embodiment 1 and the embodiment 2.

In the manufacturing method of a circuit wiring according to the embodiment of the present invention, five steps of the above-described bonding step, the above-described first exposing step, the above-described developing step, the above-described second exposing step, and the above-described etching step are regarded as one set, and it is also preferable to repeat the set a plurality of times.

The film used as the etching resist film can also be used as a protective film (permanent film) for the formed circuit wiring.

[Manufacturing Method of Touch Panel]

A manufacturing method of a touch panel according to an embodiment of the present invention is not particularly limited as long as it is a manufacturing method of a touch panel using the above-described transfer film, but it is preferable to include, in the following order, a step (bonding step) of bringing a surface of the photosensitive layer in the transfer film on an opposite side of a temporary support side into contact with a conductive layer (preferably, a patterned conductive layer; specifically, a touch panel electrode pattern or a conductive pattern such as a wiring line) in a substrate having a conductive layer to bond the transfer film and the substrate having a conductive layer, a step (first exposing step) of exposing the photosensitive layer in the bonded transfer film in a patterned manner, a step (alkali developing step) of developing the exposed photosensitive layer with an alkali developer to form a patterned photosensitive layer, and a step (second exposing step) of exposing the patterned photosensitive layer to form a protective film or an insulating film of the conductive layer.

The protective film formed by the second exposing step has a function as a film which protects the surface of the conductive layer. In addition, the insulating film has a function as an interlayer insulating film between conductive layers. In a case where the second exposing step is a step of forming an insulating film of the conductive layer, it is preferable that the manufacturing method of a touch panel according to the embodiment of the present invention further includes a step of forming a conductive layer (preferably, a patterned conductive layer; specifically, a touch panel electrode pattern or a conductive pattern such as a wiring line) on the insulating film formed by the second exposing step.

In the manufacturing method of a touch panel according to the embodiment of the present invention, all of the bonding step, the first exposing step, the alkali developing step, and the second exposing step can be performed by the same procedure as in the step Y1, the step Y2A, the step Y3, and the step Y2B of the above-described pattern forming method of the embodiment 2. In addition, the substrate having a conductive layer, which is used in the manufacturing method of a touch panel according to the embodiment of the present invention, is the same as the substrate having a conductive layer, which is used in the above-described step X1. Examples of other steps include the same steps as the optional step which may be included in the pattern forming methods of the first embodiment and the second embodiment.

As the manufacturing method of a touch panel according to the embodiment of the present invention, a known manufacturing method of a touch panel can be referred to for configurations other than those described above.

The touch panel manufactured by the manufacturing method of a touch panel according to the embodiment of the present invention preferably has a transparent substrate, an electrode, and a protective film (protective layer).

As a detection method in the touch panel, any known method such as a resistive film method, a capacitance method, an ultrasonic method, an electromagnetic induction method, and an optical method may be used. Among these, a capacitance method is preferable.

Examples of the touch panel type include a so-called in-cell type (for example, those shown in FIGS. 5, 6, 7, and 8 of JP2012-517051B), a so-called on-cell type (for example, one described in FIG. 19 of JP2013-168125A and those described in FIGS. 1 and 5 of JP2012-089102A), an one glass solution (OGS) type, a touch-on-lens (TOL) type (for example, one described in FIG. 2 of JP2013-054727A), other configurations (for example, those described in FIG. 6 of JP2013-164871A), and various out-cell types (so-called GG, G1•G2, GFF, GF2, GF1, G1F, and the like).

[Photosensitive material according to other embodiments, and transfer film, pattern forming method, manufacturing method of circuit board, and manufacturing method of touch panel using the same]

The present invention also relates to a photosensitive material having excellent pattern formability (hereinafter, also referred to as a “photosensitive material according to an embodiment of the present invention”).

Hereinafter, the photosensitive material according to the embodiment of the present invention, and a transfer film, a pattern forming method, a manufacturing method of a circuit board, and a manufacturing method of a touch panel using the same will be described.

[Photosensitive Material]

A feature point of the photosensitive material according to the embodiment of the present invention is that the photosensitive material according to the embodiment of the present invention is a photosensitive material including a compound A having a carboxy group (hereinafter, also referred to as a “compound A”) and includes the following two.

(1) the above-described compound A includes a polymer including a repeating unit derived from (meth)acrylic acid.

(2) the content of the carboxy group in the photosensitive layer which is formed from the photosensitive material is reduced by irradiation with an actinic ray or a radiation. In other words, in the photosensitive layer formed from the above-described photosensitive material, the content of the carboxy group derived from the compound A in the photosensitive layer is reduced by the irradiation (exposure) with the actinic ray or the radiation.

The photosensitive material according to the embodiment of the present invention is excellent in pattern formability due to the above-described configuration. Specifically, it is excellent in resolution and excellent in suppressing film loss.

In addition, according to the present studies by the present inventors, in the photosensitive layer formed from the above-described photosensitive material, since the content of the carboxy group derived from the compound A is reduced by the exposure, it is also confirmed that a relative permittivity after exposure is lower than that before exposure.

Examples of a method by which the photosensitive material according to the embodiment of the present invention expresses the mechanism (2) include a method of using a photosensitive material satisfying a requirement (V02) or a requirement (W02) shown below.

Requirement (V02): a photosensitive material includes a compound A having a carboxy group and a compound β having a structure (specific structure S0) in which an amount of the carboxy group included in the compound A is reduced by the exposure.

Requirement (W02): a photosensitive material includes a compound A having a carboxy group, and the compound A includes a structure (specific structure S0) in which an amount of the carboxy group is reduced by the exposure.

The specific structure S0 in the above-described requirement (V02) and requirement (W02) is the same as the specific structure S0 in the requirement (V01) and the requirement (W01) of the transfer film described above.

The above-described requirement (V02) is preferably a requirement (V2) shown below, and the above-described requirement (W02) is preferably a requirement (W2) shown below. That is, in the above-described requirement (V02), the above-described compound β is preferably a compound B which has a structure capable of accepting an electron from the carboxy group included in the compound A in a photoexcited state. In addition, in the above-described requirement (W02), the above-described structure is preferably a structure capable of accepting an electron from the carboxy group included in the compound A in a photoexcited state.

The specific structure S1 in the above-described requirement (V2) and requirement (W2) is the same as the specific structure S1 in the requirement (V1) and the requirement (W1) of the transfer film described above.

Requirement (V2): a photosensitive material includes a compound A having a carboxy group and a compound B which has a structure (specific structure S1) capable of accepting an electron from the carboxy group included in the compound A in a photoexcited state, in which the compound A includes a polymer including a repeating unit derived from (meth)acrylic acid.

Requirement (W2): a photosensitive material includes a compound A having a carboxy group, and the compound A includes a repeating unit derived from (meth)acrylic acid and a structure (specific structure S1) capable of accepting an electron from the carboxy group in a photoexcited state.

In a photosensitive layer formed from the above-described photosensitive material, due to a mechanism of action starting from the specific structure S0, the content of the carboxy group derived from the compound A can be reduced by the exposure.

Hereinafter, an estimation mechanism in which the content of the carboxy group derived from the compound A by the exposure can be reduced by the exposure will be described by taking the specific structure S1 as an example.

In a case where the above-described specific structure is exposed, acceptability of the electron increases, and the electron is transferred from the carboxy group of the compound A. In a case of transferring the electron, the above-described carboxy group may be an anion.

In a case where the above-described carboxy group which may be an anion transfers the electron to the specific structure S1, the above-described carboxy group is unstable and to be carbon dioxide, and is eliminated. In a case where the carboxy group, which is the acid group, is to be carbon dioxide and is eliminated, polarity of that portion decreases. That is, in the photosensitive layer, by the above-described mechanism of action, the polarity changes due to the elimination of the carboxy group of the compound A in the exposed portion, and the solubility in the developer changes (in the exposed portion, the solubility in an alkali developer is decreased, and the solubility in an organic solvent-based developer is increased). On the other hand, in the non-exposed portion, the solubility in the developer has not changed. As a result, the photosensitive layer has excellent pattern formability. In addition, in a case where the developer is an alkali developer, it is possible to form a pattern having a low moisture permeability with a reduced content of the carboxy group. Further, in a case where the developer is an organic solvent-based developer, by further performing an exposure treatment on the developed pattern, it is possible to form a pattern having a low moisture permeability with a reduced content of the carboxy group.

In addition, as described later, it is also preferable that the photosensitive material includes a polymerizable compound.

As described above, in a case where the above-described carboxy group transfers the electron to the specific structure S1, the above-described carboxy group is unstable and to be carbon dioxide, and is eliminated. In this case, a radical is generated at a position on the compound A where the carboxy group is to be carbon dioxide and is eliminated, and such a radical causes a radical polymerization reaction of the polymerizable compound. As a result, the photosensitive layer formed from the photosensitive material particularly has more excellent pattern forming ability to the alkali developer, and the formed pattern also has excellent film hardness.

Further, as will be described later, it is also preferable that the photosensitive material includes a polymerizable compound and a photopolymerization initiator.

In a case where the photosensitive material includes a photopolymerization initiator, the elimination of the carboxy group and the polymerization reaction as described above can occur at different timings. For example, first, the photosensitive layer formed from the photosensitive material may be subjected to a first exposure to a wavelength or an exposure amount at which the elimination of the carboxy group hardly occurs, and the polymerization reaction of the polymerizable compound based on the photopolymerization initiator may be allowed to proceed and be cured. Thereafter, the cured photosensitive layer may be subjected to a second exposure to cause the elimination of the carboxy group.

Hereinafter, an estimation mechanism of the above-described decarboxylation process (estimation mechanism capable of reducing the content of the carboxy group derived from the compound A by the exposure starting from the specific structure S1) will be described in detail by taking an aspect in which the compound A is polyacrylic acid and the compound B is quinoline as an example.

As shown below, a carboxy group of the polyacrylic acid and a nitrogen atom of the quinoline form a hydrogen bond in the coexistence. In a case where the quinoline is exposed, acceptability of the electron increases, and the electron is transferred from the carboxy group of the polyacrylic acid (step 1: photoexcitation). In a case where the carboxy group included in the polyacrylic acid transfers the electron to the quinoline, the carboxy group is unstable and to be carbon dioxide, and is eliminated (step 2: decarboxylation reaction). After the above-described decarboxylation reaction, a radical is generated in the residue of the polyacrylic acid, and a radical reaction proceeds. The radical reaction can occur between the residues of the polyacrylic acid, between the residue of the polyacrylic acid and any polymerizable compound (monomer (M)), or with a hydrogen atom in the atmosphere (step 3: polarity conversion•crosslinking•polymerization reaction). After the radical reaction is completed, the compound B can be regenerated and contribute to the decarboxylation process of the compound A again (step 4: regeneration of compound B (catalyst)).

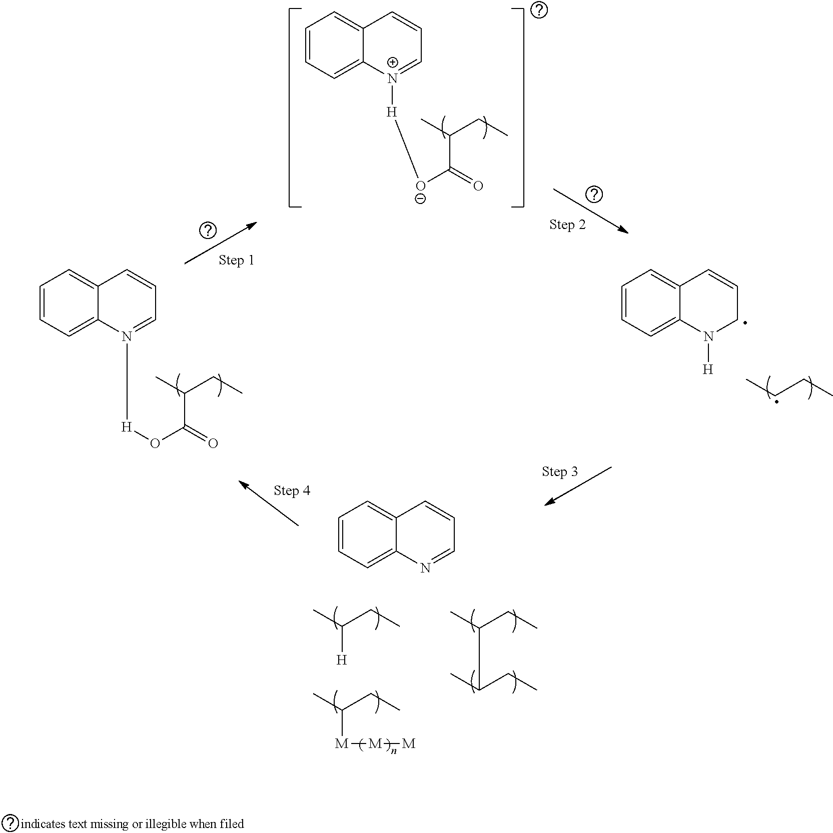

In particular, in the photosensitive layer formed from the above-described photosensitive material, from the viewpoint of having more excellent pattern forming ability to an alkali developer, it is preferable that the content of the carboxy group derived from the compound A is reduced by the exposure at a reduction rate of 5 mol % or more, more preferable to be reduced at a reduction rate of 10 mol % or more, even more preferable to be reduced at a reduction rate of 20 mol % or more, still more preferable to be reduced at a reduction rate of 31 mol % or more, particularly preferable to be reduced at a reduction rate of 40 mol % or more, more particularly preferable to be reduced at a reduction rate of 51 mol % or more, and most preferable to be reduced at a reduction rate of 71 mol % or more. The upper limit value thereof is not particularly limited, and for example, is 100 mol % or less.

A reduction rate of the content of the carboxy group derived from the compound A in the photosensitive layer can be calculated by measuring the amount of the carboxy group in the photosensitive layer before and after the exposure. In a case of measuring the amount of the carboxy group in the photosensitive layer before the exposure, for example, the amount thereof can be analyzed and quantified by potentiometric titration. In a case of measuring the amount of the carboxy group in the photosensitive layer after the exposure, the hydrogen atom of the carboxy group is substituted with a metal ion such as lithium, and the amount thereof can be calculated by analyzing and quantifying the amount of this metal ion by inductively coupled plasma optical emission spectrometer (ICP-OES).

In addition, the reduction rate of the content of the acid group derived from the compound A in the photosensitive layer can also be obtained by measuring an infrared (IR) spectrum of the photosensitive layer before and after the exposure and calculating a reduction rate of a peak derived from the acid group.

<<Embodiments of Photosensitive Material>>

The following shows an example of embodiments of the photosensitive material.

<Photosensitive Material of Embodiment Y-1-a1>

A photosensitive material which satisfies any of the requirement (V02) or the requirement (W02) and does not substantially include the polymerizable compound and the photopolymerization initiator.

<Photosensitive Material of Embodiment Y-1-a2>

A photosensitive material which satisfies any of the requirement (V02) or the requirement (W02) and does not substantially include the photopolymerization initiator.

<Photosensitive Material of Embodiment Y-1-a3>

A photosensitive material which satisfies any of the requirement (V02) or the requirement (W02) and includes the polymerizable compound and the photopolymerization initiator.

In the photosensitive material of the embodiment Y-1-a1, the “photosensitive material does not substantially include the polymerizable compound” means that a content of the polymerizable compound may be less than 3% by mass, preferably 0% to 1% by mass and more preferably 0% to 0.1% by mass with respect to the total solid content of the photosensitive material.

In addition, in the photosensitive materials of the embodiment Y-1-a1 and the embodiment Y-1-a2, the “photosensitive material does not substantially include the photopolymerization initiator” means that a content of the photopolymerization initiator may be less than 0.1% by mass, preferably 0% to 0.05% by mass and more preferably 0% to 0.01% by mass with respect to the total solid content of the photosensitive material.

As described above, the solid content is intended to be all components of the photosensitive material, except the solvent.

The photosensitive materials of the embodiment Y-1-a1 and the embodiment Y-1-a2 are preferably adopted to a pattern forming method of an embodiment 1′ described later. In addition, the photosensitive material of the embodiment Y-1-a3 is preferably adopted to a pattern forming method of an embodiment 2′ described later.

It is preferable that, in the embodiments Y-1-a1 to Y-1-a3, the requirement (V02) and the requirement (W02) are the requirement (V2) and the requirement (W2) described above, respectively.

Hereinafter, the photosensitive material according to the embodiment of the present invention will be described.

<<<Various Components>>>

<<Compound A Having Acid Group>>

The photosensitive material according to the embodiment of the present invention includes a compound A having a carboxy group.

Examples of the compound A having a carboxy group include the same compounds as the “compound having a carboxy group” included in the photosensitive layer in the above-described transfer film according to the embodiment of the present invention.

In the photosensitive material according to the embodiment of the present invention, the compound A having a carboxy group includes a polymer including a repeating unit derived from (meth)acrylic acid (hereinafter, also referred to as a “polymer A1”).

Usually, the polymer A1 is an alkali-soluble resin.

The definition and measuring method of “alkali solubility” are as described above.

The polymer A1 may further have an acid group other than the carboxy group. Examples of the acid group other than the carboxy group include a phenolic hydroxyl group, a phosphoric acid group, and a sulfonic acid group.

From the viewpoint of developability, an acid value of the polymer A1 is preferably 60 to 300 mgKOH/g, more preferably 60 to 275 mgKOH/g, and still more preferably 75 to 250 mgKOH/g.

A content of the repeating unit derived from (meth)acrylic acid in the polymer A1 is preferably 5 to 100 mol %, more preferably 10 to 65 mol %, and still more preferably 15 to 45 mol % with respect to all repeating units of the polymer A1.

The polymer A1 may include a repeating unit other than the repeating unit derived from (meth)acrylic acid.

Examples of other repeating units include the repeating units that can be included in the “carboxy group-containing polymer” which may be included in the compound A having an acid group included in the photosensitive layer of the above-described transfer film according to the embodiment of the present invention (however, repeating unit other than the “repeating unit derived from (meth)acrylic acid”). Among these, examples thereof include the repeating unit including the specific structure S0 (preferably, the specific structure S1), the repeating unit having a polymerizable group, the repeating unit having an aromatic ring, the repeating unit having an alicyclic structure, and the other repeating units.

Suitable range of each repeating unit in the polymer A1 is as follows.

In a case where the polymer A1 includes a repeating unit including the specific structure S0 (preferably, the specific structure S1), a content thereof is preferably 3 to 75 mol %, more preferably 5 to 60 mol %, and still more preferably 10 to 50 mol % with respect to all repeating units of the polymer A1.

In a case where the polymer A1 has a repeating unit having the specific structure S0 (preferably, the specific structure S1), a content thereof is preferably 1% to 75% by mass, more preferably 3% to 60% by mass, and still more preferably 5% to 30% by mass with respect to all repeating units of the polymer A1.

The repeating unit including the specific structure S0 (preferably, the specific structure S1) may be used alone, or in combination of two or more kinds thereof.

A content of the repeating unit having a polymerizable group in the polymer A1 is preferably 3 to 60 mol %, more preferably 5 to 40 mol %, and still more preferably 10 to 30 mol % with respect to all repeating units of the polymer A1.

The content of the repeating unit having a polymerizable group in the polymer A1 is preferably 1% to 70% by mass, more preferably 5% to 50% by mass, and still more preferably 12% to 45% by mass with respect to all repeating units of the polymer A1.

The repeating unit having a polymerizable group may be used alone, or in combination of two or more kinds thereof.

A content of the repeating unit having an aromatic ring in the polymer A1 is preferably 5 to 80 mol %, more preferably 15 to 75 mol %, and still more preferably 30 to 70 mol % with respect to all repeating units of the polymer A1.

A content of the repeating unit having an aromatic ring in the polymer A1 is preferably 5% to 90% by mass, more preferably 10% to 80% by mass, and still more preferably 30% to 70% by mass with respect to all repeating units of the polymer A1.

The repeating unit having an aromatic ring may be used alone, or in combination of two or more kinds thereof.

A content of the repeating unit having an alicyclic structure in the polymer A1 is preferably 3 to 70 mol %, more preferably 5 to 60 mol %, and still more preferably 10 to 55 mol % with respect to all repeating units of the polymer A1.

The content of the repeating unit having an alicyclic structure in the polymer A1 is preferably 3% to 90% by mass, more preferably 5% to 70% by mass, and still more preferably 25% to 60% by mass with respect to all repeating units of the polymer A1.

The repeating unit having an alicyclic structure may be used alone, or in combination of two or more kinds thereof.

A content of the other repeating units in the polymer A1 is preferably 1 to 70 mol %, more preferably 2 to 50 mol %, and still more preferably 3 to 20 mol % with respect to all repeating units of the polymer A1.

A content of the other repeating units in the polymer A1 is preferably 1% to 70% by mass, more preferably 2% to 50% by mass, and still more preferably 5% to 35% by mass with respect to all repeating units of the polymer A1.

The other repeating units may be used alone, or in combination of two or more kinds thereof.

From the viewpoint of excellent formability of the photosensitive layer (in other words, excellent film forming ability for forming the photosensitive layer), a lower limit value of a weight-average molecular weight of the polymer A1 is preferably 5,000 or more, more preferably 10,000 or more, and still more preferably 15,000 or more. An upper limit value thereof is not particularly limited, but from the viewpoint of more excellent adhesiveness (laminate adhesiveness) in a case of being bonded to any base material (during transfer), is preferably 50,000 or less.

As a suitable aspect of the weight-average molecular weight of the polymer A1, 5,000 to 200,000 is preferable, 10,000 to 100,000 is more preferable, and 11,000 to 49,000 is most preferable.

In the photosensitive material according to the embodiment of the present invention, a content of the compound A is more preferably 25% by mass or more, still more preferably 30% by mass or more, even more preferably 45% by mass or more, and particularly preferably 50% by mass or more with respect to the total solid content of the photosensitive material. An upper limit value of the content of the compound A is preferably 100% by mass or less, more preferably 99% by mass or less, still more preferably 97% by mass or less, particularly preferably 93% by mass or less, more particularly preferably 85% by mass or less, and most preferably 75% by mass or less with respect to the total solid content of the photosensitive material. In a case where the photosensitive material satisfies the requirement (W02), the upper limit value of the content of the compound A is preferably 99% by mass or less with respect to the total solid content of the photosensitive material.

The compound A may be used alone, or in combination of two or more kinds thereof.

Among these, in the photosensitive material of the embodiment Y-1-a1, the content of the compound A is preferably 40% to 98% by mass, more preferably 50% to 96% by mass, and still more preferably 60% to 93% by mass with respect to the total solid content of the photosensitive material.

In the photosensitive material of the embodiment Y-1-a2, the content of the compound A is preferably 30% to 85% by mass and more preferably 45% to 75% by mass with respect to the total solid content of the photosensitive material.

In the photosensitive material of the embodiment Y-1-a3, the content of the compound A is preferably 30% to 85% by mass and more preferably 45% to 75% by mass with respect to the total solid content of the photosensitive material.

<<Compound β>>

The photosensitive material preferably includes a compound β.

The compound β is the same as the compound β which can be included in the photosensitive layer of the above-described transfer film according to the embodiment of the present invention, and suitable aspects thereof are also the same.

From the viewpoint of more excellent pattern forming ability, a content of the compound β (preferably, the compound B) in the photosensitive material is preferably 0.1% to 50% by mass with respect to the total solid content of the photosensitive material.

Among these, in the photosensitive material of the embodiment Y-1-a1, the content of the compound β (preferably, the compound B) is, for example, 0.2% to 45% by mass, preferably 2.0% to 40% by mass, more preferably 4% to 35% by mass, and still more preferably 8% to 30% by mass with respect to the total solid content of the photosensitive material.

In the photosensitive material of the embodiment Y-1-a2, the content of the compound β (preferably, the compound B) is preferably 0.5% to 20% by mass and more preferably 1.0% to 10% by mass with respect to the total solid content of the photosensitive material.

In the photosensitive material of the embodiment Y-1-a3, the content of the compound β (preferably, the compound B) is preferably 0.3% to 20% by mass and more preferably 0.5% to 8% by mass with respect to the total solid content of the photosensitive material.

The compound β (preferably, the compound B) may be used alone, or in combination of two or more kinds thereof.

In a case where the compound β is the compound B, from the viewpoint of more excellent pattern forming ability, in the photosensitive material, the total number of structures (specific structures S1) capable of accepting the electron, which are included in the compound B, is preferably 1 mol % or more, more preferably 3 mol % or more, still more preferably 5 mol % or more, particularly preferably 10 mol % or more, and most preferably 20 mol % or more with respect to the total number of carboxy groups included in the compound A.

The upper limit of the total number of structures (specific structures S1) capable of accepting the electron, which are included in the compound B, is not particularly limited, but from the viewpoint of quality of the film to be obtained, is preferably 200 mol % or less, more preferably 100 mol % or less, and still more preferably 80 mol % or less with respect to the total number of carboxy groups included in the compound A.

<<Polymerizable Compound>>

The photosensitive material preferably includes a polymerizable compound.

The polymerizable compound is the same as the polymerizable compound which can be included in the photosensitive layer of the above-described transfer film according to the embodiment of the present invention, and suitable aspects thereof are also the same. This polymerizable compound is a component different from the compound A having a carboxy group, and does not include a carboxy group.

In a case where the photosensitive material includes a polymerizable compound, a content thereof is preferably 3% to 70% by mass, more preferably 10% to 70% by mass, and particularly preferably 20% to 55% by mass with respect to the total solid content of the photosensitive material.

In a case where the photosensitive material includes a polymerizable compound, a mass proportion of the polymerizable compound to the polymer A1 (mass of polymerizable compound/mass of polymer A1) is preferably 0.2 to 2.0 and more preferably 0.4 to 0.9.

The polymerizable compound may be used alone, or in combination of two or more kinds thereof.

In addition, in a case where the photosensitive material includes a bifunctional polymerizable compound and a tri- or higher functional polymerizable compound, a content of the bifunctional polymerizable compound is preferably 10% to 90% by mass, more preferably 20% to 85% by mass, and still more preferably 30% to 80% by mass with respect to all polymerizable compounds included in the photosensitive material.

In addition, in this case, a content of the tri- or higher functional polymerizable compound is preferably 10% to 90% by mass, more preferably 15% to 80% by mass, and still more preferably 20% to 70% by mass with respect to all polymerizable compounds included in the photosensitive material.

In addition, in a case where the photosensitive material includes a bi- or higher functional polymerizable compound, this photosensitive material may further contain a monofunctional polymerizable compound.

However, in a case where the photosensitive material includes a bi- or higher functional polymerizable compound, it is preferable that, among the polymerizable compounds which can be included in the photosensitive material, a main component is the bi- or higher functional polymerizable compound.

Specifically, in a case where the photosensitive material includes a bi- or higher functional polymerizable compound, a content of the bi- or higher functional polymerizable compound is preferably 60% to 100% by mass, more preferably 80% to 100% by mass, and still more preferably 90% to 100% by mass with respect to the total content of polymerizable compounds included in the photosensitive material.

<<Photopolymerization Initiator>>

The photosensitive material also preferably includes a photopolymerization initiator.

The photopolymerization initiator is the same as the photopolymerization initiator which can be included in the photosensitive layer of the above-described transfer film according to the embodiment of the present invention, and suitable aspects thereof are also the same.

In a case where the photosensitive material includes a photopolymerization initiator, a content thereof is preferably 0.1% to 15% by mass, more preferably 0.5% to 10% by mass, and particularly preferably 1% to 5% by mass with respect to the total solid content of the photosensitive material. The photopolymerization initiator may be used alone, or in combination of two or more kinds thereof

<<Surfactant>>

The photosensitive material may include a surfactant.

The surfactant is the same as the surfactant which can be included in the photosensitive layer of the above-described transfer film according to the embodiment of the present invention, and suitable aspects thereof are also the same.

A content of the surfactant is preferably 0.0001% to 10% by mass, more preferably 0.001% to 5% by mass, and still more preferably 0.005% to 3% by mass with respect to the total solid content of the photosensitive material. The surfactant may be used alone, or in combination of two or more kinds thereof

<<Solvent>>

From the viewpoint of forming the photosensitive layer by coating, the photosensitive material according to the embodiment of the present invention may include a solvent.

As the solvent, a commonly used solvent can be used without particular limitation.

As the solvent, an organic solvent is preferable.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, 2-propanol, and a mixed solvent thereof.

As the solvent, a mixed solvent of methyl ethyl ketone and propylene glycol monomethyl ether acetate, a mixed solvent of diethylene glycol ethyl methyl ether and propylene glycol monomethyl ether acetate, or a mixed solvent of methyl ethyl ketone, propylene glycol monomethyl ether, and propylene glycol monomethyl ether acetate is preferable.

In a case where the photosensitive material according to the embodiment of the present invention includes a solvent, the solid content of the photosensitive material is preferably 5% to 80% by mass, more preferably 8% to 40% by mass, and still more preferably 10% to 30% by mass. That is, in a case where the photosensitive material according to the embodiment of the present invention includes a solvent, the content of the solvent is preferably 20% to 95% by mass, more preferably 60% to 95% by mass, and still more preferably 70% to 95% by mass with respect to the total mass of the photosensitive material. The solvent may be used alone, or in combination of two or more kinds thereof.

In a case where the photosensitive material according to the embodiment of the present invention includes a solvent, from the viewpoint of coating properties, a viscosity (25° C.) of the photosensitive material is preferably 1 to 50 mPa·s, more preferably 2 to 40 mPa·s, and still more preferably 3 to 30 mPa·s.

The viscosity is measured using, for example, a VISCOMETER TV-22 (manufactured by TOKI SANGYO CO., LTD.).

In a case where the photosensitive material according to the embodiment of the present invention includes a solvent, from the viewpoint of coating properties, a surface tension (25° C.) of the photosensitive material is preferably 5 to 100 mN/m, more preferably 10 to 80 mN/m, and still more preferably 15 to 40 mN/m.

The surface tension is measured using, for example, Automatic Surface Tensiometer CBVP-Z (manufactured by Kyowa Interface Science Co., Ltd.).

As the solvent, solvents described in paragraphs 0054 and 0055 of US2005/282073A can also be used, and the contents of these publications are incorporated in the present specification.

In addition, as the solvent, an organic solvent (high-boiling-point solvent) having a boiling point of 180° C. to 250° C. can also be used as necessary.

In a case where the photosensitive material according to the embodiment of the present invention forms a photosensitive layer (layer formed of the photosensitive material) in a transfer film described later, it is also preferable that the photosensitive material as the photosensitive layer does not substantially include the solvent. The fact “does not substantially include the solvent” means that the content of the solvent may be less than 1% by mass, preferably 0% to 0.5% by mass and more preferably 0% to 0.001% by mass with respect to the total mass of the photosensitive material.

<<Other Additives>>

The photosensitive material may include other additives as necessary.

The other additives are the same as the other additives which can be included in the photosensitive layer of the above-described transfer film according to the embodiment of the present invention, and suitable aspects thereof are also the same.

[Photosensitive Layer]

The photosensitive material according to the embodiment of the present invention can be adopted as a photosensitive layer (for example, photosensitive layer of a transfer film) in a case of forming various patterns. Hereinafter, aspects of using the photosensitive material according to the embodiment of the present invention as a photosensitive layer will be described.

<<<Method for Forming Photosensitive Layer>>>

The photosensitive layer can be formed by preparing a photosensitive material including components used for forming the photosensitive layer and a solvent, and applying and drying the photosensitive material. It is also possible to prepare a composition by dissolving each component in a solvent in advance and then mixing the obtained solution at a predetermined proportion. The composition prepared as described above is preferably filtered using, for example, a filter having a pore size of 0.2 to 30 μm.

The photosensitive layer can be formed by applying the photosensitive material to a temporary support or a cover film, and drying the photosensitive material.

The application method is not particularly limited, and examples thereof include known methods such as a slit coating, a spin coating, a curtain coating, and an inkjet coating.

In addition, in a case where other layers described later are formed on the temporary support or the cover film, the photosensitive layer may be formed on the other layers.

An average thickness of the photosensitive layer is preferably 0.5 to 20 μm. In a case where the average thickness of the photosensitive layer is 20 μm or less, resolution of the pattern is more excellent, and in a case where the average thickness of the photosensitive layer is 0.5 μm or more, it is preferable from the viewpoint of pattern linearity. The average thickness of the photosensitive layer is more preferably 0.8 to 15 μm and still more preferably 1.0 to 10 μm. Specific examples of the average thickness of the photosensitive layer include 3.0 μm, 5.0 μm, and 8.0 μm.

The photosensitive layer is preferably achromatic. Specifically, in CIE1976 (L*, a*, b*) color space of the total reflection (incidence angle: 8°, light source: D-65 (visual field: 2°), the L* value is preferably 10 to 90, the a* value is preferably −1.0 to 1.0, and the b* value is preferably −1.0 to 1.0.

[Transfer Film]

The photosensitive material according to the embodiment of the present invention can be preferably adopted to a photosensitive layer of a transfer film.

A configuration of the transfer film is as described above. By forming the photosensitive layer in the above-described transfer film of the photosensitive material according to the embodiment of the present invention, a transfer film having excellent pattern formability is obtained. A manufacturing method of the transfer film is also the same as the above-described method.

[Pattern Forming Method]

A pattern forming method according to an embodiment of the present invention is not particularly limited as long as it is a pattern forming method using the above-described photosensitive material, but it is preferable to include a step of forming a photosensitive layer on a base material, a step of exposing the photosensitive layer in a patterned manner, and a step of developing the exposed photosensitive layer (alkali development or organic solvent development) in this order. In a case where the above-described development is an organic solvent development, it is preferable to include a step of further exposing the obtained pattern.

Examples of specific embodiments of the pattern forming method according to the present invention include pattern forming methods of an embodiment 1′ and an embodiment 2′ described later.

<<<Pattern Forming Method of Embodiment 1′>>>

A pattern forming method of an embodiment 1′ includes steps X1′ to X3′. The following step X2′ corresponds to a step of reducing the content of the carboxy group derived from the compound A in the photosensitive layer by the exposure. However, in a case where a developer in the step X3′ is an organic solvent-based developer, a step X4′ is further included after the step X3′.

Step X1′: step of forming a photosensitive layer on a base material using the photosensitive material

Step X2′: step of exposing the photosensitive layer in a patterned manner Step X3′: step of developing the photosensitive layer exposed in a patterned manner with a developer

Step X4′: step of further exposing the pattern formed by the development after the developing step of the step X3′

In a case where an alkali developer is used as the developer in the step X3′, the above-described photosensitive layer is preferably the photosensitive layers of the embodiment X-1-a1 and the embodiment X-1-a2. In a case where an organic solvent-based developer is used as the developer in the step X3′, the above-described photosensitive layer is preferably the photosensitive material of the embodiment X-1-a1.

The pattern forming method of the embodiment 1′ is preferably adopted to the photosensitive materials of the embodiment Y-1-a1 and the embodiment Y-1-a2 described above.

Specific procedure and suitable aspects of the pattern forming method of the embodiment 1′ are the same as those of the pattern forming method of the embodiment 1 except for the step X1′.

The step X1′ can be performed by the method described in the above-described method for forming the photosensitive layer. In addition, the step X1′ may be a step of producing a transfer film including a photosensitive layer formed from the photosensitive material according to the embodiment of the present invention in advance, and then bringing a surface of the photosensitive layer in the transfer film on an opposite side of a temporary support side into contact with a base material to bond the transfer film and the base material. In a case where the step X1′ is a bonding step using a transfer film, specific procedure and suitable aspects thereof are the same as those of the step X1 in the pattern forming method of the embodiment 1.

<<<Pattern Forming Method of Embodiment 2′>>>

A pattern forming method of an embodiment 2 includes a step Y1′, a step Y2P′, and a step Y3′ in this order, and further includes a step Y2Q′ (step of further exposing the photosensitive layer exposed in the step Y2P′) before the step Y3′ or after the step Y3′.

Step Y1′: step of bringing a surface of the photosensitive layer in the transfer film on an opposite side of a temporary support side into contact with a base material to bond the transfer film and the base material

Step Y2P′: step of exposing the photosensitive layer

Step Y3′: step of developing the photosensitive layer with a developer

The pattern forming method of the embodiment 2′ is preferably adopted to the transfer film including the above-described photosensitive resin layer of the embodiment Y-1-a3.

Specific procedure and suitable aspects of the pattern forming method of the embodiment 2′ are the same as those of the pattern forming method of the embodiment 2 except for the step Y1′. That is, the step Y2P′ is the same as the step Y2P, the step Y2Q′ is the same as the step Y2Q, and the step Y3′ is the same as the step Y3.

The step Y1′ can be performed by the method described in the above-described method for forming the photosensitive layer. In addition, the step Y1′ may be a step of producing a transfer film including a photosensitive layer formed from the photosensitive material according to the embodiment of the present invention in advance, and then bringing a surface of the photosensitive layer in the transfer film on an opposite side of a temporary support side into contact with a base material to bond the transfer film and the base material. In a case where the step Y1′ is a bonding step using a transfer film, specific procedure and suitable aspects thereof are the same as those of the step Y1 in the pattern forming method of the embodiment 2.

<<Preferred Aspect>>

Among these, as the pattern forming method of the embodiment 2′, it is preferable to include a step Y1′, a step Y2A′, a step Y3′, and a step Y2B′ in this order. One of the step Y2A′ and the step Y2B′ is an exposing step for reducing the content of the carboxy group derived from the compound A by the exposure, and the other is an exposing step for causing a polymerization reaction of the polymerizable compound based on the photopolymerization initiator.

Step Y1′: step of forming a photosensitive layer on a base material using the photosensitive material

Step Y2A′: step of exposing the photosensitive layer in a patterned manner

Step Y3′: step of developing the photosensitive layer with an alkali developer to form a patterned photosensitive layer

Step Y2B: step of exposing the patterned photosensitive layer

The above-described step Y2A′ is preferably an exposing step for causing a polymerization reaction of the polymerizable compound based on the photopolymerization initiator, and the above-described step Y2B′ is preferably an exposing step for reducing the content of the carboxy group derived from the compound A by the exposure.

[Optional Step which May be Included in Pattern Forming Methods of Embodiment 1′ and Embodiment 2′]

The pattern forming methods of the embodiment 1′ and the embodiment 2′ may include optional steps (other steps) in addition to those described above. The optional step is the same as the optional step which can be included in the pattern forming methods of the embodiment 1 and the embodiment 2 described above, and suitable aspects thereof are also the same.

[Pattern]

The pattern formed by the above-described pattern forming methods of the embodiment 1′ and the embodiment 2′ has reduced content of the carboxy group, so that polarity is low, and moisture permeability and relative permittivity are low.

Physical properties and the use of the pattern formed by the pattern forming methods of the embodiment 1′ and the embodiment 2′ are the same as the physical properties and the use of the pattern formed by the pattern forming methods of the embodiment 1 and the embodiment 2 described above, and suitable aspects thereof are also the same.

[Manufacturing Method of Circuit Wiring]

A manufacturing method of a circuit wiring according to an embodiment of the present invention is not particularly limited as long as it is a manufacturing method of a circuit wiring using the above-described photosensitive material, but it is preferable to include, in the following order, a step (photosensitive layer forming step) of forming a photosensitive layer on a substrate having a conductive layer using the above-described photosensitive material, a step (first exposing step) of exposing the photosensitive layer in the bonded transfer film in a patterned manner, a step (alkali developing step) of developing the exposed photosensitive layer with an alkali developer to form a patterned photosensitive layer, a step (second exposing step) of exposing the patterned photosensitive layer to form an etching resist film, and a step (etching step) of etching the conductive layer in a region on which the etching resist film is not disposed.

In the manufacturing method of a circuit wiring according to the embodiment of the present invention, the photosensitive layer forming step can be performed by the same procedure as in the step X1′ of the pattern forming method of the embodiment 1′ described above. In addition, all of the first exposing step, the alkali developing step, and the second exposing step can be performed by the same procedure as in the step Y1, the step Y2A, the step Y3, and the step Y2B of the above-described pattern forming method of the embodiment 2. In addition, the substrate having a conductive layer, which is used in the manufacturing method of a circuit wiring according to the embodiment of the present invention, is the same as the substrate having a conductive layer, which is used in the above-described step X1. In addition, the manufacturing method of a circuit wiring according to the embodiment of the present invention may include a step other than the above-described steps. Examples of other steps include the same steps as the optional step which may be included in the pattern forming methods of the first embodiment and the second embodiment.

In the manufacturing method of a circuit wiring according to the embodiment of the present invention, five steps of the above-described photosensitive layer forming step, the above-described first exposing step, the above-described developing step, the above-described second exposing step, and the above-described etching step are regarded as one set, and it is also preferable to repeat the set a plurality of times. The film used as the etching resist film can also be used as a protective film (permanent film) for the formed circuit wiring.

[Manufacturing Method of Touch Panel]

A manufacturing method of a touch panel according to an embodiment of the present invention is not particularly limited as long as it is a manufacturing method of a touch panel using the above-described photosensitive material, but it is preferable to include, in the following order, a step (photosensitive layer forming step) of forming a photosensitive layer on a conductive layer (preferably, a patterned conductive layer; specifically, a touch panel electrode pattern or a conductive pattern such as a wiring line) in a substrate having the conductive layer using the above-described photosensitive material, a step (first exposing step) of exposing the photosensitive layer in a patterned manner, a step (alkali developing step) of developing the exposed photosensitive layer with an alkali developer to form a patterned photosensitive layer, and a step (second exposing step) of exposing the patterned photosensitive layer to form a protective film or an insulating film of the conductive layer.

The protective film formed by the second exposing step has a function as a film which protects the surface of the conductive layer. In addition, the insulating film has a function as an interlayer insulating film between conductive layers. In a case where the second exposing step is a step of forming an insulating film of the conductive layer, it is preferable that the manufacturing method of a touch panel according to the embodiment of the present invention further includes a step of forming a conductive layer (preferably, a patterned conductive layer; specifically, a touch panel electrode pattern or a conductive pattern such as a wiring line) on the insulating film formed by the second exposing step.

In the manufacturing method of a touch panel according to the embodiment of the present invention, the photosensitive layer forming step can be performed by the same procedure as in the step X1′ of the pattern forming method of the embodiment 1′ described above. In addition, all of the first exposing step, the alkali developing step, and the second exposing step can be performed by the same procedure as in the step Y1, the step Y2A, the step Y3, and the step Y2B of the above-described pattern forming method of the embodiment 2. In addition, the substrate having a conductive layer, which is used in the manufacturing method of a touch panel according to the embodiment of the present invention, is the same as the substrate having a conductive layer, which is used in the above-described step X1. Examples of other steps include the same steps as the optional step which may be included in the pattern forming methods of the first embodiment and the second embodiment.

As the manufacturing method of a touch panel according to the embodiment of the present invention, a known manufacturing method of a touch panel can be referred to for configurations other than those described above.

The touch panel manufactured by the manufacturing method of a touch panel according to the embodiment of the present invention preferably has a transparent substrate, an electrode, and a protective film (protective layer).

As a detection method in the touch panel, any known method such as a resistive film method, a capacitance method, an ultrasonic method, an electromagnetic induction method, and an optical method may be used. Among these, a capacitance method is preferable.

Examples of the touch panel type include a so-called in-cell type (for example, those shown in FIGS. 5, 6, 7, and 8 of JP2012-517051B), a so-called on-cell type (for example, one described in FIG. 19 of JP2013-168125A and those described in FIGS. 1 and 5 of JP2012-89102A), an one glass solution (OGS) type, a touch-on-lens (TOL) type (for example, one described in FIG. 2 of JP2013-54727A), other configurations (for example, those described in FIG. 6 of JP2013-164871A), and various out-cell types (so-called GG, G1 •G2, GFF, GF2, GF1, G1F, and the like).

### EXAMPLES

Hereinafter, the present invention will be described in detail with reference to Examples. The material, the amount used, the proportion, the process contents, the process procedure, and the like shown in the following examples can be appropriately changed, within a range not departing from the gist of the present disclosure. Therefore, the scope of the present invention is not limited to the specific examples described below. “part” and “%” are based on mass unless otherwise specified.

In the following examples, a weight-average molecular weight of a resin is a weight-average molecular weight obtained by performing polystyrene conversion of a value measured by gel permeation chromatography (GPC).

In the following Examples, unless otherwise specified, H03-L31 manufactured by Eye Graphics Co., Ltd. was used as a high-pressure mercury lamp. The above-described high-pressure mercury lamp has strong line spectrum at 254 nm, 313 nm, 405 nm, and 436 nm with a wavelength of 365 nm as a main wavelength. In addition, unless otherwise specified, USH-2004 MB manufactured by Ushio Inc. was used as an ultra-high pressure mercury lamp. The above-described ultra-high pressure mercury lamp has strong line spectrum at 313 nm, 365 nm, 405 nm, and 436 nm.

### Example 1 System

<Preparation of Photosensitive Material>

A styrene/acrylic acid copolymer (acid value: 200, Mw: 8500, manufactured by Toagosei Co., Ltd., ARUFON UC3910 (product name)) as the compound A having a carboxy group and the compound β shown in Second table were mixed and dissolved in a mixed solvent of propylene glycol monomethyl ether acetate/methyl ethyl ketone=50/50 (mass ratio) so that a blending amount shown in Second table shown in the latter part was satisfied and a concentration of solid contents of the finally obtained photosensitive material was 25% by mass, thereby obtaining a mixed solution. MEGAFACE F551 (fluorine-containing nonionic surfactant manufactured by DIC Corporation) was added to the above-described mixed solution as a surfactant so that a concentration was 100 ppm by mass with respect to the total solid content of the photosensitive material, thereby preparing a photosensitive material of each of Examples or Comparative Examples.

The blending amount (part by mass) shown in the table is the solid content of each component.

<Evaluation of Physical Properties of Compound β>

(Measurement of pKa of compound β in ground state) The pKa of the compound β in a ground state was measured by the following method using an automatic titrator manufactured by HIRANUMA Co., Ltd. In a case where the compound β was a nitrogen-containing aromatic compound, the pKa of the compound β in a ground state is intended to be a pKa of a conjugate acid of the compound β.

0.1 g of the compound β was dissolved in 20 ml of methanol, and 20 ml of ultrapure water was added thereto. This mixture was titrated using a 0.1 N-HCL aqueous solution, and the pH at ½ of the titration amount required up to the equivalence point was defined as the pKa (pKa of the compound β in a ground state).

(Measurement and Evaluation of ε365 and ε365/ε313)

A molar absorption coefficient ((cm·mol/L)⁻¹, “ε365”) of the compound β at 365 nm and a molar absorption coefficient ((cm·mol/L)⁻¹, “ε313”) of the compound β at 313 nm were obtained, and a value (ε365/ε313) obtained by divided ε365 by ε313 was obtained.

The ε365 and ε313 of the compound β are molar absorption coefficients measured by dissolving the compound β in acetonitrile. In a case where the compound β was insoluble in acetonitrile, a solvent for dissolving the compound β may be appropriately changed.

<Evaluation of Photosensitive Material>

(Production of Photosensitive Layer)

The photosensitive material of each of Examples or Comparative Examples was spin-coated on a silicon wafer, and then the obtained coating film was dried on a hot plate at 80° C. to obtain a photosensitive layer having a film thickness of 5 μm.

The obtained photosensitive layer was evaluated as follows.

(Evaluation of Carboxy Group Consumption Rate (IR Measurement))

The obtained photosensitive layer was entirely exposed using a high-pressure mercury lamp. The integrated exposure amount measured with a 365 nm illuminance meter was 1000 mJ/cm². Light emitted from the above-described high-pressure mercury lamp has strong line spectrum at 254 nm, 313 nm, 405 nm, and 436 nm with a wavelength of 365 nm as a main wavelength.

IR spectra of the photosensitive layer were measured before and after the exposure, and a carboxy group consumption rate (mol %) was calculated from a reduction rate of a peak of C═O stretching and contracting (peak of 1710 cm⁻¹) of the carboxy group.

As the carboxy group consumption rate is higher, the decarboxylation reaction is more proceeding.

The results are shown in Second table (see the column of “Carboxy group consumption rate (mol %) [IR measurement]”).

(Evaluation of Carboxy Group Consumption Rate (Measurement of Ashing))

A carboxy group consumption rate was measured by the following procedure.

Measurement of carboxy group amount of photosensitive layer after exposure (measurement of carboxy group amount after exposure)

The photosensitive layer obtained in the upper part was exposed under the following exposure conditions.

<<Exposure Conditions>>

The obtained photosensitive layer was entirely exposed using a high-pressure mercury lamp. The integrated exposure amount measured with a 365 nm illuminance meter was 1000 mJ/cm². Light emitted from the above-described high-pressure mercury lamp has strong line spectrum at 254 nm, 313 nm, 405 nm, and 436 nm with a wavelength of 365 nm as a main wavelength.

Next, a total of approximately 20 mg of the photosensitive layer after exposure was scraped off and frozen and pulverized, 150 μL of N-methyl-2-pyrrolidone (NMP) was added thereto, and the mixture was stirred in an aqueous solution of lithium carbonate (Li₂CO₃) (1.2 g/100 mL; lithium carbonate was dissolved in ultrapure water and then filtered through a filter) for 6 days.

After the stirring, particles are settled by ultracentrifugation (140,000 rpm×30 min), the supernatant was replaced with ultrapure water (replacement was repeated 5 times), and the obtained precipitate was dried to dryness and used as an analysis sample (production of a sample in which n=2). This analysis sample was analyzed by ICP-OES (Optima 7300DV manufactured by PerkinElmer Inc.).

The above-described ICP-OES measurement was carried out according to the following procedure.

Approximately 1.5 mg to 2 mg of the above-described analytical sample was weighed (n=3), 5 mL of a 60% HNO₃ aqueous solution was added thereto, and MW Teflon ashing (microwave sample decomposition device UltraWAVE max: 260° C.) was performed.

After the ashing, ultrapure water was added thereto to be 50 mL, and the amount of Li was quantified by an absolute calibration curve method using ICP-OES (Optima 7300DV manufactured by PerkinElmer Inc.).

Measurement of Carboxy Group Amount of Photosensitive Material Before Exposure (Measurement of Carboxy Group Amount Before Exposure)

According to the following procedure, the carboxy group amount of the photosensitive material of each of Examples and Comparative Examples, which was used for forming the above-described photosensitive layer, was measured.

1 g of the photosensitive material was dissolved in 63 ml of tetrahydrofuran, and 12 ml of ultrapure water was added thereto. Next, the obtained solution was titrated with a 0.1 N—NaOH aqueous solution using an automatic titrator manufactured by HIRANUMA Co., Ltd. The carboxy group amount in the photosensitive material was calculated by converting the carboxy group amount obtained by the titration into a concentration of solid contents.

Calculation of Decarboxylation Rate

Based on the measurement results of the carboxy group amount before and after the exposure described above, a decarboxylation rate was calculated by the following expression.

Decarboxylation rate (%): {(Carboxy group amount before exposure−Carboxy group amount after exposure)/Carboxy group amount before exposure}×100(%)

Based on the obtained numerical values, evaluation was performed according to the following evaluation standard.

However, in a case of the above-described method, there was a detection limit. In a case where the content of the carboxy group was 1.05 mmol/g or less, 90% or more of Li can be substituted. In a region beyond that, a calibration curve was produced using a crosslinked polymer having a known acid value and calculated.

Evaluation Standard

A: decarboxylation rate was 71 mol % or more.

B: decarboxylation rate was 50 mol % or more and less than 71 mol %.

C: decarboxylation rate was 31 mol % or more and less than 50 mol %.

D: decarboxylation rate was 5 mol % or more and less than 31 mol %.

E: decarboxylation rate was less than 5 mol %.

The results are shown in Second table (see the column of “Carboxy group consumption rate (measurement of ashing)).

(Pattern Formability Evaluation 1)

The obtained photosensitive layer was exposed to a high-pressure mercury lamp through any of masks (1) to (3) below. The integrated exposure amount measured with a 365 nm illuminance meter was 1000 mJ/cm².

(1) mask having a line size=25 μm and a line:space=1:1

(2) mask having a line size=50 μm and a line:space=1:1

(3) mask having a line size=250 μm and a line:space=1:1

The exposed photosensitive layer was dip-developed with a 1% by mass sodium carbonate aqueous solution for 30 seconds, and then was rinsed with pure water for 20 seconds and dried to obtain a pattern (line-and-space pattern).

Line-and-space patterns with line widths and space widths of 25 μm, 50 μm, or 250 μm, which were produced as described above, were observed and evaluated as follows.

A: line-and-space pattern was resolved (photosensitive layer in the space portion was removed), and the pattern was not reduced.

B: line-and-space pattern was resolved, but the pattern was slightly reduced.

C: line-and-space pattern was resolved, but the pattern was greatly reduced.

D: line-and-space pattern was not resolved (photosensitive layer in the space portion remained, or the pattern was completely dissolved and disappeared).

(Relative Permittivity Evaluation 1)

The photosensitive material was spin-coated on an aluminum substrate having a thickness of 0.1 mm, and then the obtained coating film was dried on a hot plate at 80° C. to produce a photosensitive layer having a thickness of 8 μm.

The obtained photosensitive layer was entirely exposed using a high-pressure mercury lamp. The integrated exposure amount measured with a 365 nm illuminance meter was 1000 mJ/cm².

For the photosensitive layer after exposure, a relative permittivity at 1 kHz was measured in an environment of 23° C. and 50% RH using an LCR meter 4284A and a dielectric test fixture 16451B manufactured by Agilent Technologies, Inc.

A relative permittivity of the photosensitive layer formed of the photosensitive material of Comparative Example 1A after exposure was set to 100%, and in comparison with this, the reduction rate was calculated to determine how much the relative permittivity of the photosensitive layer formed of the photosensitive material of each of Examples was reduced after exposure, and evaluated according to the following standard.

As the value of the reduction rate was larger, the relative permittivity as compared with Comparative Example 1A was lower, which is useful as an insulating film.

A: reduction rate was 15% or more.

B: reduction rate was 10% or more and less than 15%.

C: reduction rate was 5% or more and less than 10%.

D: reduction rate was less than 5%.

(Relative Permittivity Evaluation 1 Before and After Exposure)

A photosensitive layer after exposure was produced in the same manner as in (Relative permittivity evaluation 1) described above. In this case, the relative permittivity of each photosensitive layer was measured before and after exposure in the same manner as in (Relative permittivity evaluation 1) described above.

A relative permittivity of each photosensitive layer before exposure was set to 100%, and how much the permittivity of each photosensitive layer was reduced by the exposure was calculated and evaluated according to the following standard.

It can be determined that, as the reduction rate was larger, the reduction in permittivity was further lowered due to the decarboxylation reaction by the exposure.

A: reduction rate was 15% or more.

B: reduction rate was 10% or more and less than 15%.

C: reduction rate was 5% or more and less than 10%.

D: reduction rate was less than 5%.

<Evaluation of Transfer Film>

(Production of Transfer Film)

To a polyethylene terephthalate film (manufactured by Toray Industries, Inc., 16KS40 (16QS62)) having a thickness of 16 μm (temporary support), the photosensitive material of each of Examples or Comparative Examples was applied using a slit-shaped nozzle such that a thickness after drying was adjusted to 5 μm, and the photosensitive material was dried at 100° C. for 2 minutes to form a photosensitive layer.

A polyethylene terephthalate film (manufactured by Toray Industries, Inc., 16KS40 (16QS62)) having a thickness of 16 μm (cover film) was pressure-bonded onto the obtained photosensitive layer to produce a transfer film of Example 1 system.

(Evaluation of Carboxy Group Consumption Rate (IR Measurement))

By peeling off the cover film from the transfer film produced above and laminating the transfer film on a silicon wafer, the photosensitive layer of the transfer film was transferred to a surface of the silicon wafer. Laminating conditions were that a temperature of a substrate for a touch panel was 40° C., a temperature of a rubber roller (that is, a laminating temperature) was 110° C., a linear pressure was 3 N/cm, and a transportation speed was 2 m/min.

The photosensitive layer after transfer was exposed under the following exposure conditions.

<<Exposure Conditions>>

After peeling off the temporary support, the photosensitive layer was entirely exposed using a high-pressure mercury lamp. The integrated exposure amount measured with a 365 nm illuminance meter was 1000 mJ/cm². Light emitted from the above-described high-pressure mercury lamp has strong line spectrum at 254 nm, 313 nm, 405 nm, and 436 nm with a wavelength of 365 nm as a main wavelength.

IR spectra of the photosensitive layer were measured before and after the exposure, and a carboxy group consumption rate (mol %) was calculated from a reduction rate of a peak of C═O stretching and contracting (peak of 1710 cm⁻¹) of the carboxy group.

As the carboxy group consumption rate is higher, the decarboxylation reaction is more proceeding.

The results are shown in Table 1 (see the column of “Carboxy group consumption rate (mol %) [IR measurement]”).

(Evaluation of Carboxy Group Consumption Rate (Measurement of Ashing))

By peeling off the cover film from the transfer film produced above and laminating the transfer film on 10×10 cm² glass (Eagle XG manufactured by Corning), the photosensitive layer of the transfer film was transferred to a surface of the glass. Laminating conditions were that a temperature of a substrate for a touch panel was 40° C., a temperature of a rubber roller (that is, a laminating temperature) was 110° C., a linear pressure was 3 N/cm, and a transportation speed was 2 m/min.

Measurement of Carboxy Group Amount of Photosensitive Layer after Exposure (Measurement of Carboxy Group Amount after Exposure)

The photosensitive layer after transfer was exposed under the following exposure conditions.

<<Exposure Conditions>>

After peeling off the temporary support, the photosensitive layer was entirely exposed using a high-pressure mercury lamp. The integrated exposure amount measured with a 365 nm illuminance meter was 1000 mJ/cm². Light emitted from the above-described high-pressure mercury lamp has strong line spectrum at 254 nm, 313 nm, 405 nm, and 436 nm with a wavelength of 365 nm as a main wavelength.

Next, a total of approximately 20 mg of the photosensitive layer after exposure was scraped off and frozen and pulverized, 150 μL of N-methyl-2-pyrrolidone (NMP) was added thereto, and the mixture was stirred in an aqueous solution of lithium carbonate (Li₂CO₃) (1.2 g/100 mL; lithium carbonate was dissolved in ultrapure water and then filtered through a filter) for 6 days.

After the stirring, particles are settled by ultracentrifugation (140,000 rpm×30 min), the supernatant was replaced with ultrapure water (replacement was repeated 5 times), and the obtained precipitate was dried to dryness and used as an analysis sample (production of a sample in which n=2). This analysis sample was analyzed by ICP-OES (Optima 7300DV manufactured by PerkinElmer Inc.).

The above-described ICP-OES measurement was carried out according to the following procedure.

Approximately 1.5 mg to 2 mg of the above-described analytical sample was weighed (n=3), 5 mL of a 60% HNO₃ aqueous solution was added thereto, and MW Teflon ashing (microwave sample decomposition device UltraWAVE max: 260° C.) was performed. After the ashing, ultrapure water was added thereto to be 50 mL, and the amount of Li was quantified by an absolute calibration curve method using ICP-OES (Optima 7300DV manufactured by PerkinElmer Inc.).

Measurement of Carboxy Group Amount of Photosensitive Layer Before Exposure (Measurement of Carboxy Group Amount Before Exposure)

According to the following procedure, the carboxy group amount of the photosensitive layer of each of Examples and Comparative Examples was measured.

1 g of the photosensitive layer before exposure was scraped off and dissolved in 63 ml of tetrahydrofuran, and 12 ml of ultrapure water was added thereto. Next, the obtained solution was titrated with a 0.1 N—NaOH aqueous solution using an automatic titrator manufactured by HIRANUMA Co., Ltd. The carboxy group amount in the photosensitive layer was calculated by converting the carboxy group amount obtained by the titration into a concentration of solid contents.

Calculation of Decarboxylation Rate

Based on the measurement results of the carboxy group amount before and after the exposure described above, a decarboxylation rate was calculated by the following expression.

Decarboxylation rate (%): {(Carboxy group amount before exposure−Carboxy group amount after exposure)/Carboxy group amount before exposure}×100(%)

Based on the obtained numerical values, evaluation was performed according to the following evaluation standard.

However, in a case of the above-described method, there was a detection limit. In a case where the content of the carboxy group was 1.05 mmol/g or less, 90% or more of Li can be substituted. In a region beyond that, a calibration curve was produced using a crosslinked polymer having a known acid value and calculated.

Evaluation Standard

A: decarboxylation rate was 71 mol % or more.

B: decarboxylation rate was 50 mol % or more and less than 71 mol %.

C: decarboxylation rate was 31 mol % or more and less than 50 mol %.

D: decarboxylation rate was 5 mol % or more and less than 31 mol %.

E: decarboxylation rate was less than 5 mol %.

The results are shown in Second table (see the column of “Carboxy group consumption rate (measurement of ashing)).

(Transmittance at 365 nm)

Using an ultraviolet-visible spectrophotometer UV1800 manufactured by Shimadzu Corporation, a transmittance of the photosensitive layer at 365 nm was measured, and evaluation was performed based on the following evaluation standard.

A: transmittance was 90% or more.

B: transmittance was 65% or more and less than 90%.

C: transmittance was 20% or more and less than 65%.

D: transmittance was less than 20%.

(Transmittance at 365 nm/transmittance at 313 nm)

Using an ultraviolet-visible spectrophotometer UV1800 manufactured by Shimadzu Corporation, a transmittance of the photosensitive layer at 365 nm and a transmittance of the photosensitive layer at 313 nm were measured, and a values calculated by dividing the transmittance at 365 nm by the transmittance at 313 nm was evaluated as follows.

A: 1.5 or more

B: 1 or more and less than 1.5

C: less than 1

(Laminate Suitability Evaluation)

By peeling off the cover film from the transfer film produced above and laminating the transfer film on a PET film (substrate for a touch panel) laminated with a copper foil manufactured by GEOMATEC Co., Ltd., the photosensitive layer of the transfer film was transferred to a surface of the copper foil to obtain a laminate having a laminated structure of “temporary support/photosensitive layer/copper foil/substrate (PET film)”. Laminating conditions were that a temperature of a substrate for a touch panel was 40° C., a temperature of a rubber roller (that is, a laminating temperature) was 110° C., a linear pressure was 3 N/cm, and a transportation speed was 2 m/min. The copper foil is a film which is assumed as a wiring line of a touch panel.

An area where the photosensitive layer was closely attached to the copper foil without bubbles and floating was visually evaluated, and based on the following expression, a proportion (%) of the closely attached area was obtained and evaluated according to the following standard. It can be said that, as the closely attached area (%) was larger, a laminate suitability was more excellent.

Proportion of closely attached area (%)=Area of closely attached photosensitive layer÷Area of laminated transfer film×100

A: proportion of the closely attached area (%) was 95% or more.

B: proportion of the closely attached area (%) was less than 95%.

(Pattern Formability Evaluation 2)

Next, the temporary support was peeled off from the above-described laminate, and the exposed photosensitive layer was exposed to light using a high-pressure mercury lamp. In the case of exposure, the exposure was performed through any of masks (1) to (3) below. The integrated exposure amount measured with a 365 nm illuminance meter was 1000 mJ/cm².

(1) mask having a line size=25 μm and a line:space=1:1

(2) mask having a line size=50 μm and a line:space=1:1

(3) mask having a line size=250 μm and a line:space=1:1

Next, the exposed photosensitive layer was developed for 40 seconds using a 1% by mass sodium carbonate aqueous solution (liquid temperature: 32° C.) as a developer. After the development, the photosensitive layer was rinsed with pure water for 20 seconds, and then air was blown to remove water, thereby obtaining a pattern (line-and-space pattern).

Line-and-space patterns with line widths and space widths of 25 μm, 50 μm, or 250 μm, which were produced as described above were evaluated in the same manner as in (Pattern formability evaluation 1) described above.

(Relative Permittivity Evaluation 2)

By peeling off the cover film from the transfer film produced above and laminating the transfer film on an aluminum substrate having a thickness of 0.1 mm under the same conditions as (Laminate suitability evaluation) described above, a laminate having a laminated structure of “temporary support/photosensitive layer/aluminum substrate” was obtained. Next, the temporary support was peeled off from the laminate. The exposed photosensitive layer was entirely exposed to light using a high-pressure mercury lamp. The integrated exposure amount measured with a 365 nm illuminance meter was 1000 mJ/cm².

For the photosensitive layer after exposure, a relative permittivity at 1 kHz was measured in an environment of 23° C. and 50% RH using an LCR meter 4284A and a dielectric test fixture 16451B manufactured by Agilent Technologies, Inc.

A relative permittivity of the photosensitive layer formed of the photosensitive material of Comparative Example 1A after exposure was set to 100%, and in comparison with this, the reduction rate was calculated to determine how much the relative permittivity of the photosensitive layer formed of the photosensitive material of each of Examples was reduced after exposure, and evaluated according to the following standard.

As the value of the reduction rate was larger, the relative permittivity as compared with Comparative Example 1A was lower, which is useful as an insulating film.

A: reduction rate was 15% or more.

B: reduction rate was 10% or more and less than 15%.

C: reduction rate was 5% or more and less than 10%.

D: reduction rate was less than 5%.

(Relative Permittivity Evaluation 2 Before and After Exposure)

A photosensitive layer after exposure was produced in the same manner as in (Relative permittivity evaluation 2) described above. In this case, the relative permittivity of each photosensitive layer was measured before and after exposure in the same manner as in (Relative permittivity evaluation 2) described above.

A relative permittivity of each photosensitive layer before exposure was set to 100%, and how much the permittivity of each photosensitive layer was reduced by the exposure was calculated and evaluated according to the following standard.

It can be determined that, as the reduction rate was larger, the reduction in permittivity was further lowered due to the decarboxylation reaction by the exposure.

A: reduction rate was 15% or more.

B: reduction rate was 10% or more and less than 15%.

C: reduction rate was 5% or more and less than 10%.

D: reduction rate was less than 5%.

(Evaluation of Moisture Permeability (WVTR))

Production of Sample for Measuring Moisture Permeability

To a polyethylene terephthalate (PET) film having a thickness of 75 μm (temporary support), the photosensitive material of each of Examples or Comparative Examples was applied using a slit-shaped nozzle, and the photosensitive material was dried to form a photosensitive layer having a thickness of 8 μm, thereby obtaining a transfer film for sample production.

Next, the transfer film for same production was laminated on PTFE (tetrafluoroethylene resin) membrane filter FP-100-100 manufactured by Sumitomo Electric Industries, Ltd., to form a laminate A having a layer structure of “temporary support/photosensitive layer having a thickness of 8 μm/membrane filter”. Laminating conditions were that a temperature of the membrane filter was 40° C., a temperature of a laminating roll was 110° C., a linear pressure was 3 N/cm, and a transportation speed was 2 m/min.

Next, the temporary support was peeled off from the laminate A.

A procedure in which the transfer film for sample production was further laminated on the exposed photosensitive layer of the laminate A in the same manner as described above, and the temporary support was peeled off from the obtained laminate was repeated 4 times to form a laminate B having a laminated structure of “photosensitive layer having a total film thickness of 40 μm/membrane filter”.

The photosensitive layer of the obtained laminate B was entirely exposed using a high-pressure mercury lamp. The integrated exposure amount measured with a 365 nm illuminance meter was 1000 mJ/cm².

Accordingly, a sample for measuring moisture permeability, which had a laminated structure of “exposed photosensitive layer having a total film thickness of 40 μm/membrane filter”, was obtained.

Measurement of Moisture Permeability (WVTR)

The measurement of the moisture permeability was performed by a cup method using the sample for measuring moisture permeability, with reference to JIS-Z-0208 (1976). Hereinafter, the details will be described.

First, a circular sample having a diameter of 70 mm was cut from the sample for measuring moisture permeability. Next, 20 g of dried calcium chloride was put in a measurement cup, and covered with the circular sample, and accordingly, a lid-attached measurement cup was prepared.

This lid-attached measurement cup was left in a constant-temperature and constant-humidity tank for 24 hours under the condition of 65° C. with 90% RH. A water vapor transmission rate (WVTR) of the circular sample (unit: g/(m²·day)) was calculated from a change in mass of the lid-attached measurement cup before and after the leaving.

The measurement described above was performed three times and an average value of the WVTRs in three times of the measurement was calculated.

A moisture permeability was evaluated based on the reduction rate (%) of the WVTR of each of Examples in a case where the WVTR of Comparative Example 1A was set to 100%. As the value of the reduction rate is larger, the moisture permeability was further lowered as compared with Comparative Example 1A, which is preferable as a protective film. In the following evaluation standard, A or B is preferable, and A is more preferable.

In the above-described measurement, the WVTR of the circular sample having a laminated structure of “exposed photosensitive layer having a total film thickness of 40 μm/membrane filter” was measured as described above. However, the WVTR of the membrane filter is extremely higher than the WVTR of the exposed photosensitive layer, and accordingly, in the above-described measurement, the WVTR of the exposed photosensitive layer is substantially measured.

A: reduction rate of the WVTR was 20% or more.

B: reduction rate of the WVTR was 10% or more and less than 20%.

C: reduction rate of the WVTR was 7.5% or more and less than 10%.

D: reduction rate of the WVTR was 5% or more and less than 7.5%.

E: reduction rate of the WVTR was less than 5%.

<Result>

Second table below shows types and blending amounts of the compound A and the compound β in the photosensitive material of each of Examples or Comparative Examples in Example 1 system, and the test results thereof.

In the table, the column of “Amount” indicates the blending amounts (part by mass) of “Compound A having acid group (compound A)” and “Compound β” added to the photosensitive material. The above-described blending amount (part by mass) is the amount of “Compound A having acid group” and “Compound β” itself (solid content) added to the photosensitive material.

In the table, the column of “Molar ratio with respect to carboxy group of compound A (mol %)” indicates a proportion (mol %) of the total number of structures (specific structures S1) capable of accepting an electron from the acid group of the compound A in a photoexcited state, which are included in the compound β, to the total number of carboxy groups included in the compound A in the photosensitive material.

The column of “ε365” indicates a molar absorption coefficient ((cm·mol/L)⁻¹) of the compound β to light having a wavelength of 365 nm in acetonitrile.

The column of “ε365/ε313” indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values measured in acetonitrile.

The column of “Transmittance at 365 nm” indicates the transmittance of the photosensitive layer to light having a wavelength of 365 nm.

The column of “Transmittance at 365 nm/transmittance at 313 nm” indicates a value obtained by dividing the transmittance of the photosensitive layer to light having a wavelength of 365 nm by the transmittance of the photosensitive layer to light having a wavelength of 313 nm.

TABLE 2

| | Blending characteristics of photosensitive material | | | | | | | |
|---|---|---|---|---|---|---|---|---|
| | | | Compound β | | | | | |
| | | | | | | | | Molar ratio |
| | | | | | | | | with respect to |
| | | | | | | | | carboxy group |
| | Compound A | | | pKa in | | | | of compound A |
| Second | having acid group | | | ground | | ε365/ | | having acid |
| table (1) | Type | Amount | Type | state | ε365 | ε313 | Amount | group (mol %) |
| Example 1-1 | Styrene/ | 100 | 5,6,7,8- | 5.9 | <10 | <1 | 25.9 | 50 |
| | acrylic acid | | Tetrahydroquinoline | | | | | |
| Example 1-2 | copolymer | 100 | 4-Acetylpyridine | 3.1 | <10 | <1 | 23.6 | 50 |
| Example 1-3 | UC3910 | 100 | 4-Benzoylpyridine | 2.9 | 69 | <1 | 35.6 | 50 |
| Example 1-4 | | 100 | Isoquinoline | 4.7 | <10 | <1 | 25.1 | 50 |
| Example 1-5 | | 100 | Quinoline | 4.2 | <10 | <1 | 25.1 | 50 |
| Example 1-6 | | 100 | Acridine | 4.7 | 4900 | >3 | 34.9 | 50 |
| Example 1-7 | | 100 | Phenanthridine | 3.8 | 500 | <1 | 34.9 | 50 |
| Example 1-8 | | 100 | Isoquinoline | 4.7 | <10 | <1 | 10.0 | 20 |
| Example 1-9 | | 100 | Isoquinoline | 4.7 | <10 | <1 | 5.0 | 10 |
| Example 1-10 | | 100 | Isoquinoline | 4.7 | <10 | <1 | 2.5 | 5 |
| Example 1-11 | | 100 | Isoquinoline | 4.7 | <10 | <1 | 1.5 | 3 |
| Comparative | | 100 | None | — | — | — | — | — |
| Example 1A | | | | | | | | |

| | Evaluation of photosensitive material | | | | | | |
|---|---|---|---|---|---|---|---|
| | | | | | | | Change in |
| | Carboxy group | Carboxy group | Pattern | | | | relative |
| | consumption rate | consumption rate | formability | | | | permittivity |
| Second | (mol %) [IR | [measurement | 25 | 50 | 250 | Relative | before and |
| table (1) | measurement] | of ashing] | μm | μm | μm | permittivity | after exposure |
| Example 1-1 | 55 | B | A | A | A | B | B |
| Example 1-2 | 50 | B | B | A | A | B | B |
| Example 1-3 | 45 | C | A | A | A | B | B |
| Example 1-4 | 70 | B | B | A | A | A | A |
| Example 1-5 | 60 | B | B | A | A | A | A |
| Example 1-6 | 30 | D | C | B | B | B | B |
| Example 1-7 | 35 | C | C | B | A | B | B |
| Example 1-8 | 60 | B | B | A | A | A | A |
| Example 1-9 | 40 | C | B | A | A | A | A |
| Example 1-10 | 20 | D | B | B | A | B | B |
| Example 1-11 | 10 | D | C | C | B | C | C |
| Comparative | 0 | E | D | D | D | Standard | D |
| Example 1A | | | | | | | |

TABLE 3

| | Blending characteristics of photosensitive material | | | | | | | | | |
|---|---|---|---|---|---|---|---|---|---|---|
| | | | Compound β | | | | | | | |
| | | | | | | | | Molar ratio | | |
| | | | | | | | | with respect to | Evaluation of transfer film | |
| | | | | | | | | carboxy group | Carboxy group | Carboxy group |
| | Compound A | | | pKa in | | | | of compound A | consumption rate | consumption rate |
| Second | having acid group | | | ground | | ε365/ | | having acid | (mol %) [IR | [measurement |
| table (2) | Type | Amount | Type | state | ε365 | ε313 | Amount | group (mol %) | measurement] | of ashing] |
| Example 1-1 | Styrene/ | 100 | 5,6,7,8- | 5.9 | <10 | <1 | 25.9 | 50 | 55 | B |
| | acrylic acid | | Tetrahydroquinoline | | | | | | | |
| Example 1-2 | copolymer | 100 | 4-Acetylpyridine | 3.1 | <10 | <1 | 23.6 | 50 | 50 | B |
| Example 1-3 | UC3910 | 100 | 4-Benzoylpyridine | 2.9 | 69 | <1 | 35.6 | 50 | 45 | C |
| Example 1-4 | | 100 | Isoquinoline | 4.7 | <10 | <1 | 25.1 | 50 | 70 | B |
| Example 1-5 | | 100 | Quinoline | 4.2 | <10 | <1 | 25.1 | 50 | 60 | B |
| Example 1-6 | | 100 | Acridine | 4.7 | 4900 | >3 | 34.9 | 50 | 30 | D |
| Example 1-7 | | 100 | Phenanthridine | 3.8 | 500 | <1 | 34.9 | 50 | 35 | C |
| Example 1-8 | | 100 | Isoquinoline | 4.7 | <10 | <1 | 10.0 | 20 | 60 | B |
| Example 1-9 | | 100 | Isoquinoline | 4.7 | <10 | <1 | 5.0 | 10 | 40 | C |
| Example 1-10 | | 100 | Isoquinoline | 4.7 | <10 | <1 | 2.5 | 5 | 20 | D |
| Example 1-11 | | 100 | Isoquinoline | 4.7 | <10 | <1 | 1.5 | 3 | 10 | D |
| Comparative | | 100 | None | — | — | — | — | — | 0 | E |
| Example 1A | | | | | | | | | | |

| | Evaluation of transfer film | | | | | | | | |
|---|---|---|---|---|---|---|---|---|---|
| | | | | | | | | Change in | |
| | | Transmittance | | Pattern | | | | relative | |
| | | at 365 nm/ | | formability | | | | permittivity | |
| Second | Transmittance | transmittance | Laminate | 25 | 50 | 250 | Relative | before and | Moisture |
| table (2) | at 365 nm | at 313 nm | suitability | μm | μm | μm | permittivity | after exposure | permeability |
| Example 1-1 | A | A | A | A | A | A | B | B | A |
| Example 1-2 | A | A | A | B | A | A | B | B | A |
| Example 1-3 | A | A | A | A | A | A | B | B | A |
| Example 1-4 | A | A | A | B | A | A | A | A | A |
| Example 1-5 | A | A | A | B | A | A | A | A | B |
| Example 1-6 | C | C | A | C | B | B | B | B | B |
| Example 1-7 | A | A | A | C | B | A | B | B | B |
| Example 1-8 | A | A | A | B | A | A | A | A | A |
| Example 1-9 | A | A | A | B | A | A | A | A | A |
| Example 1-10 | A | A | A | B | B | A | B | B | B |
| Example 1-11 | A | A | A | C | C | B | C | C | C |
| Comparative | A | B | A | D | D | D | Standard | D | Standard |
| Example 1A | | | | | | | | | |

From the results shown in the above tables, it was confirmed that the objects of the present invention could be achieved by using the transfer film according to the embodiment of the present invention.

In addition, in the photosensitive layer of the transfer film according to the embodiment of the present invention, in a case where the total number of specific structures S1 included in the compound β was 3 mol % or more (preferably 5 mol % or more and more preferably 10 mol % or more) with respect to the total number of acid groups included in the compound A, it was confirmed that the pattern formability was more excellent and the relative permittivity of the formed pattern was lower (See, e.g., the comparison of the results of Examples 1-4, 1-8, 1-9, 1-10, and 1-11).

In addition, in the photosensitive layer of the transfer film according to the embodiment of the present invention, in a case where the compound β was a compound in which a molar absorption coefficient to light having a wavelength of 365 nm was 1×10³ (cm·mol/L)⁻¹ or less (preferably, in a case where the compound β was a compound in which a molar absorption coefficient to light having a wavelength of 365 nm was 1×10² (cm·mol/L)⁻¹ or less), it was confirmed that the pattern formability was more excellent (See, e.g., the comparison of the results of Examples 1-1 to 1-7).

In addition, in the photosensitive layer of the transfer film according to the embodiment of the present invention, in a case where the ratio represented by molar absorption coefficient ((cm·mol/L)⁻¹) of the compound β to light having a wavelength of 365 nm/molar absorption coefficient ((cm·mol/L)⁻¹) of the compound β to light having a wavelength of 313 nm was 3 or less, it was confirmed that the pattern formability was more excellent (See, e.g., the comparison of the results of Examples 1-1 to 1-7).

### Example 2 System

<Preparation and Evaluation of Photosensitive Material>

Materials shown in Third table shown in the latter part were mixed and dissolved in a mixed solvent of propylene glycol monomethyl ether acetate/methyl ethyl ketone=50/50 (mass ratio) so that a blending amount shown in Third table shown in the latter part was satisfied and a concentration of solid contents of the finally obtained photosensitive material was 25% by mass, thereby obtaining a photosensitive material.

For the obtained photosensitive material (photosensitive materials of Examples 2-1 to 2-8) of Example 2 system, in a case where the carboxy group consumption rate (mol %) was confirmed by IR measurement in the same manner as shown in Example 1, the carboxy group consumption rate was all 20 mol % or more.

In addition, for the obtained photosensitive material of each of Examples or Comparative Examples in Example 2 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, and moisture permeability were evaluated in the same manner as shown in Example 1 system. In addition, for the photosensitive layer in the transfer film, the carboxy group consumption rate, transmittance to light at 365 nm, and ratio of the transmittance to light at 365 nm to the transmittance to light at 313 nm were also evaluated in the same manner as shown in Example 1 system. In addition, the physical properties of ε365/ε313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 2A.

Third table below shows blending of the solid content of the photosensitive material of each of Examples or Comparative Examples in Example 2 system, and the test results thereof

In the table, the value described in the column of “Solid content blending” indicates the content (part by mass) of each solid content component included in the photosensitive material of each of Examples or Comparative Examples. The value in parentheses in the compound β indicates a proportion (mol %) of the total number of structures (specific structures S1) capable of accepting an electron from the acid group included in the compound A, which are included in the compound β, to the total number of carboxy groups included in the compound A having an acid group (compound A) in the photosensitive material.

In addition, the value (ε365) in brackets, which is written in the component name of the compound β, indicates a molar absorption coefficient ((cm·mol/L)⁻¹) of the compound β to light having a wavelength of 365 nm measured in acetonitrile.

In addition, the value (pKa in a ground state) in brackets, which is written in the component name of the compound β, is intended to be the pKa of the compound β in a ground state. The measuring methods are as described above.

In addition, the column of “ε365/ε313” in the evaluation of the photosensitive material and the evaluation of the transfer film indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values in acetonitrile.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

TABLE 4

| | | | | | | | | | | | Comparative |
|---|---|---|---|---|---|---|---|---|---|---|---|
| | | | Example | | | | | | | | Example |
| Third table | | | 2-1 | 2-2 | 2-3 | 2-4 | 2-5 | 2-6 | 2-7 | 2-8 | 2A |
| Solid content | Compound A | UC3910 | 60 | 60 | 60 | 60 | 60 | 60 | 70 | 50 | 60 |
| blending | having acid group | | | | | | | | | | |
| | Compound β | 5,6,7,8- | 6.2 (20) | | | | | | | | |
| | (in parentheses: | Tetrahydroquinoline | | | | | | | | | |
| | molar ratio | “ε365: <10” | | | | | | | | | |
| | with respect to | “pKa in ground | | | | | | | | | |
| | carboxy group | state: 5.9” | | | | | | | | | |
| | of compound A | 4-Acetylpyridine | | 5.7 (20) | | | 5.7 (20) | 5.7 (20) | | | |
| | having acid group | “ε365: <10” | | | | | | | | | |
| | (mol %)) | “pKa in ground | | | | | | | | | |
| | | state: 3.1” | | | | | | | | | |
| | | Isoquinoline | | | 6.0 (20) | | | | 3.5 (10) | 2.5 (10) | |
| | | “ε365: <10” | | | | | | | | | |
| | | “pKa in ground | | | | | | | | | |
| | | state: 4.69” | | | | | | | | | |
| | | Acridine | | | | 8.4 (20) | | | | | |
| | | “ε365: 4900” | | | | | | | | | |
| | | “pKa in ground | | | | | | | | | |
| | | state: 4.67” | | | | | | | | | |
| | Polymerizable | DPHA | 12.6 | 12.6 | 12.6 | 12.6 | | 12.5 | | | 12.6 |
| | compound | A-NOD-N | 25 | 25 | 25 | 25 | | 12.5 | | | 25 |
| | | DTMPT | | | | | | 12.6 | 27.6 | 12.5 | |
| | | A-DCP | | | | | 25 | | | 22.5 | |
| | | TMPT | | | | | 12.6 | | | 12.6 | |
| | Surfactant | F551 | 0.1 | 0.1 | 0.1 | 0.1 | 0.1 | 0.1 | 0.1 | 0.1 | 0.1 |
| Evaluation of | ε365/ε313 | | <1 | <1 | <1 | >3 | <1 | <1 | <1 | <1 | — |
| photosensitive | Carboxy group consumption rate | | B | B | B | D | B | B | C | C | E |
| material | [measurement of ashing] | | | | | | | | | | |
| | Pattern | 25 μm | A | B | B | C | B | B | B | B | D |
| | formability | 50 μm | A | A | A | B | A | A | A | A | D |
| | | 250 μm | A | A | A | A | A | A | A | A | D |
| | Relative permittivity | | B | B | A | C | B | B | A | A | Standard |
| | Change in relative permittivity | | B | B | A | C | B | B | A | A | D |
| | before and after exposure | | | | | | | | | | |
| Evaluation of | ε365/ε313 | | <1 | <1 | <1 | >3 | <1 | <1 | <1 | <1 | — |
| transfer film | Carboxy group consumption rate | | B | B | B | D | B | B | C | C | E |
| | [measurement of ashing] | | | | | | | | | | |
| | Transmittance at 365 nm | | A | A | A | C | A | A | A | A | A |
| | Transmittance at 365 nm/ | | A | A | A | C | A | A | A | A | B |
| | transmittance at 313 nm | | | | | | | | | | |
| | Laminate suitability | | A | A | A | A | A | A | A | A | A |
| | Pattern | 25 μm | A | B | B | C | B | B | B | B | D |
| | formability | 50 μm | A | A | A | B | A | A | A | A | D |
| | | 250 μm | A | A | A | A | A | A | A | A | D |

| | | | | | | | | | |
|---|---|---|---|---|---|---|---|---|---|
| Relative permittivity | B | B | A | C | B | B | A | A | Standard |
| Change in relative permittivity | B | B | A | C | B | B | A | A | D |
| before and after exposure | | | | | | | | | |
| Moisture permeability | A | A | A | B | A | A | A | A | Standard |

UC3910: ARUFON UC3910 (manufactured by Toagosei Co., Ltd.)

DPHA: dipentaerythritol hexaacrylate (A-DPH manufactured by Shin-Nakamura Chemical Co., Ltd.)

A-NOD-N: 1,9-nonanediol diacrylate (A-NOD-N manufactured by Shin-Nakamura Chemical Co., Ltd.)

DTMPT: ditrimethylolpropane tetraacrylate (KAYARAD T-1420 (T) manufactured by Nippon Kayaku Co., Ltd.)

A-DCPP: dicyclopentane dimethanol diacrylate (A-DCP manufactured by Shin-Nakamura Chemical Co., Ltd.)

TMPT: trimethylolpropane triacrylate (A-TMPT manufactured by Shin-Nakamura Chemical Co., Ltd.)

F551: MEGAFACE F551 (manufactured by DIC Corporation)

From the results in the above table, it was confirmed that, even in a case where the photosensitive material included a polymerizable compound, the objects of the present invention could be achieved with the transfer film according to the embodiment of the present invention.

In addition, it was confirmed that conditions under which the effects of the present invention are more excellent were similar to the trends confirmed for Example 1 system.

### Example 3 System

<Preparation and Evaluation of Photosensitive Material>

Materials shown in Fourth table shown in the latter part were mixed and dissolved in a mixed solvent of propylene glycol monomethyl ether acetate/methyl ethyl ketone=50/50 (mass ratio) so that a blending amount shown in Fourth table shown in the latter part was satisfied and a concentration of solid contents of the finally obtained photosensitive material was 25% by mass, thereby obtaining a photosensitive material.

In preparing the photosensitive material, using a solution of a resin A or a solution of a resin B, which were obtained by a method described later as “Synthesizing method of resin A” or “Synthesizing method of resin B”, the resin A or the resin B was introduced into the photosensitive material.

For the obtained photosensitive material (photosensitive materials of Examples 3-1 to 3-12) of Example 3 system, in a case where the carboxy group consumption rate (mol %) was confirmed by IR measurement in the same manner as (Evaluation of the carboxy group consumption rate (IR measurement)) shown in Example 1, the carboxy group consumption rate was all 20 mol % or more.

Further, before the exposure of 1000 mJ/cm² using the high-pressure mercury lamp in (Evaluation of the carboxy group consumption rate (IR measurement)) shown in Example 1 system, an exposure of 100 mJ/cm² using an ultra-high pressure mercury lamp was performed, and then a test was also conducted in which an exposure of 1000 mJ/cm² was performed using the high-pressure mercury lamp. Even in a case where the exposure of 100 mJ/cm² was performed in advance in this way, the carboxy group consumption rate before and after the exposure of 1000 mJ/cm² was all 20 mol % or more regardless of which of the photosensitive material of Example 3 system (photosensitive materials of Examples 3-1 to 3-12) was used.

In addition, for the obtained photosensitive material of each of Examples or Comparative Examples in Example 3 system, the carboxy group consumption rate, relative permittivity of the photosensitive material, and change in relative permittivity before and after exposure, and the laminate suitability of the transfer film, relative permittivity, change in relative permittivity before and after exposure, and moisture permeability were evaluated in the same manner as shown in Example 1 system. In addition, for the photosensitive layer in the transfer film, the carboxy group consumption rate, transmittance to light at 365 nm, and ratio of the transmittance to light at 365 nm to the transmittance to light at 313 nm were also evaluated in the same manner as shown in Example 1 system. In addition, the physical properties of ε365/ε313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 3A.

The pattern formability of the photosensitive material of each of Examples or Comparative Examples in Example 3 system was evaluated in the same manner as in Example 1 system, except that the pattern forming method was changed as follows.

The photosensitive material of each of Examples or Comparative Examples was spin-coated on a silicon wafer, and then the obtained coating film was dried on a hot plate at 80° C. to obtain a photosensitive layer having a film thickness of 5 μm.

The obtained photosensitive layer was exposed to an ultra-high pressure mercury lamp through the same masks as in Example 1 system. The integrated exposure amount measured with a 365 nm illuminance meter was 100 mJ/cm².

Next, the exposed photosensitive layer in a patterned manner was developed for 40 seconds using a 1% by mass sodium carbonate aqueous solution (liquid temperature: 32° C.) as a developer. After the development, the photosensitive layer was rinsed with pure water for 20 seconds, and then air was blown to remove water, thereby obtaining a pattern.

The obtained pattern was entirely exposed using a high-pressure mercury lamp. The integrated exposure amount measured with a 365 nm illuminance meter was 1000 mJ/cm².

The pattern formability of the transfer film of each of Examples or Comparative Examples in Example 3 system was evaluated in the same manner as in Example 1 system, except that the pattern forming method was changed as follows.

By peeling off the cover film from the produced transfer film and laminating the transfer film on a COP film (substrate for a touch panel) laminated with a copper foil manufactured by GEOMATEC Co., Ltd., the photosensitive layer of the transfer film was transferred to a surface of the copper foil to obtain a laminate having a laminated structure of “temporary support/photosensitive layer/copper foil/substrate (COP film)”. Laminating conditions were that a temperature of a substrate for a touch panel was 40° C., a temperature of a rubber roller (that is, a laminating temperature) was 110° C., a linear pressure was 3 N/cm, and a transportation speed was 2 m/min. Here, the copper foil is a film which is assumed as a wiring line of a touch panel.

The laminating property was good.

Next, using a proximity type exposure machine (Hitachi High-Technologies Corporation) equipped with an ultra-high pressure mercury lamp, a distance between a surface of the exposure mask and a surface of the temporary support was set to 125 μm, and the photosensitive layer of the above-described laminate was exposed in a patterned manner under the condition of an exposure amount of 100 mJ/cm² (i-line) with the ultra-high pressure mercury lamp through the temporary support.

The mask was the same line-and-space pattern mask as that of Example 1 system.

After the exposure, the temporary support was peeled off from the laminate.

Next, the photosensitive layer of the laminate, from which the temporary support was peeled off, was developed for 40 seconds using a 1% by mass sodium carbonate aqueous solution (liquid temperature: 32° C.) as a developer. After the development, the photosensitive layer was rinsed with pure water for 20 seconds, and then air was blown to remove water, thereby obtaining a pattern.

The obtained pattern was entirely exposed using a high-pressure mercury lamp. The integrated exposure amount measured with a 365 nm illuminance meter was 1000 mJ/cm².

<Evaluation of Relative Permittivity Under Double Exposure Conditions>

In Example 3 system, the relative permittivity was also evaluated under the double exposure conditions. The evaluation of the relative permittivity under the first exposure condition means the evaluation of the relative permittivity evaluated under the same conditions as in (Relative permittivity evaluation 2) shown in Example 1 system described above.

For the photosensitive material of Example 3 system, a transfer film was produced in the same manner as in (Production of transfer film) shown in Example 1 system. By peeling off the cover film from the obtained transfer film and laminating the transfer film on an aluminum substrate having a thickness of 0.1 mm under the same conditions as (Laminate suitability evaluation) described above, a laminate having a laminated structure of “temporary support/photosensitive layer/aluminum substrate” was obtained.

As the first exposure to the above-described laminate, the photosensitive layer was entirely exposed through the temporary support using an ultra-high pressure mercury lamp. In the first exposure, the integrated exposure amount measured with a 365 nm illuminance meter was 100 mJ/cm². Since the first exposure was through the temporary support (polyethylene terephthalate), most of light having a wavelength of 320 nm or less was blocked. Therefore, it is considered that those having a large molar absorption coefficient to light having a wavelength of 365 nm (for example, 1×10³ (cm·mol/L)⁻¹ or more) are preferentially involved in the reaction.

Thereafter, the temporary support was peeled off from the above-described laminate, and as the second exposure, the photosensitive layer was entirely exposed using a high-pressure mercury lamp. In the second exposure, the integrated exposure amount measured with a 365 nm illuminance meter was 1000 mJ/cm².

For the photosensitive layer exposed in this way, the relative permittivity was measured in the same manner as in (Relative permittivity evaluation 2) shown in Example 1 system described above.

However, the standard of the relative permittivity was the relative permittivity of Comparative Example 3A under the double exposure conditions.

Fourth table below shows blending of the solid content of the photosensitive material of each of Examples or Comparative Examples in Example 3 system, and the test results thereof.

The same description in Fourth table as in Third table has the same meaning as described to Third table.

TABLE 5

| | | | Example | | | | | | |
|---|---|---|---|---|---|---|---|---|---|
| Forth table | | | 3-1 | 3-2 | 3-3 | 3-4 | 3-5 | 3-6 | 3-7 |
| Solid content | Compound A | Resin A | 60 | 60 | 60 | 60 | | | |
| blending | having acid group | Resin B | | | | | 60 | 60 | 60 |
| | Compound β | 5,6,7,8- | 2.7 (20) | | | | 2.7 (20) | | |
| | (in parentheses: | Tetrahydroquinoline | | | | | | | |
| | molar ratio | “ε365: <10” | | | | | | | |
| | with respect to | “pKa in ground | | | | | | | |
| | carboxy group | state: 5.9” | | | | | | | |
| | of compound A | 1-Acetylpyridine | | 2.4 (20) | | | | 2.4 (20) | |
| | having acid group | “ε365: <10” | | | | | | | |
| | (mol %)) | “pKa in ground | | | | | | | |
| | | state: 3.1” | | | | | | | |
| | | Isoquinoline | | | 2.2 (20) | | | | 2.2 (20) |
| | | “ε365: <10” | | | | | | | |
| | | “pKa in ground | | | | | | | |
| | | state: 4.69” | | | | | | | |
| | | Acridine | | | | 3.6 (20) | | | |
| | | “ε365:4900” | | | | | | | |
| | | “pKa in ground | | | | | | | |
| | | state: 4.67” | | | | | | | |
| | Polymerizable | DPHA | 12.6 | 12.6 | 12.6 | 12.6 | 12.6 | 12.6 | 12.6 |
| | compound | A-NOD-N | 25 | 25 | 25 | 25 | 25 | 25 | 25 |
| | | DTMPT | | | | | | | |
| | | A-DCP | | | | | | | |
| | | ΓMPT | | | | | | | |
| | Photopolymerization | OXE-02 | 0.8 | 0.8 | 0.8 | 0.8 | 0.8 | 0.8 | 0.8 |
| | initiator | Omn907 | 1.5 | 1.5 | 1.5 | 1.5 | 1.5 | 1.5 | 1.5 |
| | Surfactant | F551 | 0.1 | 0.1 | 0.1 | 0.1 | 0.1 | 0.1 | 0.1 |
| Evaluation of | ε365/ε313 | | <1 | <1 | <1 | >3 | <1 | <1 | <1 |
| photosensitive | Carboxy group consumption rate | | C | C | C | D | C | C | C |
| material | [measurement of ashing] | | | | | | | | |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | B | B | A | C | B | B | A |
| | Change in relative permittivity | | B | B | A | C | B | B | A |
| | before and after exposure | | | | | | | | |
| Evaluation of | ε365/ε313 | | <1 | <1 | <1 | >3 | <1 | <1 | <1 |
| transfer film | Carboxy group consumption rate | | C | C | C | D | C | C | C |
| | [measurement of ashing] | | | | | | | | |
| | Transmittance at 365 nm | | A | A | A | C | A | A | A |
| | Transmittance at 365 nm/ | | A | A | A | C | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | B | B | A | C | B | B | A |
| Change in relative permittivity | B | B | A | C | B | B | A |
| before and after exposure | | | | | | | |
| Moisture permeability | A | A | A | B | A | A | A |
| Change in relative permittivity | B | B | A | C | B | B | A |
| after double exposure | | | | | | | |

| | | | | | | | | Comparative | |
|---|---|---|---|---|---|---|---|---|---|
| | | | Example | | | | | Example | |
| Forth table | | | 3-8 | 3-9 | 3-10 | 3-11 | 3-12 | 3A | 3B |
| Solid content | Compound A | Resin A | | | | | | 60 | |
| blending | having acid group | Resin B | 60 | 60 | 60 | 70 | 50 | | 60 |
| | Compound β | 5,6,7,8- | | | | | | | |
| | (in parentheses: | Tetrahydroquinoline | | | | | | | |
| | molar ratio | “ε365: <10” | | | | | | | |
| | with respect to | “pKa in ground | | | | | | | |
| | carboxy group | state: 5.9” | | | | | | | |
| | of compound A | 1-Acetylpyridine | | 2.4 (20) | 2.4 (20) | | | | |
| | having acid group | “ε365: <10” | | | | | | | |
| | (mol %)) | “pKa in ground | | | | | | | |
| | | state: 3.1” | | | | | | | |
| | | Isoquinoline | | | | 1.5 (10) | 1.1 (10) | | |
| | | “ε365: <10” | | | | | | | |
| | | “pKa in ground | | | | | | | |
| | | state: 4.69” | | | | | | | |
| | | Acridine | 3.6 (20) | | | | | | |
| | | “ε365:4900” | | | | | | | |
| | | “pKa in ground | | | | | | | |
| | | state: 4.67” | | | | | | | |
| | Polymerizable | DPHA | 12.6 | | 12.5 | | | 12.6 | 12.6 |
| | compound | A-NOD-N | 25 | | 12.5 | | | 25 | 25 |
| | | DTMPT | | | 12.6 | 27.6 | 12.5 | | |
| | | A-DCP | | 25 | | | 22.5 | | |
| | | ΓMPT | | 12.6 | | | 12.6 | | |
| | Photopolymerization | OXE-02 | 0.8 | 0.8 | 0.8 | 0.8 | 0.8 | 0.8 | 0.8 |
| | initiator | Omn907 | 1.5 | 1.5 | 1.5 | 1.5 | 1.5 | 1.5 | 1.5 |
| | Surfactant | F551 | 0.1 | 0.1 | 0.1 | 0.1 | 0.1 | 0.1 | 0.1 |
| Evaluation of | ε365/ε313 | | >3 | <1 | <1 | <1 | <1 | — | — |
| photosensitive | Carboxy group consumption rate | | D | C | C | C | C | E | E |
| material | [measurement of ashing] | | | | | | | | |
| | Pattern | 25 μm | A | A | A | A | A | B | B |
| | formability | 50 μm | A | A | A | A | A | B | B |
| | | 250 μm | A | A | A | A | A | B | B |
| | Relative permittivity | | C | B | B | A | A | Standard | D |
| | Change in relative permittivity | | C | B | B | A | A | D | D |
| | before and after exposure | | | | | | | | |
| Evaluation of | ε365/ε313 | | >3 | <1 | <1 | <1 | <1 | — | — |
| transfer film | Carboxy group consumption rate | | D | C | C | C | C | E | E |
| | [measurement of ashing] | | | | | | | | |
| | Transmittance at 365 nm | | C | A | A | A | A | A | A |
| | Transmittance at 365 nm/ | | C | A | A | A | A | B | B |
| | transmittance at 313 nm | | | | | | | | |
| | Laminate suitability | | A | A | A | A | A | A | A |
| | Pattern | 25 μm | A | A | A | A | A | B | B |
| | formability | 50 μm | A | A | A | A | A | B | B |
| | | 250 μm | A | A | A | A | A | B | B |

| | | | | | | | |
|---|---|---|---|---|---|---|---|
| Relative permittivity | C | B | B | A | A | Standard | D |
| Change in relative permittivity | C | B | B | A | A | D | D |
| before and after exposure | | | | | | | |
| Moisture permeability | B | A | A | A | A | Standard | D |
| Change in relative permittivity | C | B | B | A | A | Standard | D |
| after double exposure | | | | | | | |

Resin A: resin having the following structure (acid value: 94.5 mgKOH/g)

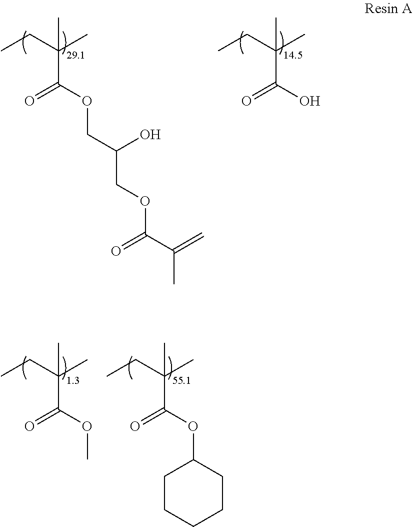

ratio is mass ratio

weight-average molecular weight: 27000

dispersity: 2.9

Synthesizing Method of Resin A

200 g of propylene glycol monomethyl ether and 50 g of propylene glycol monomethyl ether acetate poured into a flask and heated to 90° C. under a nitrogen stream. To this liquid, a solution in which 192.9 g of cyclohexyl methacrylate, 4.6 g of methyl methacrylate, and 89.3 g of methacrylic acid had been dissolved in 60 g of propylene glycol monomethyl ether acetate and a solution in which 9.2 g of a polymerization initiator V-601 (manufactured by FUJIFILM Wako Pure Chemical Corporation) had been dissolved in 114.8 g of propylene glycol monomethyl ether acetate was simultaneously added dropwise over 3 hours. After completion of the dropwise addition, a solution in which 2 g of V-601 had been dissolved in 10 g of propylene glycol monomethyl ether acetate was added thereto three times every hour. Thereafter, the reaction was continued for another 3 hours. The reaction solution was diluted with 168.7 g of propylene glycol monomethyl ether acetate. The reaction solution was heated to 100° C. under an air stream, and 1.5 g of tetraethylammonium bromide and 0.67 g of p-methoxyphenol were added thereto. 63.4 g of glycidyl methacrylate (Blemmer GH manufactured by NOF Corporation) was added dropwise thereto over 20 minutes. The reaction was continued at 100° C. for 6 hours to obtain a solution of a resin A. The concentration of solid contents of the obtained solution was 36.2%. The weight-average molecular weight in terms of standard polystyrene in GPC was 27000, the dispersity was 2.9, and the acid value of the polymer was 94.5 mgKOH/g. The amount of residual monomer measured by gas chromatography was less than 0.1% by mass with respect to the solid content of the polymer in any of the monomers.

Resin B: resin having the following structure (acid value: 94.5 mgKOH/g)

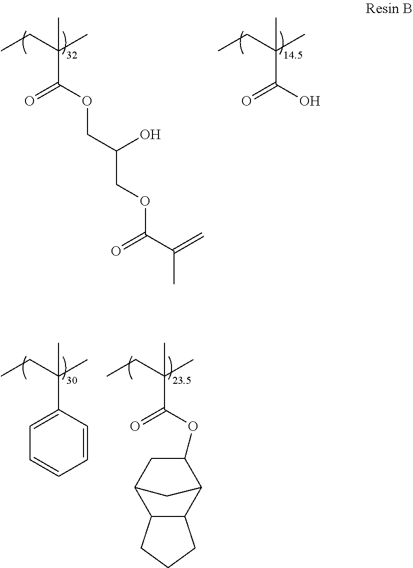

ratio is mass ratio

weight-average molecular weight: 17000

dispersity: 2.4

Synthesizing Method of Resin B 82.4 g of propylene glycol monomethyl ether was charged into a flask and heated to 90° C. under a nitrogen stream. To this liquid, a solution in which 38.4 g of styrene, 30.1 g of dicyclopentanyl methacrylate, and 34.0 g of methacrylic acid had been dissolved in 20 g of propylene glycol monomethyl ether and a solution in which 5.4 g of a polymerization initiator V-601 (manufactured by FUJIFILM Wako Pure Chemical Corporation) had been dissolved in 43.6 g of propylene glycol monomethyl ether acetate was simultaneously added dropwise over 3 hours. After the dropwise addition, 0.75 g of V-601 was added three times every hour. Thereafter, the reaction was continued for another 3 hours. Thereafter, the reaction solution was diluted with 58.4 g of propylene glycol monomethyl ether acetate and 11.7 g of propylene glycol monomethyl ether. The reaction solution was heated to 100° C. under an air stream, and 0.53 g of tetraethylammonium bromide and 0.26 g of p-methoxyphenol were added thereto. 25.5 g of glycidyl methacrylate (Blemmer GH manufactured by NOF Corporation) was added dropwise thereto over 20 minutes. The reaction was continued at 100° C. for 7 hours to obtain a solution of a resin B. The concentration of solid contents of the obtained solution was 36.2%. The weight-average molecular weight in terms of standard polystyrene in GPC was 17000, the dispersity was 2.4, and the acid value of the polymer was 94.5 mgKOH/g. The amount of residual monomer measured by gas chromatography was less than 0.1% by mass with respect to the solid content of the polymer in any of the monomers.

DPHA: dipentaerythritol hexaacrylate (A-DPH manufactured by Shin-Nakamura Chemical Co., Ltd.)

A-NOD-N: 1,9-nonanediol diacrylate (A-NOD-N manufactured by Shin-Nakamura Chemical Co., Ltd.)

DTMPT: ditrimethylolpropane tetraacrylate (KAYARAD T-1420 (T) manufactured by Nippon Kayaku Co., Ltd.) A-DCPP: dicyclopentane dimethanol diacrylate (A-DCP manufactured by Shin-Nakamura Chemical Co., Ltd.)

TMPT: trimethylolpropane triacrylate (A-TMPT manufactured by Shin-Nakamura Chemical Co., Ltd.)

F551: MEGAFACE F551 (manufactured by DIC Corporation)

OXE-02: Irgacure OXE02 (manufactured by BASF SE, oxime ester compound; molar absorption coefficient to light having a wavelength of 365 nm in acetonitrile: 2700 (cm·mol/L)⁻¹)

Omn907: Omnirad 907 (manufactured by IGM Resins B.V., aminoacetophenone compound; molar absorption coefficient to light having a wavelength of 365 nm in acetonitrile: 120 (cm·mol/L)⁻¹)

As shown in the tables, it was confirmed that, even in a case where the photosensitive layer included a photopolymerization initiator and a polymerizable compound, the objects of the present invention could be achieved with the transfer film according to the embodiment of the present invention.

In addition, it was confirmed that conditions under which the effects of the present invention are more excellent were similar to the trends confirmed for Example 1 system.

[Evaluation of layer which has photosensitive layer formed of photosensitive material of Example 3 system and second resin layer under condition of double exposure]

<Manufacturing of Transfer Film>

(Formation of Photosensitive Layer)

To a polyethylene terephthalate film (manufactured by Toray Industries, Inc., 16KS40) having a thickness of 16 μm (temporary support), the photosensitive material liquid of each of Examples shown in Example 3 system was applied using a slit-shaped nozzle such that a thickness after drying was adjusted to 5 μm, and the photosensitive material was dried at 100° C. for 2 minutes to form a photosensitive layer.

(Formation of Second Resin Layer)

Next, a coating liquid for a second resin layer formed by the following formulation 201 was applied to the photosensitive layer such that a thickness after drying was adjusted to 70 nm, dried for 1 minute at 80° C., and further dried for 1 minute at 110° C. to form a second resin layer disposed in direct contact with the photosensitive layer. The film thickness of the second resin layer was 70 nm, and the refractive index was 1.68.

The formulation 201 was prepared using a resin having an acid group and an ammonia aqueous solution, and the resin having an acid group was neutralized with the ammonia aqueous solution. That is, the coating liquid for a second resin layer was an aqueous resin composition including an ammonium salt of the resin having an acid group.

Coating Liquid for Second Resin Layer: Formulation 201 (Aqueous Resin Composition)
Acrylic resin (resin having an acid group, copolymer resin of methacrylic acid/allyl methacrylate, weight-average molecular weight: 25,000, compositional ratio (molar ratio)=40/60, solid content: 99.8%): 0.29 parts
ARONIX TO-2349 (monomer having a carboxylic acid group, manufactured by Toagosei Co., Ltd.): 0.04 parts
NanoUse OZ-S30M (ZrO₂ particles, solid content: 30.5%, methanol 69.5%, refractive index: 2.2, average particle diameter: approximately 12 nm, manufactured by Nissan Chemical Corporation): 4.80 parts
BT120 (benzotriazole, manufactured by Johoku Chemical Industry Co., Ltd.): 0.03 parts
MEGAFACE F444 (fluorine-based surfactant, manufactured by DIC Corporation): 0.01 parts
Ammonia aqueous solution (2.5% by mass): 7.80 parts
Distilled water: 24.80 parts
Methanol: 76.10 parts

(Pattern Formation)

For a laminate obtained as described above, in which the photosensitive layer and the second resin layer which was disposed to be directly adjacent to the photosensitive layer were provided on the temporary support in this order, a polyethylene terephthalate film (manufactured by Toray Industries, Inc., 16KS40) having a thickness of 16 μm (cover film) was pressure-bonded onto the second resin layer. As a result, a transfer film which had a photosensitive layer formed of the photosensitive material of each of Examples of Example 3 system and a second resin layer was produced.

By peeling off the cover film from the transfer film produced above and laminating the transfer film on a PET film (substrate for a touch panel) laminated with a copper foil manufactured by GEOMATEC Co., Ltd., the photosensitive layer of the transfer film was transferred to a surface of the copper foil to obtain a laminate having a laminated structure of “temporary support/photosensitive layer/second resin layer/copper foil/substrate (PET film)”. Laminating conditions were that a temperature of a substrate for a touch panel was 40° C., a temperature of a rubber roller (that is, a laminating temperature) was 110° C., a linear pressure was 3 N/cm, and a transportation speed was 2 m/min. Here, the copper foil is a film which is assumed as a wiring line of a touch panel.

The laminating property was as good as that of each transfer film of Example 3 system, which did not have the second resin layer.

Next, using a proximity type exposure machine (Hitachi High-Technologies Corporation) equipped with an ultra-high pressure mercury lamp, a distance between a surface of the exposure mask and a surface of the temporary support was set to 125 μm, and the photosensitive layer of the above-described laminate was exposed in a patterned manner under the condition of an exposure amount of 100 mJ/cm² (i-line) with the ultra-high pressure mercury lamp through the temporary support.

During the exposure, the exposure was performed through a mask having a line size of 50 μm and a line:space of 1:1 or a mask having a line size of 250 μm and a line:space of 1:1.

After the exposure, the temporary support was peeled off from the laminate.

Next, the photosensitive layer of the laminate, from which the temporary support was peeled off, was developed for 40 seconds using a 1% by mass sodium carbonate aqueous solution (liquid temperature: 32° C.) as a developer. After the development, the photosensitive layer was rinsed with pure water for 20 seconds, and then air was blown to remove water, thereby obtaining a pattern. The obtained pattern was entirely exposed using a high-pressure mercury lamp. The integrated exposure amount measured with a 365 nm illuminance meter was 1000 mJ/cm².

In a case where line-and-space patterns with line widths and space widths of 50 μm or 250 μm, which were produced as described above were evaluated in the same manner as in (Pattern formability evaluation 1) described above, the evaluation results were as good as those in the case where the patterns were formed and evaluated in the same manner for each transfer film of Example 3 system, which had no second resin layer.

That is, the transfer film according to the embodiment of the present invention, which includes the photosensitive layer including a polymerizable compound and a photopolymerization initiator, has good pattern formability even under the two-step exposure conditions.

In a case where the same evaluations as the evaluations under the condition of double exposure of the photosensitive layer having the second resin layer formed of the photosensitive composition in Example 3 system was performed, except that a PET film on which an ITO film assuming a transparent electrode of a touch panel was used instead of the PET film on which the copper foil was laminated, good laminating property and pattern formability were exhibited same as the case of using the PET film on which the copper foil was laminated.

### Example 4 System

Fifth table below shows structures of the compounds A (polymers) having an acid group, which were used in Example 4 system. The compound A was synthesized by a known method.

In the following, as a representative example, a method for synthesizing a polymer of a compound No. 1 will be shown.

(Synthesis of Polymer of Compound No. 1)

PGMEA (60 parts) and PGME (240 parts) were poured into a flask having a capacity of 2000 mL. The obtained liquid was heated to 90° C. while stirring at a stirring speed of 250 rpm (round per minute; the same applies hereinafter).

For a preparation of a dropping liquid (1), styrene (47.7 parts), methyl methacrylate (1.3 parts), and methacrylic acid (51 parts) were mixed and then diluted with PGMEA (60 parts) to obtain the dropping liquid (1).

For a preparation of a dropping liquid (2), V-601 (dimethyl 2,2′-azobis(2-methylpropionate) (9.637 parts) was dissolved in PGMEA (136.56 parts) to obtain the dropping liquid (2).

The dropping liquid (1) and the dropping liquid (2) were simultaneously added dropwise to the above-described flask having a capacity of 2000 mL (specifically, the flask having a capacity of 2000 mL containing the liquid heated to 90° C.) over 3 hours. After the dropwise addition, V-601 (2.401 parts) was added to the flask three times every hour. Thereafter, the reaction solution was further stirred at 90° C. for 3 hours.

Thereafter, the obtained solution (reaction solution) in the above-described flask was diluted with PGMEA (178 parts). Next, tetraethylammonium bromide (1.8 parts) and hydroquinone monomethyl ether (0.8 parts) were added to the reaction solution. Thereafter, the reaction solution was heated to 100° C.

Next, glycidyl methacrylate was added dropwise to the reaction solution over 1 hour such that an added amount was composition of the compound No. 1 in Fifth table. The above-described reaction solution was reacted at 100° C. for 6 hours to obtain a solution of a polymer (concentration of solid contents: 36.3% by mass).

As shown in Fifth table, the weight-average molecular weight of the compound A shown in Fifth table was in a range of 10,000 to 50,000.

In addition, numerical values of each structural unit in Fifth table indicate a mass ratio.

In the column of the compound A in Fifth table, abbreviations for each monomer forming the structural unit of the compound A (polymer) are as follows. GMA-MAA means a constitutional unit in which glycidyl methacrylate is added to a constitutional unit derived from methacrylic acid, and GMA-AA means a constitutional unit in which glycidyl methacrylate is added to a constitutional unit derived from acrylic acid.

St: styrene

CHMA: cyclohexyl methacrylate

CHA: cyclohexyl acrylate

MMA: methyl methacrylate

EA: ethyl acrylate

BzMA: benzyl methacrylate

BzA: benzyl acrylate

HEMA: 2-hydroxyethyl methacrylate

HEA: 2-hydroxyethyl acrylate

MAA: methacrylic acid

AA: acrylic acid

TABLE 6
Fifth table
Compound A having acid group

| | Structural unit (mass ratio) | | | | | | | | | | | | | Weight-average |
|---|---|---|---|---|---|---|---|---|---|---|---|---|---|---|
| Compound | | | | | | | | | | GMA- | GMA- | | | molecular weight |
| No. | St | CHMA | CHA | MMA | EA | BzMA | BzA | HEMA | HEA | MAA | AA | MAA | AA | (Mw) |
| 1 | 47.7 | | | 1.3 | | | | | | 32 | | 19 | | 18000 |
| 2 | 30 | | | 30 | | | | | | | | 40 | | 22000 |
| 3 | 30 | | | 30 | | | | | | | | | 40 | 25000 |
| 4 | 30 | | | | 30 | | | | | | | 40 | | 19000 |
| 5 | 30 | | | | 30 | | | | | | | | 40 | 20000 |
| 6 | 53.5 | | | | | | | | | | 32 | | 14.5 | 16000 |
| 7 | 49 | | | | | | | | | 32 | | 19 | | 15000 |
| 8 | 49 | | | | | 32 | | | | | | 19 | | 17000 |
| 9 | 53.5 | | | | | | 32 | | | | | | 14.5 | 14000 |
| 10 | 35.5 | | | | | 13.5 | | | | 32 | | 19 | | 28000 |
| 11 | 40 | | | | | | 14 | | | | 32 | | 14.5 | 29000 |
| 12 | 35.5 | | | | | | | 13.5 | | 32 | | 19 | | 30000 |
| 13 | 40 | | | | | | | | 13.5 | | 32 | | 14.5 | 32000 |
| 14 | | 81 | | | | | | | | | | 19 | | 27000 |
| 15 | | | 85.5 | | | | | | | | | | 14.5 | 28000 |
| 16 | | 49 | | | | | | | | 32 | | 19 | | 23000 |
| 17 | | | 53.5 | | | | | | | | 32 | | 14.5 | 23000 |
| 18 | | 49 | | | | 32 | | | | | | 19 | | 24000 |
| 19 | | | 53.5 | | | | 32 | | | | | | 14.5 | 30000 |
| 20 | | 49 | | | | | | 32 | | | | 19 | | 33000 |
| 21 | | | 53.5 | | | | | | 32 | | | | 14.5 | 40000 |
| 22 | | 35.5 | | | | 13.5 | | | | 32 | | 19 | | 38000 |
| 23 | | | 40 | | | | 14 | | | | 32 | | 14.5 | 35000 |
| 24 | | 35.5 | | | | | | 13.5 | | 32 | | 19 | | 49000 |
| 25 | | | 40 | | | | | | 13.5 | | 32 | | 14.5 | 45000 |
| 26 | 85 | | | | | | | | | | | | 15 | 11000 |

<Preparation and Evaluation of Photosensitive Material>

Materials shown in Sixth table shown in the latter part were mixed and dissolved in a mixed solvent of propylene glycol monomethyl ether acetate/methyl ethyl ketone=50/50 (mass ratio) so that a blending amount shown in Sixth table shown in the latter part was satisfied and a concentration of solid contents of the finally obtained photosensitive material was 25% by mass, thereby obtaining a photosensitive material.

In Sixth table below, each number of Examples and Comparative Examples is indicated by a head number+a serial number. That is, Example 4-1-1 corresponds to an example in which the head number is 4-1 and the serial number is 1. In addition, Comparative Example 4A-1 corresponds to an example in which the head number is 4A and the serial number is 1.

In addition, for the obtained photosensitive material of each of Examples or Comparative Examples in Example 4 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, and moisture permeability were evaluated in the same manner as shown in Example 1 system. In addition, the carboxy group consumption rate, transmittance to light at 365 nm, and ratio of the transmittance to light at 365 nm to the transmittance to light at 313 nm of the photosensitive layer in the transfer film were also evaluated in the same manner as shown in Example 1 system. In addition, the physical properties of ε365/ε313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Examples having the same serial number. That is, for example, in a case of Example 4-1-1, since the serial number is 1, Comparative Example 4A-1 having the serial number corresponds to the standard. In addition, for example, in a case of Example 4-27-51, since the serial number is 51, Comparative Example 4A-51 having the serial number corresponds to the standard.

Hereinafter, Sixth table below shows blending of the solid content of the photosensitive material of each of Examples or Comparative Examples in Example 4 system, and the test results thereof.

In the tables, the “Compound No.” in the column of “Compound A having acid group” corresponds to “Compound No.” shown in Fifth table described above.

In the table, the value described in the column of “Part by mass” indicates the content (part by mass) of the solid content component of each component. The above-described blending amount (part by mass) is the amount of “Compound A having acid group” and “Compound β” itself (solid content) added to the photosensitive material.

In addition, in the tables, the method for measuring “pKa in ground state” is as described above.

In addition, in the tables, the column of “ε365” indicates a molar absorption coefficient ((cm·mol/L)⁻¹) of the compound β to light having a wavelength of 365 nm in acetonitrile.

In addition, in the tables, the value of “Molar ratio with respect to carboxy group of compound A having acid group (mol %)” in the compound β indicates a proportion (mol %) of the total number of structures (specific structures S1) capable of accepting an electron from the acid group included in the compound A, which are included in the compound β, to the total number of carboxy groups included in the compound A having an acid group (compound A) in the photosensitive material.

In addition, the column of “ε365/ε313” in the evaluation of the photosensitive material and the evaluation of the transfer film indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values measured in acetonitrile.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

In addition, in Sixth table, types of the compound β used for preparing the photosensitive material are indicated by symbols.

The correspondence between the type of the compound β and the symbol is as shown below. In the following, the method for measuring “pKa in ground state” described for each compound β is as described above. The “ε365” indicates a molar absorption coefficient ((cm·mol/L)⁻¹) of the compound β to light having a wavelength of 365 nm in acetonitrile.

| | | pKa in | |
|---|---|---|---|
| Symbol; Type | | ground state | ε365 |
| B1; | isoquinoline | 4.69 | <10 |
| B2; | quinoline | 4.15 | <10 |
| B3; | acridine | 4.67 | 4900 |
| B4; | 1-n-butylisoquinoline | 5.27 | <10 |
| B5; | 1-n-butyl-4-methylisoquinoline | 5.9 | <10 |
| B6; | 1-Me-isoquinoline | 5.31 | <10 |
| B7; | 2,4,5,7-tetramethylquinoline | 6.23 | <10 |
| B8; | 2-methyl-4-methoxyquinoline | 6.51 | <10 |
| B9; | 9-methylacridine | 5.4 | 6300 |
| B10; | 9-phenylacridine | 4.04 | >10000 |
| B11; | pyridine | 5.25 | <10 |
| B12: | 2,4-dimethylquinoline | 5.67 | <10 |
| B13; | 4-aminopyridine | 9.20 | <100 |
| B14; | 2-chloropyridine | 0.70 | <10 |

TABLE 7

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (1) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-1- | 1 | 1 | 100 | B1 | 5.7 | 20 | B | <1 | B | A | A |
| | | 2 | 2 | 100 | B1 | 12.0 | 20 | B | <1 | B | A | A |
| | | 3 | 3 | 100 | B1 | 14.0 | 20 | B | <1 | B | A | A |
| | | 4 | 4 | 100 | B1 | 12.0 | 20 | B | <1 | B | A | A |
| | | 5 | 5 | 100 | B1 | 14.0 | 20 | B | <1 | B | A | A |
| | | 6 | 6 | 100 | B1 | 5.1 | 20 | B | <1 | B | A | A |
| | | 7 | 7 | 100 | B1 | 5.7 | 20 | B | <1 | B | A | A |
| | | 8 | 8 | 100 | B1 | 5.7 | 20 | B | <1 | B | A | A |
| | | 9 | 9 | 100 | B1 | 5.1 | 20 | B | <1 | B | A | A |
| | | 10 | 10 | 100 | B1 | 5.7 | 20 | B | <1 | B | A | A |
| | | 11 | 11 | 100 | B1 | 5.1 | 20 | B | <1 | B | A | A |
| | | 12 | 12 | 100 | B1 | 5.7 | 20 | B | <1 | B | A | A |
| | | 13 | 13 | 100 | B1 | 5.1 | 20 | B | <1 | B | A | A |
| | | 14 | 14 | 100 | B1 | 5.7 | 20 | B | <1 | B | A | A |
| | | 15 | 15 | 100 | B1 | 5.1 | 20 | B | <1 | B | A | A |
| | | 16 | 16 | 100 | B1 | 5.7 | 20 | B | <1 | B | A | A |
| | | 17 | 17 | 100 | B1 | 5.1 | 20 | B | <1 | B | A | A |
| | | 18 | 18 | 100 | B1 | 5.7 | 20 | B | <1 | B | A | A |
| | | 19 | 19 | 100 | B1 | 5.1 | 20 | B | <1 | B | A | A |
| | | 20 | 20 | 100 | B1 | 5.7 | 20 | B | <1 | B | A | A |
| | | 21 | 21 | 100 | B1 | 5.1 | 20 | B | <1 | B | A | A |
| | | 22 | 22 | 100 | B1 | 5.7 | 20 | B | <1 | B | A | A |
| | | 23 | 23 | 100 | B1 | 5.1 | 20 | B | <1 | B | A | A |
| | | 24 | 24 | 100 | B1 | 5.7 | 20 | B | <1 | B | A | A |
| | | 25 | 25 | 100 | B1 | 5.1 | 20 | B | <1 | B | A | A |
| | | 26 | 26 | 100 | B1 | 5.2 | 20 | B | <1 | B | A | A |

| | | | Evaluation of photosensitive material | | | | |
|---|---|---|---|---|---|---|---|
| | | | | Change in | Evaluation of transfer film | | |
| Sixth table (1) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-1- | 1 | A | A | B | A | A |
| | | 2 | A | A | B | A | A |
| | | 3 | A | A | B | A | A |
| | | 4 | A | A | B | A | A |
| | | 5 | A | A | B | A | A |
| | | 6 | A | A | B | A | A |
| | | 7 | A | A | B | A | A |
| | | 8 | A | A | B | A | A |
| | | 9 | A | A | B | A | A |
| | | 10 | A | A | B | A | A |
| | | 11 | A | A | B | A | A |
| | | 12 | A | A | B | A | A |
| | | 13 | A | A | B | A | A |
| | | 14 | A | A | B | A | A |
| | | 15 | A | A | B | A | A |
| | | 16 | A | A | B | A | A |
| | | 17 | A | A | B | A | A |
| | | 18 | A | A | B | A | A |
| | | 19 | A | A | B | A | A |
| | | 20 | A | A | B | A | A |
| | | 21 | A | A | B | A | A |
| | | 22 | A | A | B | A | A |
| | | 23 | A | A | B | A | A |
| | | 24 | A | A | B | A | A |
| | | 25 | A | A | B | A | A |
| | | 26 | A | A | B | A | A |

| | | | Evaluation of transfer film | | | | | | | |
|---|---|---|---|---|---|---|---|---|---|---|
| | | | | | | | | | Change in | |
| Sixth table (1) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-1- | 1 | A | <1 | B | A | A | A | A | A |
| | | 2 | A | <1 | B | A | A | A | A | A |
| | | 3 | A | <1 | B | A | A | A | A | A |
| | | 4 | A | <1 | B | A | A | A | A | A |
| | | 5 | A | <1 | B | A | A | A | A | A |
| | | 6 | A | <1 | B | A | A | A | A | A |
| | | 7 | A | <1 | B | A | A | A | A | A |
| | | 8 | A | <1 | B | A | A | A | A | A |
| | | 9 | A | <1 | B | A | A | A | A | A |
| | | 10 | A | <1 | B | A | A | A | A | A |
| | | 11 | A | <1 | B | A | A | A | A | A |
| | | 12 | A | <1 | B | A | A | A | A | A |
| | | 13 | A | <1 | B | A | A | A | A | A |
| | | 14 | A | <1 | B | A | A | A | A | A |
| | | 15 | A | <1 | B | A | A | A | A | A |
| | | 16 | A | <1 | B | A | A | A | A | A |
| | | 17 | A | <1 | B | A | A | A | A | A |
| | | 18 | A | <1 | B | A | A | A | A | A |
| | | 19 | A | <1 | B | A | A | A | A | A |
| | | 20 | A | <1 | B | A | A | A | A | A |
| | | 21 | A | <1 | B | A | A | A | A | A |
| | | 22 | A | <1 | B | A | A | A | A | A |
| | | 23 | A | <1 | B | A | A | A | A | A |
| | | 24 | A | <1 | B | A | A | A | A | A |
| | | 25 | A | <1 | B | A | A | A | A | A |
| | | 26 | A | <1 | B | A | A | A | A | A |

TABLE 8

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (2) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-2- | 1 | 1 | 100 | B2 | 5.7 | 20 | B | <1 | B | A | A |
| | | 2 | 2 | 100 | B2 | 12.0 | 20 | B | <1 | B | A | A |
| | | 3 | 3 | 100 | B2 | 14.0 | 20 | B | <1 | B | A | A |
| | | 4 | 4 | 100 | B2 | 12.0 | 20 | B | <1 | B | A | A |
| | | 5 | 5 | 100 | B2 | 14.0 | 20 | B | <1 | B | A | A |
| | | 6 | 6 | 100 | B2 | 5.1 | 20 | B | <1 | B | A | A |
| | | 7 | 7 | 100 | B2 | 5.7 | 20 | B | <1 | B | A | A |
| | | 8 | 8 | 100 | B2 | 5.7 | 20 | B | <1 | B | A | A |
| | | 9 | 9 | 100 | B2 | 5.1 | 20 | B | <1 | B | A | A |
| | | 10 | 10 | 100 | B2 | 5.7 | 20 | B | <1 | B | A | A |
| | | 11 | 11 | 100 | B2 | 5.1 | 20 | B | <1 | B | A | A |
| | | 12 | 12 | 100 | B2 | 5.7 | 20 | B | <1 | B | A | A |
| | | 13 | 13 | 100 | B2 | 5.1 | 20 | B | <1 | B | A | A |
| | | 14 | 14 | 100 | B2 | 5.7 | 20 | B | <1 | B | A | A |
| | | 15 | 15 | 100 | B2 | 5.1 | 20 | B | <1 | B | A | A |
| | | 16 | 16 | 100 | B2 | 5.7 | 20 | B | <1 | B | A | A |
| | | 17 | 17 | 100 | B2 | 5.1 | 20 | B | <1 | B | A | A |
| | | 18 | 18 | 100 | B2 | 5.7 | 20 | B | <1 | B | A | A |
| | | 19 | 19 | 100 | B2 | 5.1 | 20 | B | <1 | B | A | A |
| | | 20 | 20 | 100 | B2 | 5.7 | 20 | B | <1 | B | A | A |
| | | 21 | 21 | 100 | B2 | 5.1 | 20 | B | <1 | B | A | A |
| | | 22 | 22 | 100 | B2 | 5.7 | 20 | B | <1 | B | A | A |
| | | 23 | 23 | 100 | B2 | 5.1 | 20 | B | <1 | B | A | A |
| | | 24 | 24 | 100 | B2 | 5.7 | 20 | B | <1 | B | A | A |
| | | 25 | 25 | 100 | B2 | 5.1 | 20 | B | <1 | B | A | A |
| | | 26 | 26 | 100 | B2 | 5.2 | 20 | B | <1 | B | A | A |

| | | | Evaluation of photosensitive material | | | | |
|---|---|---|---|---|---|---|---|
| | | | | Change in | Evaluation of transfer film | | |
| Sixth table (2) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-2- | 1 | A | A | B | A | A |
| | | 2 | A | A | B | A | A |
| | | 3 | A | A | B | A | A |
| | | 4 | A | A | B | A | A |
| | | 5 | A | A | B | A | A |
| | | 6 | A | A | B | A | A |
| | | 7 | A | A | B | A | A |
| | | 8 | A | A | B | A | A |
| | | 9 | A | A | B | A | A |
| | | 10 | A | A | B | A | A |
| | | 11 | A | A | B | A | A |
| | | 12 | A | A | B | A | A |
| | | 13 | A | A | B | A | A |
| | | 14 | A | A | B | A | A |
| | | 15 | A | A | B | A | A |
| | | 16 | A | A | B | A | A |
| | | 17 | A | A | B | A | A |
| | | 18 | A | A | B | A | A |
| | | 19 | A | A | B | A | A |
| | | 20 | A | A | B | A | A |
| | | 21 | A | A | B | A | A |
| | | 22 | A | A | B | A | A |
| | | 23 | A | A | B | A | A |
| | | 24 | A | A | B | A | A |
| | | 25 | A | A | B | A | A |
| | | 26 | A | A | B | A | A |

| | | | Evaluation of transfer film | | | | | | | |
|---|---|---|---|---|---|---|---|---|---|---|
| | | | | | | | | | Change in | |
| Sixth table (2) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-2- | 1 | A | <1 | B | A | A | A | A | B |
| | | 2 | A | <1 | B | A | A | A | A | B |
| | | 3 | A | <1 | B | A | A | A | A | B |
| | | 4 | A | <1 | B | A | A | A | A | B |
| | | 5 | A | <1 | B | A | A | A | A | B |
| | | 6 | A | <1 | B | A | A | A | A | B |
| | | 7 | A | <1 | B | A | A | A | A | B |
| | | 8 | A | <1 | B | A | A | A | A | B |
| | | 9 | A | <1 | B | A | A | A | A | B |
| | | 10 | A | <1 | B | A | A | A | A | B |
| | | 11 | A | <1 | B | A | A | A | A | B |
| | | 12 | A | <1 | B | A | A | A | A | B |
| | | 13 | A | <1 | B | A | A | A | A | B |
| | | 14 | A | <1 | B | A | A | A | A | B |
| | | 15 | A | <1 | B | A | A | A | A | B |
| | | 16 | A | <1 | B | A | A | A | A | B |
| | | 17 | A | <1 | B | A | A | A | A | B |
| | | 18 | A | <1 | B | A | A | A | A | B |
| | | 19 | A | <1 | B | A | A | A | A | B |
| | | 20 | A | <1 | B | A | A | A | A | B |
| | | 21 | A | <1 | B | A | A | A | A | B |
| | | 22 | A | <1 | B | A | A | A | A | B |
| | | 23 | A | <1 | B | A | A | A | A | B |
| | | 24 | A | <1 | B | A | A | A | A | B |
| | | 25 | A | <1 | B | A | A | A | A | B |
| | | 26 | A | <1 | B | A | A | A | A | B |

TABLE 9

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (3) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-3- | 1 | 1 | 100 | B3 | 7.9 | 20 | D | >3 | C | B | B |
| | | 2 | 2 | 100 | B3 | 16.7 | 20 | D | >3 | C | B | B |
| | | 3 | 3 | 100 | B3 | 19.4 | 20 | D | >3 | C | B | B |
| | | 4 | 4 | 100 | B3 | 16.7 | 20 | D | >3 | C | B | B |
| | | 5 | 5 | 100 | B3 | 19.4 | 20 | D | >3 | C | B | B |
| | | 6 | 6 | 100 | B3 | 7.0 | 20 | D | >3 | C | B | B |
| | | 7 | 7 | 100 | B3 | 7.9 | 20 | D | >3 | C | B | B |
| | | 8 | 8 | 100 | B3 | 7.9 | 20 | D | >3 | C | B | B |
| | | 9 | 9 | 100 | B3 | 7.0 | 20 | D | >3 | C | B | B |
| | | 10 | 10 | 100 | B3 | 7.9 | 20 | D | >3 | C | B | B |
| | | 11 | 11 | 100 | B3 | 7.0 | 20 | D | >3 | C | B | B |
| | | 12 | 12 | 100 | B3 | 7.9 | 20 | D | >3 | C | B | B |
| | | 13 | 13 | 100 | B3 | 7.0 | 20 | D | >3 | C | B | B |
| | | 14 | 14 | 100 | B3 | 7.9 | 20 | D | >3 | C | B | B |
| | | 15 | 15 | 100 | B3 | 7.0 | 20 | D | >3 | C | B | B |
| | | 16 | 16 | 100 | B3 | 7.9 | 20 | D | >3 | C | B | B |
| | | 17 | 17 | 100 | B3 | 7.0 | 20 | D | >3 | C | B | B |
| | | 18 | 18 | 100 | B3 | 7.9 | 20 | D | >3 | C | B | B |
| | | 19 | 19 | 100 | B3 | 7.0 | 20 | D | >3 | C | B | B |
| | | 20 | 20 | 100 | B3 | 7.9 | 20 | D | >3 | C | B | B |
| | | 21 | 21 | 100 | B3 | 7.0 | 20 | D | >3 | C | B | B |
| | | 22 | 22 | 100 | B3 | 7.9 | 20 | D | >3 | C | B | B |
| | | 23 | 23 | 100 | B3 | 7.0 | 20 | D | >3 | C | B | B |
| | | 24 | 24 | 100 | B3 | 7.9 | 20 | D | >3 | C | B | B |
| | | 25 | 25 | 100 | B3 | 7.0 | 20 | D | >3 | C | B | B |
| | | 26 | 26 | 100 | B3 | 7.3 | 20 | D | >3 | C | B | B |

| | | | Evaluation of photosensitive material | | | | |
|---|---|---|---|---|---|---|---|
| | | | | Change in | Evaluation of transfer film | | |
| Sixth table (3) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-3- | 1 | B | B | D | C | C |
| | | 2 | B | B | D | C | C |
| | | 3 | B | B | D | C | C |
| | | 4 | B | B | D | C | C |
| | | 5 | B | B | D | C | C |
| | | 6 | B | B | D | C | C |
| | | 7 | B | B | D | C | C |
| | | 8 | B | B | D | C | C |
| | | 9 | B | B | D | C | C |
| | | 10 | B | B | D | C | C |
| | | 11 | B | B | D | C | C |
| | | 12 | B | B | D | C | C |
| | | 13 | B | B | D | C | C |
| | | 14 | B | B | D | C | C |
| | | 15 | B | B | D | C | C |
| | | 16 | B | B | D | C | C |
| | | 17 | B | B | D | C | C |
| | | 18 | B | B | D | C | C |
| | | 19 | B | B | D | C | C |
| | | 20 | B | B | D | C | C |
| | | 21 | B | B | D | C | C |
| | | 22 | B | B | D | C | C |
| | | 23 | B | B | D | C | C |
| | | 24 | B | B | D | C | C |
| | | 25 | B | B | D | C | C |
| | | 26 | B | B | D | C | C |

| | | | Evaluation of transfer film | | | | | | | |
|---|---|---|---|---|---|---|---|---|---|---|
| | | | | | | | | | Change in | |
| Sixth table (3) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-3- | 1 | A | >3 | C | B | B | B | B | B |
| | | 2 | A | >3 | C | B | B | B | B | B |
| | | 3 | A | >3 | C | B | B | B | B | B |
| | | 4 | A | >3 | C | B | B | B | B | B |
| | | 5 | A | >3 | C | B | B | B | B | B |
| | | 6 | A | >3 | C | B | B | B | B | B |
| | | 7 | A | >3 | C | B | B | B | B | B |
| | | 8 | A | >3 | C | B | B | B | B | B |
| | | 9 | A | >3 | C | B | B | B | B | B |
| | | 10 | A | >3 | C | B | B | B | B | B |
| | | 11 | A | >3 | C | B | B | B | B | B |
| | | 12 | A | >3 | C | B | B | B | B | B |
| | | 13 | A | >3 | C | B | B | B | B | B |
| | | 14 | A | >3 | C | B | B | B | B | B |
| | | 15 | A | >3 | C | B | B | B | B | B |
| | | 16 | A | >3 | C | B | B | B | B | B |
| | | 17 | A | >3 | C | B | B | B | B | B |
| | | 18 | A | >3 | C | B | B | B | B | B |
| | | 19 | A | >3 | C | B | B | B | B | B |
| | | 20 | A | >3 | C | B | B | B | B | B |
| | | 21 | A | >3 | C | B | B | B | B | B |
| | | 22 | A | >3 | C | B | B | B | B | B |
| | | 23 | A | >3 | C | B | B | B | B | B |
| | | 24 | A | >3 | C | B | B | B | B | B |
| | | 25 | A | >3 | C | B | B | B | B | B |
| | | 26 | A | >3 | C | B | B | B | B | B |

TABLE 10

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (4) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-4- | 1 | 1 | 100 | B4 | 8.2 | 20 | A | <1 | A | A | A |
| | | 2 | 2 | 100 | B4 | 17.2 | 20 | A | <1 | A | A | A |
| | | 3 | 3 | 100 | B4 | 20.0 | 20 | A | <1 | A | A | A |
| | | 4 | 4 | 100 | B4 | 17.2 | 20 | A | <1 | A | A | A |
| | | 5 | 5 | 100 | B4 | 20.0 | 20 | A | <1 | A | A | A |
| | | 6 | 6 | 100 | B4 | 7.3 | 20 | A | <1 | A | A | A |
| | | 7 | 7 | 100 | B4 | 8.2 | 20 | A | <1 | A | A | A |
| | | 8 | 8 | 100 | B4 | 8.2 | 20 | A | <1 | A | A | A |
| | | 9 | 9 | 100 | B4 | 7.3 | 20 | A | <1 | A | A | A |
| | | 10 | 10 | 100 | B4 | 8.2 | 20 | A | <1 | A | A | A |
| | | 11 | 11 | 100 | B4 | 7.3 | 20 | A | <1 | A | A | A |
| | | 12 | 12 | 100 | B4 | 8.2 | 20 | A | <1 | A | A | A |
| | | 13 | 13 | 100 | B4 | 7.3 | 20 | A | <1 | A | A | A |
| | | 14 | 14 | 100 | B4 | 8.2 | 20 | A | <1 | A | A | A |
| | | 15 | 15 | 100 | B4 | 7.3 | 20 | A | <1 | A | A | A |
| | | 16 | 16 | 100 | B4 | 8.2 | 20 | A | <1 | A | A | A |
| | | 17 | 17 | 100 | B4 | 7.3 | 20 | A | <1 | A | A | A |
| | | 18 | 18 | 100 | B4 | 8.2 | 20 | A | <1 | A | A | A |
| | | 19 | 19 | 100 | B4 | 7.3 | 20 | A | <1 | A | A | A |
| | | 20 | 20 | 100 | B4 | 8.2 | 20 | A | <1 | A | A | A |
| | | 21 | 21 | 100 | B4 | 7.3 | 20 | A | <1 | A | A | A |
| | | 22 | 22 | 100 | B4 | 8.2 | 20 | A | <1 | A | A | A |
| | | 23 | 23 | 100 | B4 | 7.3 | 20 | A | <1 | A | A | A |
| | | 24 | 24 | 100 | B4 | 8.2 | 20 | A | <1 | A | A | A |
| | | 25 | 25 | 100 | B4 | 7.3 | 20 | A | <1 | A | A | A |
| | | 26 | 26 | 100 | B4 | 7.5 | 20 | A | <1 | A | A | A |

| | | | Evaluation of photosensitive material | | | | |
|---|---|---|---|---|---|---|---|
| | | | | Change in | Evaluation of transfer film | | |
| Sixth table (4) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-4- | 1 | A | A | A | A | A |
| | | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |
| | | 14 | A | A | A | A | A |
| | | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (4) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-4- | 1 | A | <1 | A | A | A | A | A | A |
| | | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |
| | | 14 | A | <1 | A | A | A | A | A | A |
| | | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 11

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (5) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-5- | 1 | 1 | 100 | B5 | 8.8 | 20 | A | <1 | A | A | A |
| | | 2 | 2 | 100 | B5 | 18.5 | 20 | A | <1 | A | A | A |
| | | 3 | 3 | 100 | B5 | 21.5 | 20 | A | <1 | A | A | A |
| | | 4 | 4 | 100 | B5 | 18.5 | 20 | A | <1 | A | A | A |
| | | 5 | 5 | 100 | B5 | 21.5 | 20 | A | <1 | A | A | A |
| | | 6 | 6 | 100 | B5 | 7.8 | 20 | A | <1 | A | A | A |
| | | 7 | 7 | 100 | B5 | 8.8 | 20 | A | <1 | A | A | A |
| | | 8 | 8 | 100 | B5 | 8.8 | 20 | A | <1 | A | A | A |
| | | 9 | 9 | 100 | B5 | 7.8 | 20 | A | <1 | A | A | A |
| | | 10 | 10 | 100 | B5 | 8.8 | 20 | A | <1 | A | A | A |
| | | 11 | 11 | 100 | B5 | 7.8 | 20 | A | <1 | A | A | A |
| | | 12 | 12 | 100 | B5 | 8.8 | 20 | A | <1 | A | A | A |
| | | 13 | 13 | 100 | B5 | 7.8 | 20 | A | <1 | A | A | A |
| | | 14 | 14 | 100 | B5 | 8.8 | 20 | A | <1 | A | A | A |
| | | 15 | 15 | 100 | B5 | 7.8 | 20 | A | <1 | A | A | A |
| | | 16 | 16 | 100 | B5 | 8.8 | 20 | A | <1 | A | A | A |
| | | 17 | 17 | 100 | B5 | 7.8 | 20 | A | <1 | A | A | A |
| | | 18 | 18 | 100 | B5 | 8.8 | 20 | A | <1 | A | A | A |
| | | 19 | 19 | 100 | B5 | 7.8 | 20 | A | <1 | A | A | A |
| | | 20 | 20 | 100 | B5 | 8.8 | 20 | A | <1 | A | A | A |
| | | 21 | 21 | 100 | B5 | 7.8 | 20 | A | <1 | A | A | A |
| | | 22 | 22 | 100 | B5 | 8.8 | 20 | A | <1 | A | A | A |
| | | 23 | 23 | 100 | B5 | 7.8 | 20 | A | <1 | A | A | A |
| | | 24 | 24 | 100 | B5 | 8.8 | 20 | A | <1 | A | A | A |
| | | 25 | 25 | 100 | B5 | 7.8 | 20 | A | <1 | A | A | A |
| | | 26 | 26 | 100 | B5 | 8.1 | 20 | A | <1 | A | A | A |

| | | | Evaluation of photosensitive material | | | | |
|---|---|---|---|---|---|---|---|
| | | | | Change in | Evaluation of transfer film | | |
| Sixth table (5) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-5- | 1 | A | A | A | A | A |
| | | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |
| | | 14 | A | A | A | A | A |
| | | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (5) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-5- | 1 | A | <1 | A | A | A | A | A | A |
| | | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |
| | | 14 | A | <1 | A | A | A | A | A | A |
| | | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 12

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (6) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-6- | 1 | 1 | 100 | B6 | 6.3 | 20 | A | <1 | A | A | A |
| | | 2 | 2 | 100 | B6 | 13.3 | 20 | A | <1 | A | A | A |
| | | 3 | 3 | 100 | B6 | 15.5 | 20 | A | <1 | A | A | A |
| | | 4 | 4 | 100 | B6 | 13.3 | 20 | A | <1 | A | A | A |
| | | 5 | 5 | 100 | B6 | 15.5 | 20 | A | <1 | A | A | A |
| | | 6 | 6 | 100 | B6 | 5.6 | 20 | A | <1 | A | A | A |
| | | 7 | 7 | 100 | B6 | 6.3 | 20 | A | <1 | A | A | A |
| | | 8 | 8 | 100 | B6 | 6.3 | 20 | A | <1 | A | A | A |
| | | 9 | 9 | 100 | B6 | 5.6 | 20 | A | <1 | A | A | A |
| | | 10 | 10 | 100 | B6 | 6.3 | 20 | A | <1 | A | A | A |
| | | 11 | 11 | 100 | B6 | 5.6 | 20 | A | <1 | A | A | A |
| | | 12 | 12 | 100 | B6 | 6.3 | 20 | A | <1 | A | A | A |
| | | 13 | 13 | 100 | B6 | 5.6 | 20 | A | <1 | A | A | A |
| | | 14 | 14 | 100 | B6 | 6.3 | 20 | A | <1 | A | A | A |
| | | 15 | 15 | 100 | B6 | 5.6 | 20 | A | <1 | A | A | A |
| | | 16 | 16 | 100 | B6 | 6.3 | 20 | A | <1 | A | A | A |
| | | 17 | 17 | 100 | B6 | 5.6 | 20 | A | <1 | A | A | A |
| | | 18 | 18 | 100 | B6 | 6.3 | 20 | A | <1 | A | A | A |
| | | 19 | 19 | 100 | B6 | 5.6 | 20 | A | <1 | A | A | A |
| | | 20 | 20 | 100 | B6 | 6.3 | 20 | A | <1 | A | A | A |
| | | 21 | 21 | 100 | B6 | 5.6 | 20 | A | <1 | A | A | A |
| | | 22 | 22 | 100 | B6 | 6.3 | 20 | A | <1 | A | A | A |
| | | 23 | 23 | 100 | B6 | 5.6 | 20 | A | <1 | A | A | A |
| | | 24 | 24 | 100 | B6 | 6.3 | 20 | A | <1 | A | A | A |
| | | 25 | 25 | 100 | B6 | 5.6 | 20 | A | <1 | A | A | A |
| | | 26 | 26 | 100 | B6 | 5.8 | 20 | A | <1 | A | A | A |

| | | | Evaluation of photosensitive material | | | | |
|---|---|---|---|---|---|---|---|
| | | | | Change in | Evaluation of transfer film | | |
| Sixth table (6) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-6- | 1 | A | A | A | A | A |
| | | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |
| | | 14 | A | A | A | A | A |
| | | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (6) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-6- | 1 | A | <1 | A | A | A | A | A | A |
| | | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |
| | | 14 | A | <1 | A | A | A | A | A | A |
| | | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 13

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (7) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-7- | 1 | 1 | 100 | B7 | 8.2 | 20 | A | <1 | A | A | A |
| | | 2 | 2 | 100 | B7 | 17.2 | 20 | A | <1 | A | A | A |
| | | 3 | 3 | 100 | B7 | 20.0 | 20 | A | <1 | A | A | A |
| | | 4 | 4 | 100 | B7 | 17.2 | 20 | A | <1 | A | A | A |
| | | 5 | 5 | 100 | B7 | 20.0 | 20 | A | <1 | A | A | A |
| | | 6 | 6 | 100 | B7 | 7.3 | 20 | A | <1 | A | A | A |
| | | 7 | 7 | 100 | B7 | 8.2 | 20 | A | <1 | A | A | A |
| | | 8 | 8 | 100 | B7 | 8.2 | 20 | A | <1 | A | A | A |
| | | 9 | 9 | 100 | B7 | 7.3 | 20 | A | <1 | A | A | A |
| | | 10 | 10 | 100 | B7 | 8.2 | 20 | A | <1 | A | A | A |
| | | 11 | 11 | 100 | B7 | 7.3 | 20 | A | <1 | A | A | A |
| | | 12 | 12 | 100 | B7 | 8.2 | 20 | A | <1 | A | A | A |
| | | 13 | 13 | 100 | B7 | 7.3 | 20 | A | <1 | A | A | A |
| | | 14 | 14 | 100 | B7 | 8.2 | 20 | A | <1 | A | A | A |
| | | 15 | 15 | 100 | B7 | 7.3 | 20 | A | <1 | A | A | A |
| | | 16 | 16 | 100 | B7 | 8.2 | 20 | A | <1 | A | A | A |
| | | 17 | 17 | 100 | B7 | 7.3 | 20 | A | <1 | A | A | A |
| | | 18 | 18 | 100 | B7 | 8.2 | 20 | A | <1 | A | A | A |
| | | 19 | 19 | 100 | B7 | 7.3 | 20 | A | <1 | A | A | A |
| | | 20 | 20 | 100 | B7 | 8.2 | 20 | A | <1 | A | A | A |
| | | 21 | 21 | 100 | B7 | 7.3 | 20 | A | <1 | A | A | A |
| | | 22 | 22 | 100 | B7 | 8.2 | 20 | A | <1 | A | A | A |
| | | 23 | 23 | 100 | B7 | 7.3 | 20 | A | <1 | A | A | A |
| | | 24 | 24 | 100 | B7 | 8.2 | 20 | A | <1 | A | A | A |
| | | 25 | 25 | 100 | B7 | 7.3 | 20 | A | <1 | A | A | A |
| | | 26 | 26 | 100 | B7 | 7.5 | 20 | A | <1 | A | A | A |

| | | | Evaluation of photosensitive material | | | | |
|---|---|---|---|---|---|---|---|
| | | | | Change in | Evaluation of transfer film | | |
| Sixth table (7) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-7- | 1 | A | A | A | A | A |
| | | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |
| | | 14 | A | A | A | A | A |
| | | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (7) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-7- | 1 | A | <1 | A | A | A | A | A | A |
| | | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |
| | | 14 | A | <1 | A | A | A | A | A | A |
| | | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 14

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (8) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-8- | 1 | 1 | 100 | B8 | 7.7 | 20 | A | <1 | A | A | A |
| | | 2 | 2 | 100 | B8 | 16.1 | 20 | A | <1 | A | A | A |
| | | 3 | 3 | 100 | B8 | 18.7 | 20 | A | <1 | A | A | A |
| | | 4 | 4 | 100 | B8 | 16.1 | 20 | A | <1 | A | A | A |
| | | 5 | 5 | 100 | B8 | 18.7 | 20 | A | <1 | A | A | A |
| | | 6 | 6 | 100 | B8 | 6.8 | 20 | A | <1 | A | A | A |
| | | 7 | 7 | 100 | B8 | 7.7 | 20 | A | <1 | A | A | A |
| | | 8 | 8 | 100 | B8 | 7.7 | 20 | A | <1 | A | A | A |
| | | 9 | 9 | 100 | B8 | 6.8 | 20 | A | <1 | A | A | A |
| | | 10 | 10 | 100 | B8 | 7.7 | 20 | A | <1 | A | A | A |
| | | 11 | 11 | 100 | B8 | 6.8 | 20 | A | <1 | A | A | A |
| | | 12 | 12 | 100 | B8 | 7.7 | 20 | A | <1 | A | A | A |
| | | 13 | 13 | 100 | B8 | 6.8 | 20 | A | <1 | A | A | A |
| | | 14 | 14 | 100 | B8 | 7.7 | 20 | A | <1 | A | A | A |
| | | 15 | 15 | 100 | B8 | 6.8 | 20 | A | <1 | A | A | A |
| | | 16 | 16 | 100 | B8 | 7.7 | 20 | A | <1 | A | A | A |
| | | 17 | 17 | 100 | B8 | 6.8 | 20 | A | <1 | A | A | A |
| | | 18 | 18 | 100 | B8 | 7.7 | 20 | A | <1 | A | A | A |
| | | 19 | 19 | 100 | B8 | 6.8 | 20 | A | <1 | A | A | A |
| | | 20 | 20 | 100 | B8 | 7.7 | 20 | A | <1 | A | A | A |
| | | 21 | 21 | 100 | B8 | 6.8 | 20 | A | <1 | A | A | A |
| | | 22 | 22 | 100 | B8 | 7.7 | 20 | A | <1 | A | A | A |
| | | 23 | 23 | 100 | B8 | 6.8 | 20 | A | <1 | A | A | A |
| | | 24 | 24 | 100 | B8 | 7.7 | 20 | A | <1 | A | A | A |
| | | 25 | 25 | 100 | B8 | 6.8 | 20 | A | <1 | A | A | A |
| | | 26 | 26 | 100 | B8 | 7.0 | 20 | A | <1 | A | A | A |

| | | | Evaluation of photosensitive material | | | | |
|---|---|---|---|---|---|---|---|
| | | | | Change in | Evaluation of transfer film | | |
| Sixth table (8) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-8- | 1 | A | A | A | A | A |
| | | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |
| | | 14 | A | A | A | A | A |
| | | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (8) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-8- | 1 | A | <1 | A | A | A | A | A | A |
| | | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |
| | | 14 | A | <1 | A | A | A | A | A | A |
| | | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 15

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (9) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-9- | 1 | 1 | 100 | B9 | 8.5 | 20 | C | >3 | B | B | A |
| | | 2 | 2 | 100 | B9 | 18.0 | 20 | C | >3 | B | B | A |
| | | 3 | 3 | 100 | B9 | 20.9 | 20 | C | >3 | B | B | A |
| | | 4 | 4 | 100 | B9 | 18.0 | 20 | C | >3 | B | B | A |
| | | 5 | 5 | 100 | B9 | 20.9 | 20 | C | >3 | B | B | A |
| | | 6 | 6 | 100 | B9 | 7.6 | 20 | C | >3 | B | B | A |
| | | 7 | 7 | 100 | B9 | 8.5 | 20 | C | >3 | B | B | A |
| | | 8 | 8 | 100 | B9 | 8.5 | 20 | C | >3 | B | B | A |
| | | 9 | 9 | 100 | B9 | 7.6 | 20 | C | >3 | B | B | A |
| | | 10 | 10 | 100 | B9 | 8.5 | 20 | C | >3 | B | B | A |
| | | 11 | 11 | 100 | B9 | 7.6 | 20 | C | >3 | B | B | A |
| | | 12 | 12 | 100 | B9 | 8.5 | 20 | C | >3 | B | B | A |
| | | 13 | 13 | 100 | B9 | 7.6 | 20 | C | >3 | B | B | A |
| | | 14 | 14 | 100 | B9 | 8.5 | 20 | C | >3 | B | B | A |
| | | 15 | 15 | 100 | B9 | 7.6 | 20 | C | >3 | B | B | A |
| | | 16 | 16 | 100 | B9 | 8.5 | 20 | C | >3 | B | B | A |
| | | 17 | 17 | 100 | B9 | 7.6 | 20 | C | >3 | B | B | A |
| | | 18 | 18 | 100 | B9 | 8.5 | 20 | C | >3 | B | B | A |
| | | 19 | 19 | 100 | B9 | 7.6 | 20 | C | >3 | B | B | A |
| | | 20 | 20 | 100 | B9 | 8.5 | 20 | C | >3 | B | B | A |
| | | 21 | 21 | 100 | B9 | 7.6 | 20 | C | >3 | B | B | A |
| | | 22 | 22 | 100 | B9 | 8.5 | 20 | C | >3 | B | B | A |
| | | 23 | 23 | 100 | B9 | 7.6 | 20 | C | >3 | B | B | A |
| | | 24 | 24 | 100 | B9 | 8.5 | 20 | C | >3 | B | B | A |
| | | 25 | 25 | 100 | B9 | 7.6 | 20 | C | >3 | B | B | A |
| | | 26 | 26 | 100 | B9 | 7.8 | 20 | C | >3 | B | B | A |

| | | | Evaluation of photosensitive material | | | | |
|---|---|---|---|---|---|---|---|
| | | | | Change in | Evaluation of transfer film | | |
| Sixth table (9) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-9- | 1 | B | B | C | C | C |
| | | 2 | B | B | C | C | C |
| | | 3 | B | B | C | C | C |
| | | 4 | B | B | C | C | C |
| | | 5 | B | B | C | C | C |
| | | 6 | B | B | C | C | C |
| | | 7 | B | B | C | C | C |
| | | 8 | B | B | C | C | C |
| | | 9 | B | B | C | C | C |
| | | 10 | B | B | C | C | C |
| | | 11 | B | B | C | C | C |
| | | 12 | B | B | C | C | C |
| | | 13 | B | B | C | C | C |
| | | 14 | B | B | C | C | C |
| | | 15 | B | B | C | C | C |
| | | 16 | B | B | C | C | C |
| | | 17 | B | B | C | C | C |
| | | 18 | B | B | C | C | C |
| | | 19 | B | B | C | C | C |
| | | 20 | B | B | C | C | C |
| | | 21 | B | B | C | C | C |
| | | 22 | B | B | C | C | C |
| | | 23 | B | B | C | C | C |
| | | 24 | B | B | C | C | C |
| | | 25 | B | B | C | C | C |
| | | 26 | B | B | C | C | C |

| | | | Evaluation of transfer film | | | | | | | |
|---|---|---|---|---|---|---|---|---|---|---|
| | | | | | | | | | Change in | |
| Sixth table (9) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-9- | 1 | A | >3 | B | B | A | B | B | B |
| | | 2 | A | >3 | B | B | A | B | B | B |
| | | 3 | A | >3 | B | B | A | B | B | B |
| | | 4 | A | >3 | B | B | A | B | B | B |
| | | 5 | A | >3 | B | B | A | B | B | B |
| | | 6 | A | >3 | B | B | A | B | B | B |
| | | 7 | A | >3 | B | B | A | B | B | B |
| | | 8 | A | >3 | B | B | A | B | B | B |
| | | 9 | A | >3 | B | B | A | B | B | B |
| | | 10 | A | >3 | B | B | A | B | B | B |
| | | 11 | A | >3 | B | B | A | B | B | B |
| | | 12 | A | >3 | B | B | A | B | B | B |
| | | 13 | A | >3 | B | B | A | B | B | B |
| | | 14 | A | >3 | B | B | A | B | B | B |
| | | 15 | A | >3 | B | B | A | B | B | B |
| | | 16 | A | >3 | B | B | A | B | B | B |
| | | 17 | A | >3 | B | B | A | B | B | B |
| | | 18 | A | >3 | B | B | A | B | B | B |
| | | 19 | A | >3 | B | B | A | B | B | B |
| | | 20 | A | >3 | B | B | A | B | B | B |
| | | 21 | A | >3 | B | B | A | B | B | B |
| | | 22 | A | >3 | B | B | A | B | B | B |
| | | 23 | A | >3 | B | B | A | B | B | B |
| | | 24 | A | >3 | B | B | A | B | B | B |
| | | 25 | A | >3 | B | B | A | B | B | B |
| | | 26 | A | >3 | B | B | A | B | B | B |

TABLE 16

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (10) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-10- | 1 | 1 | 100 | B10 | 11.3 | 20 | D | >3 | B | B | B |
| | | 2 | 2 | 100 | B10 | 23.8 | 20 | D | >3 | B | B | B |
| | | 3 | 3 | 100 | B10 | 27.6 | 20 | D | >3 | B | B | B |
| | | 4 | 4 | 100 | B10 | 23.8 | 20 | D | >3 | B | B | B |
| | | 5 | 5 | 100 | B10 | 27.6 | 20 | D | >3 | B | B | B |
| | | 6 | 6 | 100 | B10 | 10.0 | 20 | D | >3 | B | B | B |
| | | 7 | 7 | 100 | B10 | 11.3 | 20 | D | >3 | B | B | B |
| | | 8 | 8 | 100 | B10 | 11.3 | 20 | D | >3 | B | B | B |
| | | 9 | 9 | 100 | B10 | 10.0 | 20 | D | >3 | B | B | B |
| | | 10 | 10 | 100 | B10 | 11.3 | 20 | D | >3 | B | B | B |
| | | 11 | 11 | 100 | B10 | 10.0 | 20 | D | >3 | B | B | B |
| | | 12 | 12 | 100 | B10 | 11.3 | 20 | D | >3 | B | B | B |
| | | 13 | 13 | 100 | B10 | 10.0 | 20 | D | >3 | B | B | B |
| | | 14 | 14 | 100 | B10 | 11.3 | 20 | D | >3 | B | B | B |
| | | 15 | 15 | 100 | B10 | 10.0 | 20 | D | >3 | B | B | B |
| | | 16 | 16 | 100 | B10 | 11.3 | 20 | D | >3 | B | B | B |
| | | 17 | 17 | 100 | B10 | 10.0 | 20 | D | >3 | B | B | B |
| | | 18 | 18 | 100 | B10 | 11.3 | 20 | D | >3 | B | B | B |
| | | 19 | 19 | 100 | B10 | 10.0 | 20 | D | >3 | B | B | B |
| | | 20 | 20 | 100 | B10 | 11.3 | 20 | D | >3 | B | B | B |
| | | 21 | 21 | 100 | B10 | 10.0 | 20 | D | >3 | B | B | B |
| | | 22 | 22 | 100 | B10 | 11.3 | 20 | D | >3 | B | B | B |
| | | 23 | 23 | 100 | B10 | 10.0 | 20 | D | >3 | B | B | B |
| | | 24 | 24 | 100 | B10 | 11.3 | 20 | D | >3 | B | B | B |
| | | 25 | 25 | 100 | B10 | 10.0 | 20 | D | >3 | B | B | B |
| | | 26 | 26 | 100 | B10 | 10.4 | 20 | D | >3 | B | B | B |

| | | | Evaluation of photosensitive material | | | | |
|---|---|---|---|---|---|---|---|
| | | | | Change in | Evaluation of transfer film | | |
| Sixth table (10) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-10- | 1 | C | C | D | C | C |
| | | 2 | C | C | D | C | C |
| | | 3 | C | C | D | C | C |
| | | 4 | C | C | D | C | C |
| | | 5 | C | C | D | C | C |
| | | 6 | C | C | D | C | C |
| | | 7 | C | C | D | C | C |
| | | 8 | C | C | D | C | C |
| | | 9 | C | C | D | C | C |
| | | 10 | C | C | D | C | C |
| | | 11 | C | C | D | C | C |
| | | 12 | C | C | D | C | C |
| | | 13 | C | C | D | C | C |
| | | 14 | C | C | D | C | C |
| | | 15 | C | C | D | C | C |
| | | 16 | C | C | D | C | C |
| | | 17 | C | C | D | C | C |
| | | 18 | C | C | D | C | C |
| | | 19 | C | C | D | C | C |
| | | 20 | C | C | D | C | C |
| | | 21 | C | C | D | C | C |
| | | 22 | C | C | D | C | C |
| | | 23 | C | C | D | C | C |
| | | 24 | C | C | D | C | C |
| | | 25 | C | C | D | C | C |
| | | 26 | C | C | D | C | C |

| | | | Evaluation of transfer film | | | | | | | |
|---|---|---|---|---|---|---|---|---|---|---|
| | | | | | | | | | Change in | |
| Sixth table (10) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-10- | 1 | A | >3 | B | B | B | C | C | B |
| | | 2 | A | >3 | B | B | B | C | C | B |
| | | 3 | A | >3 | B | B | B | C | C | B |
| | | 4 | A | >3 | B | B | B | C | C | B |
| | | 5 | A | >3 | B | B | B | C | C | B |
| | | 6 | A | >3 | B | B | B | C | C | B |
| | | 7 | A | >3 | B | B | B | C | C | B |
| | | 8 | A | >3 | B | B | B | C | C | B |
| | | 9 | A | >3 | B | B | B | C | C | B |
| | | 10 | A | >3 | B | B | B | C | C | B |
| | | 11 | A | >3 | B | B | B | C | C | B |
| | | 12 | A | >3 | B | B | B | C | C | B |
| | | 13 | A | >3 | B | B | B | C | C | B |
| | | 14 | A | >3 | B | B | B | C | C | B |
| | | 15 | A | >3 | B | B | B | C | C | B |
| | | 16 | A | >3 | B | B | B | C | C | B |
| | | 17 | A | >3 | B | B | B | C | C | B |
| | | 18 | A | >3 | B | B | B | C | C | B |
| | | 19 | A | >3 | B | B | B | C | C | B |
| | | 20 | A | >3 | B | B | B | C | C | B |
| | | 21 | A | >3 | B | B | B | C | C | B |
| | | 22 | A | >3 | B | B | B | C | C | B |
| | | 23 | A | >3 | B | B | B | C | C | B |
| | | 24 | A | >3 | B | B | B | C | C | B |
| | | 25 | A | >3 | B | B | B | C | C | B |
| | | 26 | A | >3 | B | B | B | C | C | B |

TABLE 17

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (11) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-11- | 1 | 1 | 100 | B11 | 3.5 | 20 | D | <1 | C | C | C |
| | | 2 | 2 | 100 | B11 | 7.4 | 20 | D | <1 | C | C | C |
| | | 3 | 3 | 100 | B11 | 8.6 | 20 | D | <1 | C | C | C |
| | | 4 | 4 | 100 | B11 | 7.4 | 20 | D | <1 | C | C | C |
| | | 5 | 5 | 100 | B11 | 8.6 | 20 | D | <1 | C | C | C |
| | | 6 | 6 | 100 | B11 | 3.1 | 20 | D | <1 | C | C | C |
| | | 7 | 7 | 100 | B11 | 3.5 | 20 | D | <1 | C | C | C |
| | | 8 | 8 | 100 | B11 | 3.5 | 20 | D | <1 | C | C | C |
| | | 9 | 9 | 100 | B11 | 3.1 | 20 | D | <1 | C | C | C |
| | | 10 | 10 | 100 | B11 | 3.5 | 20 | D | <1 | C | C | C |
| | | 11 | 11 | 100 | B11 | 3.1 | 20 | D | <1 | C | C | C |
| | | 12 | 12 | 100 | B11 | 3.5 | 20 | D | <1 | C | C | C |
| | | 13 | 13 | 100 | B11 | 3.1 | 20 | D | <1 | C | C | C |
| | | 14 | 14 | 100 | B11 | 3.5 | 20 | D | <1 | C | C | C |
| | | 15 | 15 | 100 | B11 | 3.1 | 20 | D | <1 | C | C | C |
| | | 16 | 16 | 100 | B11 | 3.5 | 20 | D | <1 | C | C | C |
| | | 17 | 17 | 100 | B11 | 3.1 | 20 | D | <1 | C | C | C |
| | | 18 | 18 | 100 | B11 | 3.5 | 20 | D | <1 | C | C | C |
| | | 19 | 19 | 100 | B11 | 3.1 | 20 | D | <1 | C | C | C |
| | | 20 | 20 | 100 | B11 | 3.5 | 20 | D | <1 | C | C | C |
| | | 21 | 21 | 100 | B11 | 3.1 | 20 | D | <1 | C | C | C |
| | | 22 | 22 | 100 | B11 | 3.5 | 20 | D | <1 | C | C | C |
| | | 23 | 23 | 100 | B11 | 3.1 | 20 | D | <1 | C | C | C |
| | | 24 | 24 | 100 | B11 | 3.5 | 20 | D | <1 | C | C | C |
| | | 25 | 25 | 100 | B11 | 3.1 | 20 | D | <1 | C | C | C |
| | | 26 | 26 | 100 | B11 | 3.2 | 20 | D | <1 | C | C | C |

| | | | Evaluation of photosensitive material | | | | |
|---|---|---|---|---|---|---|---|
| | | | | Change in | Evaluation of transfer film | | |
| Sixth table (11) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-11- | 1 | C | C | D | B | B |
| | | 2 | C | C | D | B | B |
| | | 3 | C | C | D | B | B |
| | | 4 | C | C | D | B | B |
| | | 5 | C | C | D | B | B |
| | | 6 | C | C | D | B | B |
| | | 7 | C | C | D | B | B |
| | | 8 | C | C | D | B | B |
| | | 9 | C | C | D | B | B |
| | | 10 | C | C | D | B | B |
| | | 11 | C | C | D | B | B |
| | | 12 | C | C | D | B | B |
| | | 13 | C | C | D | B | B |
| | | 14 | C | C | D | B | B |
| | | 15 | C | C | D | B | B |
| | | 16 | C | C | D | B | B |
| | | 17 | C | C | D | B | B |
| | | 18 | C | C | D | B | B |
| | | 19 | C | C | D | B | B |
| | | 20 | C | C | D | B | B |
| | | 21 | C | C | D | B | B |
| | | 22 | C | C | D | B | B |
| | | 23 | C | C | D | B | B |
| | | 24 | C | C | D | B | B |
| | | 25 | C | C | D | B | B |
| | | 26 | C | C | D | B | B |

| | | | Evaluation of transfer film | | | | | | | |
|---|---|---|---|---|---|---|---|---|---|---|
| | | | | | | | | | Change in | |
| Sixth table (11) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-11- | 1 | A | <1 | C | C | C | C | C | B |
| | | 2 | A | <1 | C | C | C | C | C | B |
| | | 3 | A | <1 | C | C | C | C | C | B |
| | | 4 | A | <1 | C | C | C | C | C | B |
| | | 5 | A | <1 | C | C | C | C | C | B |
| | | 6 | A | <1 | C | C | C | C | C | B |
| | | 7 | A | <1 | C | C | C | C | C | B |
| | | 8 | A | <1 | C | C | C | C | C | B |
| | | 9 | A | <1 | C | C | C | C | C | B |
| | | 10 | A | <1 | C | C | C | C | C | B |
| | | 11 | A | <1 | C | C | C | C | C | B |
| | | 12 | A | <1 | C | C | C | C | C | B |
| | | 13 | A | <1 | C | C | C | C | C | B |
| | | 14 | A | <1 | C | C | C | C | C | B |
| | | 15 | A | <1 | C | C | C | C | C | B |
| | | 16 | A | <1 | C | C | C | C | C | B |
| | | 17 | A | <1 | C | C | C | C | C | B |
| | | 18 | A | <1 | C | C | C | C | C | B |
| | | 19 | A | <1 | C | C | C | C | C | B |
| | | 20 | A | <1 | C | C | C | C | C | B |
| | | 21 | A | <1 | C | C | C | C | C | B |
| | | 22 | A | <1 | C | C | C | C | C | B |
| | | 23 | A | <1 | C | C | C | C | C | B |
| | | 24 | A | <1 | C | C | C | C | C | B |
| | | 25 | A | <1 | C | C | C | C | C | B |
| | | 26 | A | <1 | C | C | C | C | C | B |

TABLE 18

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (12) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-12- | 1 | 1 | 100 | B12 | 0.3 | 1 | C | <1 | C | B | B |
| | | 2 | 2 | 100 | B12 | 0.7 | 1 | C | <1 | C | B | B |
| | | 3 | 3 | 100 | B12 | 0.8 | 1 | C | <1 | C | B | B |
| | | 4 | 4 | 100 | B12 | 0.7 | 1 | C | <1 | C | B | B |
| | | 5 | 5 | 100 | B12 | 0.8 | 1 | C | <1 | C | B | B |
| | | 6 | 6 | 100 | B12 | 0.3 | 1 | C | <1 | C | B | B |
| | | 7 | 7 | 100 | B12 | 0.3 | 1 | C | <1 | C | B | B |
| | | 8 | 8 | 100 | B12 | 0.3 | 1 | C | <1 | C | B | B |
| | | 9 | 9 | 100 | B12 | 0.3 | 1 | C | <1 | C | B | B |
| | | 10 | 10 | 100 | B12 | 0.3 | 1 | C | <1 | C | B | B |
| | | 11 | 11 | 100 | B12 | 0.3 | 1 | C | <1 | C | B | B |
| | | 12 | 12 | 100 | B12 | 0.3 | 1 | C | <1 | C | B | B |
| | | 13 | 13 | 100 | B12 | 0.3 | 1 | C | <1 | C | B | B |
| | | 14 | 14 | 100 | B12 | 0.3 | 1 | C | <1 | C | B | B |
| | | 15 | 15 | 100 | B12 | 0.3 | 1 | C | <1 | C | B | B |
| | | 16 | 16 | 100 | B12 | 0.3 | 1 | C | <1 | C | B | B |
| | | 17 | 17 | 100 | B12 | 0.3 | 1 | C | <1 | C | B | B |
| | | 18 | 18 | 100 | B12 | 0.3 | 1 | C | <1 | C | B | B |
| | | 19 | 19 | 100 | B12 | 0.3 | 1 | C | <1 | C | B | B |
| | | 20 | 20 | 100 | B12 | 0.3 | 1 | C | <1 | C | B | B |
| | | 21 | 21 | 100 | B12 | 0.3 | 1 | C | <1 | C | B | B |
| | | 22 | 22 | 100 | B12 | 0.3 | 1 | C | <1 | C | B | B |
| | | 23 | 23 | 100 | B12 | 0.3 | 1 | C | <1 | C | B | B |
| | | 24 | 24 | 100 | B12 | 0.3 | 1 | C | <1 | C | B | B |
| | | 25 | 25 | 100 | B12 | 0.3 | 1 | C | <1 | C | B | B |
| | | 26 | 26 | 100 | B12 | 0.3 | 1 | C | <1 | C | B | B |

| | | | Evaluation of photosensitive material | | | | |
|---|---|---|---|---|---|---|---|
| | | | | Change in | Evaluation of transfer film | | |
| Sixth table (12) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-12- | 1 | C | C | C | A | A |
| | | 2 | C | C | C | A | A |
| | | 3 | C | C | C | A | A |
| | | 4 | C | C | C | A | A |
| | | 5 | C | C | C | A | A |
| | | 6 | C | C | C | A | A |
| | | 7 | C | C | C | A | A |
| | | 8 | C | C | C | A | A |
| | | 9 | C | C | C | A | A |
| | | 10 | C | C | C | A | A |
| | | 11 | C | C | C | A | A |
| | | 12 | C | C | C | A | A |
| | | 13 | C | C | C | A | A |
| | | 14 | C | C | C | A | A |
| | | 15 | C | C | C | A | A |
| | | 16 | C | C | C | A | A |
| | | 17 | C | C | C | A | A |
| | | 18 | C | C | C | A | A |
| | | 19 | C | C | C | A | A |
| | | 20 | C | C | C | A | A |
| | | 21 | C | C | C | A | A |
| | | 22 | C | C | C | A | A |
| | | 23 | C | C | C | A | A |
| | | 24 | C | C | C | A | A |
| | | 25 | C | C | C | A | A |
| | | 26 | C | C | C | A | A |

| | | | Evaluation of transfer film | | | | | | | |
|---|---|---|---|---|---|---|---|---|---|---|
| | | | | | | | | | Change in | |
| Sixth table (12) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-12- | 1 | A | <1 | C | B | B | C | C | B |
| | | 2 | A | <1 | C | B | B | C | C | B |
| | | 3 | A | <1 | C | B | B | C | C | B |
| | | 4 | A | <1 | C | B | B | C | C | B |
| | | 5 | A | <1 | C | B | B | C | C | B |
| | | 6 | A | <1 | C | B | B | C | C | B |
| | | 7 | A | <1 | C | B | B | C | C | B |
| | | 8 | A | <1 | C | B | B | C | C | B |
| | | 9 | A | <1 | C | B | B | C | C | B |
| | | 10 | A | <1 | C | B | B | C | C | B |
| | | 11 | A | <1 | C | B | B | C | C | B |
| | | 12 | A | <1 | C | B | B | C | C | B |
| | | 13 | A | <1 | C | B | B | C | C | B |
| | | 14 | A | <1 | C | B | B | C | C | B |
| | | 15 | A | <1 | C | B | B | C | C | B |
| | | 16 | A | <1 | C | B | B | C | C | B |
| | | 17 | A | <1 | C | B | B | C | C | B |
| | | 18 | A | <1 | C | B | B | C | C | B |
| | | 19 | A | <1 | C | B | B | C | C | B |
| | | 20 | A | <1 | C | B | B | C | C | B |
| | | 21 | A | <1 | C | B | B | C | C | B |
| | | 22 | A | <1 | C | B | B | C | C | B |
| | | 23 | A | <1 | C | B | B | C | C | B |
| | | 24 | A | <1 | C | B | B | C | C | B |
| | | 25 | A | <1 | C | B | B | C | C | B |
| | | 26 | A | <1 | C | B | B | C | C | B |

TABLE 19

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (13) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-13- | 1 | 1 | 100 | B12 | 1.7 | 5 | B | <1 | B | B | A |
| | | 2 | 2 | 100 | B12 | 3.7 | 5 | B | <1 | B | B | A |
| | | 3 | 3 | 100 | B12 | 4.2 | 5 | B | <1 | B | B | A |
| | | 4 | 4 | 100 | B12 | 3.7 | 5 | B | <1 | B | B | A |
| | | 5 | 5 | 100 | B12 | 4.2 | 5 | B | <1 | B | B | A |
| | | 6 | 6 | 100 | B12 | 1.5 | 5 | B | <1 | B | B | A |
| | | 7 | 7 | 100 | B12 | 1.7 | 5 | B | <1 | B | B | A |
| | | 8 | 8 | 100 | B12 | 1.7 | 5 | B | <1 | B | B | A |
| | | 9 | 9 | 100 | B12 | 1.5 | 5 | B | <1 | B | B | A |
| | | 10 | 10 | 100 | B12 | 1.7 | 5 | B | <1 | B | B | A |
| | | 11 | 11 | 100 | B12 | 1.5 | 5 | B | <1 | B | B | A |
| | | 12 | 12 | 100 | B12 | 1.7 | 5 | B | <1 | B | B | A |
| | | 13 | 13 | 100 | B12 | 1.5 | 5 | B | <1 | B | B | A |
| | | 14 | 14 | 100 | B12 | 1.7 | 5 | B | <1 | B | B | A |
| | | 15 | 15 | 100 | B12 | 1.5 | 5 | B | <1 | B | B | A |
| | | 16 | 16 | 100 | B12 | 1.7 | 5 | B | <1 | B | B | A |
| | | 17 | 17 | 100 | B12 | 1.5 | 5 | B | <1 | B | B | A |
| | | 18 | 18 | 100 | B12 | 1.7 | 5 | B | <1 | B | B | A |
| | | 19 | 19 | 100 | B12 | 1.5 | 5 | B | <1 | B | B | A |
| | | 20 | 20 | 100 | B12 | 1.7 | 5 | B | <1 | B | B | A |
| | | 21 | 21 | 100 | B12 | 1.5 | 5 | B | <1 | B | B | A |
| | | 22 | 22 | 100 | B12 | 1.7 | 5 | B | <1 | B | B | A |
| | | 23 | 23 | 100 | B12 | 1.5 | 5 | B | <1 | B | B | A |
| | | 24 | 24 | 100 | B12 | 1.7 | 5 | B | <1 | B | B | A |
| | | 25 | 25 | 100 | B12 | 1.5 | 5 | B | <1 | B | B | A |
| | | 26 | 26 | 100 | B12 | 1.6 | 5 | B | <1 | B | B | A |

| | | | Evaluation of photosensitive material | | | | |
|---|---|---|---|---|---|---|---|
| | | | | Change in | Evaluation of transfer film | | |
| Sixth table (13) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-13- | 1 | B | B | B | A | A |
| | | 2 | B | B | B | A | A |
| | | 3 | B | B | B | A | A |
| | | 4 | B | B | B | A | A |
| | | 5 | B | B | B | A | A |
| | | 6 | B | B | B | A | A |
| | | 7 | B | B | B | A | A |
| | | 8 | B | B | B | A | A |
| | | 9 | B | B | B | A | A |
| | | 10 | B | B | B | A | A |
| | | 11 | B | B | B | A | A |
| | | 12 | B | B | B | A | A |
| | | 13 | B | B | B | A | A |
| | | 14 | B | B | B | A | A |
| | | 15 | B | B | B | A | A |
| | | 16 | B | B | B | A | A |
| | | 17 | B | B | B | A | A |
| | | 18 | B | B | B | A | A |
| | | 19 | B | B | B | A | A |
| | | 20 | B | B | B | A | A |
| | | 21 | B | B | B | A | A |
| | | 22 | B | B | B | A | A |
| | | 23 | B | B | B | A | A |
| | | 24 | B | B | B | A | A |
| | | 25 | B | B | B | A | A |
| | | 26 | B | B | B | A | A |

| | | | Evaluation of transfer film | | | | | | | |
|---|---|---|---|---|---|---|---|---|---|---|
| | | | | | | | | | Change in | |
| Sixth table (13) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-13- | 1 | A | <1 | B | B | A | B | B | A |
| | | 2 | A | <1 | B | B | A | B | B | A |
| | | 3 | A | <1 | B | B | A | B | B | A |
| | | 4 | A | <1 | B | B | A | B | B | A |
| | | 5 | A | <1 | B | B | A | B | B | A |
| | | 6 | A | <1 | B | B | A | B | B | A |
| | | 7 | A | <1 | B | B | A | B | B | A |
| | | 8 | A | <1 | B | B | A | B | B | A |
| | | 9 | A | <1 | B | B | A | B | B | A |
| | | 10 | A | <1 | B | B | A | B | B | A |
| | | 11 | A | <1 | B | B | A | B | B | A |
| | | 12 | A | <1 | B | B | A | B | B | A |
| | | 13 | A | <1 | B | B | A | B | B | A |
| | | 14 | A | <1 | B | B | A | B | B | A |
| | | 15 | A | <1 | B | B | A | B | B | A |
| | | 16 | A | <1 | B | B | A | B | B | A |
| | | 17 | A | <1 | B | B | A | B | B | A |
| | | 18 | A | <1 | B | B | A | B | B | A |
| | | 19 | A | <1 | B | B | A | B | B | A |
| | | 20 | A | <1 | B | B | A | B | B | A |
| | | 21 | A | <1 | B | B | A | B | B | A |
| | | 22 | A | <1 | B | B | A | B | B | A |
| | | 23 | A | <1 | B | B | A | B | B | A |
| | | 24 | A | <1 | B | B | A | B | B | A |
| | | 25 | A | <1 | B | B | A | B | B | A |
| | | 26 | A | <1 | B | B | A | B | B | A |

TABLE 20

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (20) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-14- | 1 | 1 | 100 | B12 | 3.5 | 10 | B | <1 | B | A | A |
| | | 2 | 2 | 100 | B12 | 7.3 | 10 | B | <1 | B | A | A |
| | | 3 | 3 | 100 | B12 | 8.5 | 10 | B | <1 | B | A | A |
| | | 4 | 4 | 100 | B12 | 7.3 | 10 | B | <1 | B | A | A |
| | | 5 | 5 | 100 | B12 | 8.5 | 10 | B | <1 | B | A | A |
| | | 6 | 6 | 100 | B12 | 3.1 | 10 | B | <1 | B | A | A |
| | | 7 | 7 | 100 | B12 | 3.5 | 10 | B | <1 | B | A | A |
| | | 8 | 8 | 100 | B12 | 3.5 | 10 | B | <1 | B | A | A |
| | | 9 | 9 | 100 | B12 | 3.1 | 10 | B | <1 | B | A | A |
| | | 10 | 10 | 100 | B12 | 3.5 | 10 | B | <1 | B | A | A |
| | | 11 | 11 | 100 | B12 | 3.1 | 10 | B | <1 | B | A | A |
| | | 12 | 12 | 100 | B12 | 3.5 | 10 | B | <1 | B | A | A |
| | | 13 | 13 | 100 | B12 | 3.1 | 10 | B | <1 | B | A | A |
| | | 14 | 14 | 100 | B12 | 3.5 | 10 | B | <1 | B | A | A |
| | | 15 | 15 | 100 | B12 | 3.1 | 10 | B | <1 | B | A | A |
| | | 16 | 16 | 100 | B12 | 3.5 | 10 | B | <1 | B | A | A |
| | | 17 | 17 | 100 | B12 | 3.1 | 10 | B | <1 | B | A | A |
| | | 18 | 18 | 100 | B12 | 3.5 | 10 | B | <1 | B | A | A |
| | | 19 | 19 | 100 | B12 | 3.1 | 10 | B | <1 | B | A | A |
| | | 20 | 20 | 100 | B12 | 3.5 | 10 | B | <1 | B | A | A |
| | | 21 | 21 | 100 | B12 | 3.1 | 10 | B | <1 | B | A | A |
| | | 22 | 22 | 100 | B12 | 3.5 | 10 | B | <1 | B | A | A |
| | | 23 | 23 | 100 | B12 | 3.1 | 10 | B | <1 | B | A | A |
| | | 24 | 24 | 100 | B12 | 3.5 | 10 | B | <1 | B | A | A |
| | | 25 | 25 | 100 | B12 | 3.1 | 10 | B | <1 | B | A | A |
| | | 26 | 26 | 100 | B12 | 3.2 | 10 | B | <1 | B | A | A |

| | | | Evaluation of photosensitive material | | | | |
|---|---|---|---|---|---|---|---|
| | | | | Change in | Evaluation of transfer film | | |
| Sixth table (20) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-14- | 1 | A | A | B | A | A |
| | | 2 | A | A | B | A | A |
| | | 3 | A | A | B | A | A |
| | | 4 | A | A | B | A | A |
| | | 5 | A | A | B | A | A |
| | | 6 | A | A | B | A | A |
| | | 7 | A | A | B | A | A |
| | | 8 | A | A | B | A | A |
| | | 9 | A | A | B | A | A |
| | | 10 | A | A | B | A | A |
| | | 11 | A | A | B | A | A |
| | | 12 | A | A | B | A | A |
| | | 13 | A | A | B | A | A |
| | | 14 | A | A | B | A | A |
| | | 15 | A | A | B | A | A |
| | | 16 | A | A | B | A | A |
| | | 17 | A | A | B | A | A |
| | | 18 | A | A | B | A | A |
| | | 19 | A | A | B | A | A |
| | | 20 | A | A | B | A | A |
| | | 21 | A | A | B | A | A |
| | | 22 | A | A | B | A | A |
| | | 23 | A | A | B | A | A |
| | | 24 | A | A | B | A | A |
| | | 25 | A | A | B | A | A |
| | | 26 | A | A | B | A | A |

| | | | Evaluation of transfer film | | | | | | | |
|---|---|---|---|---|---|---|---|---|---|---|
| | | | | | | | | | Change in | |
| Sixth table (20) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-14- | 1 | A | <1 | B | A | A | A | A | A |
| | | 2 | A | <1 | B | A | A | A | A | A |
| | | 3 | A | <1 | B | A | A | A | A | A |
| | | 4 | A | <1 | B | A | A | A | A | A |
| | | 5 | A | <1 | B | A | A | A | A | A |
| | | 6 | A | <1 | B | A | A | A | A | A |
| | | 7 | A | <1 | B | A | A | A | A | A |
| | | 8 | A | <1 | B | A | A | A | A | A |
| | | 9 | A | <1 | B | A | A | A | A | A |
| | | 10 | A | <1 | B | A | A | A | A | A |
| | | 11 | A | <1 | B | A | A | A | A | A |
| | | 12 | A | <1 | B | A | A | A | A | A |
| | | 13 | A | <1 | B | A | A | A | A | A |
| | | 14 | A | <1 | B | A | A | A | A | A |
| | | 15 | A | <1 | B | A | A | A | A | A |
| | | 16 | A | <1 | B | A | A | A | A | A |
| | | 17 | A | <1 | B | A | A | A | A | A |
| | | 18 | A | <1 | B | A | A | A | A | A |
| | | 19 | A | <1 | B | A | A | A | A | A |
| | | 20 | A | <1 | B | A | A | A | A | A |
| | | 21 | A | <1 | B | A | A | A | A | A |
| | | 22 | A | <1 | B | A | A | A | A | A |
| | | 23 | A | <1 | B | A | A | A | A | A |
| | | 24 | A | <1 | B | A | A | A | A | A |
| | | 25 | A | <1 | B | A | A | A | A | A |
| | | 26 | A | <1 | B | A | A | A | A | A |

TABLE 21

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (15) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-15- | 1 | 1 | 100 | B12 | 6.9 | 20 | A | <1 | A | A | A |
| | | 2 | 2 | 100 | B12 | 14.6 | 20 | A | <1 | A | A | A |
| | | 3 | 3 | 100 | B12 | 17.0 | 20 | A | <1 | A | A | A |
| | | 4 | 4 | 100 | B12 | 14.6 | 20 | A | <1 | A | A | A |
| | | 5 | 5 | 100 | B12 | 17.0 | 20 | A | <1 | A | A | A |
| | | 6 | 6 | 100 | B12 | 6.2 | 20 | A | <1 | A | A | A |
| | | 7 | 7 | 100 | B12 | 6.9 | 20 | A | <1 | A | A | A |
| | | 8 | 8 | 100 | B12 | 6.9 | 20 | A | <1 | A | A | A |
| | | 9 | 9 | 100 | B12 | 6.2 | 20 | A | <1 | A | A | A |
| | | 10 | 10 | 100 | B12 | 6.9 | 20 | A | <1 | A | A | A |
| | | 11 | 11 | 100 | B12 | 6.2 | 20 | A | <1 | A | A | A |
| | | 12 | 12 | 100 | B12 | 6.9 | 20 | A | <1 | A | A | A |
| | | 13 | 13 | 100 | B12 | 6.2 | 20 | A | <1 | A | A | A |
| | | 14 | 14 | 100 | B12 | 6.9 | 20 | A | <1 | A | A | A |
| | | 15 | 15 | 100 | B12 | 6.2 | 20 | A | <1 | A | A | A |
| | | 16 | 16 | 100 | B12 | 6.9 | 20 | A | <1 | A | A | A |
| | | 17 | 17 | 100 | B12 | 6.2 | 20 | A | <1 | A | A | A |
| | | 18 | 18 | 100 | B12 | 6.9 | 20 | A | <1 | A | A | A |
| | | 19 | 19 | 100 | B12 | 6.2 | 20 | A | <1 | A | A | A |
| | | 20 | 20 | 100 | B12 | 6.9 | 20 | A | <1 | A | A | A |
| | | 21 | 21 | 100 | B12 | 6.2 | 20 | A | <1 | A | A | A |
| | | 22 | 22 | 100 | B12 | 6.9 | 20 | A | <1 | A | A | A |
| | | 23 | 23 | 100 | B12 | 6.2 | 20 | A | <1 | A | A | A |
| | | 24 | 24 | 100 | B12 | 6.9 | 20 | A | <1 | A | A | A |
| | | 25 | 25 | 100 | B12 | 6.2 | 20 | A | <1 | A | A | A |
| | | 26 | 26 | 100 | B12 | 6.4 | 20 | A | <1 | A | A | A |

| | | | Evaluation of photosensitive material | | | | |
|---|---|---|---|---|---|---|---|
| | | | | Change in | Evaluation of transfer film | | |
| Sixth table (15) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-15- | 1 | A | A | A | A | A |
| | | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |
| | | 14 | A | A | A | A | A |
| | | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (15) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-15- | 1 | A | <1 | A | A | A | A | A | A |
| | | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |
| | | 14 | A | <1 | A | A | A | A | A | A |
| | | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 22

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (16) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-16- | 1 | 1 | 100 | B12 | 13.9 | 40 | A | <1 | A | A | A |
| | | 2 | 2 | 100 | B12 | 29.3 | 40 | A | <1 | A | A | A |
| | | 3 | 3 | 100 | B12 | 34.0 | 40 | A | <1 | A | A | A |
| | | 4 | 4 | 100 | B12 | 29.3 | 40 | A | <1 | A | A | A |
| | | 5 | 5 | 100 | B12 | 34.0 | 40 | A | <1 | A | A | A |
| | | 6 | 6 | 100 | B12 | 12.3 | 40 | A | <1 | A | A | A |
| | | 7 | 7 | 100 | B12 | 13.9 | 40 | A | <1 | A | A | A |
| | | 8 | 8 | 100 | B12 | 13.9 | 40 | A | <1 | A | A | A |
| | | 9 | 9 | 100 | B12 | 12.3 | 40 | A | <1 | A | A | A |
| | | 10 | 10 | 100 | B12 | 13.9 | 40 | A | <1 | A | A | A |
| | | 11 | 11 | 100 | B12 | 12.3 | 40 | A | <1 | A | A | A |
| | | 12 | 12 | 100 | B12 | 13.9 | 40 | A | <1 | A | A | A |
| | | 13 | 13 | 100 | B12 | 12.3 | 40 | A | <1 | A | A | A |
| | | 14 | 14 | 100 | B12 | 13.9 | 40 | A | <1 | A | A | A |
| | | 15 | 15 | 100 | B12 | 12.3 | 40 | A | <1 | A | A | A |
| | | 16 | 16 | 100 | B12 | 13.9 | 40 | A | <1 | A | A | A |
| | | 17 | 17 | 100 | B12 | 12.3 | 40 | A | <1 | A | A | A |
| | | 18 | 18 | 100 | B12 | 13.9 | 40 | A | <1 | A | A | A |
| | | 19 | 19 | 100 | B12 | 12.3 | 40 | A | <1 | A | A | A |
| | | 20 | 20 | 100 | B12 | 13.9 | 40 | A | <1 | A | A | A |
| | | 21 | 21 | 100 | B12 | 12.3 | 40 | A | <1 | A | A | A |
| | | 22 | 22 | 100 | B12 | 13.9 | 40 | A | <1 | A | A | A |
| | | 23 | 23 | 100 | B12 | 12.3 | 40 | A | <1 | A | A | A |
| | | 24 | 24 | 100 | B12 | 13.9 | 40 | A | <1 | A | A | A |
| | | 25 | 25 | 100 | B12 | 12.3 | 40 | A | <1 | A | A | A |
| | | 26 | 26 | 100 | B12 | 12.7 | 40 | A | <1 | A | A | A |

| | | | Evaluation of photosensitive material | | | | |
|---|---|---|---|---|---|---|---|
| | | | | Change in | Evaluation of transfer film | | |
| Sixth table (16) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-16- | 1 | A | A | A | A | A |
| | | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |
| | | 14 | A | A | A | A | A |
| | | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (16) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-16- | 1 | A | <1 | A | A | A | A | A | A |
| | | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |
| | | 14 | A | <1 | A | A | A | A | A | A |
| | | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 23

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (17) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-17- | 1 | 1 | 100 | B12 | 17.4 | 50 | A | <1 | A | A | A |
| | | 2 | 2 | 100 | B12 | 36.6 | 50 | A | <1 | A | A | A |
| | | 3 | 3 | 100 | B12 | 42.5 | 50 | A | <1 | A | A | A |
| | | 4 | 4 | 100 | B12 | 36.6 | 50 | A | <1 | A | A | A |
| | | 5 | 5 | 100 | B12 | 42.5 | 50 | A | <1 | A | A | A |
| | | 6 | 6 | 100 | B12 | 15.4 | 50 | A | <1 | A | A | A |
| | | 7 | 7 | 100 | B12 | 17.4 | 50 | A | <1 | A | A | A |
| | | 8 | 8 | 100 | B12 | 17.4 | 50 | A | <1 | A | A | A |
| | | 9 | 9 | 100 | B12 | 15.4 | 50 | A | <1 | A | A | A |
| | | 10 | 10 | 100 | B12 | 17.4 | 50 | A | <1 | A | A | A |
| | | 11 | 11 | 100 | B12 | 15.4 | 50 | A | <1 | A | A | A |
| | | 12 | 12 | 100 | B12 | 17.4 | 50 | A | <1 | A | A | A |
| | | 13 | 13 | 100 | B12 | 15.4 | 50 | A | <1 | A | A | A |
| | | 14 | 14 | 100 | B12 | 17.4 | 50 | A | <1 | A | A | A |
| | | 15 | 15 | 100 | B12 | 15.4 | 50 | A | <1 | A | A | A |
| | | 16 | 16 | 100 | B12 | 17.4 | 50 | A | <1 | A | A | A |
| | | 17 | 17 | 100 | B12 | 15.4 | 50 | A | <1 | A | A | A |
| | | 18 | 18 | 100 | B12 | 17.4 | 50 | A | <1 | A | A | A |
| | | 19 | 19 | 100 | B12 | 15.4 | 50 | A | <1 | A | A | A |
| | | 20 | 20 | 100 | B12 | 17.4 | 50 | A | <1 | A | A | A |
| | | 21 | 21 | 100 | B12 | 15.4 | 50 | A | <1 | A | A | A |
| | | 22 | 22 | 100 | B12 | 17.4 | 50 | A | <1 | A | A | A |
| | | 23 | 23 | 100 | B12 | 15.4 | 50 | A | <1 | A | A | A |
| | | 24 | 24 | 100 | B12 | 17.4 | 50 | A | <1 | A | A | A |
| | | 25 | 25 | 100 | B12 | 15.4 | 50 | A | <1 | A | A | A |
| | | 26 | 26 | 100 | B12 | 15.9 | 50 | A | <1 | A | A | A |

| | | | Evaluation of photosensitive material | | | | |
|---|---|---|---|---|---|---|---|
| | | | | Change in | Evaluation of transfer film | | |
| Sixth table (17) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-17- | 1 | A | A | A | A | A |
| | | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |
| | | 14 | A | A | A | A | A |
| | | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (17) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-17- | 1 | A | <1 | A | A | A | A | A | A |
| | | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |
| | | 14 | A | <1 | A | A | A | A | A | A |
| | | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 24

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (18) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-18- | 1 | 1 | 100 | B12 | 34.7 | 100 | A | <1 | A | A | A |
| | | 2 | 2 | 100 | B12 | 73.1 | 100 | A | <1 | A | A | A |
| | | 3 | 3 | 100 | B12 | 85.0 | 100 | A | <1 | A | A | A |
| | | 4 | 4 | 100 | B12 | 73.1 | 100 | A | <1 | A | A | A |
| | | 5 | 5 | 100 | B12 | 85.0 | 100 | A | <1 | A | A | A |
| | | 6 | 6 | 100 | B12 | 30.8 | 100 | A | <1 | A | A | A |
| | | 7 | 7 | 100 | B12 | 34.7 | 100 | A | <1 | A | A | A |
| | | 8 | 8 | 100 | B12 | 34.7 | 100 | A | <1 | A | A | A |
| | | 9 | 9 | 100 | B12 | 30.8 | 100 | A | <1 | A | A | A |
| | | 10 | 10 | 100 | B12 | 34.7 | 100 | A | <1 | A | A | A |
| | | 11 | 11 | 100 | B12 | 30.8 | 100 | A | <1 | A | A | A |
| | | 12 | 12 | 100 | B12 | 34.7 | 100 | A | <1 | A | A | A |
| | | 13 | 13 | 100 | B12 | 30.8 | 100 | A | <1 | A | A | A |
| | | 14 | 14 | 100 | B12 | 34.7 | 100 | A | <1 | A | A | A |
| | | 15 | 15 | 100 | B12 | 30.8 | 100 | A | <1 | A | A | A |
| | | 16 | 16 | 100 | B12 | 34.7 | 100 | A | <1 | A | A | A |
| | | 17 | 17 | 100 | B12 | 30.8 | 100 | A | <1 | A | A | A |
| | | 18 | 18 | 100 | B12 | 34.7 | 100 | A | <1 | A | A | A |
| | | 19 | 19 | 100 | B12 | 30.8 | 100 | A | <1 | A | A | A |
| | | 20 | 20 | 100 | B12 | 34.7 | 100 | A | <1 | A | A | A |
| | | 21 | 21 | 100 | B12 | 30.8 | 100 | A | <1 | A | A | A |
| | | 22 | 22 | 100 | B12 | 34.7 | 100 | A | <1 | A | A | A |
| | | 23 | 23 | 100 | B12 | 30.8 | 100 | A | <1 | A | A | A |
| | | 24 | 24 | 100 | B12 | 34.7 | 100 | A | <1 | A | A | A |
| | | 25 | 25 | 100 | B12 | 30.8 | 100 | A | <1 | A | A | A |
| | | 26 | 26 | 100 | B12 | 31.9 | 100 | A | <1 | A | A | A |

| | | | Evaluation of photosensitive material | | | | |
|---|---|---|---|---|---|---|---|
| | | | | Change in | Evaluation of transfer film | | |
| Sixth table (18) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-18- | 1 | B | B | A | A | A |
| | | 2 | B | B | A | A | A |
| | | 3 | B | B | A | A | A |
| | | 4 | B | B | A | A | A |
| | | 5 | B | B | A | A | A |
| | | 6 | B | B | A | A | A |
| | | 7 | B | B | A | A | A |
| | | 8 | B | B | A | A | A |
| | | 9 | B | B | A | A | A |
| | | 10 | B | B | A | A | A |
| | | 11 | B | B | A | A | A |
| | | 12 | B | B | A | A | A |
| | | 13 | B | B | A | A | A |
| | | 14 | B | B | A | A | A |
| | | 15 | B | B | A | A | A |
| | | 16 | B | B | A | A | A |
| | | 17 | B | B | A | A | A |
| | | 18 | B | B | A | A | A |
| | | 19 | B | B | A | A | A |
| | | 20 | B | B | A | A | A |
| | | 21 | B | B | A | A | A |
| | | 22 | B | B | A | A | A |
| | | 23 | B | B | A | A | A |
| | | 24 | B | B | A | A | A |
| | | 25 | B | B | A | A | A |
| | | 26 | B | B | A | A | A |

| | | | Evaluation of transfer film | | | | | | | |
|---|---|---|---|---|---|---|---|---|---|---|
| | | | | | | | | | Change in | |
| Sixth table (18) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-18- | 1 | A | <1 | A | A | A | B | B | A |
| | | 2 | A | <1 | A | A | A | B | B | A |
| | | 3 | A | <1 | A | A | A | B | B | A |
| | | 4 | A | <1 | A | A | A | B | B | A |
| | | 5 | A | <1 | A | A | A | B | B | A |
| | | 6 | A | <1 | A | A | A | B | B | A |
| | | 7 | A | <1 | A | A | A | B | B | A |
| | | 8 | A | <1 | A | A | A | B | B | A |
| | | 9 | A | <1 | A | A | A | B | B | A |
| | | 10 | A | <1 | A | A | A | B | B | A |
| | | 11 | A | <1 | A | A | A | B | B | A |
| | | 12 | A | <1 | A | A | A | B | B | A |
| | | 13 | A | <1 | A | A | A | B | B | A |
| | | 14 | A | <1 | A | A | A | B | B | A |
| | | 15 | A | <1 | A | A | A | B | B | A |
| | | 16 | A | <1 | A | A | A | B | B | A |
| | | 17 | A | <1 | A | A | A | B | B | A |
| | | 18 | A | <1 | A | A | A | B | B | A |
| | | 19 | A | <1 | A | A | A | B | B | A |
| | | 20 | A | <1 | A | A | A | B | B | A |
| | | 21 | A | <1 | A | A | A | B | B | A |
| | | 22 | A | <1 | A | A | A | B | B | A |
| | | 23 | A | <1 | A | A | A | B | B | A |
| | | 24 | A | <1 | A | A | A | B | B | A |
| | | 25 | A | <1 | A | A | A | B | B | A |
| | | 26 | A | <1 | A | A | A | B | B | A |

TABLE 25

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (19) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-19- | 1 | 1 | 100 | B13 | 4.2 | 20 | D | <1 | C | C | C |
| | | 2 | 2 | 100 | B13 | 8.8 | 20 | D | <1 | C | C | C |
| | | 3 | 3 | 100 | B13 | 10.2 | 20 | D | <1 | C | C | C |
| | | 4 | 4 | 100 | B13 | 8.8 | 20 | D | <1 | C | C | C |
| | | 5 | 5 | 100 | B13 | 10.2 | 20 | D | <1 | C | C | C |
| | | 6 | 6 | 100 | B13 | 3.7 | 20 | D | <1 | C | C | C |
| | | 7 | 7 | 100 | B13 | 4.2 | 20 | D | <1 | C | C | C |
| | | 8 | 8 | 100 | B13 | 4.2 | 20 | D | <1 | C | C | C |
| | | 9 | 9 | 100 | B13 | 3.7 | 20 | D | <1 | C | C | C |
| | | 10 | 10 | 100 | B13 | 4.2 | 20 | D | <1 | C | C | C |
| | | 11 | 11 | 100 | B13 | 3.7 | 20 | D | <1 | C | C | C |
| | | 12 | 12 | 100 | B13 | 4.2 | 20 | D | <1 | C | C | C |
| | | 13 | 13 | 100 | B13 | 3.7 | 20 | D | <1 | C | C | C |
| | | 14 | 14 | 100 | B13 | 4.2 | 20 | D | <1 | C | C | C |
| | | 15 | 15 | 100 | B13 | 3.7 | 20 | D | <1 | C | C | C |
| | | 16 | 16 | 100 | B13 | 4.2 | 20 | D | <1 | C | C | C |
| | | 17 | 17 | 100 | B13 | 3.7 | 20 | D | <1 | C | C | C |
| | | 18 | 18 | 100 | B13 | 4.2 | 20 | D | <1 | C | C | C |
| | | 19 | 19 | 100 | B13 | 3.7 | 20 | D | <1 | C | C | C |
| | | 20 | 20 | 100 | B13 | 4.2 | 20 | D | <1 | C | C | C |
| | | 21 | 21 | 100 | B13 | 3.7 | 20 | D | <1 | C | C | C |
| | | 22 | 22 | 100 | B13 | 4.2 | 20 | D | <1 | C | C | C |
| | | 23 | 23 | 100 | B13 | 3.7 | 20 | D | <1 | C | C | C |
| | | 24 | 24 | 100 | B13 | 4.2 | 20 | D | <1 | C | C | C |
| | | 25 | 25 | 100 | B13 | 3.7 | 20 | D | <1 | C | C | C |
| | | 26 | 26 | 100 | B13 | 3.8 | 20 | D | <1 | C | C | C |

| | | | Evaluation of photosensitive material | | | | |
|---|---|---|---|---|---|---|---|
| | | | | Change in | Evaluation of transfer film | | |
| Sixth table (19) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-19- | 1 | C | C | D | B | B |
| | | 2 | C | C | D | B | B |
| | | 3 | C | C | D | B | B |
| | | 4 | C | C | D | B | B |
| | | 5 | C | C | D | B | B |
| | | 6 | C | C | D | B | B |
| | | 7 | C | C | D | B | B |
| | | 8 | C | C | D | B | B |
| | | 9 | C | C | D | B | B |
| | | 10 | C | C | D | B | B |
| | | 11 | C | C | D | B | B |
| | | 12 | C | C | D | B | B |
| | | 13 | C | C | D | B | B |
| | | 14 | C | C | D | B | B |
| | | 15 | C | C | D | B | B |
| | | 16 | C | C | D | B | B |
| | | 17 | C | C | D | B | B |
| | | 18 | C | C | D | B | B |
| | | 19 | C | C | D | B | B |
| | | 20 | C | C | D | B | B |
| | | 21 | C | C | D | B | B |
| | | 22 | C | C | D | B | B |
| | | 23 | C | C | D | B | B |
| | | 24 | C | C | D | B | B |
| | | 25 | C | C | D | B | B |
| | | 26 | C | C | D | B | B |

| | | | Evaluation of transfer film | | | | | | | |
|---|---|---|---|---|---|---|---|---|---|---|
| | | | | | | | | | Change in | |
| Sixth table (19) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-19- | 1 | A | <1 | C | C | C | C | C | C |
| | | 2 | A | <1 | C | C | C | C | C | C |
| | | 3 | A | <1 | C | C | C | C | C | C |
| | | 4 | A | <1 | C | C | C | C | C | C |
| | | 5 | A | <1 | C | C | C | C | C | C |
| | | 6 | A | <1 | C | C | C | C | C | C |
| | | 7 | A | <1 | C | C | C | C | C | C |
| | | 8 | A | <1 | C | C | C | C | C | C |
| | | 9 | A | <1 | C | C | C | C | C | C |
| | | 10 | A | <1 | C | C | C | C | C | C |
| | | 11 | A | <1 | C | C | C | C | C | C |
| | | 12 | A | <1 | C | C | C | C | C | C |
| | | 13 | A | <1 | C | C | C | C | C | C |
| | | 14 | A | <1 | C | C | C | C | C | C |
| | | 15 | A | <1 | C | C | C | C | C | C |
| | | 16 | A | <1 | C | C | C | C | C | C |
| | | 17 | A | <1 | C | C | C | C | C | C |
| | | 18 | A | <1 | C | C | C | C | C | C |
| | | 19 | A | <1 | C | C | C | C | C | C |
| | | 20 | A | <1 | C | C | C | C | C | C |
| | | 21 | A | <1 | C | C | C | C | C | C |
| | | 22 | A | <1 | C | C | C | C | C | C |
| | | 23 | A | <1 | C | C | C | C | C | C |
| | | 24 | A | <1 | C | C | C | C | C | C |
| | | 25 | A | <1 | C | C | C | C | C | C |
| | | 26 | A | <1 | C | C | C | C | C | C |

TABLE 26

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (20) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-20- | 1 | 1 | 100 | B14 | 5.0 | 20 | D | <1 | C | C | C |
| | | 2 | 2 | 100 | B14 | 10.6 | 20 | D | <1 | C | C | C |
| | | 3 | 3 | 100 | B14 | 12.3 | 20 | D | <1 | C | C | C |
| | | 4 | 4 | 100 | B14 | 10.6 | 20 | D | <1 | C | C | C |
| | | 5 | 5 | 100 | B14 | 12.3 | 20 | D | <1 | C | C | C |
| | | 6 | 6 | 100 | B14 | 4.4 | 20 | D | <1 | C | C | C |
| | | 7 | 7 | 100 | B14 | 5.0 | 20 | D | <1 | C | C | C |
| | | 8 | 8 | 100 | B14 | 5.0 | 20 | D | <1 | C | C | C |
| | | 9 | 9 | 100 | B14 | 4.4 | 20 | D | <1 | C | C | C |
| | | 10 | 10 | 100 | B14 | 5.0 | 20 | D | <1 | C | C | C |
| | | 11 | 11 | 100 | B14 | 4.4 | 20 | D | <1 | C | C | C |
| | | 12 | 12 | 100 | B14 | 5.0 | 20 | D | <1 | C | C | C |
| | | 13 | 13 | 100 | B14 | 4.4 | 20 | D | <1 | C | C | C |
| | | 14 | 14 | 100 | B14 | 5.0 | 20 | D | <1 | C | C | C |
| | | 15 | 15 | 100 | B14 | 4.4 | 20 | D | <1 | C | C | C |
| | | 16 | 16 | 100 | B14 | 5.0 | 20 | D | <1 | C | C | C |
| | | 17 | 17 | 100 | B14 | 4.4 | 20 | D | <1 | C | C | C |
| | | 18 | 18 | 100 | B14 | 5.0 | 20 | D | <1 | C | C | C |
| | | 19 | 19 | 100 | B14 | 4.4 | 20 | D | <1 | C | C | C |
| | | 20 | 20 | 100 | B14 | 5.0 | 20 | D | <1 | C | C | C |
| | | 21 | 21 | 100 | B14 | 4.4 | 20 | D | <1 | C | C | C |
| | | 22 | 22 | 100 | B14 | 5.0 | 20 | D | <1 | C | C | C |
| | | 23 | 23 | 100 | B14 | 4.4 | 20 | D | <1 | C | C | C |
| | | 24 | 24 | 100 | B14 | 5.0 | 20 | D | <1 | C | C | C |
| | | 25 | 25 | 100 | B14 | 4.4 | 20 | D | <1 | C | C | C |
| | | 26 | 26 | 100 | B14 | 4.6 | 20 | D | <1 | C | C | C |

| | | | Evaluation of photosensitive material | | | | |
|---|---|---|---|---|---|---|---|
| | | | | Change in | Evaluation of transfer film | | |
| Sixth table (20) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-20- | 1 | C | C | D | B | B |
| | | 2 | C | C | D | B | B |
| | | 3 | C | C | D | B | B |
| | | 4 | C | C | D | B | B |
| | | 5 | C | C | D | B | B |
| | | 6 | C | C | D | B | B |
| | | 7 | C | C | D | B | B |
| | | 8 | C | C | D | B | B |
| | | 9 | C | C | D | B | B |
| | | 10 | C | C | D | B | B |
| | | 11 | C | C | D | B | B |
| | | 12 | C | C | D | B | B |
| | | 13 | C | C | D | B | B |
| | | 14 | C | C | D | B | B |
| | | 15 | C | C | D | B | B |
| | | 16 | C | C | D | B | B |
| | | 17 | C | C | D | B | B |
| | | 18 | C | C | D | B | B |
| | | 19 | C | C | D | B | B |
| | | 20 | C | C | D | B | B |
| | | 21 | C | C | D | B | B |
| | | 22 | C | C | D | B | B |
| | | 23 | C | C | D | B | B |
| | | 24 | C | C | D | B | B |
| | | 25 | C | C | D | B | B |
| | | 26 | C | C | D | B | B |

| | | | Evaluation of transfer film | | | | | | | |
|---|---|---|---|---|---|---|---|---|---|---|
| | | | | | | | | | Change in | |
| Sixth table (20) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-20- | 1 | A | <1 | C | C | C | C | C | C |
| | | 2 | A | <1 | C | C | C | C | C | C |
| | | 3 | A | <1 | C | C | C | C | C | C |
| | | 4 | A | <1 | C | C | C | C | C | C |
| | | 5 | A | <1 | C | C | C | C | C | C |
| | | 6 | A | <1 | C | C | C | C | C | C |
| | | 7 | A | <1 | C | C | C | C | C | C |
| | | 8 | A | <1 | C | C | C | C | C | C |
| | | 9 | A | <1 | C | C | C | C | C | C |
| | | 10 | A | <1 | C | C | C | C | C | C |
| | | 11 | A | <1 | C | C | C | C | C | C |
| | | 12 | A | <1 | C | C | C | C | C | C |
| | | 13 | A | <1 | C | C | C | C | C | C |
| | | 14 | A | <1 | C | C | C | C | C | C |
| | | 15 | A | <1 | C | C | C | C | C | C |
| | | 16 | A | <1 | C | C | C | C | C | C |
| | | 17 | A | <1 | C | C | C | C | C | C |
| | | 18 | A | <1 | C | C | C | C | C | C |
| | | 19 | A | <1 | C | C | C | C | C | C |
| | | 20 | A | <1 | C | C | C | C | C | C |
| | | 21 | A | <1 | C | C | C | C | C | C |
| | | 22 | A | <1 | C | C | C | C | C | C |
| | | 23 | A | <1 | C | C | C | C | C | C |
| | | 24 | A | <1 | C | C | C | C | C | C |
| | | 25 | A | <1 | C | C | C | C | C | C |
| | | 26 | A | <1 | C | C | C | C | C | C |

TABLE 27

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (21) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-21- | 51 | 2 | 50 | B6 | 14.4 | 20 | A | <1 | A | A | A |
| | (A blended) | | 3 | 50 | | | | | | | | |
| | | 52 | 10 | 50 | B6 | 6.0 | 20 | A | <1 | A | A | A |
| | | | 11 | 50 | | | | | | | | |
| | | 53 | 12 | 50 | B6 | 6.0 | 20 | A | <1 | A | A | A |
| | | | 13 | 50 | | | | | | | | |
| | | 54 | 16 | 50 | B6 | 6.0 | 20 | A | <1 | A | A | A |
| | | | 17 | 50 | | | | | | | | |
| | | 55 | 18 | 50 | B6 | 6.0 | 20 | A | <1 | A | A | A |
| | | | 19 | 50 | | | | | | | | |
| | | 56 | 20 | 50 | B6 | 6.0 | 20 | A | <1 | A | A | A |
| | | | 21 | 50 | | | | | | | | |
| | | 57 | 1 | 50 | B6 | 6.1 | 20 | A | <1 | A | A | A |
| | | | 26 | 50 | | | | | | | | |
| | | 58 | 8 | 33 | B6 | 6.3 | 20 | A | <1 | A | A | A |
| | | | 10 | 33 | | | | | | | | |
| | | | 12 | 34 | | | | | | | | |
| | | 59 | 15 | 33 | B6 | 5.6 | 20 | A | <1 | A | A | A |
| | | | 17 | 33 | | | | | | | | |
| | | | 19 | 34 | | | | | | | | |
| | | 60 | 20 | 33 | B6 | 6.1 | 20 | A | <1 | A | A | A |
| | | | 21 | 33 | | | | | | | | |
| | | | 22 | 34 | | | | | | | | |
| | | 61 | 1 | 33 | B6 | 6.1 | 20 | A | <1 | A | A | A |
| | | | 12 | 33 | | | | | | | | |
| | | | 23 | 34 | | | | | | | | |

| | | | Evaluation of photosensitive material | | | | |
|---|---|---|---|---|---|---|---|
| | | | | Change in | Evaluation of transfer film | | |
| Sixth table (21) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-21- | 51 | A | A | A | A | A |
| | (A blended) | 52 | A | A | A | A | A |
| | | 53 | A | A | A | A | A |
| | | 54 | A | A | A | A | A |
| | | 55 | A | A | A | A | A |
| | | 56 | A | A | A | A | A |
| | | 57 | A | A | A | A | A |
| | | 58 | A | A | A | A | A |
| | | 59 | A | A | A | A | A |
| | | 60 | A | A | A | A | A |
| | | 61 | A | A | A | A | A |

| | | | Evaluation of transfer film | | | | | | | |
|---|---|---|---|---|---|---|---|---|---|---|
| | | | | | | | | | Change in | |
| Sixth table (21) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-21- | 51 | A | <1 | A | A | A | A | A | A |
| | (A blended) | 52 | A | <1 | A | A | A | A | A | A |
| | | 53 | A | <1 | A | A | A | A | A | A |
| | | 54 | A | <1 | A | A | A | A | A | A |
| | | 55 | A | <1 | A | A | A | A | A | A |
| | | 56 | A | <1 | A | A | A | A | A | A |
| | | 57 | A | <1 | A | A | A | A | A | A |
| | | 58 | A | <1 | A | A | A | A | A | A |
| | | 59 | A | <1 | A | A | A | A | A | A |
| | | 60 | A | <1 | A | A | A | A | A | A |
| | | 61 | A | <1 | A | A | A | A | A | A |

TABLE 28

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (22) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-22- | 51 | 2 | 50 | B12 | 15.8 | 20 | A | <1 | A | A | A |
| | (A blended) | | 3 | 50 | | | | | | | | |
| | | 52 | 10 | 50 | B12 | 6.6 | 20 | A | <1 | A | A | A |
| | | | 11 | 50 | | | | | | | | |
| | | 53 | 12 | 50 | B12 | 6.6 | 20 | A | <1 | A | A | A |
| | | | 13 | 50 | | | | | | | | |
| | | 54 | 16 | 50 | B12 | 6.6 | 20 | A | <1 | A | A | A |
| | | | 17 | 50 | | | | | | | | |
| | | 55 | 18 | 50 | B12 | 6.6 | 20 | A | <1 | A | A | A |
| | | | 19 | 50 | | | | | | | | |
| | | 56 | 20 | 50 | B12 | 6.6 | 20 | A | <1 | A | A | A |
| | | | 21 | 50 | | | | | | | | |
| | | 57 | 1 | 50 | B12 | 6.7 | 20 | A | <1 | A | A | A |
| | | | 26 | 50 | | | | | | | | |
| | | 58 | 8 | 33 | B12 | 6.9 | 20 | A | <1 | A | A | A |
| | | | 10 | 33 | | | | | | | | |
| | | | 12 | 34 | | | | | | | | |
| | | 59 | 15 | 33 | B12 | 6.2 | 20 | A | <1 | A | A | A |
| | | | 17 | 33 | | | | | | | | |
| | | | 19 | 34 | | | | | | | | |
| | | 60 | 20 | 33 | B12 | 6.7 | 20 | A | <1 | A | A | A |
| | | | 21 | 33 | | | | | | | | |
| | | | 22 | 34 | | | | | | | | |
| | | 61 | 1 | 33 | B12 | 6.7 | 20 | A | <1 | A | A | A |
| | | | 12 | 33 | | | | | | | | |
| | | | 23 | 34 | | | | | | | | |

| | | | Evaluation of photosensitive material | | | | |
|---|---|---|---|---|---|---|---|
| | | | | Change in | Evaluation of transfer film | | |
| Sixth table (22) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-22- | 51 | A | A | A | A | A |
| | (A blended) | 52 | A | A | A | A | A |
| | | 53 | A | A | A | A | A |
| | | 54 | A | A | A | A | A |
| | | 55 | A | A | A | A | A |
| | | 56 | A | A | A | A | A |
| | | 57 | A | A | A | A | A |
| | | 58 | A | A | A | A | A |
| | | 59 | A | A | A | A | A |
| | | 60 | A | A | A | A | A |
| | | 61 | A | A | A | A | A |

| | | | Evaluation of transfer film | | | | | | | |
|---|---|---|---|---|---|---|---|---|---|---|
| | | | | | | | | | Change in | |
| Sixth table (22) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-22- | 51 | A | <1 | A | A | A | A | A | A |
| | (A blended) | 52 | A | <1 | A | A | A | A | A | A |
| | | 53 | A | <1 | A | A | A | A | A | A |
| | | 54 | A | <1 | A | A | A | A | A | A |
| | | 55 | A | <1 | A | A | A | A | A | A |
| | | 56 | A | <1 | A | A | A | A | A | A |
| | | 57 | A | <1 | A | A | A | A | A | A |
| | | 58 | A | <1 | A | A | A | A | A | A |
| | | 59 | A | <1 | A | A | A | A | A | A |
| | | 60 | A | <1 | A | A | A | A | A | A |
| | | 61 | A | <1 | A | A | A | A | A | A |

TABLE 29

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (23) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-23- | 51 | 2 | 50 | B12 | 7.9 | 10 | B | <1 | B | A | A |
| | (A blended) | | 3 | 50 | | | | | | | | |
| | | 52 | 10 | 50 | B12 | 3.3 | 10 | B | <1 | B | A | A |
| | | | 11 | 50 | | | | | | | | |
| | | 53 | 12 | 50 | B12 | 3.3 | 10 | B | <1 | B | A | A |
| | | | 13 | 50 | | | | | | | | |
| | | 54 | 16 | 50 | B12 | 3.3 | 10 | B | <1 | B | A | A |
| | | | 17 | 50 | | | | | | | | |
| | | 55 | 18 | 50 | B12 | 3.3 | 10 | B | <1 | B | A | A |
| | | | 19 | 50 | | | | | | | | |
| | | 56 | 20 | 50 | B12 | 3.3 | 10 | B | <1 | B | A | A |
| | | | 21 | 50 | | | | | | | | |
| | | 57 | 1 | 50 | B12 | 3.3 | 10 | B | <1 | B | A | A |
| | | | 26 | 50 | | | | | | | | |
| | | 58 | 8 | 33 | B12 | 3.5 | 10 | B | <1 | B | A | A |
| | | | 10 | 33 | | | | | | | | |
| | | | 12 | 34 | | | | | | | | |
| | | 59 | 15 | 33 | B12 | 3.1 | 10 | B | <1 | B | A | A |
| | | | 17 | 33 | | | | | | | | |
| | | | 19 | 34 | | | | | | | | |
| | | 60 | 20 | 33 | B12 | 3.3 | 10 | B | <1 | B | A | A |
| | | | 21 | 33 | | | | | | | | |
| | | | 22 | 34 | | | | | | | | |
| | | 61 | 1 | 33 | B12 | 3.3 | 10 | B | <1 | B | A | A |
| | | | 12 | 33 | | | | | | | | |
| | | | 23 | 34 | | | | | | | | |

| | | | Evaluation of photosensitive material | | | | |
|---|---|---|---|---|---|---|---|
| | | | | Change in | Evaluation of transfer film | | |
| Sixth table (23) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-23- | 51 | A | A | B | A | A |
| | (A blended) | 52 | A | A | B | A | A |
| | | 53 | A | A | B | A | A |
| | | 54 | A | A | B | A | A |
| | | 55 | A | A | B | A | A |
| | | 56 | A | A | B | A | A |
| | | 57 | A | A | B | A | A |
| | | 58 | A | A | B | A | A |
| | | 59 | A | A | B | A | A |
| | | 60 | A | A | B | A | A |
| | | 61 | A | A | B | A | A |

| | | | Evaluation of transfer film | | | | | | | |
|---|---|---|---|---|---|---|---|---|---|---|
| | | | | | | | | | Change in | |
| Sixth table (23) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-23- | 51 | A | <1 | B | A | A | A | A | A |
| | (A blended) | 52 | A | <1 | B | A | A | A | A | A |
| | | 53 | A | <1 | B | A | A | A | A | A |
| | | 54 | A | <1 | B | A | A | A | A | A |
| | | 55 | A | <1 | B | A | A | A | A | A |
| | | 56 | A | <1 | B | A | A | A | A | A |
| | | 57 | A | <1 | B | A | A | A | A | A |
| | | 58 | A | <1 | B | A | A | A | A | A |
| | | 59 | A | <1 | B | A | A | A | A | A |
| | | 60 | A | <1 | B | A | A | A | A | A |
| | | 61 | A | <1 | B | A | A | A | A | A |

TABLE 30

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (24) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-24- | 1 | 1 | 100 | B6 | 3.2 | 10 | A | <1 | A | A | A |
| | (B blended) | | | | B12 | 3.5 | 10 | | | | | |
| | | 2 | 2 | 100 | B6 | 6.7 | 10 | A | <1 | A | A | A |
| | | | | | B12 | 7.3 | 10 | | | | | |
| | | 3 | 3 | 100 | B6 | 7.7 | 10 | A | <1 | A | A | A |
| | | | | | B12 | 8.5 | 10 | | | | | |
| | | 4 | 4 | 100 | B6 | 6.7 | 10 | A | <1 | A | A | A |
| | | | | | B12 | 7.3 | 10 | | | | | |
| | | 5 | 5 | 100 | B6 | 7.7 | 10 | A | <1 | A | A | A |
| | | | | | B12 | 8.5 | 10 | | | | | |
| | | 6 | 6 | 100 | B6 | 2.8 | 10 | A | <1 | A | A | A |
| | | | | | B12 | 3.1 | 10 | | | | | |
| | | 7 | 7 | 100 | B6 | 3.2 | 10 | A | <1 | A | A | A |
| | | | | | B12 | 3.5 | 10 | | | | | |
| | | 8 | 8 | 100 | B6 | 3.2 | 10 | A | <1 | A | A | A |
| | | | | | B12 | 3.5 | 10 | | | | | |
| | | 9 | 9 | 100 | B6 | 2.8 | 10 | A | <1 | A | A | A |
| | | | | | B12 | 3.1 | 10 | | | | | |
| | | 10 | 10 | 100 | B6 | 3.2 | 10 | A | <1 | A | A | A |
| | | | | | B12 | 3.5 | 10 | | | | | |
| | | 11 | 11 | 100 | B6 | 2.8 | 10 | A | <1 | A | A | A |
| | | | | | B12 | 3.1 | 10 | | | | | |
| | | 12 | 12 | 100 | B6 | 3.2 | 10 | A | <1 | A | A | A |
| | | | | | B12 | 3.5 | 10 | | | | | |
| | | 13 | 13 | 100 | B6 | 2.8 | 10 | A | <1 | A | A | A |
| | | | | | B12 | 3.1 | 10 | | | | | |

| | | | Evaluation of photosensitive material | | | | |
|---|---|---|---|---|---|---|---|
| | | | | Change in | Evaluation of transfer film | | |
| Sixth table (24) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-24- | 1 | A | A | A | A | A |
| | (B blended) | 2 | A | A | A | A | A |
| | | 3 | A | A | A | A | A |
| | | 4 | A | A | A | A | A |
| | | 5 | A | A | A | A | A |
| | | 6 | A | A | A | A | A |
| | | 7 | A | A | A | A | A |
| | | 8 | A | A | A | A | A |
| | | 9 | A | A | A | A | A |
| | | 10 | A | A | A | A | A |
| | | 11 | A | A | A | A | A |
| | | 12 | A | A | A | A | A |
| | | 13 | A | A | A | A | A |

| | | | Evaluation of transfer film | | | | | | | |
|---|---|---|---|---|---|---|---|---|---|---|
| | | | | | | | | | Change in | |
| Sixth table (24) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-24- | 1 | A | <1 | A | A | A | A | A | A |
| | (B blended) | 2 | A | <1 | A | A | A | A | A | A |
| | | 3 | A | <1 | A | A | A | A | A | A |
| | | 4 | A | <1 | A | A | A | A | A | A |
| | | 5 | A | <1 | A | A | A | A | A | A |
| | | 6 | A | <1 | A | A | A | A | A | A |
| | | 7 | A | <1 | A | A | A | A | A | A |
| | | 8 | A | <1 | A | A | A | A | A | A |
| | | 9 | A | <1 | A | A | A | A | A | A |
| | | 10 | A | <1 | A | A | A | A | A | A |
| | | 11 | A | <1 | A | A | A | A | A | A |
| | | 12 | A | <1 | A | A | A | A | A | A |
| | | 13 | A | <1 | A | A | A | A | A | A |

TABLE 31

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (25) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-24- | 14 | 14 | 100 | B6 | 3.2 | 10 | A | <1 | A | A | A |
| | (B blended) | | | | B12 | 3.5 | 10 | | | | | |
| | | 15 | 15 | 100 | B6 | 2.8 | 10 | A | <1 | A | A | A |
| | | | | | B12 | 3.1 | 10 | | | | | |
| | | 16 | 16 | 100 | B6 | 3.2 | 10 | A | <1 | A | A | A |
| | | | | | B12 | 3.5 | 10 | | | | | |
| | | 17 | 17 | 100 | B6 | 2.8 | 10 | A | <1 | A | A | A |
| | | | | | B12 | 3.1 | 10 | | | | | |
| | | 18 | 18 | 100 | B6 | 3.2 | 10 | A | <1 | A | A | A |
| | | | | | B12 | 3.5 | 10 | | | | | |
| | | 19 | 19 | 100 | B6 | 2.8 | 10 | A | <1 | A | A | A |
| | | | | | B12 | 3.1 | 10 | | | | | |
| | | 20 | 20 | 100 | B6 | 3.2 | 10 | A | <1 | A | A | A |
| | | | | | B12 | 3.5 | 10 | | | | | |
| | | 21 | 21 | 100 | B6 | 2.8 | 10 | A | <1 | A | A | A |
| | | | | | B12 | 3.1 | 10 | | | | | |
| | | 22 | 22 | 100 | B6 | 3.2 | 10 | A | <1 | A | A | A |
| | | | | | B12 | 3.5 | 10 | | | | | |
| | | 23 | 23 | 100 | B6 | 2.8 | 10 | A | <1 | A | A | A |
| | | | | | B12 | 3.1 | 10 | | | | | |
| | | 24 | 24 | 100 | B6 | 3.2 | 10 | A | <1 | A | A | A |
| | | | | | B12 | 3.5 | 10 | | | | | |
| | | 25 | 25 | 100 | B6 | 2.8 | 10 | A | <1 | A | A | A |
| | | | | | B12 | 3.1 | 10 | | | | | |
| | | 26 | 26 | 100 | B6 | 2.9 | 10 | A | <1 | A | A | A |
| | | | | | B12 | 3.2 | 10 | | | | | |

| | | | Evaluation of photosensitive material | | | | |
|---|---|---|---|---|---|---|---|
| | | | | Change in | Evaluation of transfer film | | |
| Sixth table (25) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-24- | 14 | A | A | A | A | A |
| | (B blended) | 15 | A | A | A | A | A |
| | | 16 | A | A | A | A | A |
| | | 17 | A | A | A | A | A |
| | | 18 | A | A | A | A | A |
| | | 19 | A | A | A | A | A |
| | | 20 | A | A | A | A | A |
| | | 21 | A | A | A | A | A |
| | | 22 | A | A | A | A | A |
| | | 23 | A | A | A | A | A |
| | | 24 | A | A | A | A | A |
| | | 25 | A | A | A | A | A |
| | | 26 | A | A | A | A | A |

| | | | Evaluation of transfer film | | | | | | | |
|---|---|---|---|---|---|---|---|---|---|---|
| | | | | | | | | | Change in | |
| Sixth table (25) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-24- | 14 | A | <1 | A | A | A | A | A | A |
| | (B blended) | 15 | A | <1 | A | A | A | A | A | A |
| | | 16 | A | <1 | A | A | A | A | A | A |
| | | 17 | A | <1 | A | A | A | A | A | A |
| | | 18 | A | <1 | A | A | A | A | A | A |
| | | 19 | A | <1 | A | A | A | A | A | A |
| | | 20 | A | <1 | A | A | A | A | A | A |
| | | 21 | A | <1 | A | A | A | A | A | A |
| | | 22 | A | <1 | A | A | A | A | A | A |
| | | 23 | A | <1 | A | A | A | A | A | A |
| | | 24 | A | <1 | A | A | A | A | A | A |
| | | 25 | A | <1 | A | A | A | A | A | A |
| | | 26 | A | <1 | A | A | A | A | A | A |

TABLE 32

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (26) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-25- | 1 | 1 | 100 | B6 | 1.6 | 5 | B | <1 | B | A | A |
| | (B blended) | | | | B12 | 1.7 | 5 | | | | | |
| | | 2 | 2 | 100 | B6 | 3.3 | 5 | B | <1 | B | A | A |
| | | | | | B12 | 3.7 | 5 | | | | | |
| | | 3 | 3 | 100 | B6 | 3.9 | 5 | B | <1 | B | A | A |
| | | | | | B12 | 4.2 | 5 | | | | | |
| | | 4 | 4 | 100 | B6 | 3.3 | 5 | B | <1 | B | A | A |
| | | | | | B12 | 3.7 | 5 | | | | | |
| | | 5 | 5 | 100 | B6 | 3.9 | 5 | B | <1 | B | A | A |
| | | | | | B12 | 4.2 | 5 | | | | | |
| | | 6 | 6 | 100 | B6 | 1.4 | 5 | B | <1 | B | A | A |
| | | | | | B12 | 1.5 | 5 | | | | | |
| | | 7 | 7 | 100 | B6 | 1.6 | 5 | B | <1 | B | A | A |
| | | | | | B12 | 1.7 | 5 | | | | | |
| | | 8 | 8 | 100 | B6 | 1.6 | 5 | B | <1 | B | A | A |
| | | | | | B12 | 1.7 | 5 | | | | | |
| | | 9 | 9 | 100 | B6 | 1.4 | 5 | B | <1 | B | A | A |
| | | | | | B12 | 1.5 | 5 | | | | | |
| | | 10 | 10 | 100 | B6 | 1.6 | 5 | B | <1 | B | A | A |
| | | | | | B12 | 1.7 | 5 | | | | | |
| | | 11 | 11 | 100 | B6 | 1.4 | 5 | B | <1 | B | A | A |
| | | | | | B12 | 1.5 | 5 | | | | | |
| | | 12 | 12 | 100 | B6 | 1.6 | 5 | B | <1 | B | A | A |
| | | | | | B12 | 1.7 | 5 | | | | | |
| | | 13 | 13 | 100 | B6 | 1.4 | 5 | B | <1 | B | A | A |
| | | | | | B12 | 1.5 | 5 | | | | | |

| | | | Evaluation of photosensitive material | | | | |
|---|---|---|---|---|---|---|---|
| | | | | Change in | Evaluation of transfer film | | |
| Sixth table (26) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-25- | 1 | A | A | B | A | A |
| | (B blended) | 2 | A | A | B | A | A |
| | | 3 | A | A | B | A | A |
| | | 4 | A | A | B | A | A |
| | | 5 | A | A | B | A | A |
| | | 6 | A | A | B | A | A |
| | | 7 | A | A | B | A | A |
| | | 8 | A | A | B | A | A |
| | | 9 | A | A | B | A | A |
| | | 10 | A | A | B | A | A |
| | | 11 | A | A | B | A | A |
| | | 12 | A | A | B | A | A |
| | | 13 | A | A | B | A | A |

| | | | Evaluation of transfer film | | | | | | | |
|---|---|---|---|---|---|---|---|---|---|---|
| | | | | | | | | | Change in | |
| Sixth table (26) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-25- | 1 | A | <1 | B | A | A | A | A | A |
| | (B blended) | 2 | A | <1 | B | A | A | A | A | A |
| | | 3 | A | <1 | B | A | A | A | A | A |
| | | 4 | A | <1 | B | A | A | A | A | A |
| | | 5 | A | <1 | B | A | A | A | A | A |
| | | 6 | A | <1 | B | A | A | A | A | A |
| | | 7 | A | <1 | B | A | A | A | A | A |
| | | 8 | A | <1 | B | A | A | A | A | A |
| | | 9 | A | <1 | B | A | A | A | A | A |
| | | 10 | A | <1 | B | A | A | A | A | A |
| | | 11 | A | <1 | B | A | A | A | A | A |
| | | 12 | A | <1 | B | A | A | A | A | A |
| | | 13 | A | <1 | B | A | A | A | A | A |

TABLE 33

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (27) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-25- | 14 | 14 | 100 | B6 | 1.6 | 5 | B | <1 | B | A | A |
| | (B blended) | | | | B12 | 1.7 | 5 | | | | | |
| | | 15 | 15 | 100 | B6 | 1.4 | 5 | B | <1 | B | A | A |
| | | | | | B12 | 1.5 | 5 | | | | | |
| | | 16 | 16 | 100 | B6 | 1.6 | 5 | B | <1 | B | A | A |
| | | | | | B12 | 1.7 | 5 | | | | | |
| | | 17 | 17 | 100 | B6 | 1.4 | 5 | B | <1 | B | A | A |
| | | | | | B12 | 1.5 | 5 | | | | | |
| | | 18 | 18 | 100 | B6 | 1.6 | 5 | B | <1 | B | A | A |
| | | | | | B12 | 1.7 | 5 | | | | | |
| | | 19 | 19 | 100 | B6 | 1.4 | 5 | B | <1 | B | A | A |
| | | | | | B12 | 1.5 | 5 | | | | | |
| | | 20 | 20 | 100 | B6 | 1.6 | 5 | B | <1 | B | A | A |
| | | | | | B12 | 1.7 | 5 | | | | | |
| | | 21 | 21 | 100 | B6 | 1.4 | 5 | B | <1 | B | A | A |
| | | | | | B12 | 1.5 | 5 | | | | | |
| | | 22 | 22 | 100 | B6 | 1.6 | 5 | B | <1 | B | A | A |
| | | | | | B12 | 1.7 | 5 | | | | | |
| | | 23 | 23 | 100 | B6 | 1.4 | 5 | B | <1 | B | A | A |
| | | | | | B12 | 1.5 | 5 | | | | | |
| | | 24 | 24 | 100 | B6 | 1.6 | 5 | B | <1 | B | A | A |
| | | | | | B12 | 1.7 | 5 | | | | | |
| | | 25 | 25 | 100 | B6 | 1.4 | 5 | B | <1 | B | A | A |
| | | | | | B12 | 1.5 | 5 | | | | | |
| | | 26 | 26 | 100 | B6 | 1.5 | 5 | B | <1 | B | A | A |
| | | | | | B12 | 1.6 | 5 | | | | | |

| | | | Evaluation of photosensitive material | | | | |
|---|---|---|---|---|---|---|---|
| | | | | Change in | Evaluation of transfer film | | |
| Sixth table (27) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-25- | 14 | A | A | B | A | A |
| | (B blended) | 15 | A | A | B | A | A |
| | | 16 | A | A | B | A | A |
| | | 17 | A | A | B | A | A |
| | | 18 | A | A | B | A | A |
| | | 19 | A | A | B | A | A |
| | | 20 | A | A | B | A | A |
| | | 21 | A | A | B | A | A |
| | | 22 | A | A | B | A | A |
| | | 23 | A | A | B | A | A |
| | | 24 | A | A | B | A | A |
| | | 25 | A | A | B | A | A |
| | | 26 | A | A | B | A | A |

| | | | Evaluation of transfer film | | | | | | | |
|---|---|---|---|---|---|---|---|---|---|---|
| | | | | | | | | | Change in | |
| Sixth table (27) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-25- | 14 | A | <1 | B | A | A | A | A | A |
| | (B blended) | 15 | A | <1 | B | A | A | A | A | A |
| | | 16 | A | <1 | B | A | A | A | A | A |
| | | 17 | A | <1 | B | A | A | A | A | A |
| | | 18 | A | <1 | B | A | A | A | A | A |
| | | 19 | A | <1 | B | A | A | A | A | A |
| | | 20 | A | <1 | B | A | A | A | A | A |
| | | 21 | A | <1 | B | A | A | A | A | A |
| | | 22 | A | <1 | B | A | A | A | A | A |
| | | 23 | A | <1 | B | A | A | A | A | A |
| | | 24 | A | <1 | B | A | A | A | A | A |
| | | 25 | A | <1 | B | A | A | A | A | A |
| | | 26 | A | <1 | B | A | A | A | A | A |

TABLE 34

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (28) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-26- | 51 | 2 | 50 | B6 | 7.9 | 10 | A | <1 | A | A | A |
| | (A not blended, | | 3 | 50 | B12 | 7.9 | 10 | | | | | |
| | B blended) | 52 | 10 | 50 | B6 | 3.3 | 10 | A | <1 | A | A | A |
| | | | 11 | 50 | B12 | 3.3 | 10 | | | | | |
| | | 53 | 12 | 50 | B6 | 3.3 | 10 | A | <1 | A | A | A |
| | | | 13 | 50 | B12 | 3.3 | 10 | | | | | |
| | | 54 | 16 | 50 | B6 | 3.3 | 10 | A | <1 | A | A | A |
| | | | 17 | 50 | B12 | 3.3 | 10 | | | | | |
| | | 55 | 18 | 50 | B6 | 3.3 | 10 | A | <1 | A | A | A |
| | | | 19 | 50 | B12 | 3.3 | 10 | | | | | |
| | | 56 | 20 | 50 | B6 | 3.3 | 10 | A | <1 | A | A | A |
| | | | 21 | 50 | B12 | 3.3 | 10 | | | | | |
| | | 57 | 1 | 50 | B6 | 3.3 | 10 | A | <1 | A | A | A |
| | | | 26 | 50 | B12 | 3.3 | 10 | | | | | |
| | | 58 | 8 | 33 | B6 | 3.5 | 10 | A | <1 | A | A | A |
| | | | 10 | 33 | B12 | 3.5 | 10 | | | | | |
| | | | 12 | 34 | | | | | | | | |
| | | 59 | 15 | 33 | B6 | 3.1 | 10 | A | <1 | A | A | A |
| | | | 17 | 33 | B12 | 3.1 | 10 | | | | | |
| | | | 19 | 34 | | | | | | | | |
| | | 60 | 20 | 33 | B6 | 3.3 | 10 | A | <1 | A | A | A |
| | | | 21 | 33 | B12 | 3.3 | 10 | | | | | |
| | | | 22 | 34 | | | | | | | | |
| | | 61 | 1 | 33 | B6 | 3.3 | 10 | A | <1 | A | A | A |
| | | | 12 | 33 | B12 | 3.3 | 10 | | | | | |
| | | | 23 | 34 | | | | | | | | |

| | | | Evaluation of photosensitive material | | | | |
|---|---|---|---|---|---|---|---|
| | | | | Change in | Evaluation of transfer film | | |
| Sixth table (28) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Example | 4-26- | 51 | A | A | A | A | A |
| | (A not blended, | 52 | A | A | A | A | A |
| | B blended) | 53 | A | A | A | A | A |
| | | 54 | A | A | A | A | A |
| | | 55 | A | A | A | A | A |
| | | 56 | A | A | A | A | A |
| | | 57 | A | A | A | A | A |
| | | 58 | A | A | A | A | A |
| | | 59 | A | A | A | A | A |
| | | 60 | A | A | A | A | A |
| | | 61 | A | A | A | A | A |

| | | | Evaluation of transfer film | | | | | | | |
|---|---|---|---|---|---|---|---|---|---|---|
| | | | | | | | | | Change in | |
| Sixth table (28) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Example | 4-26- | 51 | A | <1 | A | A | A | A | A | A |
| | (A not blended, | 52 | A | <1 | A | A | A | A | A | A |
| | B blended) | 53 | A | <1 | A | A | A | A | A | A |
| | | 54 | A | <1 | A | A | A | A | A | A |
| | | 55 | A | <1 | A | A | A | A | A | A |
| | | 56 | A | <1 | A | A | A | A | A | A |
| | | 57 | A | <1 | A | A | A | A | A | A |
| | | 58 | A | <1 | A | A | A | A | A | A |
| | | 59 | A | <1 | A | A | A | A | A | A |
| | | 60 | A | <1 | A | A | A | A | A | A |
| | | 61 | A | <1 | A | A | A | A | A | A |

TABLE 35

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (29) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Example | 4-27- | 51 | 2 | 50 | B6 | 4.0 | 5 | A | <1 | A | A | A |
| | (A not blended, | | 3 | 50 | B12 | 4.0 | 5 | | | | | |
| | B blended) | 52 | 10 | 50 | B6 | 1.6 | 5 | A | <1 | A | A | A |
| | | | 11 | 50 | B12 | 1.6 | 5 | | | | | |
| | | 53 | 12 | 50 | B6 | 1.6 | 5 | A | <1 | A | A | A |
| | | | 13 | 50 | B12 | 1.6 | 5 | | | | | |
| | | 54 | 16 | 50 | B6 | 1.6 | 5 | A | <1 | A | A | A |
| | | | 17 | 50 | B12 | 1.6 | 5 | | | | | |
| | | 55 | 18 | 50 | B6 | 1.6 | 5 | A | <1 | A | A | A |
| | | | 19 | 50 | B12 | 1.6 | 5 | | | | | |
| | | 56 | 20 | 50 | B6 | 1.6 | 5 | A | <1 | A | A | A |
| | | | 21 | 50 | B12 | 1.6 | 5 | | | | | |
| | | 57 | 1 | 50 | B6 | 1.7 | 5 | A | <1 | A | A | A |
| | | | 26 | 50 | B12 | 1.7 | 5 | | | | | |
| | | 58 | 8 | 33 | B6 | 1.7 | 5 | A | <1 | A | A | A |
| | | | 10 | 33 | B12 | 1.7 | 5 | | | | | |
| | | | 12 | 34 | | | | | | | | |
| | | 59 | 15 | 33 | B6 | 1.5 | 5 | A | <1 | A | A | A |
| | | | 17 | 33 | B12 | 1.5 | 5 | | | | | |
| | | | 19 | 34 | | | | | | | | |
| | | 60 | 20 | 33 | B6 | 1.7 | 5 | A | <1 | A | A | A |
| | | | 21 | 33 | B12 | 1.7 | 5 | | | | | |
| | | | 22 | 34 | | | | | | | | |
| | | 61 | 1 | 33 | B6 | 1.7 | 5 | A | <1 | A | A | A |
| | | | 12 | 33 | B12 | 1.7 | 5 | | | | | |
| | | | 23 | 34 | | | | | | | | |

| | | | | Evaluation of photosensitive material | | | | |
|---|---|---|---|---|---|---|---|---|
| | | | | | Change in | Evaluation of transfer film | | |
| Sixth table (29) | | | Compound A | | relative | Carboxy group | | Transmittance |
| Example/ | | | having acid group | | permittivity | consumption rate | | at 365 nm/ |
| Comparative | Head | Serial | Compound | Relative | before and | [measurement | Transmittance | transmittance |
| Example | number | number | No. | permittivity | after exposure | of ashing] | at 365 nm | at 313 nm |
| Example | 4-27- | 51 | 2 | A | A | A | A | A |
| | (A not blended, | | 3 | | | | | |
| | B blended) | 52 | 10 | A | A | A | A | A |
| | | | 11 | | | | | |
| | | 53 | 12 | A | A | A | A | A |
| | | | 13 | | | | | |
| | | 54 | 16 | A | A | A | A | A |
| | | | 17 | | | | | |
| | | 55 | 18 | A | A | A | A | A |
| | | | 19 | | | | | |
| | | 56 | 20 | A | A | A | A | A |
| | | | 21 | | | | | |
| | | 57 | 1 | A | A | A | A | A |
| | | | 26 | | | | | |
| | | 58 | 8 | A | A | A | A | A |
| | | | 10 | | | | | |
| | | | 12 | | | | | |
| | | 59 | 15 | A | A | A | A | A |
| | | | 17 | | | | | |
| | | | 19 | | | | | |
| | | 60 | 20 | A | A | A | A | A |
| | | | 21 | | | | | |
| | | | 22 | | | | | |
| | | 61 | 1 | A | A | A | A | A |
| | | | 12 | | | | | |
| | | | 23 | | | | | |

| | | | | Evaluation of transfer film | | | | | | | |
|---|---|---|---|---|---|---|---|---|---|---|---|
| | | | | | | | | | | Change in | |
| Sixth table (29) | | | Compound A | | | Pattern | | | | relative | |
| Example/ | | | having acid group | | | formability | | | | permittivity | |
| Comparative | Head | Serial | Compound | Laminate | ε365/ | 25 | 50 | 250 | Relative | before and | Moisture |
| Example | number | number | No. | suitability | ε313 | μm | μm | μm | permittivity | after exposure | permeability |
| Example | 4-27- | 51 | 2 | A | <1 | A | A | A | A | A | A |
| | (A not blended, | | 3 | | | | | | | | |
| | B blended) | 52 | 10 | A | <1 | A | A | A | A | A | A |
| | | | 11 | | | | | | | | |
| | | 53 | 12 | A | <1 | A | A | A | A | A | A |
| | | | 13 | | | | | | | | |
| | | 54 | 16 | A | <1 | A | A | A | A | A | A |
| | | | 17 | | | | | | | | |
| | | 55 | 18 | A | <1 | A | A | A | A | A | A |
| | | | 19 | | | | | | | | |
| | | 56 | 20 | A | <1 | A | A | A | A | A | A |
| | | | 21 | | | | | | | | |
| | | 57 | 1 | A | <1 | A | A | A | A | A | A |
| | | | 26 | | | | | | | | |
| | | 58 | 8 | A | <1 | A | A | A | A | A | A |
| | | | 10 | | | | | | | | |
| | | | 12 | | | | | | | | |
| | | 59 | 15 | A | <1 | A | A | A | A | A | A |
| | | | 17 | | | | | | | | |
| | | | 19 | | | | | | | | |
| | | 60 | 20 | A | <1 | A | A | A | A | A | A |
| | | | 21 | | | | | | | | |
| | | | 22 | | | | | | | | |
| | | 61 | 1 | A | <1 | A | A | A | A | A | A |
| | | | 12 | | | | | | | | |
| | | | 23 | | | | | | | | |

TABLE 36

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (30) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Comparative | 4A | 1 | 1 | 100 | None | — | — | E | — | D | D | D |
| Example | ※ | 2 | 2 | 100 | None | — | — | E | — | D | D | D |
| | Comparative | 3 | 3 | 100 | None | — | — | E | — | D | D | D |
| | Example | 4 | 4 | 100 | None | — | — | E | — | D | D | D |
| | (standard) | 5 | 5 | 100 | None | — | — | E | — | D | D | D |
| | with the same | 6 | 6 | 100 | None | — | — | E | — | D | D | D |
| | serial number | 7 | 7 | 100 | None | — | — | E | — | D | D | D |
| | | 8 | 8 | 100 | None | — | — | E | — | D | D | D |
| | | 9 | 9 | 100 | None | — | — | E | — | D | D | D |
| | | 10 | 10 | 100 | None | — | — | E | — | D | D | D |
| | | 11 | 11 | 100 | None | — | — | E | — | D | D | D |
| | | 12 | 12 | 100 | None | — | — | E | — | D | D | D |
| | | 13 | 13 | 100 | None | — | — | E | — | D | D | D |
| | | 14 | 14 | 100 | None | — | — | E | — | D | D | D |
| | | 15 | 15 | 100 | None | — | — | E | — | D | D | D |
| | | 16 | 16 | 100 | None | — | — | E | — | D | D | D |
| | | 17 | 17 | 100 | None | — | — | E | — | D | D | D |
| | | 18 | 18 | 100 | None | — | — | E | — | D | D | D |
| | | 19 | 19 | 100 | None | — | — | E | — | D | D | D |
| | | 20 | 20 | 100 | None | — | — | E | — | D | D | D |
| | | 21 | 21 | 100 | None | — | — | E | — | D | D | D |
| | | 22 | 22 | 100 | None | — | — | E | — | D | D | D |
| | | 23 | 23 | 100 | None | — | — | E | — | D | D | D |
| | | 24 | 24 | 100 | None | — | — | E | — | D | D | D |
| | | 25 | 25 | 100 | None | — | — | E | — | D | D | D |
| | | 26 | 26 | 100 | None | — | — | E | — | D | D | D |

| | | | Evaluation of photosensitive material | | | | |
|---|---|---|---|---|---|---|---|
| | | | | Change in | Evaluation of transfer film | | |
| Sixth table (30) | | | | relative | Carboxy group | | Transmittance |
| Example/ | | | | permittivity | consumption rate | | at 365 nm/ |
| Comparative | Head | Serial | Relative | before and | [measurement | Transmittance | transmittance |
| Example | number | number | permittivity | after exposure | of ashing] | at 365 nm | at 313 nm |
| Comparative | 4A | 1 | Standard | D | E | A | B |
| Example | ※ | 2 | Standard | D | E | A | B |
| | Comparative | 3 | Standard | D | E | A | B |
| | Example | 4 | Standard | D | E | A | B |
| | (standard) | 5 | Standard | D | E | A | B |
| | with the same | 6 | Standard | D | E | A | B |
| | serial number | 7 | Standard | D | E | A | B |
| | | 8 | Standard | D | E | A | B |
| | | 9 | Standard | D | E | A | B |
| | | 10 | Standard | D | E | A | B |
| | | 11 | Standard | D | E | A | B |
| | | 12 | Standard | D | E | A | B |
| | | 13 | Standard | D | E | A | B |
| | | 14 | Standard | D | E | A | B |
| | | 15 | Standard | D | E | A | B |
| | | 16 | Standard | D | E | A | B |
| | | 17 | Standard | D | E | A | B |
| | | 18 | Standard | D | E | A | B |
| | | 19 | Standard | D | E | A | B |
| | | 20 | Standard | D | E | A | B |
| | | 21 | Standard | D | E | A | B |
| | | 22 | Standard | D | E | A | B |
| | | 23 | Standard | D | E | A | B |
| | | 24 | Standard | D | E | A | B |
| | | 25 | Standard | D | E | A | B |
| | | 26 | Standard | D | E | A | B |

| | | | Evaluation of transfer film | | | | | | | |
|---|---|---|---|---|---|---|---|---|---|---|
| | | | | | | | | | Change in | |
| Sixth table (30) | | | | | Pattern | | | | relative | |
| Example/ | | | | | formability | | | | permittivity | |
| Comparative | Head | Serial | Laminate | ε365/ | 25 | 50 | 250 | Relative | before and | Moisture |
| Example | number | number | suitability | ε313 | μm | μm | μm | permittivity | after exposure | permeability |
| Comparative | 4A | 1 | A | — | D | D | D | Standard | D | Standard |
| Example | ※ | 2 | A | — | D | D | D | Standard | D | Standard |
| | Comparative | 3 | A | — | D | D | D | Standard | D | Standard |
| | Example | 4 | A | — | D | D | D | Standard | D | Standard |
| | (standard) | 5 | A | — | D | D | D | Standard | D | Standard |
| | with the same | 6 | A | — | D | D | D | Standard | D | Standard |
| | serial number | 7 | A | — | D | D | D | Standard | D | Standard |
| | | 8 | A | — | D | D | D | Standard | D | Standard |
| | | 9 | A | — | D | D | D | Standard | D | Standard |
| | | 10 | A | — | D | D | D | Standard | D | Standard |
| | | 11 | A | — | D | D | D | Standard | D | Standard |
| | | 12 | A | — | D | D | D | Standard | D | Standard |
| | | 13 | A | — | D | D | D | Standard | D | Standard |
| | | 14 | A | — | D | D | D | Standard | D | Standard |
| | | 15 | A | — | D | D | D | Standard | D | Standard |
| | | 16 | A | — | D | D | D | Standard | D | Standard |
| | | 17 | A | — | D | D | D | Standard | D | Standard |
| | | 18 | A | — | D | D | D | Standard | D | Standard |
| | | 19 | A | — | D | D | D | Standard | D | Standard |
| | | 20 | A | — | D | D | D | Standard | D | Standard |
| | | 21 | A | — | D | D | D | Standard | D | Standard |
| | | 22 | A | — | D | D | D | Standard | D | Standard |
| | | 23 | A | — | D | D | D | Standard | D | Standard |
| | | 24 | A | — | D | D | D | Standard | D | Standard |
| | | 25 | A | — | D | D | D | Standard | D | Standard |
| | | 26 | A | — | D | D | D | Standard | D | Standard |

TABLE 37

| | | | | | Compound β | | | | | | | |
|---|---|---|---|---|---|---|---|---|---|---|---|---|
| | | | | | | | Molar ratio | | | | | |
| | | | | | | | with respect to | Evaluation of photosensitive material | | | | |
| Sixth table (31) | | | Compound A | | | | carboxy group | Carboxy group | | Pattern | | |
| Example/ | | | having acid group | | | | of compound A | consumption rate | | formability | | |
| Comparative | Head | Serial | Compound | Part by | | Part by | having acid group | [measurement | ε365/ | 25 | 50 | 250 |
| Example | number | number | No. | mass | No. | mass | (mol %) | of ashing] | ε313 | μm | μm | μm |
| Comparative | 4A | 51 | 2 | 50 | None | — | — | E | — | D | D | D |
| Example | ※ | | 3 | 50 | | | | | | | | |
| | Comparative | 52 | 10 | 50 | None | — | — | E | — | D | D | D |
| | Example | | 11 | 50 | | | | | | | | |
| | (standard) | 53 | 12 | 50 | None | — | — | E | — | D | D | D |
| | with the same | | 13 | 50 | | | | | | | | |
| | serial number | 54 | 16 | 50 | None | — | — | E | — | D | D | D |
| | | | 17 | 50 | | | | | | | | |
| | | 55 | 18 | 50 | None | — | — | E | — | D | D | D |
| | | | 19 | 50 | | | | | | | | |
| | | 56 | 20 | 50 | None | — | — | E | — | D | D | D |
| | | | 21 | 50 | | | | | | | | |
| | | 57 | 1 | 50 | None | — | — | E | — | D | D | D |
| | | | 26 | 50 | | | | | | | | |
| | | 58 | 8 | 33 | None | — | — | E | — | D | D | D |
| | | | 10 | 33 | | | | | | | | |
| | | | 12 | 34 | | | | | | | | |
| | | 59 | 15 | 33 | None | — | — | E | — | D | D | D |
| | | | 17 | 33 | | | | | | | | |
| | | | 19 | 34 | | | | | | | | |
| | | 60 | 20 | 33 | None | — | — | E | — | D | D | D |
| | | | 21 | 33 | | | | | | | | |
| | | | 22 | 34 | | | | | | | | |
| | | 61 | 1 | 33 | None | — | — | E | — | D | D | D |
| | | | 12 | 33 | | | | | | | | |
| | | | 23 | 34 | | | | | | | | |

| | | | | Evaluation of photosensitive material | | | | |
|---|---|---|---|---|---|---|---|---|
| | | | | | Change in | Evaluation of transfer film | | |
| Sixth table (31) | | | Compound A | | relative | Carboxy group | | Transmittance |
| Example/ | | | having acid group | | permittivity | consumption rate | | at 365 nm/ |
| Comparative | Head | Serial | Compound | Relative | before and | [measurement | Transmittance | transmittance |
| Example | number | number | No. | permittivity | after exposure | of ashing] | at 365 nm | at 313 nm |
| Comparative | 4A | 51 | 2 | Standard | D | E | A | B |
| Example | ※ | | 3 | | | | | |
| | Comparative | 52 | 10 | Standard | D | E | A | B |
| | Example | | 11 | | | | | |
| | (standard) | 53 | 12 | Standard | D | E | A | B |
| | with the same | | 13 | | | | | |
| | serial number | 54 | 16 | Standard | D | E | A | B |
| | | | 17 | | | | | |
| | | 55 | 18 | Standard | D | E | A | B |
| | | | 19 | | | | | |
| | | 56 | 20 | Standard | D | E | A | B |
| | | | 21 | | | | | |
| | | 57 | 1 | Standard | D | E | A | B |
| | | | 26 | | | | | |
| | | 58 | 8 | Standard | D | E | A | B |
| | | | 10 | | | | | |
| | | | 12 | | | | | |
| | | 59 | 15 | Standard | D | E | A | B |
| | | | 17 | | | | | |
| | | | 19 | | | | | |
| | | 60 | 20 | Standard | D | E | A | B |
| | | | 21 | | | | | |
| | | | 22 | | | | | |
| | | 61 | 1 | Standard | D | E | A | B |
| | | | 12 | | | | | |
| | | | 23 | | | | | |

| | | | | Evaluation of transfer film | | | | | | | |
|---|---|---|---|---|---|---|---|---|---|---|---|
| | | | | | | | | | | Change in | |
| Sixth table (31) | | | Compound A | | | Pattern | | | | relative | |
| Example/ | | | having acid group | | | formability | | | | permittivity | |
| Comparative | Head | Serial | Compound | Laminate | ε365/ | 25 | 50 | 250 | Relative | before and | Moisture |
| Example | number | number | No. | suitability | ε313 | μm | μm | μm | permittivity | after exposure | permeability |
| Comparative | 4A | 51 | 2 | A | — | D | D | D | Standard | D | Standard |
| Example | ※ | | 3 | | | | | | | | |
| | Comparative | 52 | 10 | A | — | D | D | D | Standard | D | Standard |
| | Example | | 11 | | | | | | | | |
| | (standard) | 53 | 12 | A | — | D | D | D | Standard | D | Standard |
| | with the same | | 13 | | | | | | | | |
| | serial number | 54 | 16 | A | — | D | D | D | Standard | D | Standard |
| | | | 17 | | | | | | | | |
| | | 55 | 18 | A | — | D | D | D | Standard | D | Standard |
| | | | 19 | | | | | | | | |
| | | 56 | 20 | A | — | D | D | D | Standard | D | Standard |
| | | | 21 | | | | | | | | |
| | | 57 | 1 | A | — | D | D | D | Standard | D | Standard |
| | | | 26 | | | | | | | | |
| | | 58 | 8 | A | — | D | D | D | Standard | D | Standard |
| | | | 10 | | | | | | | | |
| | | | 12 | | | | | | | | |
| | | 59 | 15 | A | — | D | D | D | Standard | D | Standard |
| | | | 17 | | | | | | | | |
| | | | 19 | | | | | | | | |
| | | 60 | 20 | A | — | D | D | D | Standard | D | Standard |
| | | | 21 | | | | | | | | |
| | | | 22 | | | | | | | | |
| | | 61 | 1 | A | — | D | D | D | Standard | D | Standard |
| | | | 12 | | | | | | | | |
| | | | 23 | | | | | | | | |

From the results in the above tables, it was confirmed that the objects of the present invention could be achieved with the transfer film according to the embodiment of the present invention.

In addition, it was confirmed that conditions under which the effects of the present invention are more excellent were similar to the trends confirmed for Example 1 system.

### Example 5 System

<Preparation and Evaluation of Photosensitive Material>

Materials shown in Seventh table shown in the latter part were mixed and dissolved in a mixed solvent of propylene glycol monomethyl ether acetate/methyl ethyl ketone=50/50 (mass ratio) so that a concentration of solid contents of the finally obtained photosensitive material was 25% by mass, thereby obtaining a photosensitive material.

In addition, for the obtained photosensitive material of each of Examples or Comparative Examples in Example 5 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, and moisture permeability were evaluated in the same manner as shown in Example 1 system. In addition, the carboxy group consumption rate, transmittance to light at 365 nm, and ratio of the transmittance to light at 365 nm to the transmittance to light at 313 nm of the photosensitive layer in the transfer film were also evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 5A.

Hereinafter, Seventh table below shows blending of the solid content of the photosensitive material of each of Examples or Comparative Examples in Example 5 system, and the test results thereof. The photosensitive material of each of Examples shown in Example 5 system has a composition of 100% by mass of the compound A having an acid group and the specific structure S1 (solid content).

In the table, the column of “x/y/z” indicates a mass ratio of each structural unit constituting the compound A.

As shown in Seventh table, the weight-average molecular weight of the compound A shown in Seventh table was all 10,000 to 50,000.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

In addition, in the table, the description of St/AA means a styrene/acrylic acid copolymer (compositional ratio: styrene-based repeating unit/acrylic acid-based repeating unit=80/20 (mass ratio)).

| | | | | Evaluation of photosensitive material | | | | | |
|---|---|---|---|---|---|---|---|---|---|
| | | | | [symbol] | | | | | [symbol] |
| | | | | [symbol] | | | | | [symbol] |
| | | | | [symbol] | Pattern | | | [symbol] | [symbol] |
| | Compound A having acid group and specific structure | | | [symbol] | formability | | | [symbol] | [symbol] |
| Seventh | | x, y, z | | [symbol] | 25 | 50 | 250 | [symbol] | [symbol] |
| table | Structure | (mass ratio) | M [symbol] | [symbol] | μm | μm | μm | [symbol] | [symbol] |
| Example 5-1 | 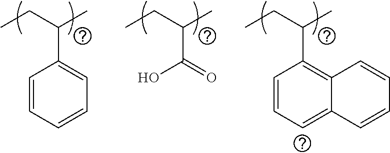 | [symbol] /20/7.5 | 2000 | B | B | A | A | A | A |
| Example 5-2 | 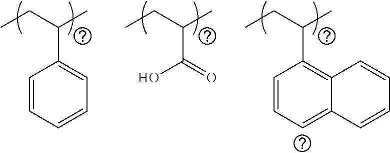 | [symbol] /20/ [symbol] | 22000 | B | B | A | A | A | A |
| Example 5-3 | 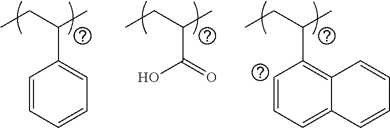 | [symbol] /20/7.5 | 25000 | A | B | A | A | A | A |
| Example 5-4 | 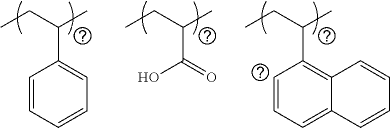 | [symbol] /20/ [symbol] | 24000 | A | B | A | A | A | A |
| Example 5-5 | 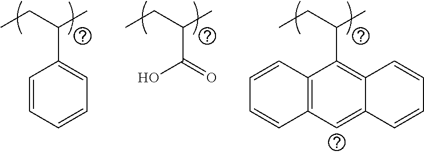 | 70/20/10 | 20000 | C | B | B | A | B | B |
| Example 5-6 | 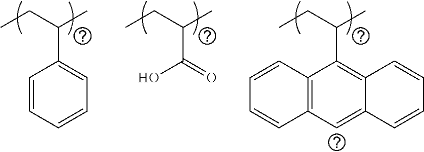 | [symbol] /20/11. [symbol] | 22000 | C | B | B | A | B | B |
| Comparative Example 5A | [symbol] /AA | 80/20 | 11000 | E | D | D | D | Standard | D |

Evaluation of transfer film

| [symbol] | | | | | | | | [symbol] | |
|---|---|---|---|---|---|---|---|---|---|
| [symbol] | | [symbol] | | | | | | [symbol] | |
| [symbol] | [symbol] | [symbol] | [symbol] | Pattern | | | | [symbol] | |
| [symbol] | [symbol] | [symbol] | [symbol] | formability | | | [symbol] | [symbol] | [symbol] |
| [symbol] | [symbol] | [symbol] | [symbol] | 25 | 50 | 250 | [symbol] | [symbol] | [symbol] |
| [symbol] | [symbol] | [symbol] | [symbol] | μm | μm | μm | [symbol] | [symbol] | [symbol] |
| B | A | A | A | B | A | A | A | A | B |
| B | A | A | A | B | A | A | A | A | B |
| A | A | A | A | B | A | A | A | A | B |
| A | A | A | A | B | A | A | A | A | B |
| C | C | C | A | B | B | A | B | B | B |
| C | C | C | A | B | B | A | B | B | B |
| E | A | B | A | D | D | D | [symbol] | D | [symbol] |

[symbol]

indicates data missing or illegible when filed

From the results in the above tables, it was confirmed that the objects of the present invention could be achieved with the transfer film according to the embodiment of the present invention.

### Example 6 System

<Preparation and Evaluation of Photosensitive Material>

Materials shown in Eighth table shown in the latter part were mixed and dissolved in a mixed solvent of propylene glycol monomethyl ether acetate/methyl ethyl ketone=50/50 (mass ratio) so that a blending amount shown in Eighth table shown in the latter part was satisfied and a concentration of solid contents of the finally obtained photosensitive material was 25% by mass, thereby obtaining a photosensitive material.

In addition, for the obtained photosensitive material of each of Examples or Comparative Examples in Example 6 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, and moisture permeability were evaluated in the same manner as shown in Example 1 system. In addition, the carboxy group consumption rate, transmittance to light at 365 nm, and ratio of the transmittance to light at 365 nm to the transmittance to light at 313 nm of the photosensitive layer in the transfer film were also evaluated in the same manner as shown in Example 1 system. In addition, the physical properties of ε365/ε313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 6A.

Eighth table below shows blending of the solid content of the photosensitive material of each of Examples or Comparative Examples in Example 6 system, and the test results thereof.

In the table, the value described in the column of “Solid content blending” indicates the content (part by mass) of each solid content component included in the photosensitive material of each of Examples or Comparative Examples. The value in parentheses in the compound β indicates a proportion (mol %) of the total number of structures (specific structures S1) capable of accepting an electron from the acid group included in the compound A, which are included in the compound β, to the total number of carboxy groups included in the compound A having an acid group (compound A) in the photosensitive material.

In addition, in the tables, the method for measuring “pKa of compound β in ground state” is as described above.

In addition, in the tables, the column of “ε365 of compound β” indicates a molar absorption coefficient ((cm·mol/L)⁻¹) of the compound β to light having a wavelength of 365 nm in acetonitrile.

In addition, the column of “ε365/ε313” in the evaluation of the photosensitive material and the evaluation of the transfer film indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values measured in acetonitrile.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

TABLE 39

| | | | Mw of | pKa of | | | | |
|---|---|---|---|---|---|---|---|---|
| | | | compound A | Compound β | ε365 of | Example | | |
| Eighth table (1) | | | having acid group | in ground state | Compound β | 6-1 | 6-2 | 6-3 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | 3.5 (20) | | |
| | (in parentheses: | Quinoline | | 4.15 | <10 | | 3.5 (20) | |
| | molar ratio | Acridine | | 4.67 | 4900 | | | 4.9 (20) |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | B | B | D |
| photosensitive | [measurement of ashing] | | | | | | | |
| material | ε365/ε313 | | | — | — | <1 | <1 | >3 |
| | Pattern | 25 μm | | — | — | B | B | C |
| | formability | 50 μm | | — | — | A | A | B |
| | | 250 μm | | — | — | A | A | A |
| | Relative permittivity | | | — | — | A | A | B |
| | Change in relative permittivity | | | — | — | A | A | B |
| | before and after exposure | | | | | | | |
| Evaluation of | Carboxy group consumption rate | | | — | — | B | B | D |
| transfer film | [measurement of ashing] | | | | | | | |
| | ε365/ε313 | | | — | — | <1 | <1 | >3 |
| | Transmittance at 365 nm | | | — | — | A | A | C |
| | Transmittance at 365 nm/ | | | — | — | A | A | C |
| | transmittance at 313 nm | | | | | | | |
| | Laminate suitability | | | — | — | A | A | A |
| | Pattern | 25 μm | | — | — | B | B | C |
| | formability | 50 μm | | — | — | A | A | B |
| | | 250 μm | | — | — | A | A | A |

| | | | | | |
|---|---|---|---|---|---|
| Relative permittivity | — | — | A | A | B |
| Change in relative permittivity | — | — | A | A | B |
| before and after exposure | | | | | |
| Moisture permeability | — | — | A | B | B |

| | | | Example | | | | | | |
|---|---|---|---|---|---|---|---|---|---|
| Eighth table (1) | | | 6-4 | 6-5 | 6-6 | 6-7 | 6-8 | 6-9 | 6-10 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | 5.0 (20) | | | | | | |
| | carboxy group | 1-n-Butyl-4-methylisoquinoline | | 5.4 (20) | | | | | |
| | of compound A | 1-Me-isoquinoline | | | 3.9 (20) | | | | |
| | having acid group | 2,4,5,7-Tetramethylquinoline | | | | 5.0 (20) | | | |
| | (mol %)) | 2-Methyl-4-methoxyquinoline | | | | | 4.7 (20) | | |
| | | 9-Methylacridine | | | | | | 5.2 (20) | |
| | | 9-Phenylacridine | | | | | | | 6.9 (20) |
| | | Pyridine | | | | | | | |
| | | 2,4-Dimethylquinoline | | | | | | | |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | A | A | A | A | C | D |
| photosensitive | [measurement of ashing] | | | | | | | | |
| material | ε365/ε313 | | <1 | <1 | <1 | <1 | <1 | >3 | >3 |
| | Pattern | 25 μm | A | A | A | A | A | B | B |
| | formability | 50 μm | A | A | A | A | A | B | B |
| | | 250 μm | A | A | A | A | A | A | B |
| | Relative permittivity | | A | A | A | A | A | B | C |
| | Change in relative permittivity | | A | A | A | A | A | B | C |
| | before and after exposure | | | | | | | | |
| Evaluation of | Carboxy group consumption rate | | A | A | A | A | A | C | D |
| transfer film | [measurement of ashing] | | | | | | | | |
| | ε365/ε313 | | <1 | <1 | <1 | <1 | <1 | >3 | >3 |
| | Transmittance at 365 nm | | A | A | A | A | A | C | C |
| | Transmittance at 365 nm/ | | A | A | A | A | A | C | C |
| | transmittance at 313 nm | | | | | | | | |
| | Laminate suitability | | A | A | A | A | A | A | A |
| | Pattern | 25 μm | A | A | A | A | A | B | B |
| | formability | 50 μm | A | A | A | A | A | B | B |
| | | 250 μm | A | A | A | A | A | A | B |

| | | | | | | | |
|---|---|---|---|---|---|---|---|
| Relative permittivity | A | A | A | A | A | B | C |
| Change in relative permittivity | A | A | A | A | A | B | C |
| before and after exposure | | | | | | | |
| Moisture permeability | A | A | A | A | A | B | B |

| | | | Example | | | | | | |
|---|---|---|---|---|---|---|---|---|---|
| Eighth table (1) | | | 6-11 | 6-12 | 6-13 | 6-14 | 6-15 | 6-16 | 6-17 |
| Solid content | Compound A | St/MAA/MMA/GMA-MAA = | 60 | 60 | 60 | 60 | 60 | | |
| blending | having acid group | 47.7/19.0/1.3/32.0 (mass ratio) | | | | | | | |
| | | CHMA/MAA/BzMA = | | | | | | 60 | 60 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | 3.5 (20) | |
| | (in parentheses: | Quinoline | | | | | | | 3.5 (20) |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | | | | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | 2.1 (20) | | | | | | |
| | | 2,4-Dimethylquinoline | | 4.3 (20) | 2.1 (10) | | | | |
| | | 4-Aminopyridine | | | | 2.6 (20) | | | |
| | | 2-Chloropyridine | | | | | 3.1 (20) | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | D | A | B | D | D | B | B |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | C | A | B | C | C | B | B |
| formability | 50 μm | C | A | A | C | C | A | A |
| | 250 μm | C | A | A | C | C | A | A |

| | | | | | | | | |
|---|---|---|---|---|---|---|---|---|
| | Relative permittivity | C | A | A | C | C | A | A |
| | Change in relative permittivity | C | A | A | C | C | A | A |
| | before and after exposure | | | | | | | |
| Evaluation of | Carboxy group consumption rate | D | A | B | D | D | B | B |
| transfer film | [measurement of ashing] | | | | | | | |
| | ε365/ε313 | <1 | <1 | <1 | <1 | <1 | <1 | <1 |
| | Transmittance at 365 nm | B | A | A | B | B | A | A |
| | Transmittance at 365 nm/ | B | A | A | B | B | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | C | A | B | C | C | B | B |
| formability | 50 μm | C | A | A | C | C | A | A |
| | 250 μm | C | A | A | C | C | A | A |

| | | | | | | | |
|---|---|---|---|---|---|---|---|
| Relative permittivity | C | A | A | C | C | A | A |
| Change in relative permittivity | C | A | A | C | C | A | A |
| before and after exposure | | | | | | | |
| Moisture permeability | B | A | A | C | C | A | B |

TABLE 40

| | | | Mw of | pKa of | | | | |
|---|---|---|---|---|---|---|---|---|
| | | | compound A | Compound β | ε365 of | Example | | |
| Eighth table (2) | | | having acid group | in ground state | Compound β | 6-18 | 6-19 | 6-20 |
| Solid content | Compound A | St/MAA/MMA/GMA-MAA = | 18000 | — | — | | | |
| blending | having acid group | 47.7/19.0/1.3/32.0 (mass ratio) | | | | | | |
| | | CHMA/MAA/BzMA = | 24000 | — | — | 60 | 60 | 60 |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | 4.9 (20) | | |
| | with respect to | 1-n-Butylisoquinoline | | 5.27 | <10 | | 5.0 (20) | |
| | carboxy group | 1-n-Butyl-4-methylisoquinoline | | 5.9 | <10 | | | 5.4 (20) |
| | of compound A | 1-Me-isoquinoline | | 5.31 | <10 | | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | D | A | A |
| photosensitive | [measurement of ashing] | | | | | | | |
| material | ε365/ε313 | | | — | — | >3 | <1 | <1 |
| | Pattern | 25 μm | | — | — | C | A | A |
| | formability | 50 μm | | — | — | B | A | A |
| | | 250 μm | | — | — | A | A | A |
| | Relative permittivity | | | — | — | B | A | A |
| | Change in relative permittivity | | | — | — | B | A | A |
| | before and after exposure | | | | | | | |
| Evaluation of | Carboxy group consumption rate | | | — | — | D | A | A |
| transfer film | [measurement of ashing] | | | | | | | |
| | ε365/ε313 | | | — | — | >3 | <1 | <1 |
| | Transmittance at 365 nm | | | — | — | C | A | A |
| | Transmittance at 365 nm/ | | | — | — | C | A | A |
| | transmittance at 313 nm | | | | | | | |
| | Laminate suitability | | | — | — | A | A | A |
| | Pattern | 25 μm | | — | — | C | A | A |
| | formability | 50 μm | | — | — | B | A | A |
| | | 250 μm | | — | — | A | A | A |

| | | | | | |
|---|---|---|---|---|---|
| Relative permittivity | — | — | B | A | A |
| Change in relative permittivity | — | — | B | A | A |
| before and after exposure | | | | | |
| Moisture permeability | — | — | B | A | A |

| | | | Example | | | | | | |
|---|---|---|---|---|---|---|---|---|---|
| Eighth table (2) | | | 6-21 | 6-22 | 6-23 | 6-24 | 6-25 | 6-26 | 6-27 |
| Solid content | Compound A | St/MAA/MMA/GMA-MAA = | | | | | | | |
| blending | having acid group | 47.7/19.0/1.3/32.0 (mass ratio) | | | | | | | |
| | | CHMA/MAA/BzMA = | 60 | 60 | 60 | 60 | 60 | 60 | 60 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.9 (20) | | | | | | |
| | having acid group | 2,4,5,7-Tetramethylquinoline | | 5.0 (20) | | | | | |
| | (mol %)) | 2-Methyl-4-methoxyquinoline | | | 4.7 (20) | | | | |
| | | 9-Methylacridine | | | | 5.2 (20) | | | |
| | | 9-Phenylacridine | | | | | 6.9 (20) | | |
| | | Pyridine | | | | | | 2.1 (20) | |
| | | 2,4-Dimethylquinoline | | | | | | | 4.3 (20) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | A | A | C | D | D | A |
| photosensitive | [measurement of ashing] | | | | | | | | |
| material | ε365/ε313 | | <1 | <1 | <1 | >3 | >3 | <1 | <1 |
| | Pattern | 25 μm | A | A | A | B | B | C | A |
| | formability | 50 μm | A | A | A | B | B | C | A |
| | | 250 μm | A | A | A | A | B | C | A |
| | Relative permittivity | | A | A | A | B | C | C | A |
| | Change in relative permittivity | | A | A | A | B | C | C | A |
| | before and after exposure | | | | | | | | |
| Evaluation of | Carboxy group consumption rate | | A | A | A | C | D | D | A |
| transfer film | [measurement of ashing] | | | | | | | | |
| | ε365/ε313 | | <1 | <1 | <1 | >3 | >3 | <1 | <1 |
| | Transmittance at 365 nm | | A | A | A | C | C | B | A |
| | Transmittance at 365 nm/ | | A | A | A | C | C | B | A |
| | transmittance at 313 nm | | | | | | | | |
| | Laminate suitability | | A | A | A | A | A | A | A |
| | Pattern | 25 μm | A | A | A | B | B | C | A |
| | formability | 50 μm | A | A | A | B | B | C | A |
| | | 250 μm | A | A | A | A | B | C | A |

| | | | | | | | |
|---|---|---|---|---|---|---|---|
| Relative permittivity | A | A | A | B | C | C | A |
| Change in relative permittivity | A | A | A | B | C | C | A |
| before and after exposure | | | | | | | |
| Moisture permeability | A | A | A | B | B | B | A |

| | | | Example | | | | | | |
|---|---|---|---|---|---|---|---|---|---|
| Eighth table (2) | | | 6-28 | 6-29 | 6-30 | 6-31 | 6-32 | 6-33 | 6-34 |
| Solid content | Compound A | St/MAA/MMA/GMA-MAA = | | | | | | | |
| blending | having acid group | 47.7/19.0/1.3/32.0 (mass ratio) | | | | | | | |
| | | CHMA/MAA/BzMA = | 60 | 60 | 60 | | | | |
| | | 49/19/32 (mass ratio) | | | | | | | |
| | | St/AA/AA-GMA = | | | | 60 | 60 | 60 | 60 |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | 3.1 (20) | | | |
| | (in parentheses: | Quinoline | | | | | 3.1 (20) | | |
| | molar ratio | Acridine | | | | | | 4.3 (20) | |
| | with respect to | 1-n-Butylisoquinoline | | | | | | | 4.5 (20) |
| | carboxy group | 1-n-Butyl-4-methylisoquinoline | | | | | | | |
| | of compound A | 1-Me-isoquinoline | | | | | | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 2.1 (10) | | | | | | |
| | | 4-Aminopyridine | | 2.6 (20) | | | | | |
| | | 2-Chloropyridine | | | 3.1 (20) | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | B | D | D | B | B | D | A |
| photosensitive | [measurement of ashing] | | | | | | | |
| material | ε365/ε313 | <1 | <1 | <1 | <1 | <1 | >3 | <1 |

| | | | | | | | | |
|---|---|---|---|---|---|---|---|---|
| Pattern | 25 μm | B | C | C | B | B | C | A |
| formability | 50 μm | A | C | C | A | A | B | A |
| | 250 μm | A | C | C | A | A | A | A |

| | | | | | | | | |
|---|---|---|---|---|---|---|---|---|
| | Relative permittivity | A | C | C | A | A | B | A |
| | Change in relative permittivity | A | C | C | A | A | B | A |
| | before and after exposure | | | | | | | |
| Evaluation of | Carboxy group consumption rate | B | D | D | B | B | D | A |
| transfer film | [measurement of ashing] | | | | | | | |
| | ε365/ε313 | <1 | <1 | <1 | <1 | <1 | >3 | <1 |
| | Transmittance at 365 nm | A | B | B | A | A | C | A |
| | Transmittance at 365 nm/ | A | B | B | A | A | C | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | B | C | C | B | B | C | A |
| formability | 50 μm | A | C | C | A | A | B | A |
| | 250 μm | A | C | C | A | A | A | A |

| | | | | | | | |
|---|---|---|---|---|---|---|---|
| Relative permittivity | A | C | C | A | A | B | A |
| Change in relative permittivity | A | C | C | A | A | B | A |
| before and after exposure | | | | | | | |
| Moisture permeability | A | C | C | A | B | B | A |

TABLE 41

| | | | Mw of | pKa of | | | | |
|---|---|---|---|---|---|---|---|---|
| | | | compound A | Compound β | ε365 of | Example | | |
| Eighth table (3) | | | having acid group | in ground state | Compound β | 6-35 | 6-36 | 6-37 |
| Solid content | Compound A | St/MAA/MMA/GMA-MAA = | 18000 | — | — | | | |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | 60 | 60 | 60 |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | 4.8 (20) | | |
| | of compound A | 1-Me-isoquinoline | | 5.31 | <10 | | 3.5 (20) | |
| | having acid group | 2,4,5,7-Tetramethylquinoline | | 6.23 | <10 | | | 4.5 (20) |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | A | A |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | A | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

| | | | Example | | | | | | |
|---|---|---|---|---|---|---|---|---|---|
| Eighth table (3) | | | 6-38 | 6-39 | 6-40 | 6-41 | 6-42 | 6-43 | 6-44 |
| Solid content | Compound A | St/MAA/MMA/GMA-MAA = | | | | | | | |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | 60 | 60 | 60 | 60 | 60 | 60 | 60 |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | | | | | |
| | having acid group | 2,4,5,7-Tetramethylquinoline | | | | | | | |
| | (mol %)) | 2-Methyl-4-methoxyquinoline | 4.2 (20) | | | | | | |
| | | 9-Methylacridine | | 4.7 (20) | | | | | |
| | | 9-Phenylacridine | | | 6.2 (20) | | | | |
| | | Pyridine | | | | 1.9 (20) | | | |
| | | 2,4-Dimethylquinoline | | | | | 3.8 (20) | 1.9 (10) | |
| | | 4-Aminopyridine | | | | | | | 2.3 (20) |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | C | D | D | A | B | D |
| photosensitive | [measurement of ashing] | | | | | | | | |
| material | ε365/ε313 | | <1 | >3 | >3 | <1 | <1 | <1 | <1 |
| | Pattern | 25 μm | A | B | B | C | A | B | C |
| | formability | 50 μm | A | B | B | C | A | A | C |
| | | 250 μm | A | A | B | C | A | A | C |
| | Relative permittivity | | A | B | C | C | A | A | C |
| | Change in relative permittivity | | A | B | C | C | A | A | C |
| | before and after exposure | | | | | | | | |
| Evaluation of | Carboxy group consumption rate | | A | C | D | D | A | B | D |
| transfer film | [measurement of ashing] | | | | | | | | |
| | ε365/ε313 | | <1 | >3 | >3 | <1 | <1 | <1 | <1 |
| | Transmittance at 365 nm | | A | C | C | B | A | A | B |
| | Transmittance at 365 nm/ | | A | C | C | B | A | A | B |
| | transmittance at 313 nm | | | | | | | | |
| | Laminate suitability | | A | A | A | A | A | A | A |
| | Pattern | 25 μm | A | B | B | C | A | B | C |
| | formability | 50 μm | A | B | B | C | A | A | C |
| | | 250 μm | A | A | B | C | A | A | C |

| | | | | | | | |
|---|---|---|---|---|---|---|---|
| Relative permittivity | A | B | C | C | A | A | C |
| Change in relative permittivity | A | B | C | C | A | A | C |
| before and after exposure | | | | | | | |
| Moisture permeability | A | B | B | B | A | A | C |

| | | | Example | | | | | | |
|---|---|---|---|---|---|---|---|---|---|
| Eighth table (3) | | | 6-45 | 6-46 | 6-47 | 6-48 | 6-49 | 6-50 | 6-51 |
| Solid content | Compound A | St/MAA/MMA/GMA-MAA = | | | | | | | |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | 60 | | | | | | |
| | | 53.5/14.5/32 (mass ratio) | | | | | | | |
| | | CHA/AA/HEA = | | 60 | 60 | 60 | 60 | 60 | 60 |
| | | 53.5/14.5/32 (mass ratio) | | | | | | | |
| | Compound β | Isoquinoline | | 3.1 (20) | | | | | |
| | (in parentheses: | Quinoline | | | 3.1 (20) | | | | |
| | molar ratio | Acridine | | | | 4.3 (20) | | | |
| | with respect to | 1-n-Butylisoquinoline | | | | | 4.5 (20) | | |
| | carboxy group | 1-n-Butyl-4-methylisoquinoline | | | | | | 4.8 (20) | |
| | of compound A | 1-Me-isoquinoline | | | | | | | 3.5 (20) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | | | | | | |
| | | 4-Aminopyridine | | | | | | | |
| | | 2-Chloropyridine | 2.7 (20) | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | D | B | B | D | A | A | A |
| photosensitive | [measurement of ashing] | | | | | | | |
| material | ε365/ε313 | <1 | <1 | <1 | >3 | <1 | <1 | <1 |

| | | | | | | | | |
|---|---|---|---|---|---|---|---|---|
| Pattern | 25 μm | C | B | B | C | A | A | A |
| formability | 50 μm | C | A | A | B | A | A | A |
| | 250 μm | C | A | A | A | A | A | A |

| | | | | | | | | |
|---|---|---|---|---|---|---|---|---|
| | Relative permittivity | C | A | A | B | A | A | A |
| | Change in relative permittivity | C | A | A | B | A | A | A |
| | before and after exposure | | | | | | | |
| Evaluation of | Carboxy group consumption rate | D | B | B | D | A | A | A |
| transfer film | [measurement of ashing] | | | | | | | |
| | ε365/ε313 | <1 | <1 | <1 | >3 | <1 | <1 | <1 |
| | Transmittance at 365 nm | B | A | A | C | A | A | A |
| | Transmittance at 365 nm/ | B | A | A | C | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | C | B | B | C | A | A | A |
| formability | 50 μm | C | A | A | B | A | A | A |
| | 250 μm | C | A | A | A | A | A | A |

| | | | | | | | |
|---|---|---|---|---|---|---|---|
| Relative permittivity | C | A | A | B | A | A | A |
| Change in relative permittivity | C | A | A | B | A | A | A |
| before and after exposure | | | | | | | |
| Moisture permeability | C | A | B | B | A | A | A |

TABLE 42

| | | | Mw of | pKa of | | | | |
|---|---|---|---|---|---|---|---|---|
| | | | compound A | Compound β | ε365 of | Example | | |
| Eighth table (4) | | | having acid group | in ground state | Compound β | 6-52 | 6-53 | 6-54 |
| Solid content | Compound A | St/MAA/MMA/GMA-MAA = | 18000 | — | — | | | |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | 60 | 60 | 60 |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | |
| | having acid group | 2,4,5,7-Tetramethylquinoline | | 6.23 | <10 | 4.5 (20) | | |
| | (mol %)) | 2-Methyl-4-methoxyquinoline | | 6.51 | <10 | | 4.2 (20) | |
| | | 9-Methylacridine | | 5.4 | 6300 | | | 4.7 (20) |
| | | 9-Phenylacridine | | 4.04 | >10000 | | | |
| | | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | A | C |
| photosensitive | [measurement of ashing] | | | | | | | |
| material | ε365/ε313 | | | — | — | <1 | <1 | >3 |
| | Pattern | 25 μm | | — | — | A | A | B |
| | formability | 50 μm | | — | — | A | A | B |
| | | 250 μm | | — | — | A | A | A |
| | Relative permittivity | | | — | — | A | A | B |
| | Change in relative permittivity | | | — | — | A | A | B |
| | before and after exposure | | | | | | | |
| Evaluation of | Carboxy group consumption rate | | | — | — | A | A | C |
| transfer film | [measurement of ashing] | | | | | | | |
| | ε365/ε313 | | | — | — | <1 | <1 | >3 |
| | Transmittance at 365 nm | | | — | — | A | A | C |
| | Transmittance at 365 nm/ | | | — | — | A | A | C |
| | transmittance at 313 nm | | | | | | | |
| | Laminate suitability | | | — | — | A | A | A |
| | Pattern | 25 μm | | — | — | A | A | B |
| | formability | 50 μm | | — | — | A | A | B |
| | | 250 μm | | — | — | A | A | A |

| | | | | | |
|---|---|---|---|---|---|
| Relative permittivity | — | — | A | A | B |
| Change in relative permittivity | — | — | A | A | B |
| before and after exposure | | | | | |
| Moisture permeability | — | — | A | A | B |

| | | | Example | | | | | | |
|---|---|---|---|---|---|---|---|---|---|
| Eighth table (4) | | | 6-55 | 6-56 | 6-57 | 6-58 | 6-59 | 6-60 | 6-61 |
| Solid content | Compound A | St/MAA/MMA/GMA-MAA = | | | | | | | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | 60 | 60 | 60 | 60 | 60 | 60 | |
| | | 53.5/14.5/32 (mass ratio) | | | | | | | |
| | Compound β | Isoquinoline | | | | | | | 3.5 (20) |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | | | | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | 6.2 (20) | | | | | | |
| | | Pyridine | | 1.9 (20) | | | | | |
| | | 2,4-Dimethylquinoline | | | 3.8 (20) | 1.9 (10) | | | |
| | | 4-Aminopyridine | | | | | 2.3 (20) | | |
| | | 2-Chloropyridine | | | | | | 2.7 (20) | |
| | Polymerizable | DPHA | 12.6 | 12.6 | 12.6 | 12.6 | 12.6 | 12.6 | |
| | compound | A-NOD-N | 25.0 | 25.0 | 25.0 | 25.0 | 25.0 | 25.0 | |
| | | DTMPT | | | | | | | 18.8 |
| | | A-DCP | | | | | | | |
| | | TMPT | | | | | | | 18.8 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | D | D | A | B | D | D | B |
| photosensitive | [measurement of ashing] | | | | | | | | |
| material | ε365/ε313 | | >3 | <1 | <1 | <1 | <1 | <1 | <1 |
| | Pattern | 25 μm | B | C | A | B | C | C | B |
| | formability | 50 μm | B | C | A | A | C | C | A |
| | | 250 μm | B | C | A | A | C | C | A |
| | Relative permittivity | | C | C | A | A | C | C | A |
| | Change in relative permittivity | | C | C | A | A | C | C | A |
| | before and after exposure | | | | | | | | |
| Evaluation of | Carboxy group consumption rate | | D | D | A | B | D | D | B |
| transfer film | [measurement of ashing] | | | | | | | | |
| | ε365/ε313 | | >3 | <1 | <1 | <1 | <1 | <1 | <1 |
| | Transmittance at 365 nm | | C | B | A | A | B | B | A |
| | Transmittance at 365 nm/ | | C | B | A | A | B | B | A |
| | transmittance at 313 nm | | | | | | | | |
| | Laminate suitability | | A | A | A | A | A | A | A |
| | Pattern | 25 μm | B | C | A | B | C | C | B |
| | formability | 50 μm | B | C | A | A | C | C | A |
| | | 250 μm | B | C | A | A | C | C | A |

| | | | | | | | |
|---|---|---|---|---|---|---|---|
| Relative permittivity | C | C | A | A | C | C | A |
| Change in relative permittivity | C | C | A | A | C | C | A |
| before and after exposure | | | | | | | |
| Moisture permeability | B | B | A | A | C | C | A |

| | | | Example | | | | | | |
|---|---|---|---|---|---|---|---|---|---|
| Eighth table (4) | | | 6-62 | 6-63 | 6-64 | 6-65 | 6-66 | 6-67 | 6-68 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | 3.5 (20) | | | | | | |
| | molar ratio | Acridine | | 4.9 (20) | | | | | |
| | with respect to | 1-n-Butylisoquinoline | | | 5.0 (20) | | | | |
| | carboxy group | 1-n-Butyl-4-methylisoquinoline | | | | 5.4 (20) | | | |
| | of compound A | 1-Me-isoquinoline | | | | | 3.9 (20) | | |
| | having acid group | 2,4,5,7-Tetramethylquinoline | | | | | | 5.0 (20) | |
| | (mol %)) | 2-Methyl-4-methoxyquinoline | | | | | | | 4.7 (20) |
| | | 9-Methylacridine | | | | | | | |
| | | 9-Phenylacridine | | | | | | | |
| | | Pyridine | | | | | | | |
| | | 2,4-Dimethylquinoline | | | | | | | |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 18.8 | 18.8 | 18.8 | 18.8 | 18.8 | 18.8 | 18.8 |
| | | A-DCP | | | | | | | |
| | | TMPT | 18.8 | 18.8 | 18.8 | 18.8 | 18.8 | 18.8 | 18.8 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | B | D | A | A | A | A | A |
| photosensitive | [measurement of ashing] | | | | | | | |
| material | ε365/ε313 | <1 | >3 | <1 | <1 | <1 | <1 | <1 |

| | | | | | | | | |
|---|---|---|---|---|---|---|---|---|
| Pattern | 25 μm | B | C | A | A | A | A | A |
| formability | 50 μm | A | B | A | A | A | A | A |
| | 250 μm | A | A | A | A | A | A | A |

| | | | | | | | | |
|---|---|---|---|---|---|---|---|---|
| | Relative permittivity | A | B | A | A | A | A | A |
| | Change in relative permittivity | A | B | A | A | A | A | A |
| | before and after exposure | | | | | | | |
| Evaluation of | Carboxy group consumption rate | B | D | A | A | A | A | A |
| transfer film | [measurement of ashing] | | | | | | | |
| | ε365/ε313 | <1 | >3 | <1 | <1 | <1 | <1 | <1 |
| | Transmittance at 365 nm | A | C | A | A | A | A | A |
| | Transmittance at 365 nm/ | A | C | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | B | C | A | A | A | A | A |
| formability | 50 μm | A | B | A | A | A | A | A |
| | 250 μm | A | A | A | A | A | A | A |

| | | | | | | | |
|---|---|---|---|---|---|---|---|
| Relative permittivity | A | B | A | A | A | A | A |
| Change in relative permittivity | A | B | A | A | A | A | A |
| before and after exposure | | | | | | | |
| Moisture permeability | B | B | A | A | A | A | A |

TABLE 43

| | | | Mw of | pKa of | | | | |
|---|---|---|---|---|---|---|---|---|
| | | | compound A | Compound β | ε365 of | Example | | |
| Eighth table (5) | | | having acid group | in ground state | Compound β | 6-69 | 6-70 | 6-71 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | 5.2 (20) | | |
| | | 9-Phenylacridine | | 4.04 | >10000 | | 6.9 (20) | |
| | | Pyridine | | 5.25 | <10 | | | 2.1 (20) |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | | | |
| | compound | A-NOD-N | | — | — | | | |
| | | DTMPT | | — | — | 18.8 | 18.8 | 18.8 |
| | | A-DCP | | — | — | | | |
| | | TMPT | | — | — | 18.8 | 18.8 | 18.8 |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | C | D | D |
| photosensitive | [measurement of ashing] | | | | | | | |
| material | ε365/ε313 | | | — | — | >3 | >3 | <1 |
| | Pattern | 25 μm | | — | — | B | B | C |
| | formability | 50 μm | | — | — | B | B | C |
| | | 250 μm | | — | — | A | B | C |
| | Relative permittivity | | | — | — | B | C | C |
| | Change in relative permittivity | | | — | — | B | C | C |
| | before and after exposure | | | | | | | |
| Evaluation of | Carboxy group consumption rate | | | — | — | C | D | D |
| transfer film | [measurement of ashing] | | | | | | | |
| | ε365/ε313 | | | — | — | >3 | >3 | <1 |
| | Transmittance at 365 nm | | | — | — | C | C | B |
| | Transmittance at 365 nm/ | | | — | — | C | C | B |
| | transmittance at 313 nm | | | | | | | |
| | Laminate suitability | | | — | — | A | A | A |
| | Pattern | 25 μm | | — | — | B | B | C |
| | formability | 50 μm | | — | — | B | B | C |
| | | 250 μm | | — | — | A | B | C |

| | | | | | |
|---|---|---|---|---|---|
| Relative permittivity | — | — | B | C | C |
| Change in relative permittivity | — | — | B | C | C |
| before and after exposure | | | | | |
| Moisture permeability | — | — | B | B | B |

| | | | Example | | | | | | |
|---|---|---|---|---|---|---|---|---|---|
| Eighth table (5) | | | 6-72 | 6-73 | 6-74 | 6-75 | 6-76 | 6-77 | 6-78 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | | | 3.9 (20) | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 4.3 (20) | 2.1 (10) | | | | 4.3 (20) | 2.1 (10) |
| | | 4-Aminopyridine | | | 2.6 (20) | | | | |
| | | 2-Chloropyridine | | | | 3.1 (20) | | | |
| | Polymerizable | DPHA | | | | | | | |
| | compound | A-NOD-N | | | | | | | |
| | | DTMPT | 18.8 | 18.8 | 18.8 | 18.8 | | | |
| | | A-DCP | | | | | 25.0 | 25.0 | 25.0 |
| | | TMPT | 18.8 | 18.8 | 18.8 | 18.8 | 12.6 | 12.6 | 12.6 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | B | D | D | A | A | B |
| photosensitive | [measurement of ashing] | | | | | | | | |
| material | ε365/ε313 | | <1 | <1 | <1 | <1 | <1 | <1 | <1 |
| | Pattern | 25 μm | A | B | C | C | A | A | B |
| | formability | 50 μm | A | A | C | C | A | A | A |
| | | 250 μm | A | A | C | C | A | A | A |
| | Relative permittivity | | A | A | C | C | A | A | A |
| | Change in relative permittivity | | A | A | C | C | A | A | A |
| | before and after exposure | | | | | | | | |
| Evaluation of | Carboxy group consumption rate | | A | B | D | D | A | A | B |
| transfer film | [measurement of ashing] | | | | | | | | |
| | ε365/ε313 | | <1 | <1 | <1 | <1 | <1 | <1 | <1 |
| | Transmittance at 365 nm | | A | A | B | B | A | A | A |
| | Transmittance at 365 nm/ | | A | A | B | B | A | A | A |
| | transmittance at 313 nm | | | | | | | | |
| | Laminate suitability | | A | A | A | A | A | A | A |
| | Pattern | 25 μm | A | B | C | C | A | A | B |
| | formability | 50 μm | A | A | C | C | A | A | A |
| | | 250 μm | A | A | C | C | A | A | A |

| | | | | | | | |
|---|---|---|---|---|---|---|---|
| Relative permittivity | A | A | C | C | A | A | A |
| Change in relative permittivity | A | A | C | C | A | A | A |
| before and after exposure | | | | | | | |
| Moisture permeability | A | A | C | C | A | A | A |

| | | | Example | | | | | | |
|---|---|---|---|---|---|---|---|---|---|
| Eighth table (5) | | | 6-79 | 6-80 | 6-81 | 6-82 | 6-83 | 6-84 | 6-85 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.9 (20) | | | 3.9 (20) | | | 3.9 (20) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | 4.3 (20) | 2.1 (10) | | 4.3 (20) | 2.1 (10) | |
| | | 4-Aminopyridine | | | | | | | |
| | | 2-Chloropyridine | | | | | | | |
| | Polymerizable | DPHA | | | | | | | 12.6 |
| | compound | A-NOD-N | | | | 12.6 | 12.6 | 12.6 | 12.6 |
| | | DTMPT | 12.6 | 12.6 | 12.6 | | | | 12.6 |
| | | A-DCP | 12.6 | 12.6 | 12.6 | 12.6 | 12.6 | 12.6 | |
| | | TMPT | 12.6 | 12.6 | 12.6 | 12.6 | 12.6 | 12.6 | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | A | B | A | A | B | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | B | A | A | B | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | A | B | A | A | B | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | B | A | A | B | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 44

| | | | Mw of | pKa of | | | | |
|---|---|---|---|---|---|---|---|---|
| | | | compound A | Compound β | ε365 of | Example | | |
| Eighth table (6) | | | having acid group | in ground state | Compound β | 5-86 | 6-87 | 6-88 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | 3.9 (20) |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | 4.3 (20) | 2.1 (10) | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 12.6 | 12.6 | 12.6 |
| | | DTMPT | | — | — | 12.6 | 12.6 | |
| | | A-DCP | | — | — | | | |
| | | TMPT | | — | — | | | |
| | | SR601 | | — | — | | | 12.6 |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | B | A |
| photosensitive | [measurement of ashing] | | | | | | | |
| material | ε365/ε313 | | | — | — | <1 | <1 | <1 |
| | Pattern | 25 μm | | — | — | A | B | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | B | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | B | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

| | | | Example | | | | | | |
|---|---|---|---|---|---|---|---|---|---|
| Eighth table (6) | | | 5-89 | 6-90 | 6-91 | 6-92 | 6-93 | 6-94 | 6-95 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | 3.9 (20) | | | 3.9 (20) | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 4.3 (20) | 2.1 (10) | | 4.3 (20) | 2.1 (10) | | 4.3 (20) |
| | | 4-Aminopyridine | | | | | | | |
| | | 2-Chloropyridine | | | | | | | |
| | Polymerizable | DPHA | 12.6 | 12.6 | | | | | |
| | compound | A-NOD-N | 12.6 | 12.6 | 12.6 | 12.6 | 12.6 | 12.6 | 12.6 |
| | | DTMPT | | | 12.6 | 12.6 | 12.6 | 12.6 | 12.6 |
| | | A-DCP | | | | | | | |
| | | TMPT | | | | | | | |
| | | SR601 | 12.6 | 12.6 | | | | | |
| | | KRM8904 | | | | | | 12.6 | 12.6 |
| | | KRM8452 | | | 12.6 | 12.6 | 12.6 | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | B | A | A | B | A | A |
| photosensitive | [measurement of ashing] | | | | | | | | |
| material | ε365/ε313 | | <1 | <1 | <1 | <1 | <1 | <1 | <1 |
| | Pattern | 25 μm | A | B | A | A | B | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | B | A | A | B | A | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | B | A | A | B | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

| | | | Example | | | | | | |
|---|---|---|---|---|---|---|---|---|---|
| Eighth table (6) | | | 5-96 | 6-97 | 6-98 | 6-99 | 6-100 | 6-101 | 6-102 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | 3.9 (20) | | | 3.9 (20) | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 2.1 (10) | | 4.3 (20) | 2.1 (10) | | 4.3 (20) | 2.1 (10) |
| | | 4-Aminopyridine | | | | | | | |
| | | 2-Chloropyridine | | | | | | | |
| | Polymerizable | DPHA | | 12.6 | 12.6 | 12.6 | 12.6 | 12.6 | 12.6 |
| | compound | A-NOD-N | 12.6 | 25.0 | 25.0 | 25.0 | 25.0 | 25.0 | 25.0 |
| | | DTMPT | 12.6 | | | | | | |
| | | A-DCP | | | | | | | |
| | | TMPT | | | | | | | |
| | | SR601 | | | | | | | |
| | | KRM8904 | 12.6 | | | | | | |
| | | KRM8452 | | | | | | | |
| | Surfactant | F551A | 0.1 | | | | 0.2 | 0.2 | 0.2 |
| | | R41 | | | | | | | |
| | | 710FL | | | | | | | |

| | | | | | | | | |
|---|---|---|---|---|---|---|---|---|
| Evaluation of | Carboxy group consumption rate | B | A | A | B | A | A | B |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | B | A | A | B | A | A | B |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | B | A | A | B | A | A | B |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | B | A | A | B | A | A | B |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 45

| | | | Mw of | pKa of | | | | |
|---|---|---|---|---|---|---|---|---|
| | | | compound A | Compound β | ε365 of | Example | | |
| Eighth table (7) | | | having acid group | in ground state | Compound β | 5-103 | 6-104 | 6-105 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | 3.9 (20) | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | | 4.3 (20) | 2.1 (10) |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.5 | 0.5 | 0.5 |
| | | R41 | | — | — | | | |
| | | 710FL | | — | — | | | |
| Evaluation of | Carboxy group consumption rate | | | — | — | A | A | B |
| photosensitive | [measurement of ashing] | | | | | | | |
| material | ε365/ε313 | | | — | — | <1 | <1 | <1 |
| | Pattern | 25 μm | | — | — | A | A | B |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | A | B |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | B |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

| | | | Example | | | | | | |
|---|---|---|---|---|---|---|---|---|---|
| Eighth table (7) | | | 5-106 | 6-107 | 6-108 | 6-109 | 6-110 | 6-111 | 6-112 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.9 (20) | | | 3.9 (20) | | | 3.9 (20) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | 4.3 (20) | 2.1 (10) | | 4.3 (20) | 2.1 (10) | |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 10.0 |
| | compound | A-NOD-N | 25.0 | 25.0 | 25.0 | 25.0 | 25.0 | 25.0 | 20.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | | | | | | | 0.1 |
| | | R41 | 0.1 | 0.1 | 0.1 | | | | |
| | | 710FL | | | | 0.1 | 0.1 | 0.1 | |
| Evaluation of | Carboxy group consumption rate | | A | A | B | A | A | B | A |
| photosensitive | [measurement of ashing] | | | | | | | | |
| material | ε365/ε313 | | <1 | <1 | <1 | <1 | <1 | <1 | <1 |
| | Pattern | 25 μm | A | A | B | A | A | B | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | A | B | A | A | B | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | B | A | A | B | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

| | | | Example | | | | | | |
|---|---|---|---|---|---|---|---|---|---|
| Eighth table (7) | | | 6-113 | 6-114 | 6-115 | 6-116 | 6-117 | 6-118 | 6-119 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | 3.9 (20) | | | 3.9 (20) | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 4.3 (20) | 2.1 (10) | | 4.3 (20) | 2.1 (10) | | 2.1 (10) |
| | | 4-Aminopyridine | | | | | | | |
| | | 2-Chloropyridine | | | | | | | |
| | Polymerizable | DPHA | 10.0 | 10.0 | 14.0 | 14.0 | 14.0 | 28.0 | 28.0 |
| | compound | A-NOD-N | 20.0 | 20.0 | 28.0 | 28.0 | 28.0 | 14.0 | 14.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | B | A | A | B | A | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | B | A | A | B | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | B | A | A | B | A | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | B | A | A | B | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 46

| | | | Mw of | pKa of | | | | |
|---|---|---|---|---|---|---|---|---|
| | | | compound A | Compound β | ε365 of | Example | | |
| Eighth table (8) | | | having acid group | in ground state | Compound β | 5-120 | 6-121 | 6-122 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | 3.9 (20) | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | 2.1 (10) | | 4.3 (20) |
| | | 4-Aminopyridine | | 9.20 | <100 | | | |
| | | 2-Chloropyridine | | 0.70 | <10 | | | |
| | Polymerizable | DPHA | | — | — | 28.0 | | |
| | compound | A-NOD-N | | — | — | 14.0 | | |
| | | DTMPT | | — | — | | 21.0 | 21.0 |
| | | A-DCP | | — | — | | | |
| | | TMPT | | — | — | | 21.0 | 21.0 |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | B | A | A |
| photosensitive | [measurement of ashing] | | | | | | | |
| material | ε365/ε313 | | | — | — | <1 | <1 | <1 |
| | Pattern | 25 μm | | — | — | B | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | B | A | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | B | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

| | | | Example | | | | | | |
|---|---|---|---|---|---|---|---|---|---|
| Eighth table (8) | | | 5-123 | 6-124 | 6-125 | 6-126 | 6-127 | 6-128 | 6-129 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | 3.9 (20) | | | 3.9 (20) | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 2.1 (10) | | 4.3 (20) | 2.1 (10) | | 4.3 (20) | 2.1 (10) |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 21.0 | 10.0 | 10.0 | 10.0 | 30.0 | 30.0 | 30.0 |
| | | A-DCP | | | | | | | |
| | | TMPT | 21.0 | 32.0 | 32.0 | 32.0 | 12.0 | 12.0 | 12.0 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | B | A | A | B | A | A | B |
| photosensitive | [measurement of ashing] | | | | | | | | |
| material | ε365/ε313 | | <1 | <1 | <1 | <1 | <1 | <1 | <1 |
| | Pattern | 25 μm | B | A | A | B | A | A | B |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | B | A | A | B | A | A | B |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | B | A | A | B | A | A | B |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

| | | | Example | | | | | | |
|---|---|---|---|---|---|---|---|---|---|
| Eighth table (8) | | | 6-130 | 6-131 | 6-132 | 6-133 | 6-134 | 6-135 | 6-136 |
| Solid content | Compound A | St/MAA/MMA/GMA-MAA = | | | | 60 | 60 | 60 | 30 |
| blending | having acid group | 47.7/19.0/1.3/32.0 (mass ratio) | | | | | | | |
| | | CHMA/MAA/BzMA = | | | | | | | 30 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | 60 | 60 | 60 | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.5 (20) | | | 3.9 (20) | | | 3.9 (20) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | 3.8 (20) | 1.9 (10) | | 4.3 (20) | 2.1 (10) | |
| | | 4-Aminopyridine | | | | | | | |
| | | 2-Chloropyridine | | | | | | | |
| | Polymerizable | DPHA | | | | 16.0 | 16.0 | 16.0 | 12.6 |
| | compound | A-NOD-N | | | | 32.0 | 32.0 | 32.0 | 25.0 |
| | | DTMPT | 21.0 | 21.0 | 21.0 | | | | |
| | | A-DCP | | | | | | | |
| | | TMPT | 21.0 | 21.0 | 21.0 | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | A | B | A | A | B | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | B | A | A | B | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | A | B | A | A | B | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | B | A | A | B | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 47

| | | | Mw of | pKa of | | | | |
|---|---|---|---|---|---|---|---|---|
| | | | compound A | Compound β | ε365 of | Example | | |
| Eighth table (9) | | | having acid group | in ground state | Compound β | 6-137 | 6-138 | 6-139 |
| Solid content | Compound A | St/MAA/MMA/GMA-MAA = | 18000 | — | — | 30 | 30 | |
| blending | having acid group | 47.7/19.0/1.3/32.0 (mass ratio) | | | | | | |
| | | CHMA/MAA/BzMA = | 24000 | — | — | 30 | 30 | |
| | | 49/19/32 (mass ratio) | | | | | | |
| | | St/AA/AA-GMA = | 16000 | — | — | | | 30 |
| | | 53.5/14.5/32 (mass ratio) | | | | | | |
| | | CHA/AA/HEA = | 40000 | — | — | | | 30 |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | 3.5 (20) |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | 4.3 (20) | 2.1 (10) | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | B | A |
| photosensitive | [measurement of ashing] | | | | | | | |
| material | ε365/ε313 | | | — | — | <1 | <1 | <1 |
| | Pattern | 25 μm | | — | — | A | B | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | B | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | B | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

| | | | Example | | | | | | |
|---|---|---|---|---|---|---|---|---|---|
| Eighth table (9) | | | 6-140 | 6-141 | 6-142 | 6-143 | 6-144 | 6-145 | 6-146 |
| Solid content | Compound A | St/MAA/MMA/GMA-MAA = | | | 60 | 60 | 60 | | |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | 30 | 30 | | | | | |
| | | 53.5/14.5/32 (mass ratio) | | | | | | | |
| | | CHA/AA/HEA = | 30 | 30 | | | | 60 | 60 |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | 1.9 (10) | 1.0 (5) | 1.0 (5) | 1.7 (10) | 0.8 (5) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 3.8 (20) | 1.9 (10) | 2.1 (10) | 3.1 (15) | 1.0 (5) | 1.9 (10) | 2.8 (15) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | B | A | A | B | A | A |
| photosensitive | [measurement of ashing] | | | | | | | | |
| material | ε365/ε313 | | <1 | <1 | <1 | <1 | <1 | <1 | <1 |
| | Pattern | 25 μm | A | B | A | A | B | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | B | A | A | B | A | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | B | A | A | B | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

| | | | Example | | | | | | |
|---|---|---|---|---|---|---|---|---|---|
| Eighth table (9) | | | 6-147 | 6-148 | 6-149 | 6-150 | 6-151 | 6-152 | 6-153 |
| Solid content | Compound A | St/MAA/MMA/GMA-MAA = | | 30 | 30 | 30 | | | |
| blending | having acid group | 47.7/19.0/1.3/32.0 (mass ratio) | | | | | | | |
| | | CHMA/MAA/BzMA = | | 30 | 30 | 30 | | | |
| | | 49/19/32 (mass ratio) | | | | | | | |
| | | St/AA/AA-GMA = | | | | | 30 | 30 | 30 |
| | | 53.5/14.5/32 (mass ratio) | | | | | | | |
| | | CHA/AA/HEA = | 60 | | | | 30 | 30 | 30 |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 0.8 (5) | 3.9 (20) | | | 3.5 (20) | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 0.9 (5) | | 4.3 (20) | 2.1 (10) | | 3.8 (20) | 1.9 (10) |
| | | 4-Aminopyridine | | | | | | | |
| | | 2-Chloropyridine | | | | | | | |
| | Polymerizable | DPHA | 12.6 | | | | | | |
| | compound | A-NOD-N | 25.0 | | | | | | |
| | | DTMPT | | 21.0 | 21.0 | 21.0 | 21.0 | 21.0 | 21.0 |
| | | A-DCP | | | | | | | |
| | | TMPT | | 21.0 | 21.0 | 21.0 | 21.0 | 21.0 | 21.0 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | B | A | A | B | A | A | B |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | B | A | A | B | A | A | B |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | B | A | A | B | A | A | B |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | B | A | A | B | A | A | B |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 48

| | | | Mw of | pKa of | | | | |
|---|---|---|---|---|---|---|---|---|
| | | | compound A | Compound β | ε365 of | Example | | |
| Eighth table (10) | | | having acid group | in ground state | Compound β | 6-154 | 6-155 | 6-156 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | 1.9 (10) | 1.0 (5) | 1.0 (5) |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | 2.1 (10) | 3.1 (15) | 1.0 (5) |
| | | 4-Aminopyridine | | 9.20 | <100 | | | |
| | | 2-Chloropyridine | | 0.70 | <10 | | | |
| | Polymerizable | DPHA | | — | — | | | |
| | compound | A-NOD-N | | — | — | | | |
| | | DTMPT | | — | — | 21.0 | 21.0 | 21.0 |
| | | A-DCP | | — | — | | | |
| | | TMPT | | — | — | 21.0 | 21.0 | 21.0 |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | A | B |
| photosensitive | [measurement of ashing] | | | | | | | |
| material | ε365/ε313 | | | — | — | <1 | <1 | <1 |
| | Pattern | 25 μm | | — | — | A | A | B |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | A | B |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | B |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

| | | | Example | | | | | | |
|---|---|---|---|---|---|---|---|---|---|
| Eighth table (10) | | | 6-157 | 6-158 | 6-159 | 6-160 | 6-161 | 6-162 | 6-163 |
| Solid content | Compound A | St/MAA/MMA/GMA-MAA = | | | | 30 | 30 | 30 | |
| blending | having acid group | 47.7/19.0/1.3/32.0 (mass ratio) | | | | | | | |
| | | CHMA/MAA/BzMA = | | | | 30 | 30 | 30 | |
| | | 49/19/32 (mass ratio) | | | | | | | |
| | | St/AA/AA-GMA = | | | | | | | 30 |
| | | 53.5/14.5/32 (mass ratio) | | | | | | | |
| | | CHA/AA/HEA = | 60 | 60 | 60 | | | | 30 |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 1.7 (10) | 0.8 (5) | 0.8 (5) | 1.9 (10) | 1.0 (5) | 1.0 (5) | 1.7 (10) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 1.9 (10) | 2.8 (15) | 0.9 (5) | 2.1 (10) | 3.1 (15) | 1.0 (5) | 1.9 (10) |
| | | 4-Aminopyridine | | | | | | | |
| | | 2-Chloropyridine | | | | | | | |
| | Polymerizable | DPHA | | | | 12.6 | 12.6 | 12.6 | 12.6 |
| | compound | A-NOD-N | | | | 25.0 | 25.0 | 25.0 | 25.0 |
| | | DTMPT | 21.0 | 21.0 | 21.0 | | | | |
| | | A-DCP | | | | | | | |
| | | TMPT | 21.0 | 21.0 | 21.0 | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | A | B | A | A | B | A |
| photosensitive | [measurement of ashing] | | | | | | | | |
| material | ε365/ε313 | | <1 | <1 | <1 | <1 | <1 | <1 | <1 |
| | Pattern | 25 μm | A | A | B | A | A | B | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | A | B | A | A | B | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | B | A | A | B | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

| | | | Example | | | | | | |
|---|---|---|---|---|---|---|---|---|---|
| Eighth table (10) | | | 6-164 | 6-165 | 6-166 | 6-167 | 6-168 | 6-169 | 6-170 |
| Solid content | Compound A | St/MAA/MMA/GMA-MAA = | | | 30 | 30 | 30 | | |
| blending | having acid group | 47.7/19.0/1.3/32.0 (mass ratio) | | | | | | | |
| | | CHMA/MAA/BzMA = | | | 30 | 30 | 30 | | |
| | | 49/19/32 (mass ratio) | | | | | | | |
| | | St/AA/AA-GMA = | 30 | 30 | | | | 30 | 30 |
| | | 53.5/14.5/32 (mass ratio) | | | | | | | |
| | | CHA/AA/HEA = | 30 | 30 | | | | 30 | 30 |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 0.8 (5) | 0.8 (5) | 1.9 (10) | 1.0 (5) | 1.0 (5) | 1.7 (10) | 0.8 (5) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 2.8 (15) | 0.9 (5) | 2.1 (10) | 3.1 (15) | 1.0 (5) | 1.9 (10) | 2.8 (15) |
| | | 4-Aminopyridine | | | | | | | |
| | | 2-Chloropyridine | | | | | | | |
| | Polymerizable | DPHA | 12.6 | 12.6 | | | | | |
| | compound | A-NOD-N | 25.0 | 25.0 | | | | | |
| | | DTMPT | | | 21.0 | 21.0 | 21.0 | 21.0 | 21.0 |
| | | A-DCP | | | | | | | |
| | | TMPT | | | 21.0 | 21.0 | 21.0 | 21.0 | 21.0 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | B | A | A | B | A | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | B | A | A | B | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | B | A | A | B | A | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | B | A | A | B | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 49

| | | | Mw of | pKa of | | | |
|---|---|---|---|---|---|---|---|
| | | | compound A | Compound β | ε365 of | Example | |
| Eighth table (11) | | | having acid group | in ground state | Compound β | 6-171 | 6-172 |
| Solid content | Compound A | St/MAA/MMA/GMA-MAA = | 18000 | — | — | | 30 |
| blending | having acid group | 47.7/19.0/1.3/32.0 (mass ratio) | | | | | |
| | | CHMA/MAA/BzMA = | 24000 | — | — | | 30 |
| | | 49/19/32 (mass ratio) | | | | | |
| | | St/AA/AA-GMA = | 16000 | — | — | 30 | |
| | | 53.5/14.5/32 (mass ratio) | | | | | |
| | | CHA/AA/HEA = | 40000 | — | — | 30 | |
| | | 53.5/14.5/32 (mass ratio) | | | | | |
| | Compound β | Isoquinoline | | 4.69 | <10 | | |
| | (in parentheses: | Quinoline | | 4.15 | <10 | | |
| | molar ratio | Acridine | | 4.67 | 4900 | | |
| | with respect to | 1-n-Butylisoquinoline | | 5.27 | <10 | | |
| | carboxy group | 1-n-Butyl-4-methylisoquinoline | | 5.9 | <10 | | |
| | of compound A | 1-Me-isoquinoline | | 5.31 | <10 | 0.8 (5) | 1.9 (10) |
| | having acid group | 2,4,5,7-Tetramethylquinoline | | 6.23 | <10 | | |
| | (mol %)) | 2-Methyl-4-methoxyquinoline | | 6.51 | <10 | | |
| | | 9-Methylacridine | | 5.4 | 6300 | | |
| | | 9-Phenylacridine | | 4.04 | >10000 | | |
| | | Pyridine | | 5.25 | <10 | | |
| | | 2,4-Dimethylquinoline | | 5.67 | <10 | 0.9 (5) | 2.1 (10) |
| | | 4-Aminopyridine | | 9.20 | <100 | | |
| | | 2-Chloropyridine | | 0.70 | <10 | | |
| | Polymerizable | DPHA | | — | — | | 12.0 |
| | compound | A-NOD-N | | — | — | | 12.0 |
| | | DTMPT | | — | — | 21.0 | 12.0 |
| | | A-DCP | | — | — | | |
| | | TMPT | | — | — | 21.0 | 12.0 |
| | | SR601 | | — | — | | |
| | | KRM8904 | | — | — | | |
| | | KRM8452 | | — | — | | |
| | Surfactant | F551A | | — | — | 0.1 | 0.1 |
| | | R41 | | — | — | | |
| | | 710FL | | — | — | | |
| Evaluation of | Carboxy group consumption rate | | | — | — | B | A |
| photosensitive | [measurement of ashing] | | | | | | |
| material | ε365/ε313 | | | — | — | <1 | <1 |
| | Pattern | 25 μm | | — | — | B | A |
| | formability | 50 μm | | — | — | A | A |
| | | 250 μm | | — | — | A | A |
| | Relative permittivity | | | — | — | A | A |
| | Change in relative permittivity | | | — | — | A | A |
| | before and after exposure | | | | | | |
| Evaluation of | Carboxy group consumption rate | | | — | — | B | A |
| transfer film | [measurement of ashing] | | | | | | |
| | ε365/ε313 | | | — | — | <1 | <1 |
| | Transmittance at 365 nm | | | — | — | A | A |
| | Transmittance at 365 nm/ | | | — | — | A | A |
| | transmittance at 313 nm | | | | | | |
| | Laminate suitability | | | — | — | A | A |
| | Pattern | 25 μm | | — | — | B | A |
| | formability | 50 μm | | — | — | A | A |
| | | 250 μm | | — | — | A | A |

| | | | | |
|---|---|---|---|---|
| Relative permittivity | — | — | A | A |
| Change in relative permittivity | — | — | A | A |
| before and after exposure | | | | |
| Moisture permeability | | | A | A |

| | | | | | | | | Comparative |
|---|---|---|---|---|---|---|---|---|
| | | | Example | | | | | Example |
| Eighth table (11) | | | 6-173 | 6-174 | 6-175 | 6-176 | 6-177 | 6A |
| Solid content | Compound A | St/MAA/MMA/GMA-MAA = | 30 | 30 | | | | 60 |
| blending | having acid group | 47.7/19.0/1.3/32.0 (mass ratio) | | | | | | |
| | | CHMA/MAA/BzMA = | 30 | 30 | | | | |
| | | 49/19/32 (mass ratio) | | | | | | |
| | | St/AA/AA-GMA = | | | 30 | 30 | 30 | |
| | | 53.5/14.5/32 (mass ratio) | | | | | | |
| | | CHA/AA/HEA = | | | 30 | 30 | 30 | |
| | | 53.5/14.5/32 (mass ratio) | | | | | | |
| | Compound β | Isoquinoline | | | | | | |
| | (in parentheses: | Quinoline | | | | | | |
| | molar ratio | Acridine | | | | | | |
| | with respect to | 1-n-Butylisoquinoline | | | | | | |
| | carboxy group | 1-n-Butyl-4-methylisoquinoline | | | | | | |
| | of compound A | 1-Me-isoquinoline | 1.0 (5) | 1.0 (5) | 1.7 (10) | 0.8 (5) | 0.8 (5) | |
| | having acid group | 2,4,5,7-Tetramethylquinoline | | | | | | |
| | (mol %)) | 2-Methyl-4-methoxyquinoline | | | | | | |
| | | 9-Methylacridine | | | | | | |
| | | 9-Phenylacridine | | | | | | |
| | | Pyridine | | | | | | |
| | | 2,4-Dimethylquinoline | 3.1 (15) | 1.0 (5) | 1.9 (10) | 2.8 (15) | 0.9 (5) | |
| | | 4-Aminopyridine | | | | | | |
| | | 2-Chloropyridine | | | | | | |
| | Polymerizable | DPHA | 12.0 | 12.0 | 12.0 | 12.0 | 12.0 | 12.6 |
| | compound | A-NOD-N | 12.0 | 12.0 | 12.0 | 12.0 | 12.0 | 25.0 |
| | | DTMPT | 12.0 | 12.0 | 12.0 | 12.0 | 12.0 | |
| | | A-DCP | | | | | | |
| | | TMPT | 12.0 | 12.0 | 12.0 | 12.0 | 12.0 | |
| | | SR601 | | | | | | |
| | | KRM8904 | | | | | | |
| | | KRM8452 | | | | | | |
| | Surfactant | F551A | 0.1 | 0.1 | 0.1 | 0.1 | 0.1 | 0.1 |
| | | R41 | | | | | | |
| | | 710FL | | | | | | |

| | | | | | | | |
|---|---|---|---|---|---|---|---|
| Evaluation of | Carboxy group consumption rate | A | B | A | A | B | E |
| photosensitive | [measurement of ashing] | | | | | | |
| material | ε365/ε313 | <1 | <1 | <1 | <1 | <1 | — |

| | | | | | | | |
|---|---|---|---|---|---|---|---|
| Pattern | 25 μm | A | B | A | A | B | D |
| formability | 50 μm | A | A | A | A | A | D |
| | 250 μm | A | A | A | A | A | D |

| | | | | | | | |
|---|---|---|---|---|---|---|---|
| | Relative permittivity | A | A | A | A | A | Standard |
| | Change in relative permittivity | A | A | A | A | A | D |
| | before and after exposure | | | | | | |
| Evaluation of | Carboxy group consumption rate | A | B | A | A | B | E |
| transfer film | [measurement of ashing] | | | | | | |
| | ε365/ε313 | <1 | <1 | <1 | <1 | <1 | — |
| | Transmittance at 365 nm | A | A | A | A | A | A |
| | Transmittance at 365 nm/ | A | A | A | A | A | B |
| | transmittance at 313 nm | | | | | | |
| | Laminate suitability | A | A | A | A | A | A |

| | | | | | | | |
|---|---|---|---|---|---|---|---|
| Pattern | 25 μm | A | B | A | A | B | D |
| formability | 50 μm | A | A | A | A | A | D |
| | 250 μm | A | A | A | A | A | D |

| | | | | | | |
|---|---|---|---|---|---|---|
| Relative permittivity | A | A | A | A | A | Standard |
| Change in relative permittivity | A | A | A | A | A | D |
| before and after exposure | | | | | | |
| Moisture permeability | A | A | A | A | A | Standard |

(Compound A Having Acid Group)

Polymers 1 to 4 corresponding the compound A having an acid group were synthesized by the same method as in Example 4 system described above. Abbreviations for the monomer forming each structural unit of the polymers are as described above.

Polymer 1: St/MAA/MMA/GMA-MAA=47.7/19.0/1.3/32.0 (mass ratio)

Polymer 2: CHMA/MAA/BzMA=49/19/32 (mass ratio)

Polymer 3: St/AA/AA-GMA=53.5/14.5/32 (mass ratio)

Polymer 4: CHA/AA/HEA=53.5/14.5/32 (mass ratio)

As shown in Eighth table, the weight-average molecular weight of the compound A shown in Eighth table was all in a range of 10,000 to 50,000.

(Polymerizable Compound)

DPHA: dipentaerythritol hexaacrylate (A-DPH manufactured by Shin-Nakamura Chemical Co., Ltd.)

A-NOD-N: 1,9-nonanediol diacrylate (A-NOD-N manufactured by Shin-Nakamura Chemical Co., Ltd.)

DTMPT: ditrimethylolpropane tetraacrylate (KAYARAD T-1420 (T) manufactured by Nippon Kayaku Co., Ltd.)

A-DCPP: dicyclopentane dimethanol diacrylate (A-DCP manufactured by Shin-Nakamura Chemical Co., Ltd.)

TMPT: trimethylolpropane triacrylate (A-TMPT manufactured by Shin-Nakamura Chemical Co., Ltd.)

SR601: ethoxylated (4) bisphenol A diacrylate (SR601 manufactured by TOMOE Engineering Co., Ltd.)

KRM8904: 9-functional aliphatic urethane acrylate (KRM8904 manufactured by Daicel-Allnex Ltd.)

KRM8452: 10-functional aliphatic urethane acrylate (KRM8452 manufactured by Daicel-Allnex Ltd.)

(Surfactant)

F551: MEGAFACE F551 (manufactured by DIC Corporation)

R41: MEGAFACE R-41 (manufactured by DIC Corporation)

710FL: FTERGENT 710FL (manufactured by NEOS COMPANY LIMITED)

From the results in the above tables, it was confirmed that, even in a case where the photosensitive material included a polymerizable compound, the objects of the present invention could be achieved with the transfer film according to the embodiment of the present invention.

### Example 7 System

<Preparation and Evaluation of Photosensitive Material>

Materials shown in Ninth table shown in the latter part were mixed and dissolved in a mixed solvent of propylene glycol monomethyl ether acetate/methyl ethyl ketone=50/50 (mass ratio) so that a blending ratio shown in Ninth table shown in the latter part was satisfied and a concentration of solid contents of the finally obtained photosensitive material was 25% by mass, thereby obtaining a photosensitive material.

In addition, for the obtained photosensitive material of each of Examples or Comparative Examples in Example 7 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, moisture permeability, and change in relative permittivity after double exposure were evaluated in the same manner as shown in Example 3 system. In addition, the carboxy group consumption rate, transmittance to light at 365 nm, and ratio of the transmittance to light at 365 nm to the transmittance to light at 313 nm of the photosensitive layer in the transfer film were also evaluated in the same manner as shown in Example 3 system. In addition, the physical properties of ε365/ε313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 7A.

Ninth table below shows blending of the solid content of the photosensitive material of each of Examples or Comparative Examples in Example 7 system, and the test results thereof

In the table, the value described in the column of “Solid content blending” indicates the content (part by mass) of each solid content component included in the photosensitive material of each of Examples or Comparative Examples. The value in parentheses in the compound β indicates a proportion (mol %) of the total number of structures (specific structures S1) capable of accepting an electron from the acid group included in the compound A, which are included in the compound β, to the total number of carboxy groups included in the compound A having an acid group (compound A) in the photosensitive material.

In addition, in the tables, the method for measuring “pKa of compound β in ground state” is as described above.

In addition, in the tables, the column of “ε365 of compound β” indicates a molar absorption coefficient ((cm·mol/L)⁻¹) of the compound β to light having a wavelength of 365 nm measured in acetonitrile.

In addition, the column of “ε365/ε313” in the evaluation of the photosensitive material and the evaluation of the transfer film indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values in acetonitrile.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

TABLE 50

| | | | Mw of | pKa of | | | | |
|---|---|---|---|---|---|---|---|---|
| | | | compound A | Compound β | ε365 of | Example | | |
| Ninth table (1) | | | having acid group | in ground state | Compound β | 7-1 | 7-2 | 7-3 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | 3.5 (20) | | |
| | (in parentheses: | Quinoline | | 4.15 | <10 | | 3.5 (20) | |
| | molar ratio | Acridine | | 4.67 | 4900 | | | 4.9 (20) |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >10000 | | | |
| | | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | B | B | D |
| photosensitive | [measurement of ashing] | | | | | | | |
| material | ε365/ε313 | | | — | — | <1 | <1 | >3 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | B |
| | Change in relative permittivity | | | — | — | A | A | B |
| | before and after exposure | | | | | | | |
| Evaluation of | Carboxy group consumption rate | | | — | — | B | B | D |
| transfer film | [measurement of ashing] | | | | | | | |
| | ε365/ε313 | | | — | — | <1 | <1 | >3 |
| | Transmittance at 365 nm | | | — | — | A | A | C |
| | Transmittance at 365 nm/ | | | — | — | A | A | C |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | B |
| Change in relative permittivity | — | — | A | A | B |
| before and after exposure | | | | | |
| Moisture permeability | — | — | A | B | B |
| Change in relative permittivity | — | — | A | B | A |
| after double exposure | | | | | |

| | | | Example | | | | | | |
|---|---|---|---|---|---|---|---|---|---|
| Ninth table (1) | | | 7-4 | 7-5 | 7-6 | 7-7 | 7-8 | 7-9 | 7-10 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | 5.0 (20) | | | | | | |
| | carboxy group | 1-n-Butyl-4-methylisoquinoline | | 5.4 (20) | | | | | |
| | of compound A | 1-Me-isoquinoline | | | 3.9 (20) | | | | |
| | having acid group | 2,4,5,7-Tetramethylquinoline | | | | 5.0 (20) | | | |
| | (mol %)) | 2-Methyl-4-methoxyquinoline | | | | | 4.7 (20) | | |
| | | 9-Methylacridine | | | | | | 5.2 (20) | |
| | | 9-Phenylacridine | | | | | | | 6.9 (20) |
| | | Pyridine | | | | | | | |
| | | 2,4-Dimethylquinoline | | | | | | | |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | A | A | A | A | C | D |
| photosensitive | [measurement of ashing] | | | | | | | | |
| material | ε365/ε313 | | <1 | <1 | <1 | <1 | <1 | >3 | >3 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | B | C |
| | Change in relative permittivity | | A | A | A | A | A | B | C |
| | before and after exposure | | | | | | | | |
| Evaluation of | Carboxy group consumption rate | | A | A | A | A | A | C | D |
| transfer film | [measurement of ashing] | | | | | | | | |
| | ε365/ε313 | | <1 | <1 | <1 | <1 | <1 | >3 | >3 |
| | Transmittance at 365 nm | | A | A | A | A | A | C | C |
| | Transmittance at 365 nm/ | | A | A | A | A | A | C | C |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | B | C |
| Change in relative permittivity | A | A | A | A | A | B | C |
| before and after exposure | | | | | | | |
| Moisture permeability | A | A | A | A | A | B | B |
| Change in relative permittivity | A | A | A | A | A | B | C |
| after double exposure | | | | | | | |

| | | | Example | | | | | | |
|---|---|---|---|---|---|---|---|---|---|
| Ninth table (1) | | | 7-11 | 7-12 | 7-13 | 7-14 | 7-15 | 7-16 | 7-17 |
| Solid content | Compound A | St/MAA/MMA/GMA-MAA = | 60 | 60 | 60 | 60 | 60 | | |
| blending | having acid group | 47.7/19.0/1.3/32.0 (mass ratio) | | | | | | | |
| | | CHMA/MAA/BzMA = | | | | | | 60 | 60 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | 3.5 (20) | |
| | (in parentheses: | Quinoline | | | | | | | 3.5 (20) |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | | | | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | 2.1 (20) | | | | | | |
| | | 2,4-Dimethylquinoline | | 4.3 (20) | 2.1 (10) | | | | |
| | | 4-Aminopyridine | | | | 2.6 (20) | | | |
| | | 2-Chloropyridine | | | | | 3.1 (20) | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | D | A | B | D | D | B | B |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | C | A | A | C | C | A | A |
| | Change in relative permittivity | C | A | A | C | C | A | A |
| | before and after exposure | | | | | | | |
| Evaluation of | Carboxy group consumption rate | D | A | B | D | D | B | B |
| transfer film | [measurement of ashing] | | | | | | | |
| | ε365/ε313 | <1 | <1 | <1 | <1 | <1 | <1 | <1 |
| | Transmittance at 365 nm | B | A | A | B | B | A | A |
| | Transmittance at 365 nm/ | B | A | A | B | B | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | C | A | A | C | C | A | A |
| Change in relative permittivity | C | A | A | C | C | A | A |
| before and after exposure | | | | | | | |
| Moisture permeability | B | A | A | C | C | A | B |
| Change in relative permittivity | C | A | A | C | C | A | A |
| after double exposure | | | | | | | |

TABLE 51

| | | | Mw of | pKa of | | | | |
|---|---|---|---|---|---|---|---|---|
| | | | compound A | Compound β | ε365 of | Example | | |
| Ninth table (2) | | | having acid group | in ground state | Compound β | 7-18 | 7-19 | 7-20 |
| Solid content | Compound A | St/MAA/MMA/GMA-MAA = | 18000 | — | — | | | |
| blending | having acid group | 47.7/19.0/1.3/32.0 (mass ratio) | | | | | | |
| | | CHMA/MAA/BzMA = | 24000 | — | — | 60 | 60 | 60 |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | 4.9 (20) | | |
| | with respect to | 1-n-Butylisoquinoline | | 5.27 | <10 | | 5.0 (20) | |
| | carboxy group | 1-n-Butyl-4-methylisoquinoline | | 5.9 | <10 | | | 5.4 (20) |
| | of compound A | 1-Me-isoquinoline | | 5.31 | <10 | | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | D | A | A |
| photosensitive | [measurement of ashing] | | | | | | | |
| material | ε365/ε313 | | | — | — | >3 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | B | A | A |
| | Change in relative permittivity | | | — | — | B | A | A |
| | before and after exposure | | | | | | | |
| Evaluation of | Carboxy group consumption rate | | | — | — | D | A | A |
| transfer film | [measurement of ashing] | | | | | | | |
| | ε365/ε313 | | | — | — | >3 | <1 | <1 |
| | Transmittance at 365 nm | | | — | — | C | A | A |
| | Transmittance at 365 nm/ | | | — | — | C | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | B | A | A |
| Change in relative permittivity | — | — | B | A | A |
| before and after exposure | | | | | |
| Moisture permeability | — | — | B | A | A |
| Change in relative permittivity | — | — | B | A | A |
| after double exposure | | | | | |

| | | | Example | | | | | | |
|---|---|---|---|---|---|---|---|---|---|
| Ninth table (2) | | | 7-21 | 7-22 | 7-23 | 7-24 | 7-25 | 7-26 | 7-27 |
| Solid content | Compound A | St/MAA/MMA/GMA-MAA = | | | | | | | |
| blending | having acid group | 47.7/19.0/1.3/32.0 (mass ratio) | | | | | | | |
| | | CHMA/MAA/BzMA = | 60 | 60 | 60 | 60 | 60 | 60 | 60 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.9 (20) | | | | | | |
| | having acid group | 2,4,5,7-Tetramethylquinoline | | 5.0 (20) | | | | | |
| | (mol %)) | 2-Methyl-4-methoxyquinoline | | | 4.7 (20) | | | | |
| | | 9-Methylacridine | | | | 5.2 (20) | | | |
| | | 9-Phenylacridine | | | | | 6.9 (20) | | |
| | | Pyridine | | | | | | 2.1 (20) | |
| | | 2,4-Dimethylquinoline | | | | | | | 4.3 (20) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | A | A | C | D | D | A |
| photosensitive | [measurement of ashing] | | | | | | | | |
| material | ε365/ε313 | | <1 | <1 | <1 | >3 | >3 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | B | C | C | A |
| | Change in relative permittivity | | A | A | A | B | C | C | A |
| | before and after exposure | | | | | | | | |
| Evaluation of | Carboxy group consumption rate | | A | A | A | C | D | D | A |
| transfer film | [measurement of ashing] | | | | | | | | |
| | ε365/ε313 | | <1 | <1 | <1 | >3 | >3 | <1 | <1 |
| | Transmittance at 365 nm | | A | A | A | C | C | B | A |
| | Transmittance at 365 nm/ | | A | A | A | C | C | B | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | B | C | C | A |
| Change in relative permittivity | A | A | A | B | C | C | A |
| before and after exposure | | | | | | | |
| Moisture permeability | A | A | A | B | B | B | A |
| Change in relative permittivity | A | A | A | B | C | C | A |
| after double exposure | | | | | | | |

| | | | Example | | | | | | |
|---|---|---|---|---|---|---|---|---|---|
| Ninth table (2) | | | 7-28 | 7-29 | 7-30 | 7-31 | 7-32 | 7-33 | 7-34 |
| Solid content | Compound A | St/MAA/MMA/GMA-MAA = | | | | | | | |
| blending | having acid group | 47.7/19.0/1.3/32.0 (mass ratio) | | | | | | | |
| | | CHMA/MAA/BzMA = | 60 | 60 | 60 | | | | |
| | | 49/19/32 (mass ratio) | | | | | | | |
| | | St/AA/AA-GMA = | | | | 60 | 60 | 60 | 60 |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | 3.1 (20) | | | |
| | (in parentheses: | Quinoline | | | | | 3.1 (20) | | |
| | molar ratio | Acridine | | | | | | 4.3 (20) | |
| | with respect to | 1-n-Butylisoquinoline | | | | | | | 4.5 (20) |
| | carboxy group | 1-n-Butyl-4-methylisoquinoline | | | | | | | |
| | of compound A | 1-Me-isoquinoline | | | | | | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 2.1 (10) | | | | | | |
| | | 4-Aminopyridine | | 2.6 (20) | | | | | |
| | | 2-Chloropyridine | | | 3.1 (20) | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | B | D | D | B | B | D | A |
| photosensitive | [measurement of ashing] | | | | | | | |
| material | ε365/ε313 | <1 | <1 | <1 | <1 | <1 | >3 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | C | C | A | A | B | A |
| | Change in relative permittivity | A | C | C | A | A | B | A |
| | before and after exposure | | | | | | | |
| Evaluation of | Carboxy group consumption rate | B | D | D | B | B | D | A |
| transfer film | [measurement of ashing] | | | | | | | |
| | ε365/ε313 | <1 | <1 | <1 | <1 | <1 | >3 | <1 |
| | Transmittance at 365 nm | A | B | B | A | A | C | A |
| | Transmittance at 365 nm/ | A | B | B | A | A | C | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | C | C | A | A | B | A |
| Change in relative permittivity | A | C | C | A | A | B | A |
| before and after exposure | | | | | | | |
| Moisture permeability | A | C | C | A | B | B | A |
| Change in relative permittivity | A | C | C | A | A | B | A |
| after double exposure | | | | | | | |

TABLE 52

| | | | Mw of | pKa of | | | | |
|---|---|---|---|---|---|---|---|---|
| | | | compound A | Compound β | ε365 of | Example | | |
| Ninth table (3) | | | having acid group | in ground state | Compound β | 7-35 | 7-36 | 7-37 |
| Solid content | Compound A | St/MAA/MMA/GMA-MAA = | 18000 | — | — | | | |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | 60 | 60 | 60 |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | 4.8 (20) | | |
| | of compound A | 1-Me-isoquinoline | | 5.31 | <10 | | 3.5 (20) | |
| | having acid group | 2,4,5,7-Tetramethylquinoline | | 6.23 | <10 | | | 4.5 (20) |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | A | A |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | A | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (3) | | | 7-38 | 7-39 | 7-40 | 7-41 | 7-42 | 7-43 | 7-44 |
| Solid content | Compound A | St/MAA/MMA/GMA-MAA = | | | | | | | |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | 60 | 60 | 60 | 60 | 60 | 60 | 60 |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | | | | | |
| | having acid group | 2,4,5,7-Tetramethylquinoline | | | | | | | |
| | (mol %)) | 2-Methyl-4-methoxyquinoline | 4.2 (20) | | | | | | |
| | | 9-Methylacridine | | 4.7 (20) | | | | | |
| | | 9-Phenylacridine | | | 6.2 (20) | | | | |
| | | Pyridine | | | | 1.9 (20) | | | |
| | | 2,4-Dimethylquinoline | | | | | 3.8 (20) | 1.9 (10) | |
| | | 4-Aminopyridine | | | | | | | 2.3 (20) |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | C | D | D | A | B | D |
| photosensitive | [measurement of ashing] | | | | | | | | |
| material | ε365/ε313 | | <1 | >3 | >3 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | B | C | C | A | A | C |
| | Change in relative permittivity | | A | B | C | C | A | A | C |
| | before and after exposure | | | | | | | | |
| Evaluation of | Carboxy group consumption rate | | A | C | D | D | A | B | D |
| transfer film | [measurement of ashing] | | | | | | | | |
| | ε365/ε313 | | <1 | >3 | >3 | <1 | <1 | <1 | <1 |
| | Transmittance at 365 nm | | A | C | C | B | A | A | B |
| | Transmittance at 365 nm/ | | A | C | C | B | A | A | B |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | B | C | C | A | A | C |
| Change in relative permittivity | A | B | C | C | A | A | C |
| before and after exposure | | | | | | | |
| Moisture permeability | A | B | B | B | A | A | C |
| Change in relative permittivity | A | B | C | C | A | A | C |
| after double exposure | | | | | | | |

| | | | Example | | | | | | |
|---|---|---|---|---|---|---|---|---|---|
| Ninth table (3) | | | 7-45 | 7-46 | 7-47 | 7-48 | 7-49 | 7-50 | 7-51 |
| Solid content | Compound A | St/MAA/MMA/GMA-MAA = | | | | | | | |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | 60 | | | | | | |
| | | 53.5/14.5/32 (mass ratio) | | | | | | | |
| | | CHA/AA/HEA = | | 60 | 60 | 60 | 60 | 60 | 60 |
| | | 53.5/14.5/32 (mass ratio) | | | | | | | |
| | Compound β | Isoquinoline | | 3.1 (20) | | | | | |
| | (in parentheses: | Quinoline | | | 3.1 (20) | | | | |
| | molar ratio | Acridine | | | | 4.3 (20) | | | |
| | with respect to | 1-n-Butylisoquinoline | | | | | 4.5 (20) | | |
| | carboxy group | 1-n-Butyl-4-methylisoquinoline | | | | | | 4.8 (20) | |
| | of compound A | 1-Me-isoquinoline | | | | | | | 3.5 (20) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | | | | | | |
| | | 4-Aminopyridine | | | | | | | |
| | | 2-Chloropyridine | 2.7 (20) | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | D | B | B | D | A | A | A |
| photosensitive | [measurement of ashing] | | | | | | | |
| material | ε365/ε313 | <1 | <1 | <1 | >3 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | C | A | A | B | A | A | A |
| | Change in relative permittivity | C | A | A | B | A | A | A |
| | before and after exposure | | | | | | | |
| Evaluation of | Carboxy group consumption rate | D | B | B | D | A | A | A |
| transfer film | [measurement of ashing] | | | | | | | |
| | ε365/ε313 | <1 | <1 | <1 | >3 | <1 | <1 | <1 |
| | Transmittance at 365 nm | B | A | A | C | A | A | A |
| | Transmittance at 365 nm/ | B | A | A | C | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | C | A | A | B | A | A | A |
| Change in relative permittivity | C | A | A | B | A | A | A |
| before and after exposure | | | | | | | |
| Moisture permeability | C | A | B | B | A | A | A |
| Change in relative permittivity | C | A | A | B | A | A | A |
| after double exposure | | | | | | | |

TABLE 53

| | | | Mw of | pKa of | | | | |
|---|---|---|---|---|---|---|---|---|
| | | | compound A | Compound β | ε365 of | Example | | |
| Ninth table (4) | | | having acid group | in ground state | Compound β | 7-52 | 7-53 | 7-54 |
| Solid content | Compound A | St/MAA/MMA/GMA-MAA = | 18000 | — | — | | | |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | 60 | 60 | 60 |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | |
| | having acid group | 2,4,5,7-Tetramethylquinoline | | 6.23 | <10 | 4.5 (20) | | |
| | (mol %)) | 2-Methyl-4-methoxyquinoline | | 6.51 | <10 | | 4.2 (20) | |
| | | 9-Methylacridine | | 5.4 | 6300 | | | 4.7 (20) |
| | | 9-Phenylacridine | | 4.04 | >1000 | | | |
| | | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | A | C |
| photosensitive | [measurement of ashing] | | | | | | | |
| material | ε365/ε313 | | | — | — | <1 | <1 | >3 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | B |
| | Change in relative permittivity | | | — | — | A | A | B |
| | before and after exposure | | | | | | | |
| Evaluation of | Carboxy group consumption rate | | | — | — | A | A | C |
| transfer film | [measurement of ashing] | | | | | | | |
| | ε365/ε313 | | | — | — | <1 | <1 | >3 |
| | Transmittance at 365 nm | | | — | — | A | A | C |
| | Transmittance at 365 nm/ | | | — | — | A | A | C |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | B |
| Change in relative permittivity | — | — | A | A | B |
| before and after exposure | | | | | |
| Moisture permeability | — | — | A | A | B |
| Change in relative permittivity | — | — | A | A | B |
| after double exposure | | | | | |

| | | | Example | | | | | | |
|---|---|---|---|---|---|---|---|---|---|
| Ninth table (4) | | | 7-55 | 7-56 | 7-57 | 7-58 | 7-59 | 7-60 | 7-61 |
| Solid content | Compound A | St/MAA/MMA/GMA-MAA = | | | | | | | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | 60 | 60 | 60 | 60 | 60 | 60 | |
| | | 53.5/14.5/32 (mass ratio) | | | | | | | |
| | Compound β | Isoquinoline | | | | | | | 3.5 (20) |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | | | | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | 6.2 (20) | | | | | | |
| | | Pyridine | | 1.9 (20) | | | | | |
| | | 2,4-Dimethylquinoline | | | 3.8 (20) | 1.9 (10) | | | |
| | | 4-Aminopyridine | | | | | 2.3 (20) | | |
| | | 2-Chloropyridine | | | | | | 2.7 (20) | |
| | Polymerizable | DPHA | 12.6 | 12.6 | 12.6 | 12.6 | 12.6 | 12.6 | |
| | compound | A-NOD-N | 25.0 | 25.0 | 25.0 | 25.0 | 25.0 | 25.0 | |
| | | DTMPT | | | | | | | 18.8 |
| | | A-DCP | | | | | | | |
| | | TMPT | | | | | | | 18.8 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | D | D | A | B | D | D | B |
| photosensitive | [measurement of ashing] | | | | | | | | |
| material | ε365/ε313 | | >3 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | C | C | A | A | C | C | A |
| | Change in relative permittivity | | C | C | A | A | C | C | A |
| | before and after exposure | | | | | | | | |
| Evaluation of | Carboxy group consumption rate | | D | D | A | B | D | D | B |
| transfer film | [measurement of ashing] | | | | | | | | |
| | ε365/ε313 | | >3 | <1 | <1 | <1 | <1 | <1 | <1 |
| | Transmittance at 365 nm | | C | B | A | A | B | B | A |
| | Transmittance at 365 nm/ | | C | B | A | A | B | B | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | C | C | A | A | C | C | A |
| Change in relative permittivity | C | C | A | A | C | C | A |
| before and after exposure | | | | | | | |
| Moisture permeability | B | B | A | A | C | C | A |
| Change in relative permittivity | C | C | A | A | C | C | A |
| after double exposure | | | | | | | |

| | | | Example | | | | | | |
|---|---|---|---|---|---|---|---|---|---|
| Ninth table (4) | | | 7-62 | 7-63 | 7-64 | 7-65 | 7-66 | 7-67 | 7-68 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | 3.5 (20) | | | | | | |
| | molar ratio | Acridine | | 4.9 (20) | | | | | |
| | with respect to | 1-n-Butylisoquinoline | | | 5.0 (20) | | | | |
| | carboxy group | 1-n-Butyl-4-methylisoquinoline | | | | 5.4 (20) | | | |
| | of compound A | 1-Me-isoquinoline | | | | | 3.9 (20) | | |
| | having acid group | 2,4,5,7-Tetramethylquinoline | | | | | | 5.0 (20) | |
| | (mol %)) | 2-Methyl-4-methoxyquinoline | | | | | | | 4.7 (20) |
| | | 9-Methylacridine | | | | | | | |
| | | 9-Phenylacridine | | | | | | | |
| | | Pyridine | | | | | | | |
| | | 2,4-Dimethylquinoline | | | | | | | |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 18.8 | 18.8 | 18.8 | 18.8 | 18.8 | 18.8 | 18.8 |
| | | A-DCP | | | | | | | |
| | | TMPT | 18.8 | 18.8 | 18.8 | 18.8 | 18.8 | 18.8 | 18.8 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | B | D | A | A | A | A | A |
| photosensitive | [measurement of ashing] | | | | | | | |
| material | ε365/ε313 | <1 | >3 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | B | A | A | A | A | A |
| | Change in relative permittivity | A | B | A | A | A | A | A |
| | before and after exposure | | | | | | | |
| Evaluation of | Carboxy group consumption rate | B | D | A | A | A | A | A |
| transfer film | [measurement of ashing] | | | | | | | |
| | ε365/ε313 | <1 | >3 | <1 | <1 | <1 | <1 | <1 |
| | Transmittance at 365 nm | A | C | A | A | A | A | A |
| | Transmittance at 365 nm/ | A | C | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | B | A | A | A | A | A |
| Change in relative permittivity | A | B | A | A | A | A | A |
| before and after exposure | | | | | | | |
| Moisture permeability | B | B | A | A | A | A | A |
| Change in relative permittivity | A | B | A | A | A | A | A |
| after double exposure | | | | | | | |

TABLE 54

| | | | Mw of | pKa of | | | | |
|---|---|---|---|---|---|---|---|---|
| | | | compound A | Compound β | ε365 of | Example | | |
| Ninth table (5) | | | having acid group | in ground state | Compound β | 7-69 | 7-70 | 7-71 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | 5.2 (20) | | |
| | | 9-Phenylacridine | | 4.04 | >1000 | | 6.9 (20) | |
| | | Pyridine | | 5.25 | <10 | | | 2.1 (20) |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | | | |
| | compound | A-NOD-N | | — | — | | | |
| | | DTMPT | | — | — | 18.8 | 18.8 | 18.8 |
| | | A-DCP | | — | — | | | |
| | | TMPT | | — | — | 18.8 | 18.8 | 18.8 |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | C | D | D |
| photosensitive | [measurement of ashing] | | | | | | | |
| material | ε365/ε313 | | | — | — | >3 | >3 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | B | C | C |
| | Change in relative permittivity | | | — | — | B | C | C |
| | before and after exposure | | | | | | | |
| Evaluation of | Carboxy group consumption rate | | | — | — | C | D | D |
| transfer film | [measurement of ashing] | | | | | | | |
| | ε365/ε313 | | | — | — | >3 | >3 | <1 |
| | Transmittance at 365 nm | | | — | — | C | C | B |
| | Transmittance at 365 nm/ | | | — | — | C | C | B |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | B | C | C |
| Change in relative permittivity | — | — | B | C | C |
| before and after exposure | | | | | |
| Moisture permeability | — | — | B | B | B |
| Change in relative permittivity | — | — | B | C | C |
| after double exposure | | | | | |

| | | | Example | | | | | | |
|---|---|---|---|---|---|---|---|---|---|
| Ninth table (5) | | | 7-72 | 7-73 | 7-74 | 7-75 | 7-76 | 7-77 | 7-78 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | | | 3.9 (20) | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 4.3 (20) | 2.1 (10) | | | | 4.3 (20) | 2.1 (10) |
| | | 4-Aminopyridine | | | 2.6 (20) | | | | |
| | | 2-Chloropyridine | | | | 3.1 (20) | | | |
| | Polymerizable | DPHA | | | | | | | |
| | compound | A-NOD-N | | | | | | | |
| | | DTMPT | 18.8 | 18.8 | 18.8 | 18.8 | | | |
| | | A-DCP | | | | | 25.0 | 25.0 | 25.0 |
| | | TMPT | 18.8 | 18.8 | 18.8 | 18.8 | 12.6 | 12.6 | 12.6 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | B | D | D | A | A | B |
| photosensitive | [measurement of ashing] | | | | | | | | |
| material | ε365/ε313 | | <1 | <1 | <1 | <1 | <1 | <1 | >3 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | C | C | A | A | A |
| | Change in relative permittivity | | A | A | C | C | A | A | A |
| | before and after exposure | | | | | | | | |
| Evaluation of | Carboxy group consumption rate | | A | B | D | D | A | A | B |
| transfer film | [measurement of ashing] | | | | | | | | |
| | ε365/ε313 | | <1 | <1 | <1 | <1 | <1 | <1 | <1 |
| | Transmittance at 365 nm | | A | A | B | B | A | A | A |
| | Transmittance at 365 nm/ | | A | A | B | B | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | C | C | A | A | A |
| Change in relative permittivity | A | A | C | C | A | A | A |
| before and after exposure | | | | | | | |
| Moisture permeability | A | A | C | C | A | A | A |
| Change in relative permittivity | A | A | C | C | A | A | A |
| after double exposure | | | | | | | |

| | | | Example | | | | | | |
|---|---|---|---|---|---|---|---|---|---|
| Ninth table (5) | | | 7-79 | 7-80 | 7-81 | 7-82 | 7-83 | 7-84 | 7-85 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.9 (20) | | | 3.9 (20) | | | 3.9 (20) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | 4.3 (20) | 2.1 (10) | | 4.3 (20) | 2.1 (10) | |
| | | 4-Aminopyridine | | | | | | | |
| | | 2-Chloropyridine | | | | | | | |
| | Polymerizable | DPHA | | | | | | | 12.6 |
| | compound | A-NOD-N | | | | 12.6 | 12.6 | 12.6 | 12.6 |
| | | DTMPT | 12.6 | 12.6 | 12.6 | | | | 12.6 |
| | | A-DCP | 12.6 | 12.6 | 12.6 | 12.6 | 12.6 | 12.6 | |
| | | TMPT | 12.6 | 12.6 | 12.6 | 12.6 | 12.6 | 12.6 | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | A | B | A | A | B | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | A | B | A | A | B | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 55

| | | | Mw of | pKa of | | | | |
|---|---|---|---|---|---|---|---|---|
| | | | compound A | Compound β | ε365 of | Example | | |
| Ninth table (6) | | | having acid group | in ground state | Compound β | 7-86 | 7-87 | 7-88 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | | 3.9 (20) |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | 4.3 (20) | 2.1 (10) | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 12.6 | 12.6 | 12.6 |
| | | DTMPT | | — | — | 12.6 | 12.6 | |
| | | A-DCP | | — | — | | | |
| | | TMPT | | — | — | | | |
| | | SR601 | | — | — | | | 12.6 |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | B | A |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | B | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (6) | | | 7-89 | 7-90 | 7-91 | 7-92 | 7-93 | 7-94 | 7-95 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | 3.9 (20) | | | 3.9 (20) | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 4.3 (20) | 2.1 (10) | | 4.3 (20) | 2.1 (10) | | 4.3 (20) |
| | | 4-Aminopyridine | | | | | | | |
| | | 2-Chloropyridine | | | | | | | |
| | Polymerizable | DPHA | 12.6 | 12.6 | | | | | |
| | compound | A-NOD-N | 12.6 | 12.6 | 12.6 | 12.6 | 12.6 | 12.6 | 12.6 |
| | | DTMPT | | | 12.6 | 12.6 | 12.6 | 12.6 | 12.6 |
| | | A-DCP | | | | | | | |
| | | TMPT | | | | | | | |
| | | SR601 | 12.6 | 12.6 | | | | | |
| | | KRM8904 | | | 12.6 | 12.6 | 12.6 | | |
| | | KRM8452 | | | | | | 12.6 | 12.6 |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | B | A | A | B | A | A |
| photosensitive | [measurement of ashing] | | | | | | | | |
| material | ε365/ε313 | | <1 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | B | A | A | B | A | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | | |
|---|---|---|---|---|---|---|---|---|---|
| Ninth table (6) | | | 7-96 | 7-97 | 7-98 | 7-99 | 7-100 | 7-101 | 7-102 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | 3.9 (20) | | | 3.9 (20) | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 2.1 (10) | | 4.3 (20) | 2.1 (10) | | 4.3 (20) | 2.1 (10) |
| | | 4-Aminopyridine | | | | | | | |
| | | 2-Chloropyridine | | | | | | | |
| | Polymerizable | DPHA | | 12.6 | 12.6 | 12.6 | 12.6 | 12.6 | 12.6 |
| | compound | A-NOD-N | 12.6 | 25.0 | 25.0 | 25.0 | 25.0 | 25.0 | 25.0 |
| | | DTMPT | 12.6 | | | | | | |
| | | A-DCP | | | | | | | |
| | | TMPT | | | | | | | |
| | | SR601 | | | | | | | |
| | | KRM8904 | | | | | | | |
| | | KRM8452 | 12.6 | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | | | | 0.2 | 0.2 | 0.2 |
| | | R41 | | | | | | | |
| | | 710FL | | | | | | | |

| | | | | | | | | |
|---|---|---|---|---|---|---|---|---|
| Evaluation of | Carboxy group consumption rate | B | A | A | B | A | A | B |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | B | A | A | B | A | A | B |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 56

| | | | Mw of | pKa of | | | | |
|---|---|---|---|---|---|---|---|---|
| | | | compound A | Compound β | ε365 of | Example | | |
| Ninth table (7) | | | having acid group | in ground state | Compound β | 7-103 | 7-104 | 7-105 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | 3.9 (20) | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | | 4.3 (20) | 2.1 (10) |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.5 | 0.5 | 0.5 |
| | | R41 | | — | — | | | |
| | | 710FL | | — | — | | | |
| Evaluation of | Carboxy group consumption rate | | | — | — | A | A | B |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | A | B |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (7) | | | 7-106 | 7-107 | 7-108 | 7-109 | 7-110 | 7-111 | 7-112 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.9 (20) | | | 3.9 (20) | | | 3.9 (20) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | 4.3 (20) | 2.1 (10) | | 4.3 (20) | 2.1 (10) | |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | |
| | initiator | Oxe02 | | | | | | | 0.8 |
| | | Api307 | | | | | | | |
| | Surfactant | F551A | | | | | | | |
| | | R41 | 0.1 | 0.1 | 0.1 | | | | |
| | | 710FL | | | | 0.1 | 0.1 | 0.1 | 0.1 |
| Evaluation of | Carboxy group consumption rate | | A | A | B | A | A | B | A |
| photosensitive | [measurement of ashing] | | | | | | | | |
| material | ε365/ε313 | | <1 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | A | B | A | A | B | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | | |
|---|---|---|---|---|---|---|---|---|---|
| Ninth table (7) | | | 7-113 | 7-114 | 7-115 | 7-116 | 7-117 | 7-118 | 7-119 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | 3.9 (20) | | | 3.9 (20) | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 4.3 (20) | 2.1 (10) | | 4.3 (20) | 2.1 (10) | | 4.3 (20) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | | | 0.8 | 0.8 | 0.8 | | |
| | initiator | Oxe02 | 0.8 | 0.8 | | | | 0.8 | 0.8 |
| | | Api307 | | | 1.5 | 1.5 | 1.5 | 1.5 | 1.5 |
| | Surfactant | F551A | | | | | | | |
| | | R41 | | | | | | | |
| | | 710FL | 0.1 | 0.1 | 0.1 | 0.1 | 0.1 | 0.1 | 0.1 |

| | | | | | | | | |
|---|---|---|---|---|---|---|---|---|
| Evaluation of | Carboxy group consumption rate | A | B | A | A | B | A | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | B | A | A | B | A | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 57

| | | | Mw of | pKa of | | | | |
|---|---|---|---|---|---|---|---|---|
| | | | compound A | Compound β | ε365 of | Example | | |
| Ninth table (8) | | | having acid group | in ground state | Compound β | 7-120 | 7-121 | 7-122 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | 3.9 (20) | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | 2.1 (10) | | 4.3 (20) |
| | | 4-Aminopyridine | | 9.20 | <100 | | | |
| | | 2-Chloropyridine | | 0.70 | <10 | | | |
| | Polymerizable | DPHA | | — | — | 12.6 | 10.0 | 10.0 |
| | compound | A-NOD-N | | — | — | 25.0 | 20.0 | 20.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | | 0.8 | 0.8 |
| | initiator | Oxe02 | | — | — | 0.8 | | |
| | | Api307 | | — | — | 1.5 | | |
| | Surfactant | F551A | | — | — | | 0.1 | 0.1 |
| | | R41 | | — | — | | | |
| | | 710FL | | — | — | 0.1 | | |
| Evaluation of | Carboxy group consumption rate | | | — | — | B | A | A |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | B | A | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (8) | | | 7-123 | 7-124 | 7-125 | 7-126 | 7-127 | 7-128 | 7-129 |
| Solid content | Compound A | St/MAA/MMA/GMA-MAA = | 60 | 60 | 60 | 60 | 60 | 60 | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | 3.9 (20) | | | 3.9 (20) | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 2.1 (10) | | 4.3 (20) | 2.1 (10) | | 4.3 (20) | 2.1 (10) |
| | | 4-Aminopyridine | | | | | | | |
| | | 2-Chloropyridine | | | | | | | |
| | Polymerizable | DPHA | 10.0 | 14.0 | 14.0 | 14.0 | 28.0 | 28.0 | 28.0 |
| | compound | A-NOD-N | 20.0 | 28.0 | 28.0 | 28.0 | 14.0 | 14.0 | 14.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.9 | 0.9 | 0.9 | 0.9 | 0.9 | 0.9 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | B | A | A | B | A | A | B |
| photosensitive | [measurement of ashing] | | | | | | | | |
| material | ε365/ε313 | | <1 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | B | A | A | B | A | A | B |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | |
|---|---|---|---|---|---|---|---|---|
| Ninth table (8) | | | 7-130 | 7-131 | 7-132 | 7-133 | 7-134 | 7-135 |
| Solid content | Compound A | St/MAA/MMA/GMA-MAA = | 60 | 60 | 60 | 60 | 60 | 60 |
| blending | having acid group | 47.7/19.0/1.3/32.0 (mass ratio) | | | | | | |
| | | CHMA/MAA/BzMA = | | | | | | |
| | | 49/19/32 (mass ratio) | | | | | | |
| | | St/AA/AA-GMA = | | | | | | |
| | | 53.5/14.5/32 (mass ratio) | | | | | | |
| | | CHA/AA/HEA = | | | | | | |
| | | 53.5/14.5/32 (mass ratio) | | | | | | |
| | Compound β | Isoquinoline | | | | | | |
| | (in parentheses: | Quinoline | | | | | | |
| | molar ratio | Acridine | | | | | | |
| | with respect to | 1-n-Butylisoquinoline | | | | | | |
| | carboxy group | 1-n-Butyl-4-methylisoquinoline | | | | | | |
| | of compound A | 1-Me-isoquinoline | 3.9 (20) | | | 3.9 (20) | | |
| | having acid group | 2,4,5,7-Tetramethylquinoline | | | | | | |
| | (mol %)) | 2-Methyl-4-methoxyquinoline | | | | | | |
| | | 9-Methylacridine | | | | | | |
| | | 9-Phenylacridine | | | | | | |
| | | Pyridine | | | | | | |
| | | 2,4-Dimethylquinoline | | 4.3 (20) | 2.1 (10) | | 4.3 (20) | 2.1 (10) |
| | | 4-Aminopyridine | | | | | | |
| | | 2-Chloropyridine | | | | | | |
| | Polymerizable | DPHA | | | | | | |
| | compound | A-NOD-N | | | | | | |
| | | DTMPT | 21.0 | 21.0 | 21.0 | 10.0 | 10.0 | 10.0 |
| | | A-DCP | | | | | | |
| | | TMPT | 21.0 | 21.0 | 21.0 | 32.0 | 32.0 | 32.0 |
| | | SR601 | | | | | | |
| | | KRM8904 | | | | | | |
| | | KRM8452 | | | | | | |
| | Photopolymerization | Omn379 | 0.9 | 0.9 | 0.9 | 0.9 | 0.9 | 0.9 |
| | initiator | Oxe02 | | | | | | |
| | | Api307 | | | | | | |
| | Surfactant | F551A | 0.1 | 0.1 | 0.1 | 0.1 | 0.1 | 0.1 |
| | | R41 | | | | | | |
| | | 710FL | | | | | | |

| | | | | | | | |
|---|---|---|---|---|---|---|---|
| Evaluation of | Carboxy group consumption rate | A | A | B | A | A | B |
| photosensitive | [measurement of ashing] | | | | | | |
| material | ε365/ε313 | <1 | <1 | <1 | <1 | <1 | <1 |

| | | | | | | | |
|---|---|---|---|---|---|---|---|
| Pattern | 25 μm | A | A | A | A | A | A |
| formability | 50 μm | A | A | A | A | A | A |
| | 250 μm | A | A | A | A | A | A |

| | | | | | | | |
|---|---|---|---|---|---|---|---|
| | Relative permittivity | A | A | A | A | A | A |
| | Change in relative permittivity | A | A | A | A | A | A |
| | before and after exposure | | | | | | |
| Evaluation of | Carboxy group consumption rate | A | A | B | A | A | B |
| transfer film | [measurement of ashing] | | | | | | |
| | ε365/ε313 | <1 | <1 | <1 | <1 | <1 | <1 |
| | Transmittance at 365 nm | A | A | A | A | A | A |
| | Transmittance at 365 nm/ | A | A | A | A | A | A |
| | transmittance at 313 nm | | | | | | |
| | Laminate suitability | A | A | A | A | A | A |

| | | | | | | | |
|---|---|---|---|---|---|---|---|
| Pattern | 25 μm | A | A | A | A | A | A |
| formability | 50 μm | A | A | A | A | A | A |
| | 250 μm | A | A | A | A | A | A |

| | | | | | | |
|---|---|---|---|---|---|---|
| Relative permittivity | A | A | A | A | A | A |
| Change in relative permittivity | A | A | A | A | A | A |
| before and after exposure | | | | | | |
| Moisture permeability | A | A | A | A | A | A |
| Change in relative permittivity | A | A | A | A | A | A |
| after double exposure | | | | | | |

TABLE 58

| | | | Mw of | pKa of | | | | |
|---|---|---|---|---|---|---|---|---|
| | | | compound A | Compound β | ε365 of | Example | | |
| Ninth table (9) | | | having acid group | in ground state | Compound β | 7-136 | 7-137 | 7-138 |
| Solid content | Compound A | St/MAA/MMA/GMA-MAA = | 18000 | — | — | 60 | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | 3.9 (20) | | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | | 4.3 (20) | 2.1 (10) |
| | | 4-Aminopyridine | | 9.20 | <100 | | | |
| | | 2-Chloropyridine | | 0.70 | <10 | | | |
| | Polymerizable | DPHA | | — | — | | | |
| | compound | A-NOD-N | | — | — | | | |
| | | DTMPT | | — | — | 30.0 | 30.0 | 30.0 |
| | | A-DCP | | — | — | | | |
| | | TMPT | | — | — | 12.0 | 12.0 | 12.0 |
| | | SR601 | | — | — | | | |
| | | KRM8904 | | — | — | | | |
| | | KRM8452 | | — | — | | | |
| | Photopolymerization | Omn379 | | — | — | 0.9 | 0.9 | 0.9 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | A | B |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | A | B |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (9) | | | 7-139 | 7-140 | 7-141 | 7-142 | 7-143 | 7-144 | 7-145 |
| Solid content | Compound A | St/MAA/MMA/GMA-MAA = | | | | | | | 60 |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | 60 | 60 | 60 | 60 | 60 | 60 | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.5 (20) | | | 3.5 (20) | | | 3.9 (20) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | 3.8 (20) | 1.9 (10) | | 3.8 (20) | 1.9 (10) | |
| | | 4-Aminopyridine | | | | | | | |
| | | 2-Chloropyridine | | | | | | | |
| | Polymerizable | DPHA | | | | | | | 16.0 |
| | compound | A-NOD-N | | | | | | | 32.0 |
| | | DTMPT | 21.0 | 21.0 | 21.0 | 21.0 | 21.0 | 21.0 | |
| | | A-DCP | | | | | | | |
| | | TMPT | 21.0 | 21.0 | 21.0 | 21.0 | 21.0 | 21.0 | |
| | | SR601 | | | | | | | |
| | | KRM8904 | | | | | | | |
| | | KRM8452 | | | | | | | |
| | Photopolymerization | Omn379 | 0.9 | 0.9 | 0.9 | 2.4 | 2.4 | 2.4 | 1.0 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | A | B | A | A | B | A |
| photosensitive | [measurement of ashing] | | | | | | | | |
| material | ε365/ε313 | | <1 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | A | B | A | A | B | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | | |
|---|---|---|---|---|---|---|---|---|---|
| Ninth table (9) | | | 7-146 | 7-147 | 7-148 | 7-149 | 7-150 | 7-151 | 7-152 |
| Solid content | Compound A | St/MAA/MMA/GMA-MAA = | 60 | 60 | 30 | 30 | 30 | | |
| blending | having acid group | 47.7/19.0/1.3/32.0 (mass ratio) | | | | | | | |
| | | CHMA/MAA/BzMA = | | | 30 | 30 | 30 | | |
| | | 49/19/32 (mass ratio) | | | | | | | |
| | | St/AA/AA-GMA = | | | | | | 30 | 30 |
| | | 53.5/14.5/32 (mass ratio) | | | | | | | |
| | | CHA/AA/HEA = | | | | | | 30 | 30 |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | | 3.9 (20) | | | 3.5 (20) | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 4.3 (20) | 2.1 (10) | | 4.3 (20) | 2.1 (10) | | 3.8 (20) |
| | | 4-Aminopyridine | | | | | | | |
| | | 2-Chloropyridine | | | | | | | |
| | Polymerizable | DPHA | 16.0 | 16.0 | 12.6 | 12.6 | 12.6 | 12.6 | 12.6 |
| | compound | A-NOD-N | 32.0 | 32.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 1.0 | 1.0 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | B | A | A | B | A | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | B | A | A | B | A | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 59

| | | | Mw of | pKa of | | | | |
|---|---|---|---|---|---|---|---|---|
| | | | compound A | Compound β | ε365 of | Example | | |
| Ninth table (10) | | | having acid group | in ground state | Compound β | 7-153 | 7-154 | 7-155 |
| Solid content | Compound A | St/MAA/MMA/GMA-MAA = | 18000 | — | — | | 60 | 60 |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | 30 | | |
| | | 53.5/14.5/32 (mass ratio) | | | | | | |
| | | CHA/AA/HEA = | 40000 | — | — | 30 | | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | 1.9 (10) | 1.0 (5) |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | 1.9 (10) | 2.1 (10) | 3.1 (15) |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | B | A | A |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | B | A | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (10) | | | 7-156 | 7-157 | 7-158 | 7-159 | 7-160 | 7-161 | 7-162 |
| Solid content | Compound A | St/MAA/MMA/GMA-MAA = | 60 | | | | 30 | 30 | 30 |
| blending | having acid group | 47.7/19.0/1.3/32.0 (mass ratio) | | | | | | | |
| | | CHMA/MAA/BzMA = | | | | | 30 | 30 | 30 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | 60 | 60 | 60 | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 1.0 (5) | 1.7 (10) | 0.8 (5) | 0.8 (5) | 3.9 (20) | | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 1.0 (5) | 1.9 (10) | 2.8 (15) | 0.9 (5) | | 4.3 (20) | 2.1 (10) |
| | | 4-Aminopyridine | | | | | | | |
| | | 2-Chloropyridine | | | | | | | |
| | Polymerizable | DPHA | 12.6 | 12.6 | 12.6 | 12.6 | | | |
| | compound | A-NOD-N | 25.0 | 25.0 | 25.0 | 25.0 | | | |
| | | DTMPT | | | | | 21.0 | 21.0 | 21.0 |
| | | A-DCP | | | | | | | |
| | | TMPT | | | | | 21.0 | 21.0 | 21.0 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.9 | 0.9 | 0.9 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | B | A | A | B | A | A | B |
| photosensitive | [measurement of ashing] | | | | | | | | |
| material | ε365/ε313 | | <1 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | B | A | A | B | A | A | B |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | | |
|---|---|---|---|---|---|---|---|---|---|
| Ninth table (10) | | | 7-163 | 7-164 | 7-165 | 7-166 | 7-167 | 7-168 | 7-169 |
| Solid content | Compound A | St/MAA/MMA/GMA-MAA = | | | | 60 | 60 | 60 | |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | 30 | 30 | 30 | | | | |
| | | 53.5/14.5/32 (mass ratio) | | | | | | | |
| | | CHA/AA/HEA = | 30 | 30 | 30 | | | | 60 |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.5 (20) | | | 1.9 (10) | 1.0 (5) | 1.0 (5) | 1.7 (10) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | 3.8 (20) | 1.9 (10) | 2.1 (10) | 3.1 (15) | 1.0 (5) | 1.9 (10) |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 21.0 | 21.0 | 21.0 | 21.0 | 21.0 | 21.0 | 21.0 |
| | | A-DCP | | | | | | | |
| | | TMPT | 21.0 | 21.0 | 21.0 | 21.0 | 21.0 | 21.0 | 21.0 |
| | | SR601 | | | | | | | |
| | | KRM8904 | | | | | | | |
| | | KRM8452 | | | | | | | |
| | Photopolymerization | Omn379 | 0.9 | 0.9 | 0.9 | 0.9 | 0.9 | 0.9 | 0.9 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | A | B | A | A | B | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | A | B | A | A | B | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 60

| | | | Mw of | pKa of | | | | |
|---|---|---|---|---|---|---|---|---|
| | | | compound A | Compound β | ε365 of | Example | | |
| Ninth table (11) | | | having acid group | in ground state | Compound β | 7-170 | 7-171 | 7-172 |
| Solid content | Compound A | St/MAA/MMA/GMA-MAA = | 18000 | — | — | | | 30 |
| blending | having acid group | 47.7/19.0/1.3/32.0 (mass ratio) | | | | | | |
| | | CHMA/MAA/BzMA = | 24000 | — | — | | | 30 |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | 60 | 60 | |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | 0.8 (5) | 0.8 (5) | 1.9 (10) |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | 2.8 (15) | 0.9 (5) | 2.1 (10) |
| | | 4-Aminopyridine | | 9.20 | <100 | | | |
| | | 2-Chloropyridine | | 0.70 | <10 | | | |
| | Polymerizable | DPHA | | — | — | | | 12.6 |
| | compound | A-NOD-N | | — | — | | | 25.0 |
| | | DTMPT | | — | — | 21.0 | 21.0 | |
| | | A-DCP | | — | — | | | |
| | | TMPT | | — | — | 21.0 | 21.0 | |
| | | SR601 | | — | — | | | |
| | | KRM8904 | | — | — | | | |
| | | KRM8452 | | — | — | | | |
| | Photopolymerization | Omn379 | | — | — | 0.9 | 0.9 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | B | A |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | B | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (11) | | | 7-173 | 7-174 | 7-175 | 7-176 | 7-177 | 7-178 | 7-179 |
| Solid content | Compound A | St/MAA/MMA/GMA-MAA = | 30 | 30 | | | | 30 | 30 |
| blending | having acid group | 47.7/19.0/1.3/32.0 (mass ratio) | | | | | | | |
| | | CHMA/MAA/BzMA = | 30 | 30 | | | | 30 | 30 |
| | | 49/19/32 (mass ratio) | | | | | | | |
| | | St/AA/AA-GMA = | | | 30 | 30 | 30 | | |
| | | 53.5/14.5/32 (mass ratio) | | | | | | | |
| | | CHA/AA/HEA = | | | 30 | 30 | 30 | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 1.0 (5) | 1.0 (5) | 1.7 (10) | 0.8 (5) | 0.8 (5) | 1.9 (10) | 1.0 (5) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 3.1 (15) | 1.0 (5) | 1.9 (10) | 2.8 (15) | 0.9 (5) | 2.1 (10) | 3.1 (15) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | | |
| | compound | A-NOD-N | 25.0 | 25.0 | 25.0 | 25.0 | 25.0 | | |
| | | DTMPT | | | | | | 21.0 | 21.0 |
| | | A-DCP | | | | | | | |
| | | TMPT | | | | | | 21.0 | 21.0 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.9 | 0.9 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | B | A | A | B | A | A |
| photosensitive | [measurement of ashing] | | | | | | | | |
| material | ε365/ε313 | | <1 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | B | A | A | B | A | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | | |
|---|---|---|---|---|---|---|---|---|---|
| Ninth table (11) | | | 7-180 | 7-181 | 7-182 | 7-183 | 7-184 | 7-185 | 7-186 |
| Solid content | Compound A | St/MAA/MMA/GMA-MAA = | 30 | | | | 30 | 30 | 30 |
| blending | having acid group | 47.7/19.0/1.3/32.0 (mass ratio) | | | | | | | |
| | | CHMA/MAA/BzMA = | 30 | | | | 30 | 30 | 30 |
| | | 49/19/32 (mass ratio) | | | | | | | |
| | | St/AA/AA-GMA = | | 30 | 30 | 30 | | | |
| | | 53.5/14.5/32 (mass ratio) | | | | | | | |
| | | CHA/AA/HEA = | | 30 | 30 | 30 | | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 1.0 (5) | 1.7 (10) | 0.8 (5) | 0.8 (5) | 1.9 (10) | 1.0 (5) | 1.0 (5) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 1.0 (5) | 1.9 (10) | 2.8 (15) | 0.9 (5) | 2.1 (10) | 3.1 (15) | 1.0 (5) |
| | | 4-Aminopyridine | | | | | | | |
| | | 2-Chloropyridine | | | | | | | |
| | Polymerizable | DPHA | | | | | 12.0 | 12.0 | 12.0 |
| | compound | A-NOD-N | | | | | 12.0 | 12.0 | 12.0 |
| | | DTMPT | 21.0 | 21.0 | 21.0 | 21.0 | 12.0 | 12.0 | 12.0 |
| | | A-DCP | | | | | | | |
| | | TMPT | 21.0 | 21.0 | 21.0 | 21.0 | 12.0 | 12.0 | 12.0 |
| | | SR601 | | | | | | | |
| | | KRM8904 | | | | | | | |
| | | KRM8452 | | | | | | | |
| | Photopolymerization | Omn379 | 0.9 | 0.9 | 0.9 | 0.9 | 1.0 | 1.0 | 1.0 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | B | A | A | B | A | A | B |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | B | A | A | B | A | A | B |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 61

| | | | Mw of | pKa of | | | | |
|---|---|---|---|---|---|---|---|---|
| | | | compound A | Compound β | ε365 of | Example | | |
| Ninth table (12) | | | having acid group | in ground state | Compound β | 7-187 | 7-188 | 7-189 |
| Solid content | Compound A | St/MAA/MMA/GMA-MAA = | 18000 | — | — | | | |
| blending | having acid group | 47.7/19.0/1.3/32.0 (mass ratio) | | | | | | |
| | | CHMA/MAA/BzMA = | 24000 | — | — | | | |
| | | 49/19/32 (mass ratio) | | | | | | |
| | | St/AA/AA-GMA = | 16000 | — | — | 30 | 30 | 30 |
| | | 53.5/14.5/32 (mass ratio) | | | | | | |
| | | CHA/AA/HEA = | 40000 | — | — | 30 | 30 | 30 |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | 1.7 (10) | 0.8 (5) | 0.8 (5) |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | 1.9 (10) | 2.8 (15) | 0.9 (5) |
| | | 4-Aminopyridine | | 9.20 | <100 | | | |
| | | 2-Chloropyridine | | 0.70 | <10 | | | |
| | Polymerizable | DPHA | | — | — | 12.0 | 12.0 | 12.0 |
| | compound | A-NOD-N | | — | — | 12.0 | 12.0 | 12.0 |
| | | DTMPT | | — | — | 12.0 | 12.0 | 12.0 |
| | | A-DCP | | — | — | | | |
| | | TMPT | | — | — | 12.0 | 12.0 | 12.0 |
| | | SR601 | | — | — | | | |
| | | KRM8904 | | — | — | | | |
| | | KRM8452 | | — | — | | | |
| | Photopolymerization | Omn379 | | — | — | 1.0 | 1.0 | 1.0 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | A | A | B |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | A | A | B |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (12) | | | 7-190 | 7-191 | 7-192 | 7-193 | 7-194 | 7-195 | 7-196 |
| Solid content | Compound A | St/MAA/MMA/GMA-MAA = | 30 | 30 | 30 | | | | 60 |
| blending | having acid group | 47.7/19.0/1.3/32.0 (mass ratio) | | | | | | | |
| | | CHMA/MAA/BzMA = | 30 | 30 | 30 | | | | |
| | | 49/19/32 (mass ratio) | | | | | | | |
| | | St/AA/AA-GMA = | | | | 30 | 30 | 30 | |
| | | 53.5/14.5/32 (mass ratio) | | | | | | | |
| | | CHA/AA/HEA = | | | | 30 | 30 | 30 | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 3.9 (20) | | | 3.5 (20) | | | 1.9 (10) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | | 4.3 (20) | 2.1 (10) | | 3.8 (20) | 1.9 (10) | 2.1 (10) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 1.6 | 1.6 | 1.6 | 1.6 | 1.6 | 1.6 | 1.6 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | A | A | B | A | A | B | A |
| photosensitive | [measurement of ashing] | | | | | | | | |
| material | ε365/ε313 | | <1 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | A | A | B | A | A | B | A |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | | |
|---|---|---|---|---|---|---|---|---|---|
| Ninth table (12) | | | 7-197 | 7-198 | 7-199 | 7-200 | 7-201 | 7-202 | 7-203 |
| Solid content | Compound A | St/MAA/MMA/GMA-MAA = | 60 | 60 | | | | 30 | 30 |
| blending | having acid group | 47.7/19.0/1.3/32.0 (mass ratio) | | | | | | | |
| | | CHMA/MAA/BzMA = | | | | | | 30 | 30 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | 60 | 60 | 60 | | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 1.0 (5) | 1.0 (5) | 1.7 (10) | 0.8 (5) | 0.8 (5) | 3.9 (20) | |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 3.1 (15) | 1.0 (5) | 1.9 (10) | 2.8 (15) | 0.9 (5) | | 4.3 (20) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 1.6 | 1.6 | 1.6 | 1.6 | 1.6 | 0.4 | 0.4 |
| | initiator | Oxe02 | | | | | | 0.4 | 0.4 |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | B | A | A | B | A | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | B | A | A | B | A | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 62

| | | | Mw of | pKa of | | | | |
|---|---|---|---|---|---|---|---|---|
| | | | compound A | Compound β | ε365 of | Example | | |
| Ninth table (13) | | | having acid group | in ground state | Compound β | 7-204 | 7-205 | 7-206 |
| Solid content | Compound A | St/MAA/MMA/GMA-MAA = | 18000 | — | — | 30 | | |
| blending | having acid group | 47.7/19.0/1.3/32.0 (mass ratio) | | | | | | |
| | | CHMA/MAA/BzMA = | 24000 | — | — | 30 | | |
| | | 49/19/32 (mass ratio) | | | | | | |
| | | St/AA/AA-GMA = | 16000 | — | — | | 30 | 30 |
| | | 53.5/14.5/32 (mass ratio) | | | | | | |
| | | CHA/AA/HEA = | 40000 | — | — | | 30 | 30 |
| | | 53.5/14.5/32 (mass ratio) | | | | | | |
| | Compound β | Isoquinoline | | 4.69 | <10 | | | |
| | (in parentheses: | Quinoline | | 4.15 | <10 | | | |
| | molar ratio | Acridine | | 4.67 | 4900 | | | |
| | with respect to | 1-n-Butylisoquinoline | | 5.27 | <10 | | | |
| | carboxy group | 1-n-Butyl-4-methylisoquinoline | | 5.9 | <10 | | | |
| | of compound A | 1-Me-isoquinoline | | 5.31 | <10 | | 3.5 (20) | |
| | having acid group | 2,4,5,7-Tetramethylquinoline | | 6.23 | <10 | | | |
| | (mol %)) | 2-Methyl-4-methoxyquinoline | | 6.51 | <10 | | | |
| | | 9-Methylacridine | | 5.4 | 6300 | | | |
| | | 9-Phenylacridine | | 4.04 | >1000 | | | |
| | | Pyridine | | 5.25 | <10 | | | |
| | | 2,4-Dimethylquinoline | | 5.67 | <10 | 2.1 (10) | | 3.8 (20) |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.4 | 0.4 | 0.4 |
| | initiator | Oxe02 | | — | — | 0.4 | 0.4 | 0.4 |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation of | Carboxy group consumption rate | | | — | — | B | A | A |
| photosensitive | [measurement of ashing] | | | | | | | |
| material | ε365/ε313 | | | — | — | <1 | <1 | <1 |
| | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation of | Carboxy group consumption rate | | | — | — | B | A | A |
| transfer film | [measurement of ashing] | | | | | | | |
| | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

| | | | Example | | | | | | |
|---|---|---|---|---|---|---|---|---|---|
| Ninth table (13) | | | 7-207 | 7-208 | 7-209 | 7-210 | 7-211 | 7-212 | 7-213 |
| Solid content | Compound A | St/MAA/MMA/GMA-MAA = | | 60 | 60 | 60 | | | |
| blending | having acid group | 47.7/19.0/1.3/32.0 (mass ratio) | | | | | | | |
| | | CHMA/MAA/BzMA = | | | | | | | |
| | | 49/19/32 (mass ratio) | | | | | | | |
| | | St/AA/AA-GMA = | 30 | | | | | | |
| | | 53.5/14.5/32 (mass ratio) | | | | | | | |
| | | CHA/AA/HEA = | 30 | | | | 60 | 60 | 60 |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | | 1.9 (10) | 1.0 (5) | 1.0 (5) | 1.7 (10) | 0.8 (5) | 0.8 (5) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 1.9 (10) | 2.1 (10) | 3.1 (15) | 1.0 (5) | 1.9 (10) | 2.8 (15) | 0.9 (5) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.4 | 0.4 | 0.4 | 0.4 | 0.4 | 0.4 | 0.4 |
| | initiator | Oxe02 | 0.4 | 0.4 | 0.4 | 0.4 | 0.4 | 0.4 | 0.4 |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation of | Carboxy group consumption rate | | B | A | A | B | A | A | B |
| photosensitive | [measurement of ashing] | | | | | | | | |
| material | ε365/ε313 | | <1 | <1 | <1 | <1 | <1 | <1 | <1 |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation of | Carboxy group consumption rate | | B | A | A | B | A | A | B |
| transfer film | [measurement of ashing] | | | | | | | | |
| | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | | |
|---|---|---|---|---|---|---|---|---|---|
| Ninth table (13) | | | 7-214 | 7-215 | 7-216 | 7-217 | 7-218 | 7-219 | 7-220 |
| Solid content | Compound A | St/MAA/MMA/GMA-MAA = | 30 | 30 | 30 | | | | 30 |
| blending | having acid group | 47.7/19.0/1.3/32.0 (mass ratio) | | | | | | | |
| | | CHMA/MAA/BzMA = | 30 | 30 | 30 | | | | 30 |
| | | 49/19/32 (mass ratio) | | | | | | | |
| | | St/AA/AA-GMA = | | | | 30 | 30 | 30 | |
| | | 53.5/14.5/32 (mass ratio) | | | | | | | |
| | | CHA/AA/HEA = | | | | 30 | 30 | 30 | |
| | | 53.5/14.5/32 (mass ratio) | | | | | | | |
| | Compound β | Isoquinoline | | | | | | | |
| | (in parentheses: | Quinoline | | | | | | | |
| | molar ratio | Acridine | | | | | | | |
| | with respect to | 1-n-Butylisoquinoline | | | | | | | |
| | carboxy group | 1-n-Butyl-4-methylisoquinoline | | | | | | | |
| | of compound A | 1-Me-isoquinoline | 1.9 (10) | 1.0 (5) | 1.0 (5) | 1.7 (10) | 0.8 (5) | 0.8 (5) | 1.9 (10) |
| | having acid group | 2,4,5,7-Tetramethylquinoline | | | | | | | |
| | (mol %)) | 2-Methyl-4-methoxyquinoline | | | | | | | |
| | | 9-Methylacridine | | | | | | | |
| | | 9-Phenylacridine | | | | | | | |
| | | Pyridine | | | | | | | |
| | | 2,4-Dimethylquinoline | 2.1 (10) | 3.1 (15) | 1.0 (5) | 1.9 (10) | 2.8 (15) | 0.9 (5) | 2.1 (10) |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 21.0 | 21.0 | 21.0 | 21.0 | 21.0 | 14.0 | 14.0 |
| | | A-DCP | | | | | | | |
| | | TMPT | 21.0 | 21.0 | 21.0 | 21.0 | 21.0 | 14.0 | 14.0 |
| | | SR601 | | | | | | 14.0 | 14.0 |
| | | KRM8904 | | | | | | | |
| | | KRM8452 | | | | | | | |
| | Photopolymerization | Omn379 | 1.2 | 1.2 | 1.2 | 1.2 | 1.2 | 1.2 | 1.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |

| | | | | | | | | |
|---|---|---|---|---|---|---|---|---|
| Evaluation of | Carboxy group consumption rate | A | A | B | A | A | B | A |
| photosensitive | [measurement of ashing] | | | | | | | |
| material | ε365/ε313 | <1 | <1 | <1 | <1 | <1 | <1 | <1 |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation of | Carboxy group consumption rate | A | A | B | A | A | B | A |
| transfer film | [measurement of ashing] | | | | | | | |
| | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 63

| | | | Mw of | pKa of | | |
|---|---|---|---|---|---|---|
| | | | compound A | Compound β | ε365 of | Example |
| Ninth table (14) | | | having acid group | in ground state | Compound β | 7-221 |
| Solid content | Compound A | St/MAA/MMA/GMA-MAA = | 18000 | — | — | 30 |
| blending | having acid group | 47.7/19.0/1.3/32.0 (mass ratio) | | | | |
| | | CHMA/MAA/BzMA = | 24000 | — | — | 30 |
| | | 49/19/32 (mass ratio) | | | | |
| | | St/AA/AA-GMA = | 16000 | — | — | |
| | | 53.5/14.5/32 (mass ratio) | | | | |
| | | CHA/AA/HEA = | 40000 | — | — | |
| | | 53.5/14.5/32 (mass ratio) | | | | |
| | Compound β | Isoquinoline | | 4.69 | <10 | |
| | (in parentheses: | Quinoline | | 4.15 | <10 | |
| | molar ratio | Acridine | | 4.67 | 4900 | |
| | with respect to | 1-n-Butylisoquinoline | | 5.27 | <10 | |
| | carboxy group | 1-n-Butyl-4-methylisoquinoline | | 5.9 | <10 | |
| | of compound A | 1-Me-isoquinoline | | 5.31 | <10 | 1.0 (5) |
| | having acid group | 2,4,5,7-Tetramethylquinoline | | 6.23 | <10 | |
| | (mol %)) | 2-Methyl-4-methoxyquinoline | | 6.51 | <10 | |
| | | 9-Methylacridine | | 5.4 | 6300 | |
| | | 9-Phenylacridine | | 4.04 | >10000 | |
| | | Pyridine | | 5.25 | <10 | |
| | | 2,4-Dimethylquinoline | | 5.67 | <10 | 3.1 (15) |
| | | 4-Aminopyridine | | 9.20 | <100 | |
| | | 2-Chloropyridine | | 0.70 | <10 | |
| | Polymerizable | DPHA | | — | — | |
| | compound | A-NOD-N | | — | — | |
| | | DTMPT | | — | — | 14.0 |
| | | A-DCP | | — | — | |
| | | TMPT | | — | — | 14.0 |
| | | SR601 | | — | — | 14.0 |
| | | KRM8904 | | — | — | |
| | | KRM8452 | | — | — | |
| | Photopolymerization | Omn379 | | — | — | 1.8 |
| | initiator | Oxe02 | | — | — | |
| | | Api307 | | — | — | |
| | Surfactant | F551A | | — | — | 0.1 |
| | | R41 | | — | — | |
| | | 710FL | | — | — | |
| Evaluation of | Carboxy group consumption rate | | | — | — | A |
| photosensitive | [measurement of ashing] | | | | | |
| material | ε365/ε313 | | | — | — | <1 |
| | Pattern | 25 μm | | — | — | A |
| | formability | 50 μm | | — | — | A |
| | | 250 μm | | — | — | A |
| | Relative permittivity | | | — | — | A |
| | Change in relative permittivity | | | — | — | A |
| | before and after exposure | | | | | |
| Evaluation of | Carboxy group consumption rate | | | — | — | A |
| transfer film | [measurement of ashing] | | | | | |
| | ε365/ε313 | | | — | — | <1 |
| | Transmittance at 365 nm | | | — | — | A |
| | Transmittance at 365 nm/ | | | — | — | A |
| | transmittance at 313 nm | | | | | |
| | Laminate suitability | | | — | — | A |
| | Pattern | 25 μm | | — | — | A |
| | formability | 50 μm | | — | — | A |
| | | 250 μm | | — | — | A |

| | | | |
|---|---|---|---|
| Relative permittivity | — | — | A |
| Change in relative permittivity | — | — | A |
| before and after exposure | | | |
| Moisture permeability | — | — | A |
| Change in relative permittivity | — | — | A |
| after double exposure | | | |

| | | | | | | | Comparative |
|---|---|---|---|---|---|---|---|
| | | | Example | | | | Example |
| Ninth table (14) | | | 7-222 | 7-223 | 7-224 | 7-225 | 7A |
| Solid content | Compound A | St/MAA/MMA/GMA-MAA = | 30 | | | | 60 |
| blending | having acid group | 47.7/19.0/1.3/32.0 (mass ratio) | | | | | |
| | | CHMA/MAA/BzMA = | 30 | | | | |
| | | 49/19/32 (mass ratio) | | | | | |
| | | St/AA/AA-GMA = | | 30 | 30 | 30 | |
| | | 53.5/14.5/32 (mass ratio) | | | | | |
| | | CHA/AA/HEA = | | 30 | 30 | 30 | |
| | | 53.5/14.5/32 (mass ratio) | | | | | |
| | Compound β | Isoquinoline | | | | | |
| | (in parentheses: | Quinoline | | | | | |
| | molar ratio | Acridine | | | | | |
| | with respect to | 1-n-Butylisoquinoline | | | | | |
| | carboxy group | 1-n-Butyl-4-methylisoquinoline | | | | | |
| | of compound A | 1-Me-isoquinoline | 1.0 (5) | 1.7 (10) | 0.8 (5) | 0.8 (5) | |
| | having acid group | 2,4,5,7-Tetramethylquinoline | | | | | |
| | (mol %)) | 2-Methyl-4-methoxyquinoline | | | | | |
| | | 9-Methylacridine | | | | | |
| | | 9-Phenylacridine | | | | | |
| | | Pyridine | | | | | |
| | | 2,4-Dimethylquinoline | 1.0 (5) | 1.9 (10) | 2.8 (15) | 0.9 (5) | |
| | | 4-Aminopyridine | | | | | |
| | | 2-Chloropyridine | | | | | |
| | Polymerizable | DPHA | | | | | 12.6 |
| | compound | A-NOD-N | | | | | 25.0 |
| | | DTMPT | 14.0 | 14.0 | 14.0 | 14.0 | |
| | | A-DCP | | | | | |
| | | TMPT | 14.0 | 14.0 | 14.0 | 14.0 | |
| | | SR601 | 14.0 | 14.0 | 14.0 | 14.0 | |
| | | KRM8904 | | | | | |
| | | KRM8452 | | | | | |
| | Photopolymerization | Omn379 | 1.8 | 1.8 | 1.8 | 1.8 | 1.8 |
| | initiator | Oxe02 | | | | | |
| | | Api307 | | | | | |
| | Surfactant | F551A | 0.1 | 0.1 | 0.1 | 0.1 | 0.1 |
| | | R41 | | | | | |
| | | 710FL | | | | | |

| | | | | | | |
|---|---|---|---|---|---|---|
| Evaluation of | Carboxy group consumption rate [measurement | B | A | A | B | E |
| photosensitive | of ashing] | | | | | |
| material | ε365/ε313 | <1 | <1 | <1 | <1 | — |

| | | | | | | |
|---|---|---|---|---|---|---|
| Pattern | 25 μm | A | A | A | A | B |
| formability | 50 μm | A | A | A | A | B |
| | 250 μm | A | A | A | A | B |

| | | | | | | |
|---|---|---|---|---|---|---|
| | Relative permittivity | A | A | A | A | Standard |
| | Change in relative permittivity before and | A | A | A | A | D |
| | after exposure | | | | | |
| Evaluation of | Carboxy group consumption rate [measurement | B | A | A | B | E |
| transfer film | of ashing] | | | | | |
| | ε365/ε313 | <1 | <1 | <1 | <1 | — |
| | Transmittance at 365 nm | A | A | A | A | A |
| | Transmittance at 365 nm/transmittance at 313 nm | A | A | A | A | B |
| | Laminate suitability | A | A | A | A | A |

| | | | | | | |
|---|---|---|---|---|---|---|
| Pattern | 25 μm | A | A | A | A | B |
| formability | 50 μm | A | A | A | A | B |
| | 250 μm | A | A | A | A | B |

| | | | | | |
|---|---|---|---|---|---|
| Relative permittivity | A | A | A | A | Standard |
| Change in relative permittivity before and | A | A | A | A | D |
| after exposure | | | | | |
| Moisture permeability | A | A | A | A | Standard |
| Change in relative permittivity after | A | A | A | A | D |
| double exposure | | | | | |

(Compound A Having Acid Group)

Polymers 1 to 4 corresponding the compound A having an acid group were synthesized by the same method as in Example 4 system described above. Abbreviations for the monomer forming each structural unit of the polymers are as described above.

Polymer 1: St/MAA/MMA/GMA-MAA=47.7/19.0/1.3/32.0 (mass ratio)

Polymer 2: CHMA/MAA/BzMA=49/19/32 (mass ratio)

Polymer 3: St/AA/AA-GMA=53.5/14.5/32 (mass ratio)

Polymer 4: CHA/AA/HEA=53.5/14.5/32 (mass ratio)

As shown in Ninth table, the weight-average molecular weight of the compound A shown in Ninth table was in a range of 10,000 to 50,000.

(Polymerizable Compound)

DPHA: dipentaerythritol hexaacrylate (A-DPH manufactured by Shin-Nakamura Chemical Co., Ltd.)

A-NOD-N: 1,9-nonanediol diacrylate (A-NOD-N manufactured by Shin-Nakamura Chemical Co., Ltd.)

DTMPT: ditrimethylolpropane tetraacrylate (KAYARAD T-1420 (T) manufactured by Nippon Kayaku Co., Ltd.)

A-DCPP: dicyclopentane dimethanol diacrylate (A-DCP manufactured by Shin-Nakamura Chemical Co., Ltd.)

TMPT: trimethylolpropane triacrylate (A-TMPT manufactured by Shin-Nakamura Chemical Co., Ltd.)

SR601: ethoxylated (4) bisphenol A diacrylate (SR601 manufactured by TOMOE Engineering Co., Ltd.)

KRM8904: 9-functional aliphatic urethane acrylate (KRM8904 manufactured by Daicel-Allnex Ltd.)

KRM8452: 10-functional aliphatic urethane acrylate (KRM8452 manufactured by Daicel-Allnex Ltd.)

(Photopolymerization Initiator)

Omn379: Omnirad 379 (manufactured by IGM Resins B.V., alkylphenone-based compound)

Oxe02: Irgacure OXE02 (manufactured by BASF SE, oxime ester compound)

Api307: (1-(biphenyl-4-yl)-2-methyl-2-morpholinopropan-1-one (manufactured by Shenzhen UV-ChemTech Co., Ltd.)

(Surfactant)

F551: MEGAFACE F551 (manufactured by DIC Corporation)

R41: MEGAFACE R-41 (manufactured by DIC Corporation)

710FL: FTERGENT 710FL (manufactured by NEOS COMPANY LIMITED)

### Examples 201 to 218 and Comparative Example 201: Evaluation of Physical Properties of Compound β

For the compound β used in Examples 1 to 7 systems described above, volatilization resistance in the coating process during the formation of the photosensitive layer (residual rate in the photosensitive layer after the coating process) was evaluated by the following procedure.

<Preparation of Photosensitive Material>

Photosensitive materials of Examples 201 to 218 were prepared in the same manner as in the photosensitive material of Example 1-1 in Example 1 system described above, except that the compound β was changed to compounds exemplified below, and the blending amount of the compound β was set to 0.2 equivalent with respect to the molar amount of the carboxy group of the compound A.

In addition, a photosensitive material of Comparative Example 201 was prepared in the same manner as in the photosensitive material of Example 1-1 in Example 1 system described above, except that the 5,6,7,8-tetrahydroquinoline was not added.

<Evaluation of Photosensitive Material>

(Production of Photosensitive Layer)

The photosensitive material of each of Examples or Comparative Examples was spin-coated on 10×10 cm² glass (Eagle XG manufactured by Corning), and then the obtained coating film was dried using a hot plate at 80° C. to obtain a photosensitive layer having a film thickness of 5 μm.

The obtained photosensitive layer was evaluated as follows.

(Measurement of Residual Ratio of Compound β)

First, the following two types of samples were prepared.

(1) sample in which the photosensitive material was diluted 2-fold with deuterated acetone (sample A)

(2) sample obtained by scraping off approximately 5 mg of the obtained photosensitive layer and dissolving it in deuterated acetone (sample B)

Next, using AVANCE III manufactured by Bruker, ¹H-NMR (lock solvent: deuterated acetone, pulse program: zg30, number of integrations: 32 times) of each sample was measured, and based on a peak surface area of styrene and the compound β, a residual rate (%) of the compound β was calculated from the following expression (H).

Residual rate=(Content of compound β in sample A−Content of compound β in sample B)/content of compound β in sample A×100[%] Expression (H):

Next, the evaluation was performed based on the following evaluation standard.

The results are shown in Tenth table. In Tenth table shown below, the molecular weight of the compound β is also shown.

(Evaluation Standard)

A: residual rate was 85% or more.

B: residual rate was 60% or more and less than 85%.

C: residual rate was 20% or more and less than 60%.

D: residual rate was less than 20%.

TABLE 64

| | Compound β (decarboxylator)(blending amount: 0.2 eq.) | | |
|---|---|---|---|
| | | | Volatility |
| | | Molecular | in coating |
| Tenth table | Type | weight | process |
| Example 201 | Isoquinoline | 129 | C |
| Example 202 | Quinoline | 129 | C |
| Example 203 | Acridine | 179 | B |
| Example 204 | 1-Me-isoquinoline | 143 | B |
| Example 205 | 1-n-Butylisoquinoline | 185 | A |
| Example 206 | 1-n-Butyl-4-methylisoquinoline | 199 | A |
| Example 207 | 2,4-Dimethylquinoline | 157 | B |
| Example 208 | 2-Methyl-4-t-butyiquinoline | 199 | A |
| Example 209 | 2,4,5,7-Tetramethylquinoline | 185 | A |
| Example 210 | 2-Methyl-4-methoxyquinoline | 173 | B |
| Example 211 | 9-Methylacridine | 193 | A |
| Example 212 | 9-Phenylacridine | 255 | A |
| Example 213 | Pyridine | 79 | D |
| Example 214 | 5,6,7,8-Tetrahydroquinoline | 133 | B |
| Example 215 | 4-Acetylpyridine | 121 | C |
| Example 216 | 4-Benzoylpyridine | 183 | A |
| Example 217 | 4-Aminopyridine | 94 | D |
| Example 218 | 2-Chloropyridine | 114 | D |
| Comparative | None | — | — |
| Example 201 | | | |

From the results of Tenth table, in a case where the molecular weight of the compound β was 120 or more (preferably, a case of being 130 or more, and more preferably, a case of being 180 or more), it is clear that volatility in the coating process is low (residual rate of the compound β in the photosensitive layer after the coating process is high).

<Evaluation of Transfer Film>

(Production of Transfer Film)

To a polyethylene terephthalate film (manufactured by Toray Industries, Inc., 16KS40 (16QS62)) having a thickness of 16 μm (temporary support), the photosensitive material of each of Examples and Comparative Examples was applied using a slit-shaped nozzle such that a thickness after drying was adjusted to 5 μm, and the photosensitive material was dried at 100° C. for 2 minutes to form a photosensitive layer.

A polyethylene terephthalate film (manufactured by Toray Industries, Inc., 16KS40 (16QS62)) having a thickness of 16 μm (cover film) was pressure-bonded onto the obtained photosensitive layer to produce transfer films of Examples and Comparative Examples.

By peeling off the cover film from the transfer film produced above and laminating the transfer film on 10×10 cm² glass (Eagle XG manufactured by Corning), the photosensitive layer of the transfer film was transferred to a surface of the glass. Laminating conditions were that a temperature of a substrate for a touch panel was 40° C., a temperature of a rubber roller (that is, a laminating temperature) was 110° C., a linear pressure was 3 N/cm, and a transportation speed was 2 m/min.

Approximately 5 mg of the photosensitive layer in the obtained glass with the photosensitive layer was scraped off to produce a sample dissolved in deuterated acetone (sample C).

In a case where volatility of the compound β in the coating process (residual ratio of the compound β in the photosensitive layer after the coating process) was obtained by the same method according to (Measurement of residual rate of compound β) described above, except that the sample B was changed to the sample C, the results were the same as those shown in Tenth table described above.

### Example 1001 (Production and Evaluation of Device)

<Manufacturing of Transparent Laminate>

A substrate in which an ITO transparent electrode pattern and copper lead wire were formed on a cycloolefin transparent film was prepared.

Using the transfer film of Example 1-1 in Example 1 system from which the protective film was peeled off, the ITO transparent electrode pattern and the copper lead wire were laminated at a position covered by the transfer film. The laminating was performed using a vacuum laminator manufactured by MCK under conditions of a cycloolefin transparent film temperature: 40° C., a rubber roller temperature: 100° C., a linear pressure: 3 N/cm, and a transportation speed: 2 m/min.

Then, after the temporary support was peeled off, an exposure was performed in a patterned manner using an exposure mask (quartz exposure mask having a pattern for forming an overcoat) and a high-pressure mercury lamp. As the exposure condition, the integrated exposure amount measured with a 365 nm illuminance meter was 1000 mJ/cm².

After the exposure, the photosensitive layer of the laminate, from which the temporary support was peeled off, was developed for 40 seconds using a 1% by mass sodium carbonate aqueous solution (liquid temperature: 32° C.) as a developer.

Thereafter, the residue was removed by injecting ultrapure water from an ultrapure water washing nozzle onto the transparent film substrate after the development treatment. Subsequently, air was blown to remove water on the transparent film substrate to form a transparent laminate in which the ITO transparent electrode pattern, the copper lead wire, and the cured film were laminated in this order on the transparent film substrate.

Using the produced transparent laminate, a touch panel was produced by a known method. The produced touch panel was attached to a liquid crystal display element produced by a method described in paragraphs 0097 to 0119 of JP2009-47936A, thereby producing a liquid crystal display device equipped with a touch panel.

It was confirmed that all of the obtained liquid crystal display devices equipped with the touch panel had excellent display characteristics and operated without problems.

### Example 1002 (Production and Evaluation of Device)

A liquid crystal display device equipped with a touch panel was produced by the same method as in Example 1001, except that the above-described transfer film was changed to any of the transfer films of Examples other than Example 1-1 in Example 1 system described above or the transfer films of Examples in Example 2 system, Example 4 system, Example 5 system, and Example 6 system described above.

It was confirmed that all of the obtained liquid crystal display devices equipped with the touch panel had excellent display characteristics and operated without problems.

### Example 1003 (Production and Evaluation of Device)

<Manufacturing of Transparent Laminate>

A substrate in which an ITO transparent electrode pattern and copper lead wire were formed on a cycloolefin transparent film was prepared.

Using the transfer film of Examples in Example 3 system from which the protective film was peeled off, the ITO transparent electrode pattern and the copper lead wire were laminated at a position covered by the transfer film. The laminating was performed using a vacuum laminator manufactured by MCK under conditions of a cycloolefin transparent film temperature: 40° C., a rubber roller temperature: 100° C., a linear pressure: 3 N/cm, and a transportation speed: 2 m/min.

Thereafter, the temporary support of the obtained base material with a photosensitive layer was closely attached to an exposure mask (quartz exposure mask having a pattern for forming an overcoat), and using a proximity type exposure machine (Hitachi High-Technologies Corporation) equipped with an ultra-high pressure mercury lamp, an exposure was performed in a patterned manner through the temporary support through a filter which cuts wavelengths of 350 nm or less. As the exposure condition, the integrated exposure amount measured with a 365 nm illuminance meter was 80 mJ/cm².

After the exposure, the temporary support was peeled off, and the photosensitive layer of the laminate, from which the temporary support was peeled off, was developed for 40 seconds using a 1% by mass sodium carbonate aqueous solution (liquid temperature: 32° C.) as a developer.

Thereafter, the residue was removed by injecting ultrapure water from an ultrapure water washing nozzle onto the transparent film substrate after the development treatment. Subsequently, air was blown to remove water on the transparent film substrate.

Next, the formed pattern was subjected to a second exposure using a high-pressure mercury lamp.

In the second exposure using a high-pressure mercury lamp, the integrated exposure amount measured with a 365 nm illuminance meter was 1000 mJ/cm².

By the above-described procedure, a transparent laminate in which the ITO transparent electrode pattern, the copper lead wire, and the cured film were laminated in this order on the transparent film substrate was formed.

Using the produced transparent laminate, a touch panel was produced by a known method. The produced touch panel was attached to a liquid crystal display element produced by a method described in paragraphs 0097 to 0119 of JP2009-47936A, thereby producing a liquid crystal display device equipped with a touch panel.

It was confirmed that all of the obtained liquid crystal display devices equipped with the touch panel had excellent display characteristics and operated without problems.

### Example 1004 (Production and Evaluation of Device)

A liquid crystal display device equipped with a touch panel was produced by the same method as in Example 1003, except that the above-described transfer film was changed to the transfer film of Examples in Example 7 system described above.

It was confirmed that all of the obtained liquid crystal display devices equipped with the touch panel had excellent display characteristics and operated without problems.

### EXPLANATION OF REFERENCES

12: temporary support
14: photosensitive layer
16: cover film
100: transfer film

What is claimed is:

1. A photosensitive material comprising:
a compound A having a carboxy group,
wherein the compound A includes a polymer including a repeating unit derived from (meth)acrylic acid, and
a content of the carboxy group in a photosensitive layer which is formed from the photosensitive material is reduced by irradiation with an actinic ray or a radiation.

2. The photosensitive material according to claim 1,
wherein a weight-average molecular weight of the polymer is 50,000 or less.

3. The photosensitive material according to claim 1,
wherein any of the following requirement (V02) or the following requirement (W02) is satisfied,
requirement (V02): the photosensitive material includes the compound A and a compound β having a structure in which an amount of the carboxy group included in the compound A is reduced by an exposure,
requirement (W02): the photosensitive material includes the compound A, and the compound A includes a structure in which an amount of the carboxy group is reduced by an exposure.

4. The photosensitive material according to claim 3,
wherein, in the requirement (V02), the compound β is a compound B which has a structure capable of accepting an electron from the carboxy group included in the compound A in a photoexcited state, and
in the requirement (W02), the structure is a structure capable of accepting an electron from the carboxy group in a photoexcited state.

5. The photosensitive material according to claim 3,
wherein the requirement (V02) is satisfied,
the compound β is a compound B which has a structure capable of accepting an electron from the carboxy group included in the compound A in a photoexcited state, and
in the photosensitive material, a total number of structures capable of accepting the electron, which are included in the compound B, is 1 mol % or more with respect to a total number of carboxy groups included in the compound A.

6. The photosensitive material according to claim 3,
wherein a molar absorption coefficient E of the compound β at 365 nm is 1×10³ (cm·mol/L)⁻¹ or less.

7. The photosensitive material according to claim 3,
wherein a ratio of a molar absorption coefficient E of the compound β at 365 nm to a molar absorption coefficient ε′ of the compound β at 313 nm is 3 or less.

8. The photosensitive material according to claim 3,
wherein a pKa of the compound β in a ground state is 2.0 or more.

9. The photosensitive material according to claim 3,
wherein a pKa of the compound β in a ground state is 9.0 or less.

10. The photosensitive material according to claim 3,
wherein the compound β is an aromatic compound which may have a substituent.

11. The photosensitive material according to claim 10,
wherein the compound β is an aromatic compound having a substituent.

12. The photosensitive material according to claim 1,
wherein the content of the carboxy group in the photosensitive layer which is formed from the photosensitive material is reduced at a reduction rate of 5 mol % or more by the irradiation with the actinic ray or the radiation.

13. The photosensitive material according to claim 1,
wherein the carboxy group is decarboxylated by the irradiation with the actinic ray or the radiation.

14. The photosensitive material according to claim 1,
wherein a relative permittivity of the photosensitive layer which is formed from the photosensitive material is reduced by the irradiation with the actinic ray or the radiation.

15. The photosensitive material according to claim 5,
wherein the total number of structures capable of accepting the electron, which are included in the compound B, is 10 mol % or more to 200 mol % or less with respect to the total number of acid groups included in the compound A.

16. The photosensitive material according to claim 3,
wherein the requirement (V02) is satisfied, and
a content of the compound β in the photosensitive material is 8% to 30% by mass with respect to a total solid content of the photosensitive material.

17. The photosensitive material according to claim 3,
wherein the requirement (V02) is satisfied,
the compound β is a compound B which is an aromatic compound having a substituent, and has a structure capable of accepting an electron from the carboxy group included in the compound A in a photoexcited state,
a pKa of the compound β in a ground state is 2.0 or more to 9.0 or less, and
in the photosensitive material, a total number of structures capable of accepting the electron, which are included in the compound B, is 1 mol % or more with respect to a total number of carboxy groups included in the compound A.

18. A pattern forming method comprising:
forming a photosensitive layer on a base material by using the photosensitive material according to claim 1;
exposing the photosensitive layer in a patterned manner; and
developing the exposed photosensitive layer with a developer,
wherein, in a case where the developer is an organic solvent-based developer, the method further includes exposing the pattern formed by the development after developing.

19. A pattern forming method comprising, in the following order:
forming a photosensitive layer on a base material by using the photosensitive material according to claim 1;
exposing the photosensitive layer in a patterned manner;
developing the exposed photosensitive layer with an alkali developer to form a patterned photosensitive layer; and
exposing the patterned photosensitive layer.

20. A manufacturing method of a circuit wiring, comprising, in the following order:
forming a photosensitive layer on a base material having a conductive layer by using the photosensitive material according to claim 1;
exposing the photosensitive layer in a patterned manner;
developing the exposed photosensitive layer with an alkali developer to form a patterned photosensitive layer;
exposing the patterned photosensitive layer to form an etching resist film; and
etching the conductive layer in a region on which the etching resist film is not disposed.

21. A manufacturing method of a touch panel, comprising, in the following order:
forming a photosensitive layer on a base material having a conductive layer by using the photosensitive material according to claim 1;
exposing the photosensitive layer in a patterned manner;
developing the exposed photosensitive layer with an alkali developer to form a patterned photosensitive layer; and
exposing the patterned photosensitive layer to form a protective film or an insulating film of the conductive layer.
